(19) United States
(12) Patent Application Publication
(10) Pub. No.: US 2011/0318693 A1
(43) Pub. Date: Dec. 29, 2011

(54) ACTINIC-RAY- OR RADIATION-SENSITIVE RESIN COMPOSITION, AND RESIST FILM AND PATTERN FORMING METHOD USING THE SAME

(75) Inventors: Hidenori TAKAHASHI, Shizuoka (JP); Tomotaka TSUCHIMURA, Shizuoka (JP); Shuji HIRANO, Shizuoka (JP); Takeshi KAWABATA, Shizuoka (JP); Hideaki TSUBAKI, Shizuoka (JP)

(73) Assignee: FUJIFILM CORPORATION, Tokyo (JP)

(21) Appl. No.: 13/171,144

(22) Filed: Jun. 28, 2011

Related U.S. Application Data
(60) Provisional application No. 61/407,720, filed on Oct. 28, 2010.

(30) Foreign Application Priority Data
Jun. 29, 2010 (JP) 2010-148224
Oct. 18, 2010 (JP) 2010-233655

(51) Int. Cl. G03F 7/20; C08F 226/06; C08F 228/02

(52) U.S. Cl. 430/296; 430/325; 526/243

(57) ABSTRACT

An embodiment of the composition contains a resin (P) containing a repeating unit (A) that is configured to decompose when exposed to actinic rays or radiation to thereby generate an acid. The repeating unit (A) contains a cation structure with a monocyclic or polycyclic heterocycle containing a nitrogen atom.

### CROSS-REFERENCE TO RELATED APPLICATIONS

This application claims the benefit of U.S. Provisional Application No. 61/407,720, filed Oct. 28, 2010.

This application is based upon and claims the benefit of priority from prior Japanese Patent Applications No. 2010-148224, filed Jun. 29, 2010; and No. 2010-233655, filed Oct. 18, 2010, the entire contents of both of which are incorporated herein by reference.

### BACKGROUND OF THE INVENTION

1. Field of the Invention

The present invention relates to an actinic-ray- or radiation-sensitive resin composition, and a resist film and pattern forming method using the same. More specifically, the present invention relates to, for example, a composition employed in manufacturing ICs, photomasks, and the like which may be used for semiconductor production, a circuit board production process for a liquid crystal, a thermal head and the like and other photofabrication processes, and also relates to a method of forming a pattern with the use of the composition. Even more specifically, the present invention relates to a composition that is suitable when, for example, far-ultraviolet rays of wavelength 250 nm or shorter, an electron beam or soft X-rays are used as an exposure radiation source, and also relates to a method of forming a pattern with the use of the composition.

In the present invention, the terms “actinic rays” and “radiation” mean, for example, a mercury lamp bright line spectrum, far ultraviolet rays represented by an excimer laser, extreme ultraviolet rays, X-rays, electron beams and the like. In the present invention, the term “light” means actinic rays or radiation.

The expression “exposure” used herein, unless otherwise noted, means not only light irradiation using a mercury lamp, far ultraviolet, X-rays, EUV light, etc. but also lithography using particle beams, such as an electron beam and an ion beam.

2. Description of the Related Art

In recent years, the field of lithographic microfabrication of integrated circuits has seen increased demand for the achievement of ultrafine patterns of the order of tens of nanometers in order to realize high circuit density. This demand has led to a trend toward short-wavelength exposure—for example, from g-rays to i-rays and onward to KrF excimer laser light. At the same time, the development of lithography using an electron beam, X-rays or EUV light in addition to excimer laser light is also advancing.

In the case of microfabrication using a resist composition, not only is this being directly used in the manufacture of integrated circuits but, in recent years, has also been applied to the fabrication of so-called imprint mold structures, etc. (See, for example, patent references 1 and 2, and non-patent reference 1.)

Electron beam lithography in particular is now positioned as the next-generation or a future-generation pattern formation technology. Positive resists of high sensitivity and high resolution are needed for such lithography, increasing the sensitivity being an especially important matter with regard to reducing wafer processing time. However, increasing the sensitivity of positive resists to an electron beam is likely not only to reduce the resolving power but also to increase line edge roughness and degrade iso/dense bias. Thus, there is great demand for the development of resists in which none of these properties is compromised. Line edge roughness refers to the phenomenon wherein the edge at an interface of a resist pattern and substrate irregularly varies perpendicularly to the line because of the characteristics of the resist, so that viewed from above, the pattern edge appears uneven. This unevenness is transferred when etching using the resist as a mask, thereby causing poor electrical properties and hence poor yield. Especially in the ultrafine region of 0.25 μm or less, line edge roughness is now an extremely important area in which to achieve improvement. Iso/dense bias refers to the pattern dimension difference between an area of high resist pattern density and one of low resist pattern density. When this difference is great, the process margin is unfavorably narrow in the actual pattern formation. How to minimize this difference is an important aspect of resist technology development. Since there are trade-offs between high resolution, good pattern configuration, good line edge roughness and good iso/dense bias, how to achieve them all without compromise is a critical issue. This is also the case in lithography using X-rays or EUV light.

As a means for solving these problems, using a resin containing a photoacid generator in its polymer side chain is being studied (see, for example, patent references 3 and 4). Patent reference 3 discloses a resin containing in its molecule both a photoacid generating group and a group whose solubility in an alkali developer is increased by acid decomposition. Patent reference 4 discloses a resin containing a photoacid generator with specified structure in its polymer side chain.

### CITATION LIST

### Patent Reference

[Patent reference 1] Jpn. Pat. Appln. KOKAI Publication No. (hereinafter referred to as JP-A-) 2004-158287,
[Patent reference 2] JP-A-2008-162101,
[Patent reference 3] JP-A-2009-93137, and
[Patent reference 4] JP-A-2008-133448.

### Non-Patent Reference

[Non-patent reference 1] “Fundamentals of nanoimprint and its technology development/application deployment—technology of nanoimprint substrate and its latest technology deployment” edited by Yoshihiko Hirai, published by Frontier Publishing (issued in June, 2006).

### BRIEF SUMMARY OF THE INVENTION

It is an object of the present invention to provide an actinic-ray- or radiation-sensitive resin composition that can simultaneously satisfy the requirements for high sensitivity, high resolution, desirable pattern configuration, and desirable line edge roughness (LER), and to provide a resist film and pattern forming method using the same.

Followings are some aspects of the present invention.

[1] An actinic-ray- or radiation-sensitive resin composition comprising a resin (P) containing a repeating unit (A) that is configured to decompose when exposed to actinic rays or radiation to thereby generate an acid, the repeating unit (A) containing a cation structure with a monocyclic or polycyclic heterocycle containing a nitrogen atom.

[2] The composition according to [1], wherein the cation structure contains an azinium cation.

[3] The composition according to [1] or [2], wherein the cation structure is represented by any of general formula (AZ) below.

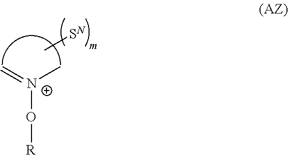

wherein

R represents a monovalent substituent,

the moiety:

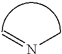

represents a monocyclic or polycyclic heterocycle containing a nitrogen atom,

S^{N} represents a substituent, and

m is an integer of 0 or greater.

[4] The composition according to any of [1] to [3], wherein the resin (P) further contains a repeating unit (B) that is configured to decompose when acted on by an acid to thereby generate an alkali-soluble group.

[5] The composition according to any of [1] to [4], wherein the resin (P) further contains a repeating unit represented by any of general formula (IV) below

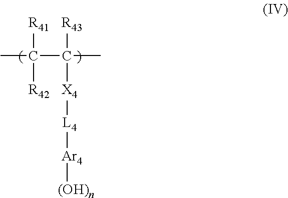

In the formula,

each of R₄₁, R₄₂ and R₄₃ independently represents a hydrogen atom, an alkyl group, a cycloalkyl group, a halogen atom, a cyano group or an alkoxycarbonyl group, provided that R₄₂ may be bonded to Ar₄ to thereby form a ring (preferably a 5- or 6-membered ring), which R₄₂ in this instance is an alkylene group.

X₄ represents a single bond, —COO—, or —CONR₆₄— in which R₆₄ represents a hydrogen atom or an alkyl group.

L₄ represents a single bond or an alkylene group.

Ar₄ represents a bivalent aromatic ring group; and

n is an integer of 1 to 4.

[6] The composition according to any of [1] to [5], wherein the repeating unit (A) is configured to decompose when exposed to actinic rays or radiation to thereby generate an acid group in a side chain of the resin (P).

[7] The composition any of [1] to [6], which is to be used as a positive resist composition.

[8] The composition according to any of [1] to [7], which is to be exposed to electron beams, X-rays or soft X-rays.

[9] A resist film formed from the composition according to any of [1] to [8].

[10] A method of forming a pattern, comprising:

forming the composition according to any of [1] to [8] into a film,

exposing the film to light, and

developing the exposed film.

[11] The method according to [10], wherein the exposure is performed using electron beams, X-rays or soft X-rays.

### DETAILED DESCRIPTION OF THE INVENTION

The embodiments of the present invention will be described in detail below.

Note that, with respect to the expression of a group (or an atomic group) used in this specification, the expression without explicitly referring to whether the group is substituted or unsubstituted encompasses not only groups with no substituents but also groups having one or more substituents. For example, the expression “alkyl group” encompasses not only alkyl groups having no substituents (viz. unsubstituted alkyl groups) but also alkyl groups having one or more substituents (viz. substituted alkyl groups).

The actinic-ray- or radiation-sensitive resin composition according to the present invention is typically used as a positive resist composition.

The composition comprises a resin (P). The resin (P) contains a repeating unit (A) that is configured to decompose when exposed to actinic rays or radiation to thereby generate an acid.

[Repeating Unit (A)]

The repeating unit (A) contains a cation structure with a monocyclic or polycyclic heterocycle containing a nitrogen atom. As the repeating unit (A), use can be made of any units being configured to decompose when exposed to actinic rays or radiation to thereby generate an acid and containing the above-mentioned cation structure. Employing such resin (P) containing the repeating unit (A) makes it feasible to simultaneously satisfy the requirements for high sensitivity, high resolution, desirable pattern configuration, and desirable line edge roughness.

The cation structure preferably contains an azinium cation. Employing such embodiment makes it feasible to simultaneously satisfy the requirements for high sensitivity, high resolution, desirable pattern configuration, and desirable line edge roughness at higher level.

The “azinium” used herein means (1) a structure containing azine ring (six-membered ring containing a nitrogen atom) such as a pyridinium, diazinium and triazinium; or (2) a structure containing azine ring and one or more aromatic rings condensed therewith, such as quinolinium, isoquinolinium, benzoazinium and naphthoazinium.

The cation structure is also preferable to be represented by general formula (AZ) below. Employing such embodiment also makes it feasible to simultaneously satisfy the requirements for high sensitivity, high resolution, desirable pattern configuration, and desirable line edge roughness at higher level. Note that the cation represented by general formula (AZ) below may or may not be the azinium cation.

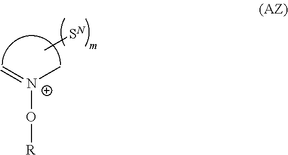

wherein R represents a monovalent substituent,

the moiety:

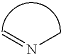

represents a monocyclic or polycyclic heterocycle containing a nitrogen atom,

S^{N} represents a substituent,

m is an integer of 0 or greater.

The substituent represented by R may be an organic group or an inorganic group. As this substituent, there can be mentioned, for example, an alkyl group, a cycloalkyl group, an aryl group, an alkenyl group, an alkynyl group, a substituted carbonyl group or a substituted sulfonyl group. A further substituent may be introduced in these substituent groups.

The alkyl group represented by R may be in the form of a linear or branched chain. This alkyl group preferably has 1 to 50 carbon atoms, more preferably 1 to 30 carbon atoms and further more preferably 1 to 20 carbon atoms. As such an alkyl group, there can be mentioned, for example, a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group or a 2-ethylhexyl group.

A substituent may be introduced in the alkyl group represented by R. Namely, R may be a substituted alkyl group. As such a substituted alkyl group, there can be mentioned, for example, a trifluoromethyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group, a 3-nitrophenacyl group, a chloromethyl group, a bromomethyl group, a 2-chloroethyl group, a methoxymethyl group, a methoxycarbonylmethyl group, an isopropoxymethyl group, a butoxymethyl group, an s-butoxybutyl group, a methoxyethoxyethyl group, an allyloxymethyl group, a phenoxymethyl group, an acetyloxymethyl group, a methylthiomethyl group, a tolylthiomethyl group, a pyridylmethyl group, a tetramethylpiperidinylmethyl group, an N-acetyltetramethylpiperidinylmethyl group, a trimethylsilylmethyl group, a methoxyethyl group, an ethylaminoethyl group, a diethylaminopropyl group, a morpholinopropyl group, a benzoyloxymethyl group, an N-cyclohexylcarbamoyloxyethyl group, an N-phenylcarbamoyloxyethyl group, an acetylaminoethyl group, an N-methylbenzoylaminopropyl group, a 2-oxoethyl group, a 2-oxopropyl group, a carboxypropyl group, a methoxycarbonylethyl group, an allyloxycarbonylbutyl group, a chlorophenoxycarbonylmethyl group, a carbamoylmethyl group, an N-methylcarbamoylethyl group, an N,N-dipropylcarbamoylmethyl group, an N-(methoxyphenyl)carbamoylethyl group, an N-methyl-N-(sulfophenyl)carbamoylmethyl group, a sulfobutyl group, a sulfonatobutyl group, a sulfamoylbutyl group, an N-ethylsulfamoylmethyl group, an N,N-dipropylsulfamoylpropyl group, an N-tolylsulfamoylpropyl group, an N-methyl-N-(phosphonophenyl)sulfamoyloctyl group, a phosphonobutyl group, a phosphonatohexyl group, a diethylphosphonobutyl group, a diphenylphosphonopropyl group, a methylphosphonobutyl group, a methylphosphonatobutyl group, a tolylphosphonohexyl group, a tolylphosphonatohexyl group, a phosphonooxypropyl group, a phosphonatooxybutyl group, a benzyl group, a phenethyl group, an α-methylbenzyl group, a 1-methyl-1-phenylethyl group or a p-methylbenzyl group.

As substituents that can be introduced in the alkyl groups represented by R, there can be mentioned, for example, not only the substituents set forth above in the description of substituted alkyl groups but also monovalent substituents composed of nonmetallic atoms whose examples are given below. As preferred examples containing these substituents, there can be mentioned a halogen atom (—F, —Br, —CI or —I), a hydroxyl group, an alkoxy group, an aryloxy group, a mercapto group, an alkylthio group, an arylthio group, an amino group, an acyloxy group, a carbamoyloxy group, an alkylsulfoxy group, an arylsulfoxy group, an acylthio group, an acylamino group, a ureido group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, a carboxyl group, a carbamoyl group, an alkylsulfinyl group, an arylsulfinyl group, an alkylsulfonyl group, an arylsulfonyl group, a sulfo group (—SO₃H) or its conjugated base group (referred to as a sulfonato group), an alkoxysulfonyl group, an aryloxysulfonyl group, a sulfinamoyl group, a phosphono group (—PO₃H₂) or its conjugated base group (referred to as a phosphonato group), a phosphonooxy group (—OPO₃H₂) or its conjugated base group (referred to as a phosphonatooxy group), a cyano group, a nitro group, an aryl group, an alkenyl group, an alkynyl group, a heterocyclic group and a silyl group.

As specific examples of the aryl groups that can be contained in the substituents that can be introduced in the alkyl groups represented by R, there can be mentioned a phenyl group, a biphenyl group, a naphthyl group, a tolyl group, a xylyl group, a mesityl group and a cumenyl group.

The cycloalkyl group represented by R may be monocyclic or polycyclic. This cycloalkyl group preferably has 3 to 50 carbon atoms, more preferably 4 to 30 carbon atoms and further more preferably 5 to 20 carbon atoms. As the cycloalkyl group, there can be mentioned, for example, a cyclopentyl group, a cyclohexyl group, an adamantyl group or a norbornyl group.

A further substituent may be introduced in the cycloalkyl group represented by R. As the further substituent, there can be mentioned, for example, any of those mentioned above as the substituents that can be introduced in the alkyl groups.

The aryl group represented by R may be monocyclic or polycyclic. This aryl group may be a heteroaryl group. The aryl group represented by R preferably has 6 to 50 carbon atoms, more preferably 6 to 30 carbon atoms and further more preferably 6 to 20 carbon atoms. As the aryl group, there can be mentioned, for example, a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quaterphenyl group, an o-, m- or p-tolyl group, a xylyl group, an o-, m- or p-cumenyl group, a mesityl group, a pentalenyl group, a binaphthalenyl group, a ternaphthalenyl group, a quaternaphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quateranthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group or an ovalenyl group.

A further substituent may be introduced in the aryl group represented by R. As the further substituent, there can be mentioned, for example, any of those mentioned above as the substituents that can be introduced in the alkyl groups.

The alkenyl group represented by R may be in the form of a linear or branched chain. This alkenyl group preferably has 2 to 50 carbon atoms, more preferably 2 to 30 carbon atoms and further more preferably 3 to 20 carbon atoms. A further substituent may be introduced in the alkenyl group.

As such an alkenyl group, there can be mentioned, for example, a vinyl group, an allyl group or a styryl group. As the further substituent that can be introduced in the alkenyl group, there can be mentioned, for example, any of those mentioned above as the substituents can be introduced in the alkyl groups.

The alkynyl group represented by R may be in the form of a linear or branched chain. This alkynyl group preferably has 2 to 50 carbon atoms, more preferably 2 to 30 carbon atoms and further more preferably 3 to 20 carbon atoms. A further substituent may be introduced in the alkynyl group.

As such an alkynyl group, there can be mentioned, for example, an ethynyl group, a propynyl group or a propargyl group. As the further substituent that can be introduced in the alkynyl group, there can be mentioned, for example, any of those mentioned above as the substituents can be introduced in the alkyl groups.

The substituted carbonyl group represented by R is any of the groups of general formula: —CO—R⁰¹³. R⁰¹³ represents a group composed of a monovalent nonmetallic atomic group.

As the substituted carbonyl group, there can be mentioned, for example, a formyl group, an acyl group, a carboxyl group, an alkoxycarbonyl group, an aryloxycarbonyl group or a carbamoyl group. As the alkyl group and aryl group contained in these groups, there can be mentioned, for example, those set forth above as the groups represented by R.

The substituted sulfonyl group represented by R is any of the groups of general formula: —SO₂—R⁰¹¹. R⁰¹¹ represents a group composed of a monovalent nonmetallic atomic group.

As the substituted sulfonyl group, there can be mentioned, for example, an alkylsulfonyl group, an arylsulfonyl group or a sulfamoyl group. The sulfamoyl group may be substituted or unsubstituted. As the alkyl group and aryl group contained in these groups, there can be mentioned, for example, those set forth above as the groups represented by R.

The heterocycle containing a nitrogen atom appearing in general formula (AZ) may be an aromatic ring or a nonaromatic ring. This heterocycle may further contain a heteroatom, such as a nitrogen atom, an oxygen atom or a sulfur atom, other than the nitrogen atom of the formula. Moreover, this heterocycle may be monocyclic or polycyclic as mentioned above.

As such a heterocycle, there can be mentioned, for example, an imidazole ring, a pyridine ring, a pyrazine ring, a pyrimidine ring, a pyridazine ring, a 2H-pyrrole ring, a 3H-indole ring, a 1H-indazole ring, a purine ring, an isoquinoline ring, a 4H-quinolizine ring, a quinoline ring, a phthalazine ring, a naphthyridine ring, a quinoxaline ring, a quinazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isooxazole ring or a benzothiazole ring. Among these rings, a pyridine ring and a quinoline ring are especially preferred.

As mentioned above, S^{N} represents a substituent. As the substituent, there can be mentioned, for example, any of those set forth above in connection with R. A further substituent may be introduced in this substituent.

As mentioned above, m is an integer of 0 or greater. The upper limit of m is equal to the number of atoms that can be substituted with a substituent among the atoms constituting the heterocycle.

The cation represented by general formula (AZ) above are preferably expressed by general formula (AZ-1) or (AZ-2) below. Namely, the heterocycle containing a nitrogen atom appearing in general formula (AZ) preferably contains a 6-membered ring or a 5-membered ring.

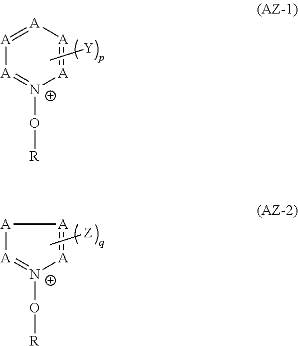

In the formula,

each of A's independently represents a carbon atom, a nitrogen atom, an oxygen atom or a sulfur atom.

Y, or each of Y's independently, represents a substituent. At least two of Y's may be bonded to each other to thereby form a ring, and p is an integer of 0 to 5.

Z, or each of Z's independently, represents a substituent. At least two of Z's may be bonded to each other to thereby form a ring, and q is an integer of 0 to 4.

R is as defined above in connection with general formula (AZ).

In both of general formulae (AZ-1) and (AZ-2), the number of A's each representing a nitrogen atom, an oxygen atom or a sulfur atom among all the A's is preferably in the range of 0 to 2, more preferably 0 or 1.

As particular examples of Y's and Z's, there can be mentioned those set forth above in connection with SN of general formula (AZ). At least two of Y's, or Z's, may be bonded to each other to thereby form a ring. Namely, each of the compounds of general formula (AZ-1) or (AZ-2) may have a condensed-ring structure.

The ring formed by the mutual bonding of Y's, or Z's may be an aromatic ring or a nonaromatic ring. This ring may be a heterocycle containing a heteroatom. The ring formed by the mutual bonding of Y's, or Z's is preferably a 5- to 7-membered ring, more preferably a 5- or 6-membered ring and most preferably a 6-membered ring.

Further, a substituent may be introduced in the ring formed by the mutual bonding of Y's or Z's. As the substituent, there can be mentioned, for example, any of those set forth above in connection with S^{N} of general formula (AZ).

When at least one of A's is a nitrogen atom, an oxygen atom or a sulfur atom, more preferably, the compounds of general formula (AZ-1) are expressed by general formula (AZ-1A) or (AZ-1B) below.

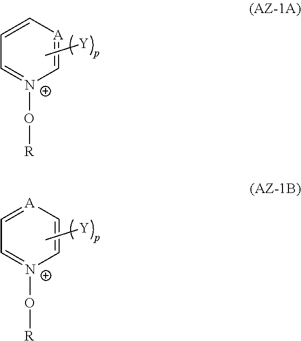

In general formulae (AZ-1A) and (AZ-1B), A represents a nitrogen atom, an oxygen atom or a sulfur atom. Y, p and R are as defined above in connection with general formula (AZ-1).

When at least one of A's is a nitrogen atom, an oxygen atom or a sulfur atom, more preferably, the compounds of general formula (AZ-2) are expressed by general formula (AZ-2A) below.

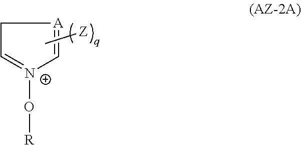

In general formula (AZ-2A), A represents a nitrogen atom, an oxygen atom or a sulfur atom. Z, q and R are as defined above in connection with general formula (AZ-2).

Specific examples of the cation structure with a monocyclic or polycyclic heterocycle containing a nitrogen atom will be shown below.

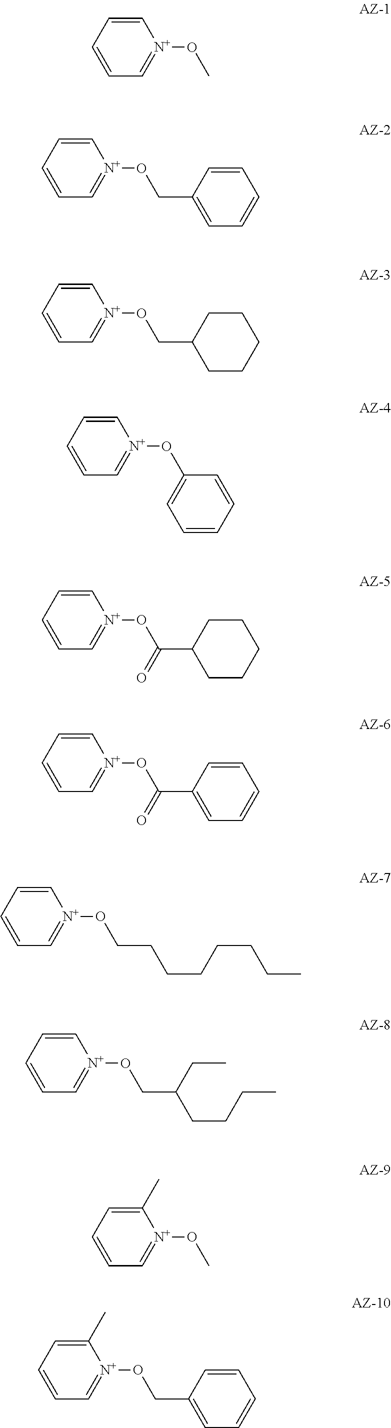

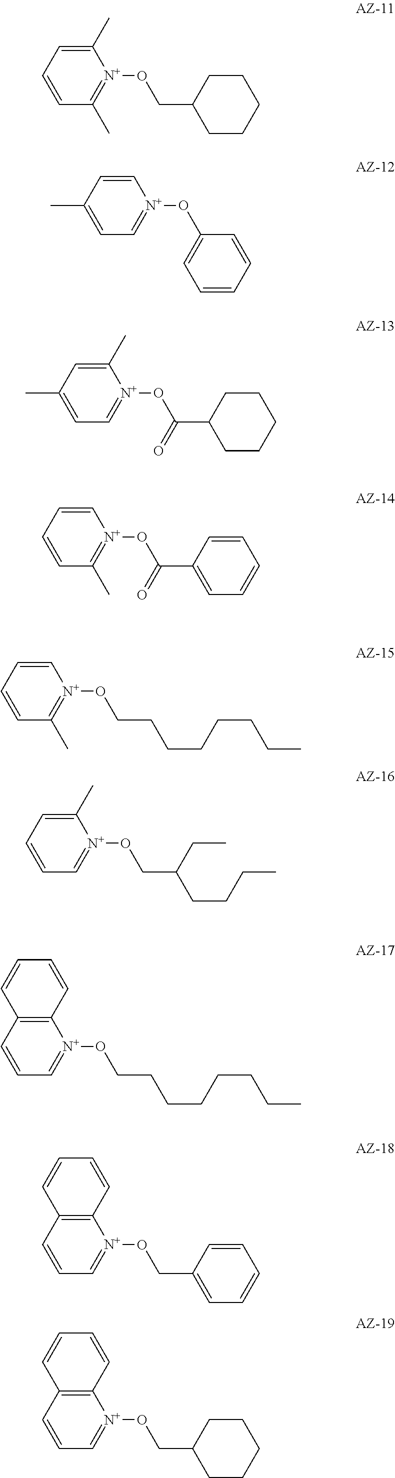

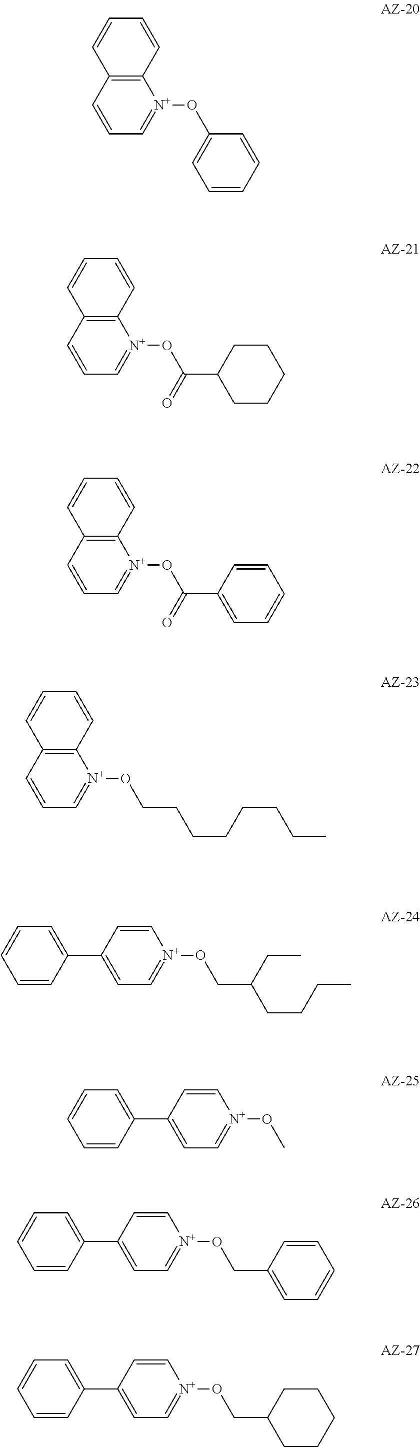

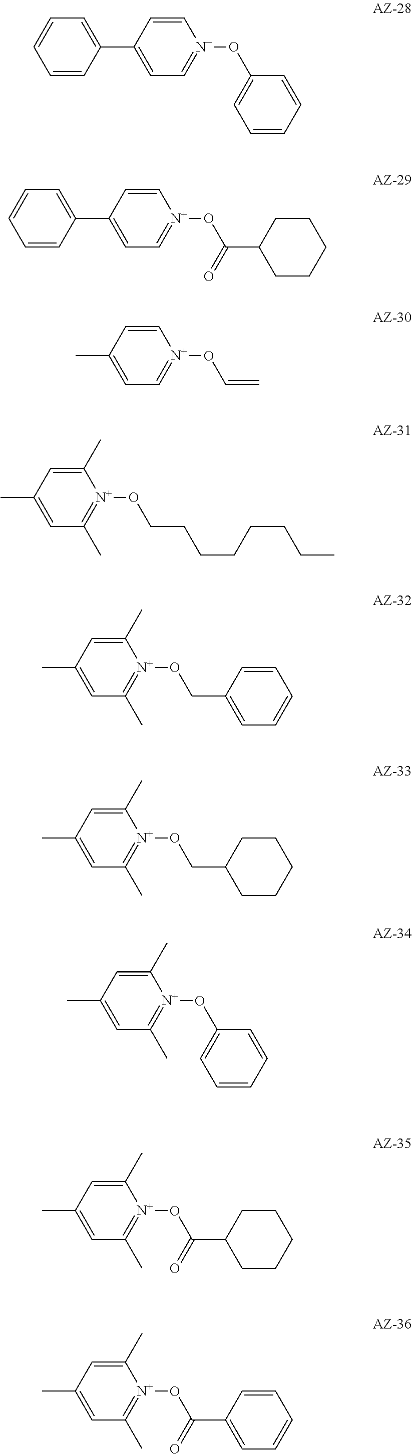

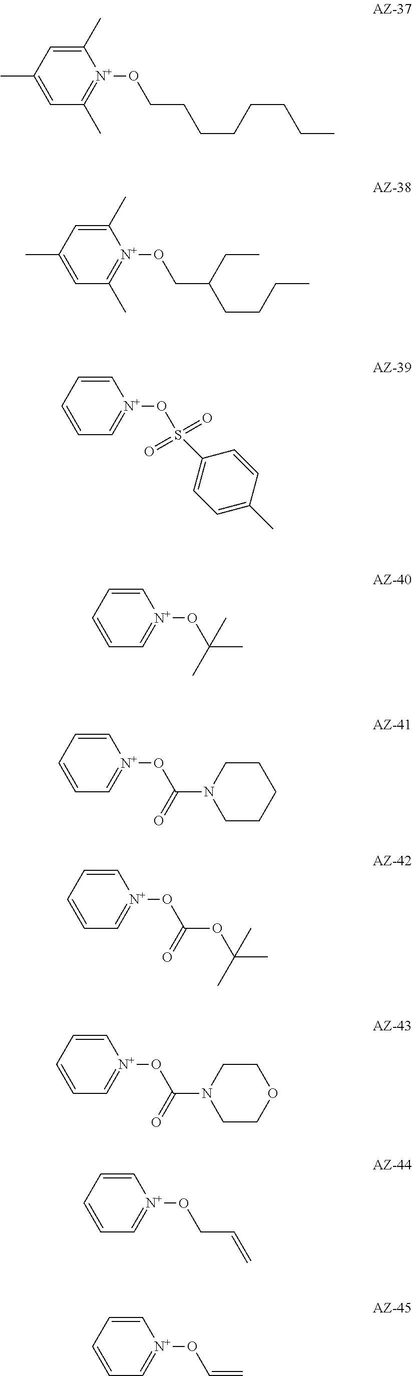

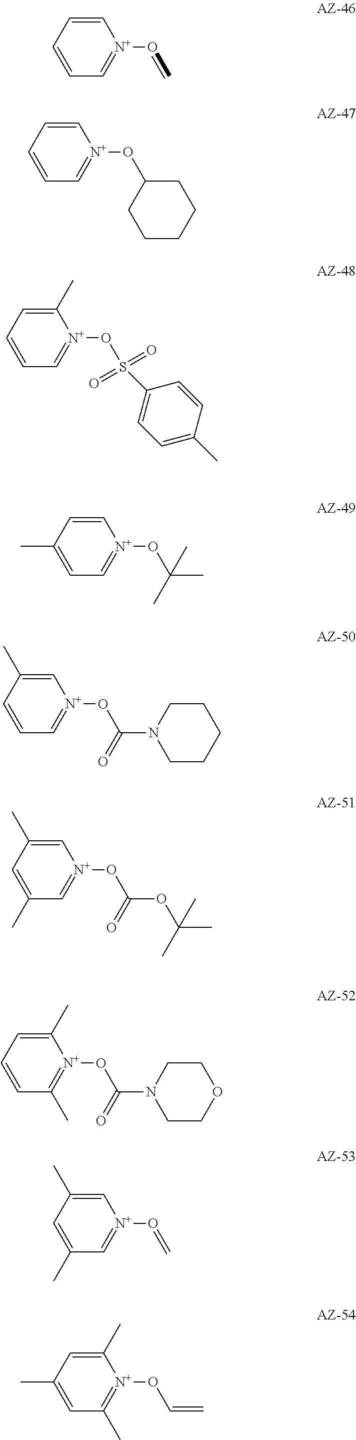

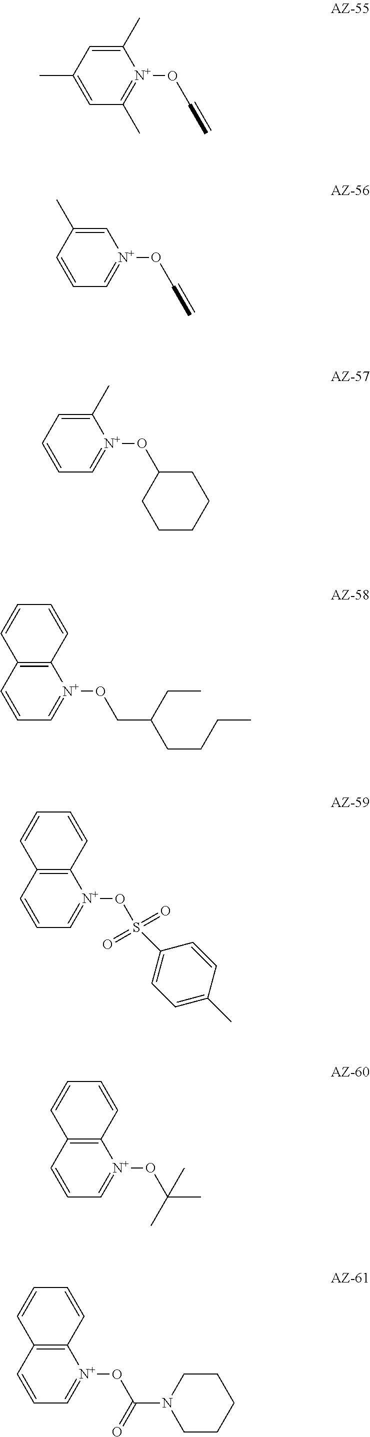

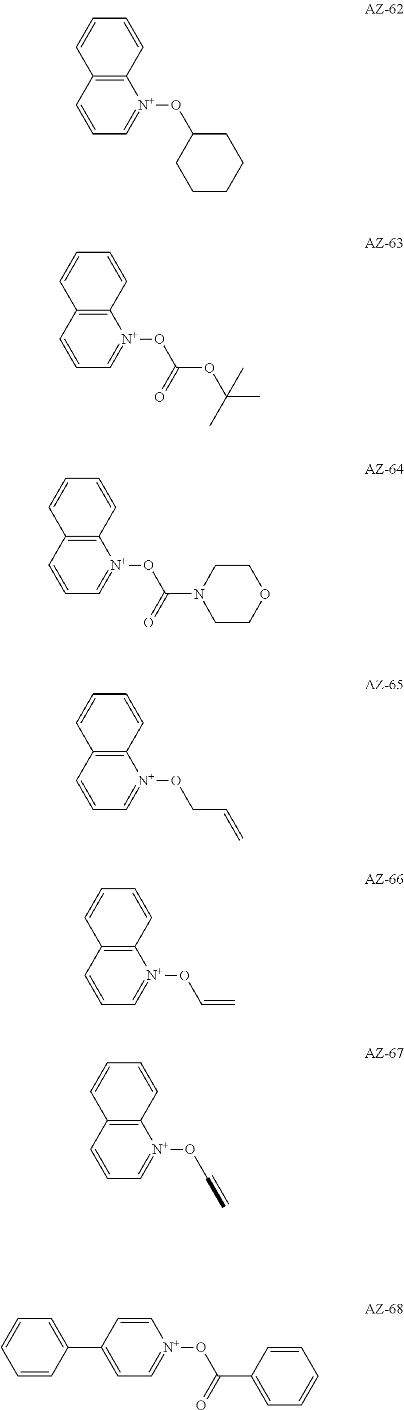

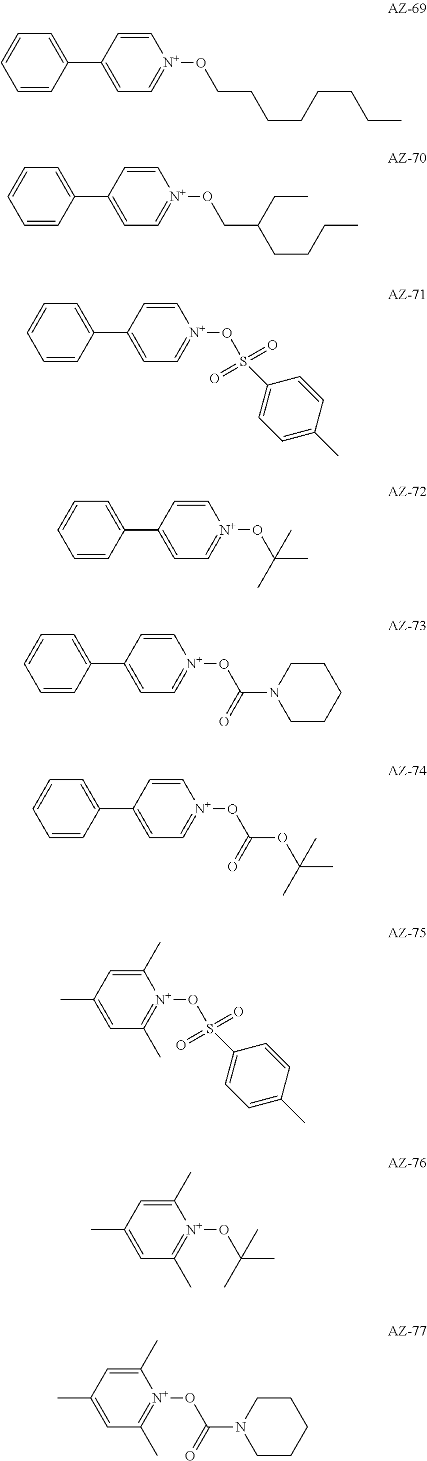

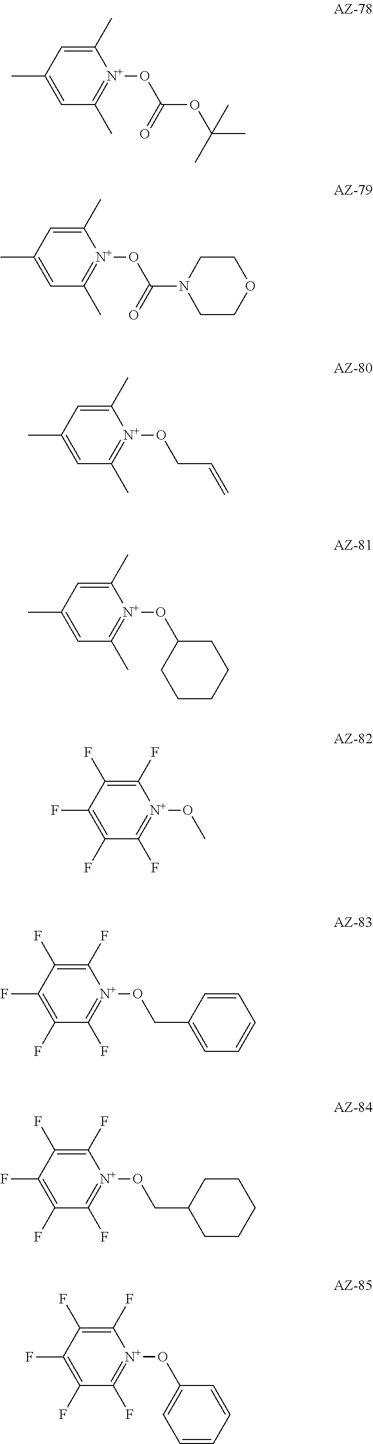

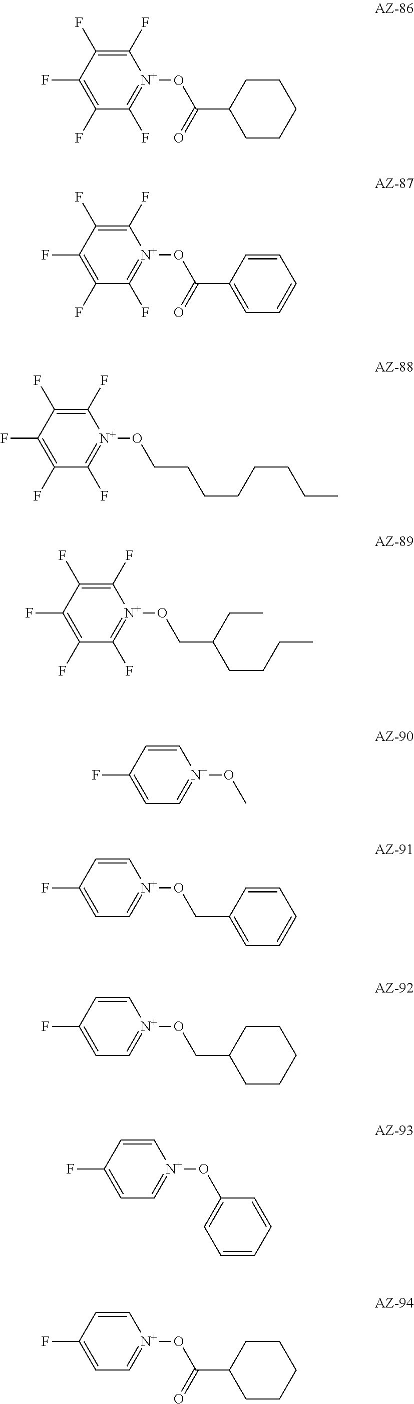

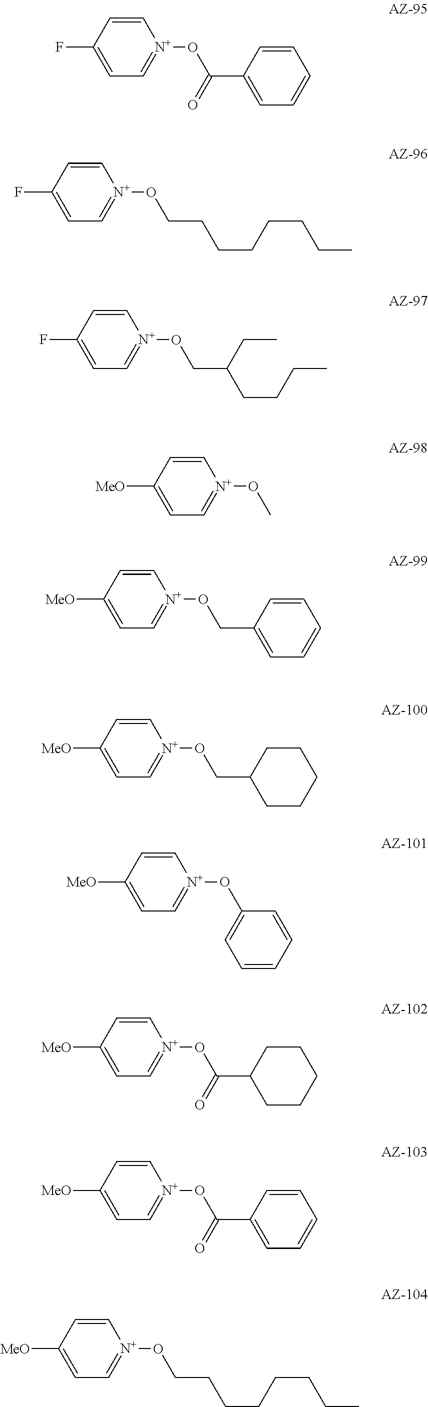

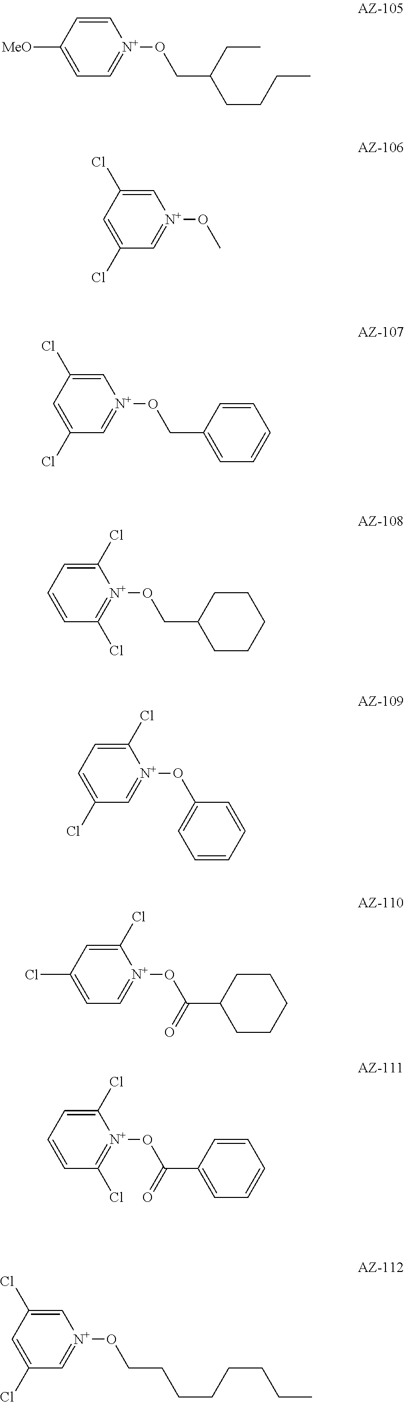

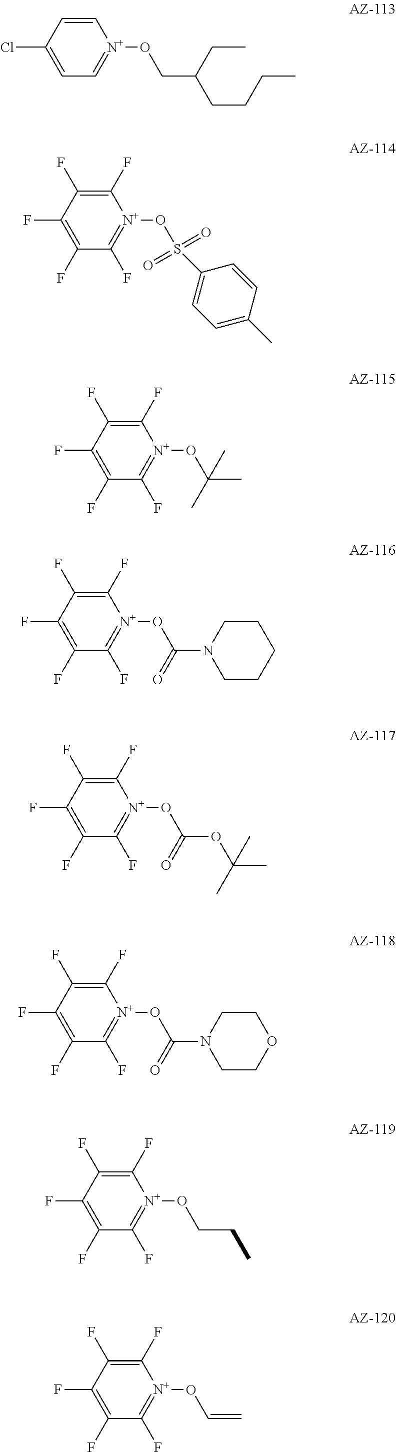

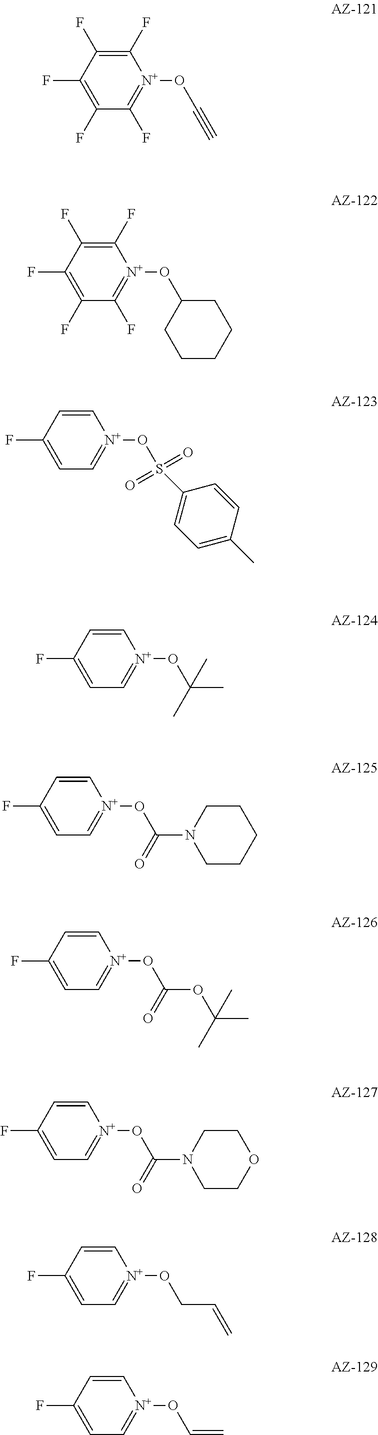

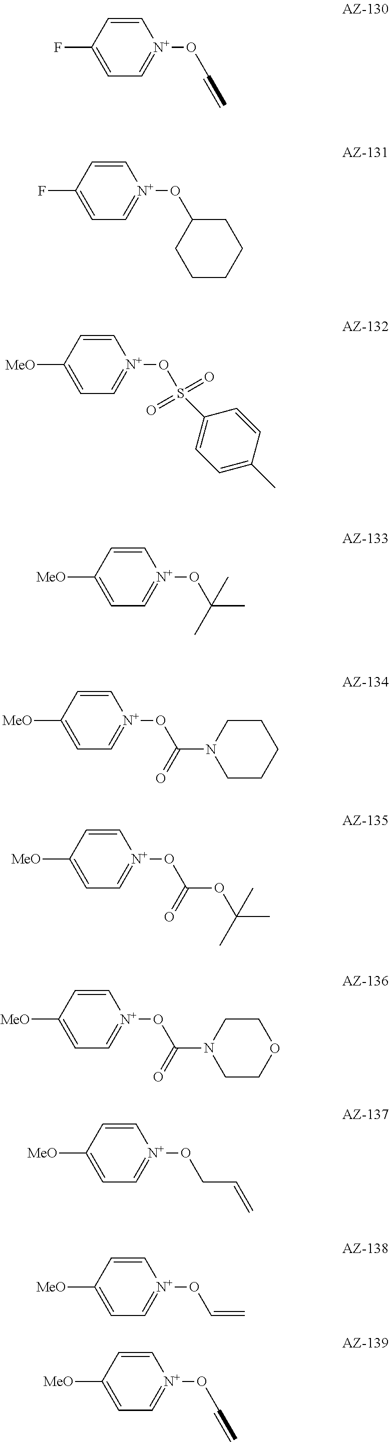

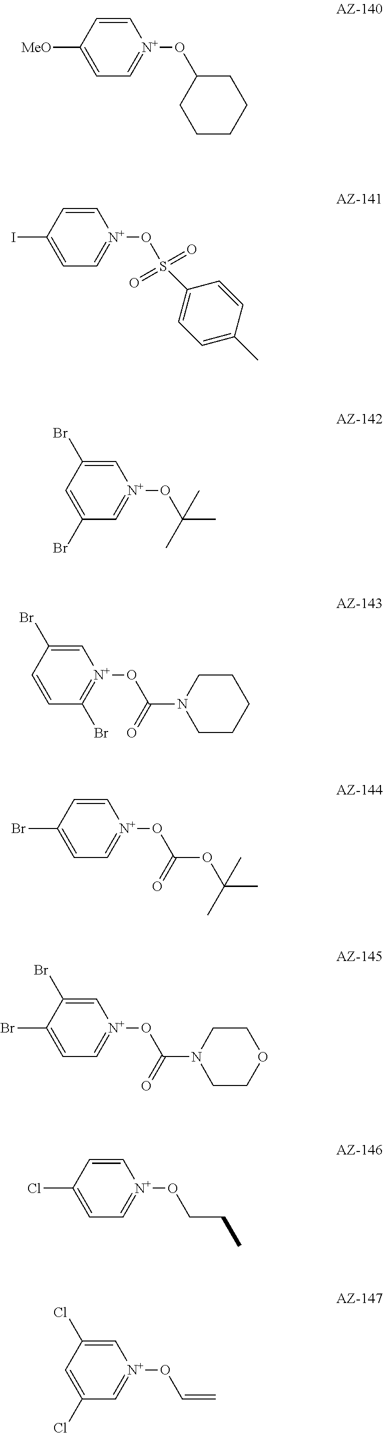

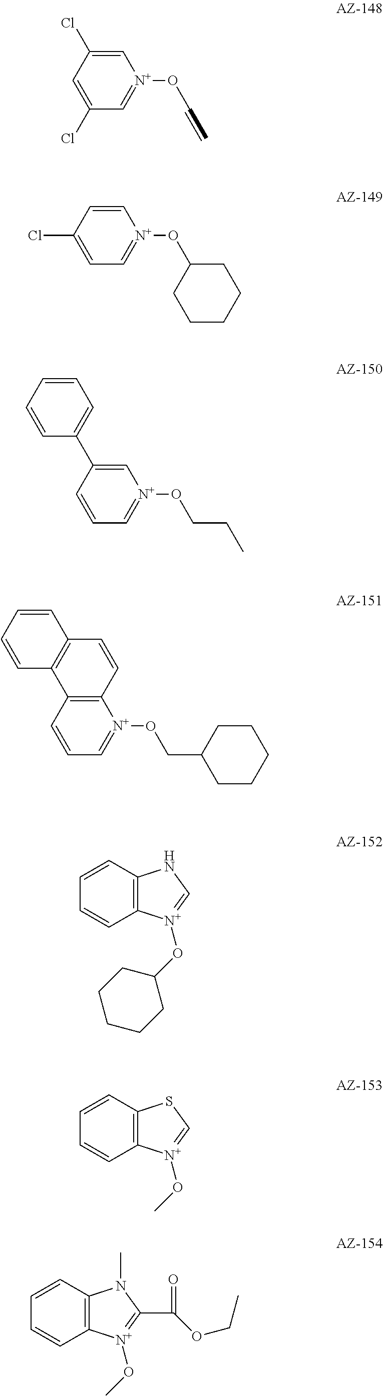

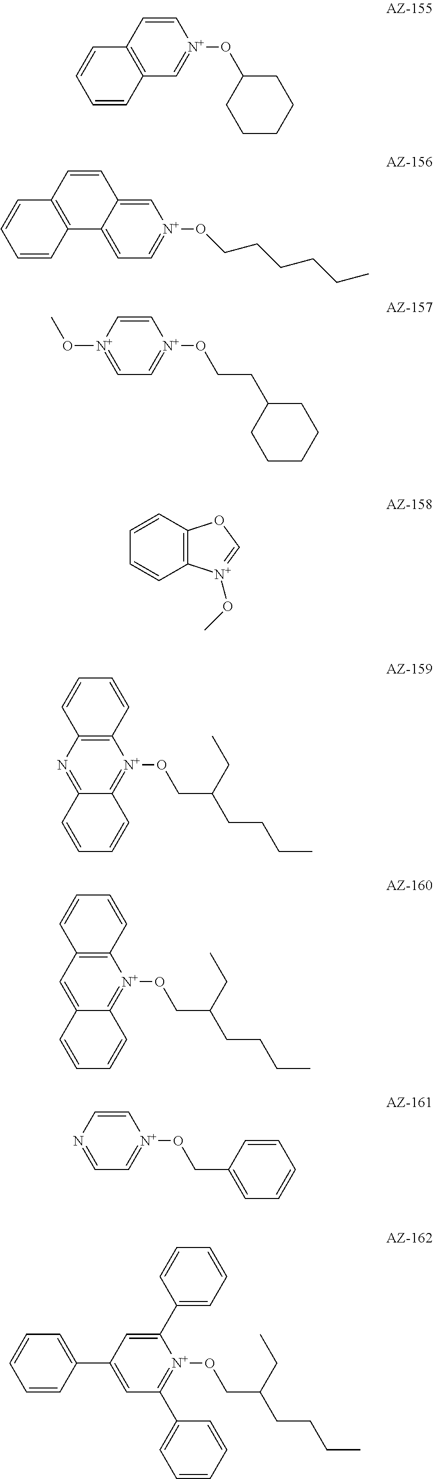

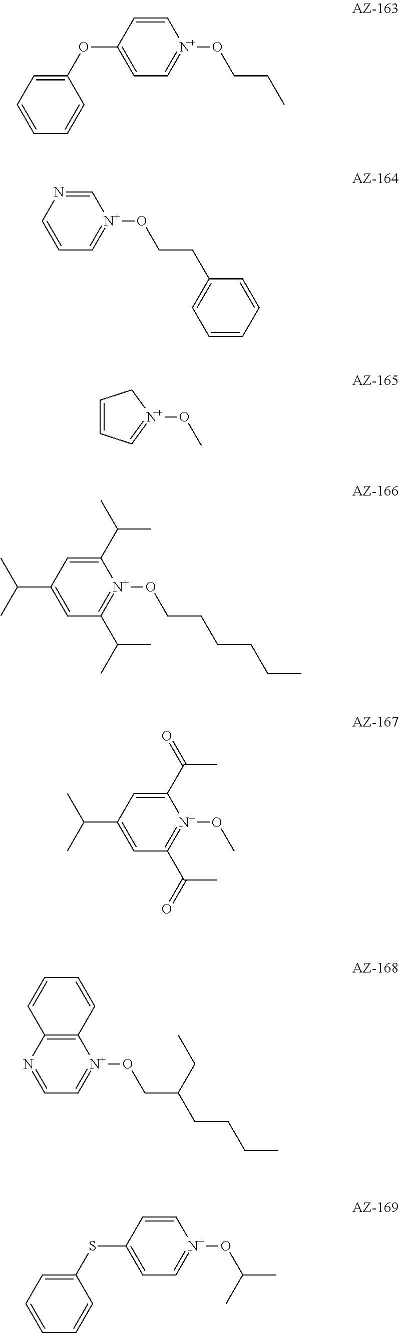

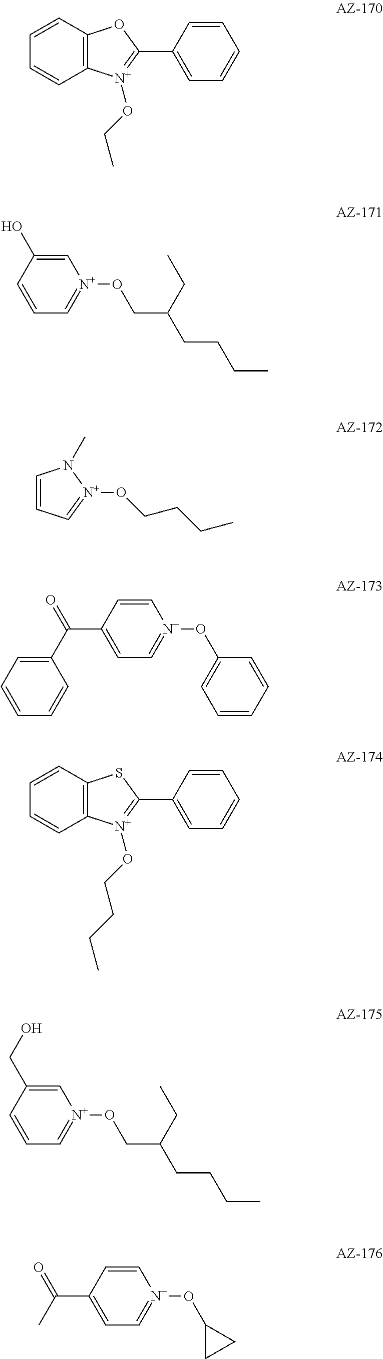

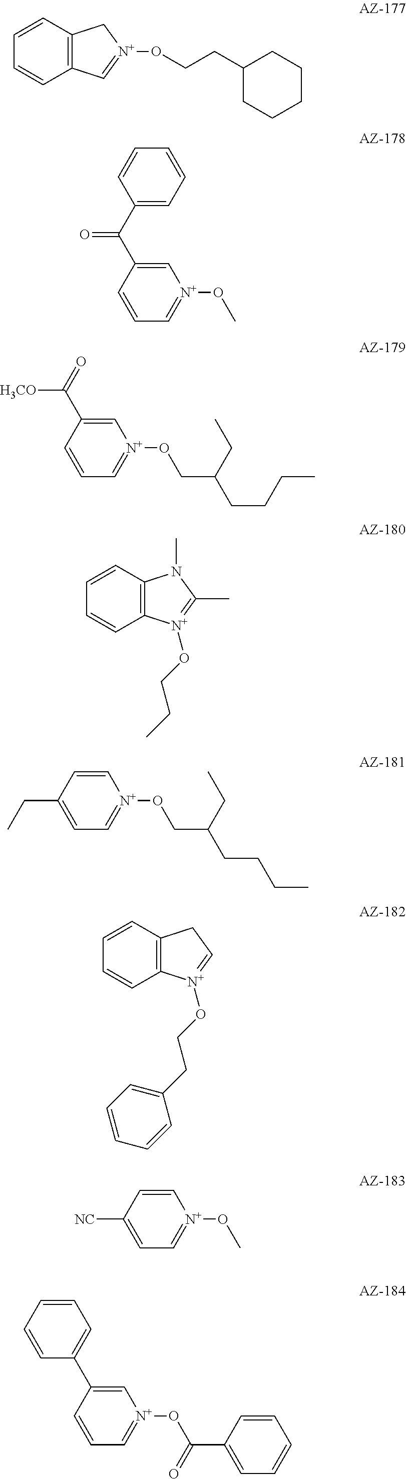

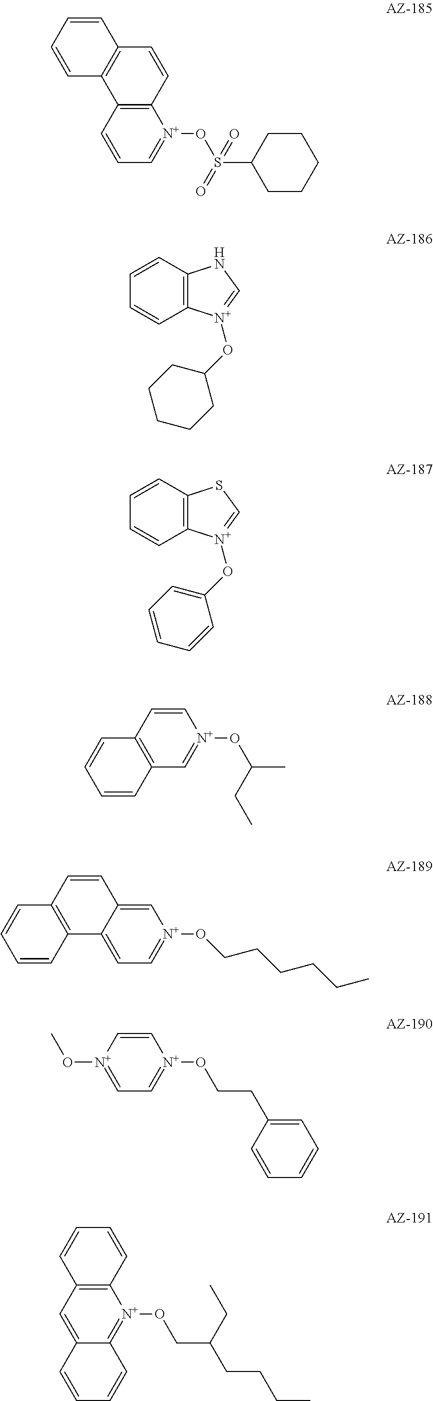

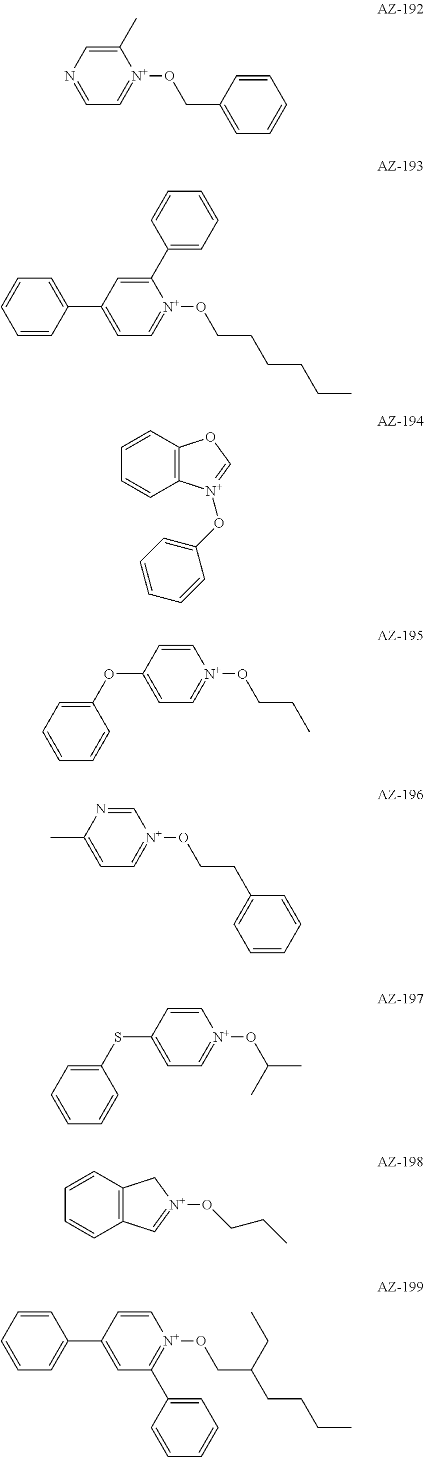

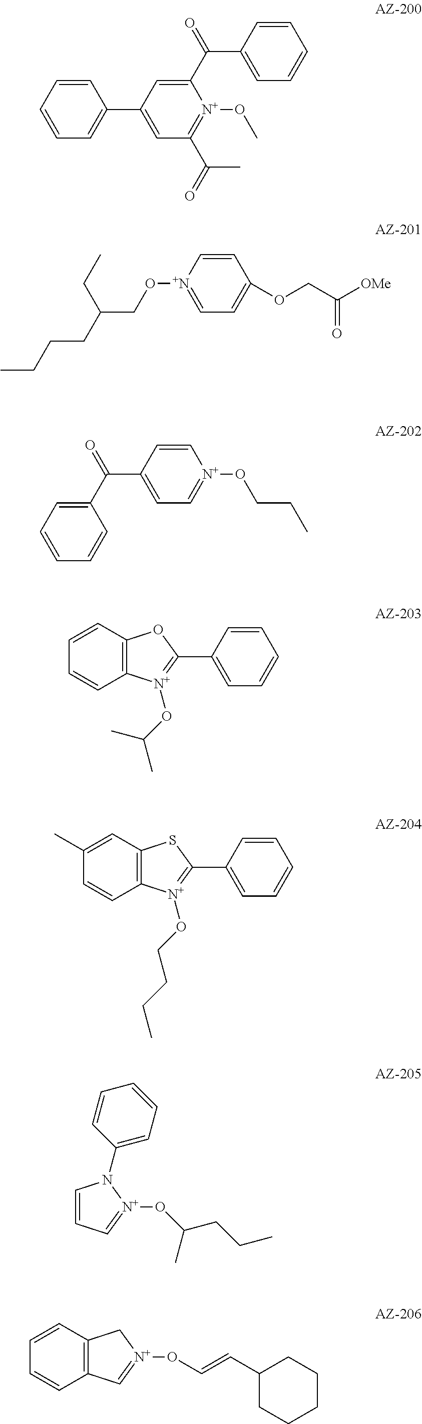

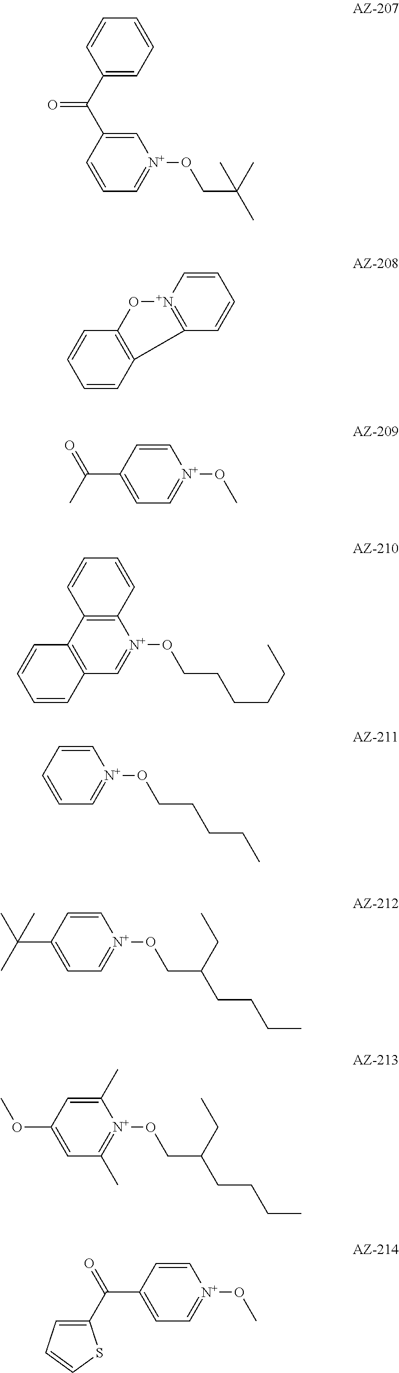

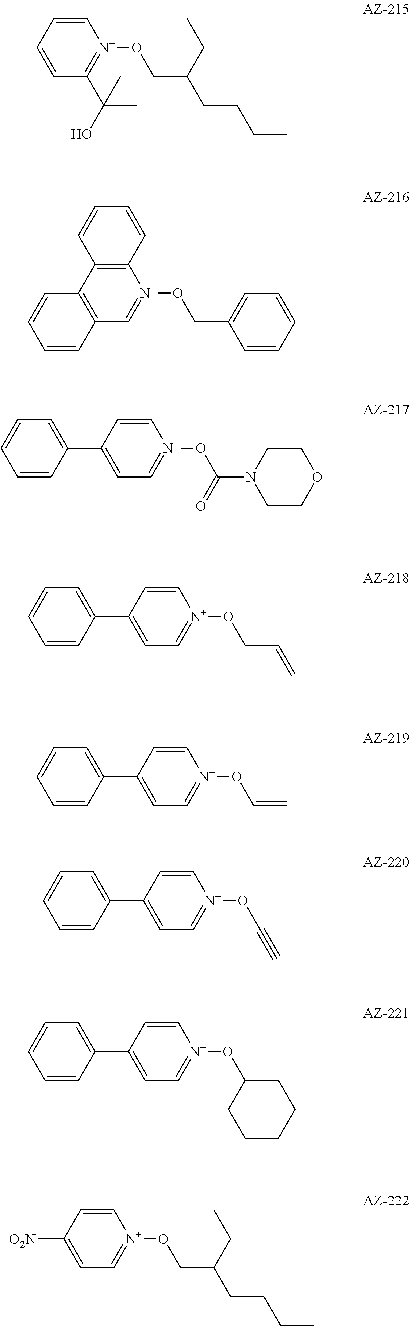

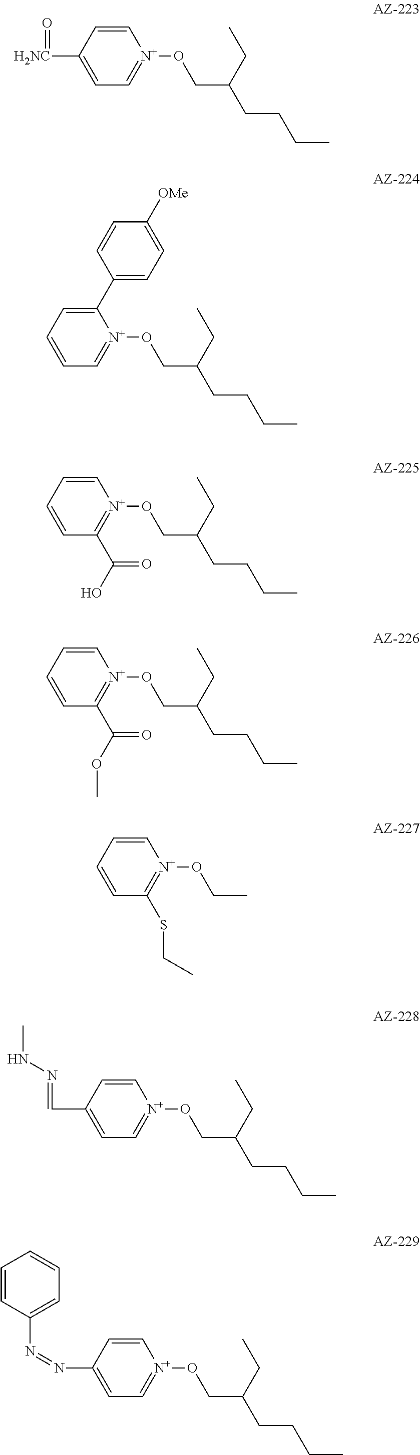

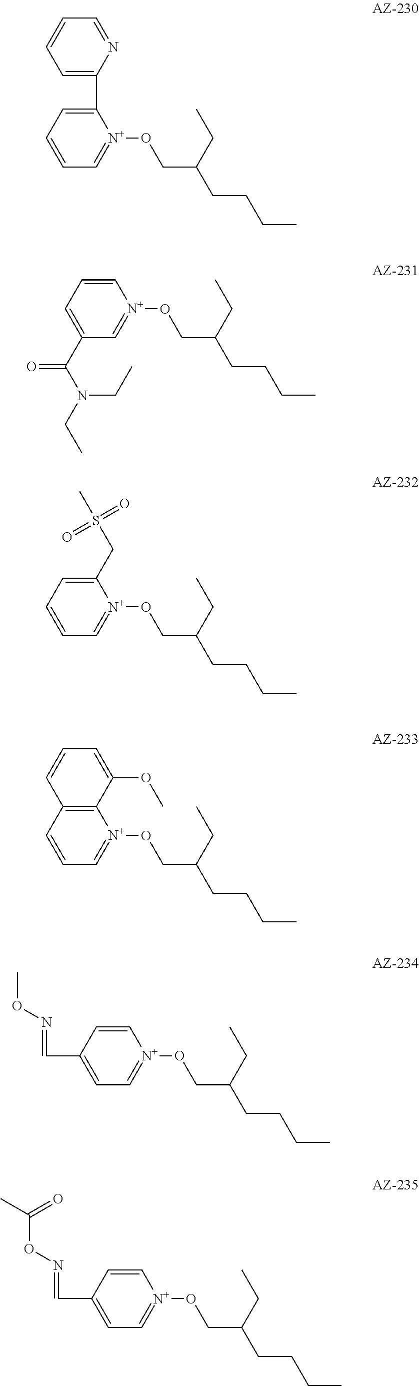

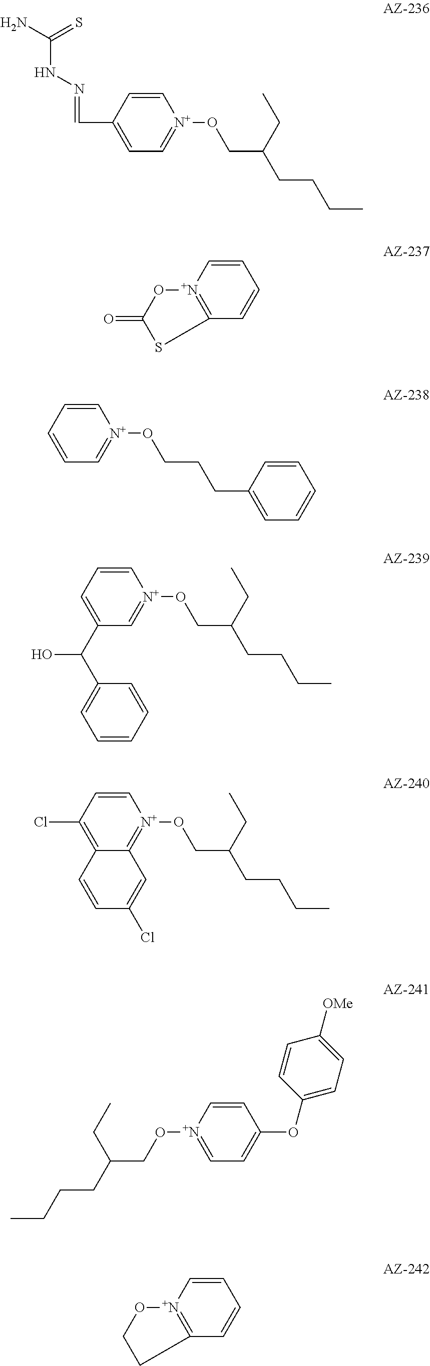

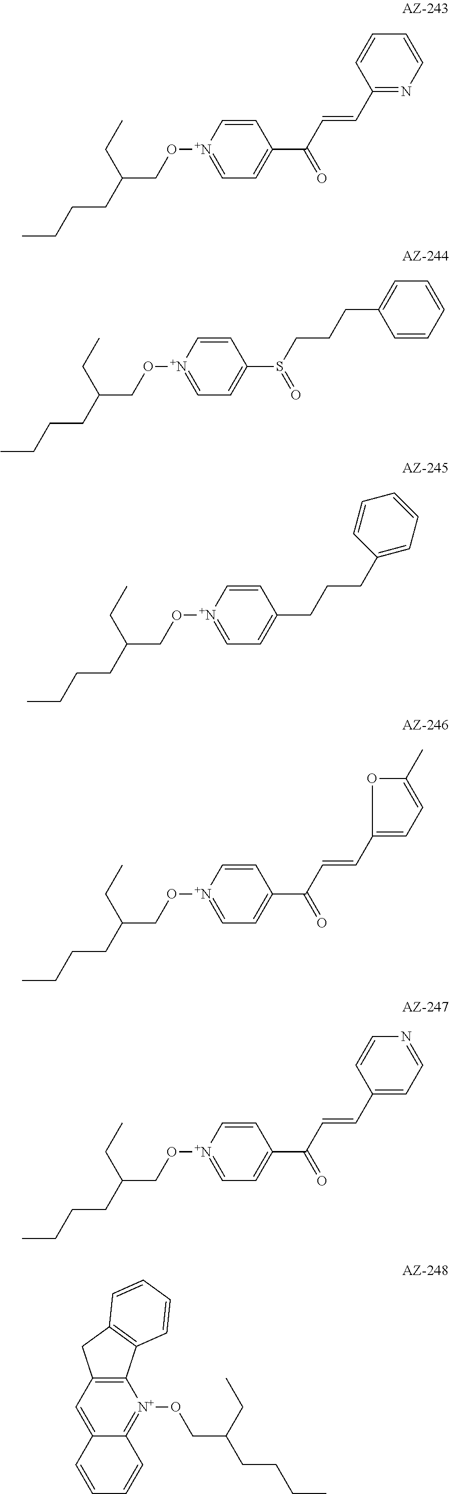

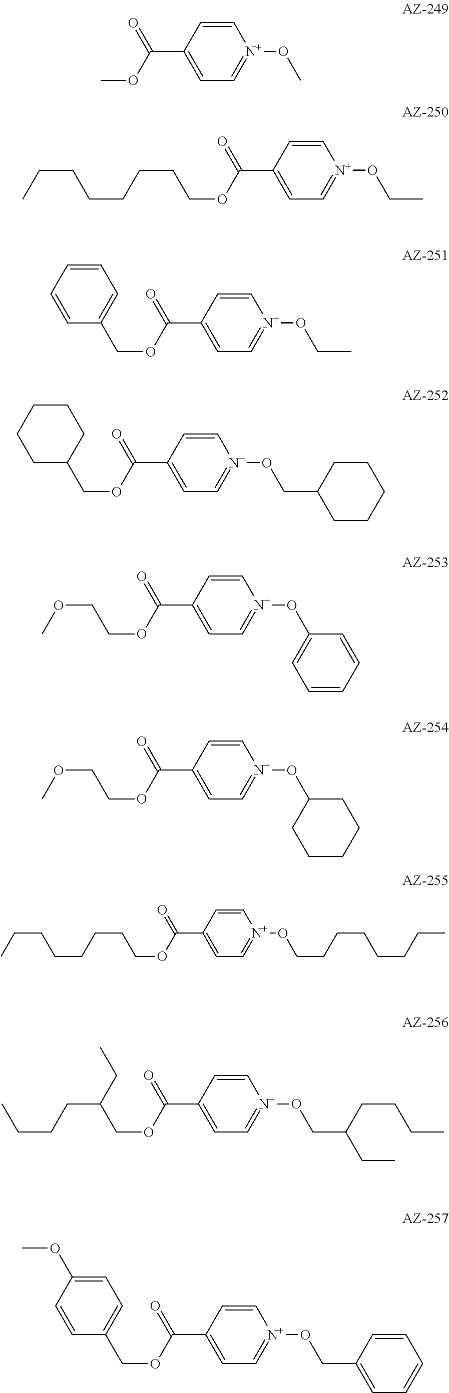

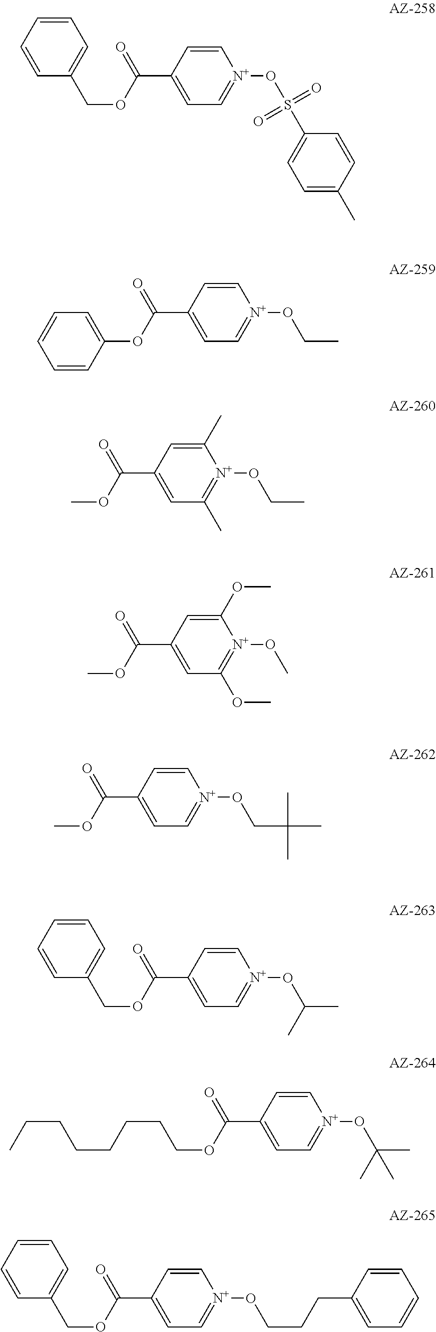

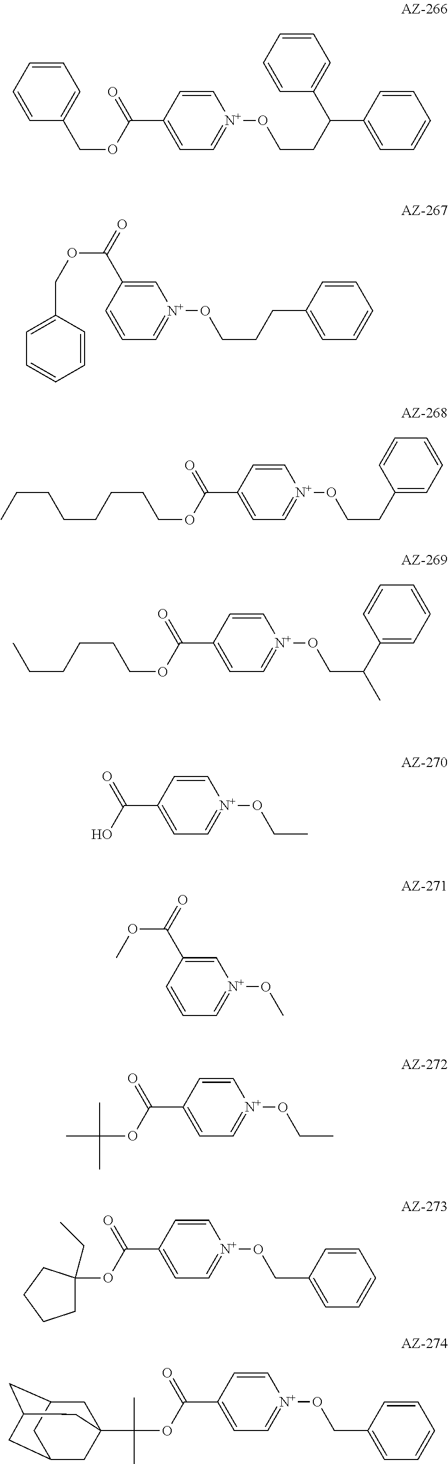

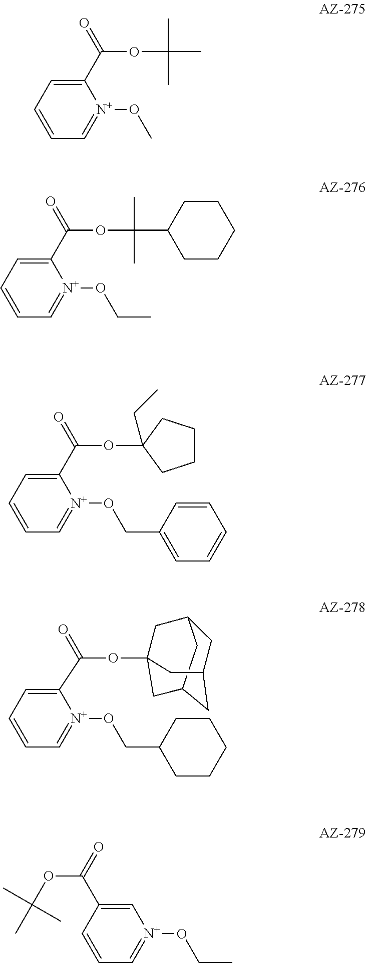

The cation represented by general formula (AZ) can be synthesized by, for example, the methods described in J. AM. CHEM. SOC. 2004, 126, 14071-14078 or J. AM. CHEM. SOC. 2002, 124, 15225-15238.

It is preferred for the repeating unit (A) to be the one that is configured to decompose when exposed to actinic rays or radiation to thereby generate an acid group in a side chain of the resin. Employing such embodiment can further suppress the diffusion of generated acids, thus making it possible to further improve resolution and pattern configuration.

In particular, it is preferred for the repeating unit (A) to be any of the repeating units of general formulae (I) and (II) below.

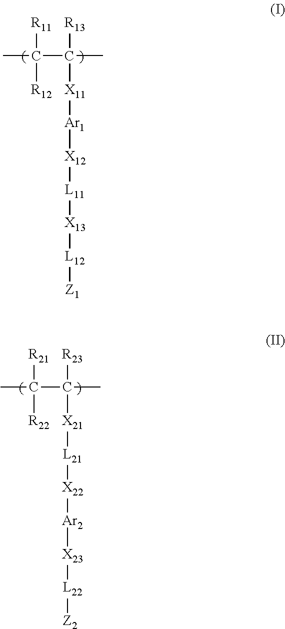

In general formula (I), each of R₁₁, R₁₂ and R₁₃ independently represents a hydrogen atom, an alkyl group, a cycloalkyl group, a halogen atom, a cyano group or an alkoxycarbonyl group.

The alkyl group is an optionally substituted linear or branched alkyl group, preferably an optionally substituted alkyl group having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred. An alkyl group having 3 or less carbon atoms is most preferred.

The alkyl group contained in the alkoxycarbonyl group is preferably the same as that mentioned above with respect to R₁₁, R₁₂ and R₁₃.

As the cycloalkyl group, there can be mentioned an optionally substituted monocyclic or polycyclic cycloalkyl group. An optionally substituted cycloalkyl group having 3 to 8 carbon atoms, such as a cyclopropyl group, a cyclopentyl group or a cyclohexyl group, is preferred.

As the halogen atom, there can be mentioned a fluorine atom, a chlorine atom, a bromine atom or an iodine atom. A fluorine atom is most preferred.

As preferred substituents that can be introduced in these groups, there can be mentioned a hydroxyl group; a halogen atom (fluorine, chlorine, bromine or iodine); a nitro group; a cyano group; an amido group;

a sulfonamido group; any of the alkyl groups mentioned above with respect to R₁₁ to R₁₃; an alkoxy group, such as a methoxy group, an ethoxy group, a hydroxyethoxy group, a propoxy group, a hydroxypropoxy group or a butoxy group; an alkoxycarbonyl group, such as a methoxycarbonyl group or an ethoxycarbonyl group; an acyl group, such as a formyl group, an acetyl group or a benzoyl group; an acyloxy group, such as an acetoxy group or a butyryloxy group; and a carboxyl group. A hydroxyl group and a halogen atom are especially preferred.

In general formula (I), each of R₁₁, R₁₂ and R₁₃ is preferably a hydrogen atom, an alkyl group or a halogen atom. A hydrogen atom, a methyl group, an ethyl group, a trifluoromethyl group (—CF₃), a hydroxymethyl group (—CH₂—OH), a chloromethyl group (—CH₂—Cl) and a fluorine atom (—F) are especially preferred.

Each of X₁₁, X₁₂ and X₁₃ independently represents a single bond, —O—, —S—, —CO—, —SO₂—, —NR— (R represents a hydrogen atom or an alkyl group), a bivalent nitrogen-containing nonaromatic heterocyclic group or a group composed of a combination of these.

With respect to —NR—, the alkyl group represented by R is an optionally substituted linear or branched alkyl group. Particular examples thereof are the same as those of the alkyl groups represented by R₁₁, R₁₂ and R₁₃. R is most preferably a hydrogen atom, a methyl group or an ethyl group.

The bivalent nitrogen-containing nonaromatic heterocyclic group refers to a preferably 3- to 8-membered nonaromatic heterocyclic group having at least one nitrogen atom. In particular, there can be mentioned, for example, bivalent connecting groups with the following structures.

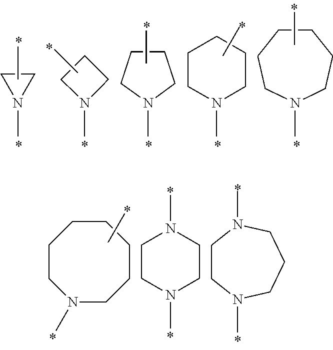

When X₁₁ is a single bond, R₁₂ may form a ring in cooperation with Ar₁, which R₁₂ represents an alkylene group. X₁₁ is preferably a single bond, —COO— or —CONR— (R represents a hydrogen atom or an alkyl group). A single bond and —COO— are most preferred.

X₁₂ is preferably a single bond, —O—, —CO—, —SO₂—, —NR— (R represents a hydrogen atom or an alkyl group) or a group composed of a combination of these. X₁₂ is most preferably a single bond, —COO— or —OSO₂—.

X₁₃ is preferably a single bond, —O—, —CO—, —SO₂—, —NR— (R represents a hydrogen atom or an alkyl group) or a group composed of a combination of these. X₁₃ is most preferably a single bond, —COO— or —OSO₂—.

L₁₁ represents a single bond, an alkylene group, an alkenylene group, a cycloalkylene group, a bivalent aromatic ring group or a group composed of a combination of two or more of these, provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group or a group composed of a combination of these.

The alkylene group represented by L₁₁ may be linear or branched. As preferred examples thereof, there can be mentioned, for example, alkylene groups having 1 to 8 carbon atoms, such as a methylene group, an ethylene group, a propylene group, a butylene group, a hexylene group and an octylene group. An alkylene group having 1 to 6 carbon atoms is more preferred. An alkylene group having 1 to 4 carbon atoms is most preferred.

As the alkenylene group, there can be mentioned a group resulting from the introduction of a double bond in any position of the alkylene group described above in connection with L₁₁.

The cycloalkylene group may be monocyclic or polycyclic. As preferred examples thereof, there can be mentioned, for example, cycloalkylene groups each having 3 to 17 carbon atoms, such as a cyclobutylene group, a cyclopentylene group, a cyclohexylene group, a norbornanylene group, an adamantylene group or a diamantanylene group. A cycloalkylene group having 5 to 12 carbon atoms is more preferred. A cycloalkylene group having 6 to 10 carbon atoms is more preferred.

As the bivalent aromatic ring group, there can be mentioned, for example, an optionally substituted arylene group having 6 to 14 carbon atoms, such as a phenylene group, a tolylene group or a naphthylene group, or a bivalent aromatic ring group containing a heteroring, such as thiophene, furan, pyrrole, benzothiophene, benzofuran, benzopyrrole, triazine, imidazole, benzimidazole, triazole, thiadiazole or triazole.

Particular examples of the —NR— and bivalent nitrogenous nonaromatic heterocyclic group are the same as mentioned above in connection with X₁₁. Preferred examples are also the same.

L₁₁ is more preferably a single bond, an alkylene group or a cycloalkylene group, most preferably a single bond or an alkylene group.

L₁₂ represents a single bond, an alkylene group, an alkenylene group, a cycloalkylene group, a bivalent aromatic ring group or a group composed of a combination of two or more of these, provided that the hydrogen atoms of these groups are partially or entirely substituted with a substituent selected from among a fluorine atom, a fluoroalkyl group, a nitro group and a cyano group, and provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group or a group composed of a combination of these.

Preferably, L₁₂ is an alkylene group, bivalent aromatic ring group or group composed of a combination of these whose hydrogen atoms are partially or entirely substituted with a fluorine atom or a fluoroalkyl group (more preferably a perfluoroalkyl group). An alkylene group at least partially or entirely substituted with a fluorine atom are especially preferred. L₁₂ is most preferably an alkylene group, 30 to 100% of the hydrogen atoms of which are substituted with a fluorine atom.

The alkylene group represented by L₁₂ may be linear or branched. As preferred examples thereof, there can be mentioned, for example, alkylene groups each having 1 to 8 carbon atoms, such as a methylene group, an ethylene group, a propylene group, a butylene group, a hexylene group and an octylene group. An alkylene group having 1 to 6 carbon atoms is more preferred. An alkylene group having 1 to 4 carbon atoms is most preferred.

As the alkenylene group, there can be mentioned a group resulting from the introduction of a double bond in any position of the above alkylene group.

The cycloalkylene group may be monocyclic or polycyclic. As preferred examples thereof, there can be mentioned, for example, cycloalkylene groups each having 3 to 17 carbon atoms, such as a cyclobutylene group, a cyclopentylene group, a cyclohexylene group, a norbornanylene group, an adamantylene group or a diadamantanylene group.

Particular examples of the bivalent aromatic ring group are the same as set forth above with respect to the bivalent aromatic ring group as a connecting group represented by L₁₁.

Particular examples of the —NR— and bivalent nitrogen-containing nonaromatic heterocyclic group as connecting groups represented by L₁₂ are the same as mentioned above in connection with X₁₁. Preferred examples are also the same.

Preferred particular examples of L₁₂ are shown below, which in no way limit the scope of appropriate L₁₂.

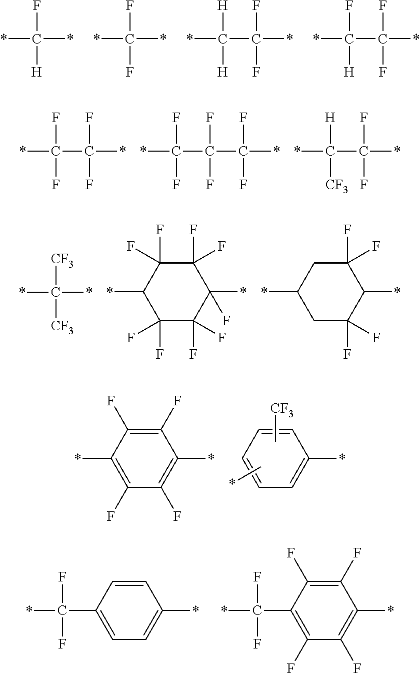

Ar₁ represents a bivalent aromatic ring group or a group composed of a combination of a bivalent aromatic ring group and an alkylene group.

A substituent may be introduced in the bivalent aromatic ring group. As preferred examples thereof, there can be mentioned, for example, an arylene group having 6 to 18 carbon atoms, such as a phenylene group, a tolylene group or a naphthylene group; and a bivalent aromatic ring group containing a heteroring, such as thiophene, furan, pyrrole, benzothiophene, benzofuran, benzopyrrole, triazine, imidazole, benzimidazole, triazole, thiadiazole or thiazole.

Preferred substituents that can be introduced in these groups are, for example, the alkyl group mentioned in connection with R₁₁ to R₁₃, an alkoxy group such as a methoxy group, an ethoxy group, a hydroxyethoxy group, a propoxy group, a hydroxypropoxy group or a butoxy group and an aryl group such as a phenyl group.

As a preferred example of the group composed of a combination of a bivalent aromatic ring group and an alkylene group, there can be mentioned an aralkylene group composed of a combination of any of the above-mentioned bivalent aromatic ring groups and, for example, an alkylene group having 1 to 8 carbon atoms (may be linear or branched), such as a methylene group, an ethylene group, a propylene group, a butylene group, a hexylene group or an octylene group.

Preferably, Ar₁ is an optionally substituted arylene group having 6 to 18 carbon atoms. A phenylene group, a naphthylene group, a biphenylene group and a phenylene group substituted with a phenyl group are especially preferred.

Z₁ represents a structural unit being configured to decompose when exposed to actinic rays or radiation to thereby generate an acid and containing a cation structure with a monocyclic or polycyclic heterocycle containing a nitrogen atom. The cation structure preferably contains an azinium cation. Also, the cation structure is preferably represented by the general formula (AZ) above.

The acid group generated by Z₁ is preferably a sulfonate group, an imidate group or a methide group. More specifically, Z₁ preferably has any of the structures of general formulae (ZI) to (ZIII) below.

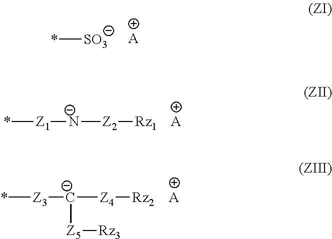

In general formulae (ZII) and (ZIII), each of Z₁, Z₂, Z₃, Z₄ and Z₅ independently represents —CO— or —SO₂—, preferably —SO₂—.

Each of Rz₁, Rz₂ and Rz₃ independently represents an alkyl group, a cycloalkyl group, an aryl group or an aralkyl group. Forms of these groups having the hydrogen atoms thereof partially or entirely substituted with a fluorine atom or a fluoroalkyl group (especially a perfluoroalkyl group) are preferred.

Forms of these groups having 30 to 100% of the hydrogen atoms thereof substituted with a fluorine atom are most preferred.

The above alkyl group may be linear or branched. As a preferred form thereof, there can be mentioned, for example, an alkyl group having 1 to 8 carbon atoms, such as a methyl group, an ethyl group, a propyl group, a butyl group, a hexyl group or an octyl group. An alkyl group having 1 to 6 carbon atoms is more preferred. An alkyl group having 1 to 4 carbon atoms is most preferred.

The cycloalkyl group is preferably a cycloalkyl group having 3 to 10 carbon atoms, such as a cyclobutyl group, a cyclopentyl group or a cyclohexyl group. A cycloalkyl group having 3 to 6 carbon atoms is more preferred.

The aryl group is preferably one having 6 to 18 carbon atoms. An aryl group having 6 to 10 carbon atoms is more preferred. A phenyl group is most preferred.

As a preferred form of the aralkyl group, there can be mentioned one resulting from the bonding of the above aryl group to an alkylene group having 1 to 8 carbon atoms. An aralkyl group resulting from the bonding of the above aryl group to an alkylene group having 1 to 6 carbon atoms is more preferred. An aralkyl group resulting from the bonding of the above aryl group to an alkylene group having 1 to 4 carbon atoms is most preferred.

Each of Rz₁, Rz₂ and Rz₃ is preferably an alkyl group having the hydrogen atoms thereof partially or entirely substituted with a fluorine atom or a fluoroalkyl group (especially a perfluoroalkyl group), most preferably an alkyl group having 30 to 100% of the hydrogen atoms thereof substituted with a fluorine atom.

In general formulae (ZI) to (ZIII) above, A⁺ represents the cation structure with a monocyclic or polycyclic heterocycle containing a nitrogen atom as explained above. A⁺ preferably contains the azinium cation described above.

A⁺ is preferably represented by the general formula (AZ) above. That is, Z₁ is more preferably represented by any of general formulae (ZI-A), (ZII-A) and (ZIII-A) below.

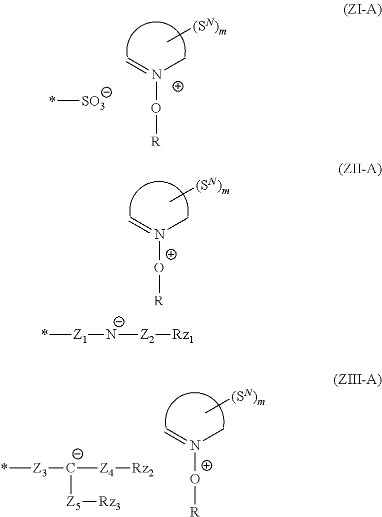

In the formulae,

Each of R, S^{N} and m represents the same as set forth with respect to general formula (AZ).

Each of Z₁, Z₂, Z₃, Z₄, Z₅, Rz₁, Rz₂ and Rz₃ represents the same as set forth with respect to general formula (ZII) and (ZIII).

With respect to the polymerizable monomer units corresponding to the repeating units of general formula (I), examples thereof will be shown below as acids formed by the cleavage of a cation upon exposure to actinic rays or radiation.

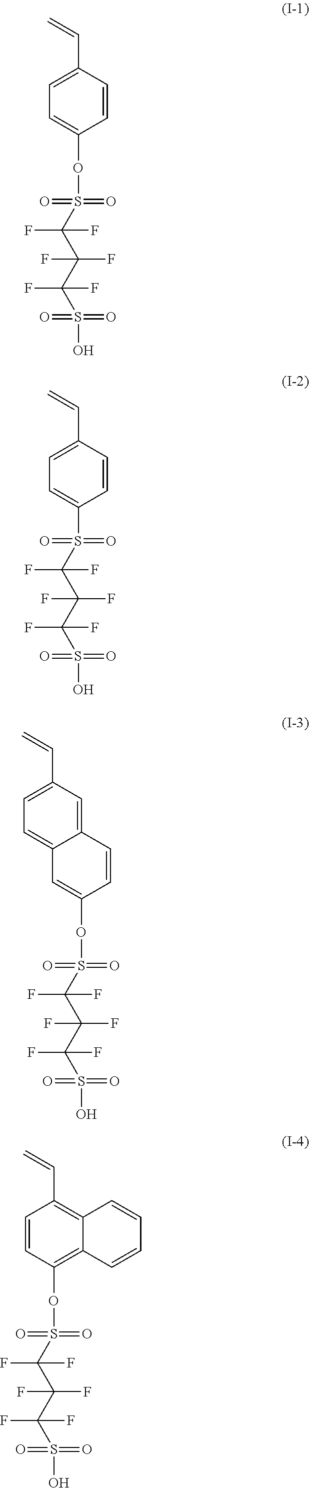

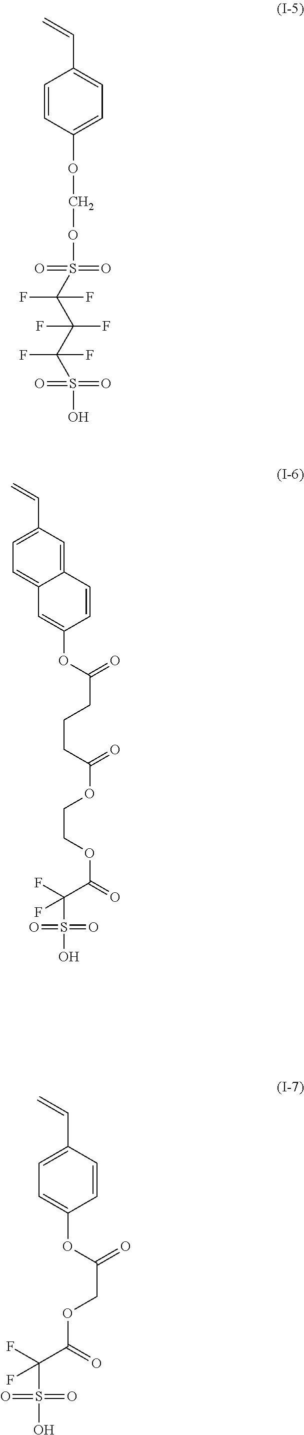

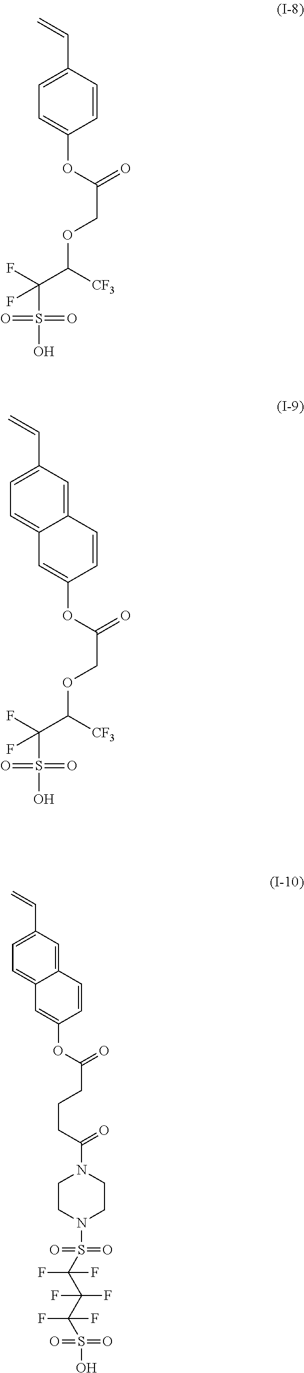

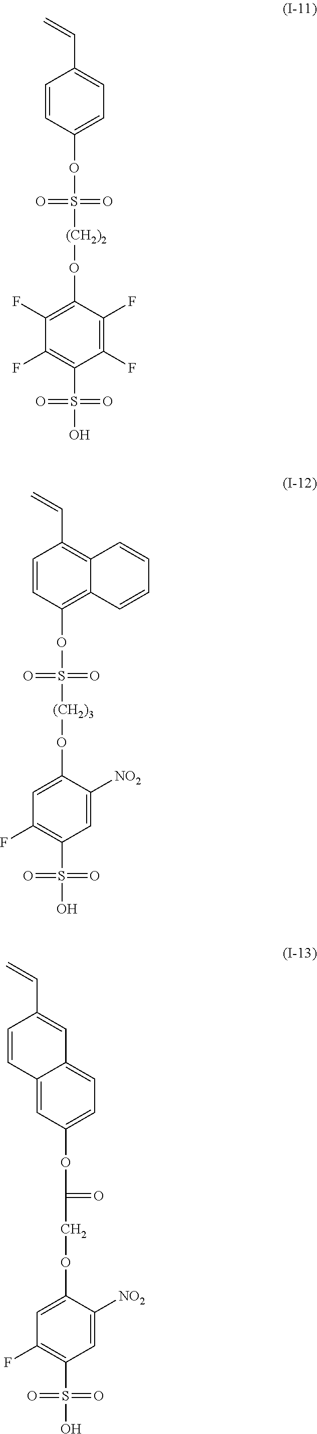

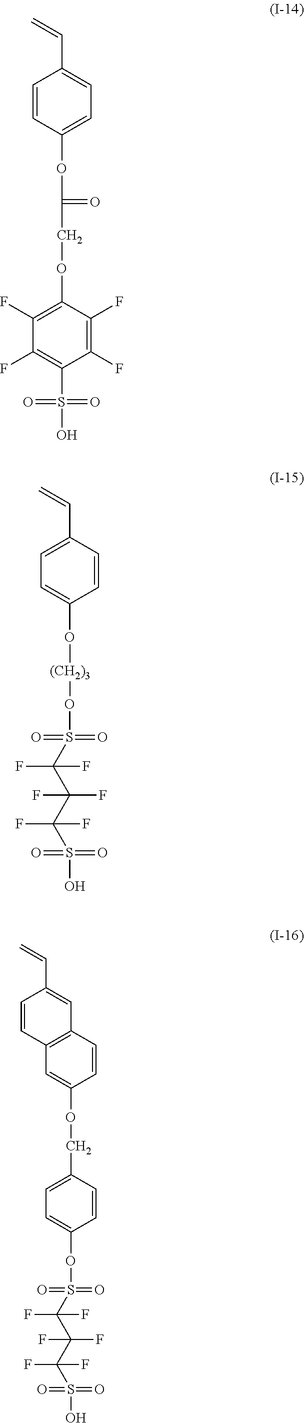

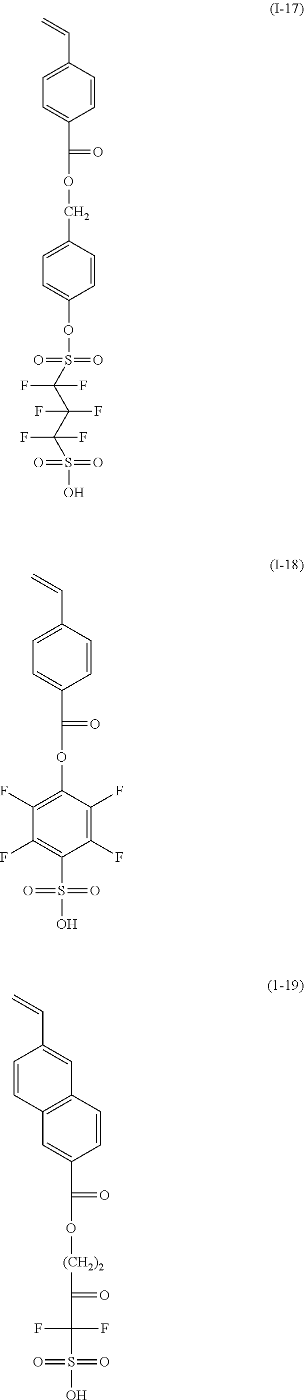

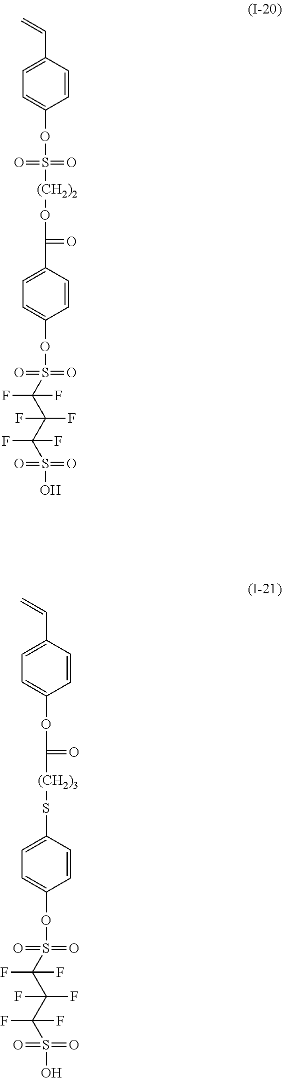

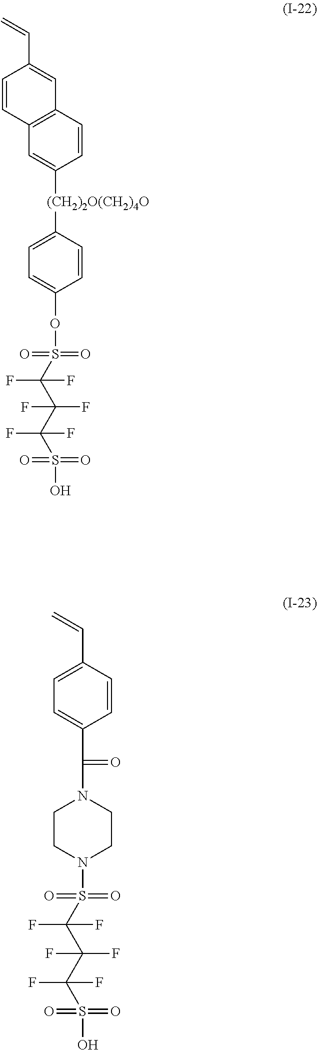

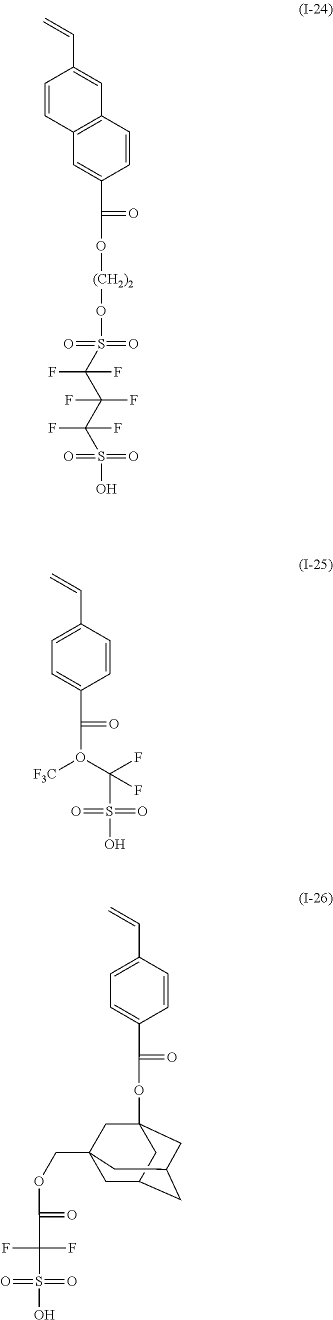

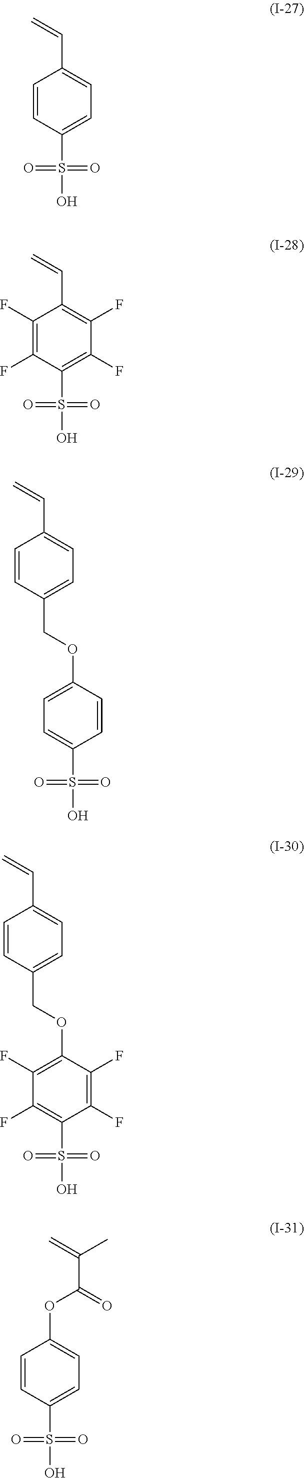

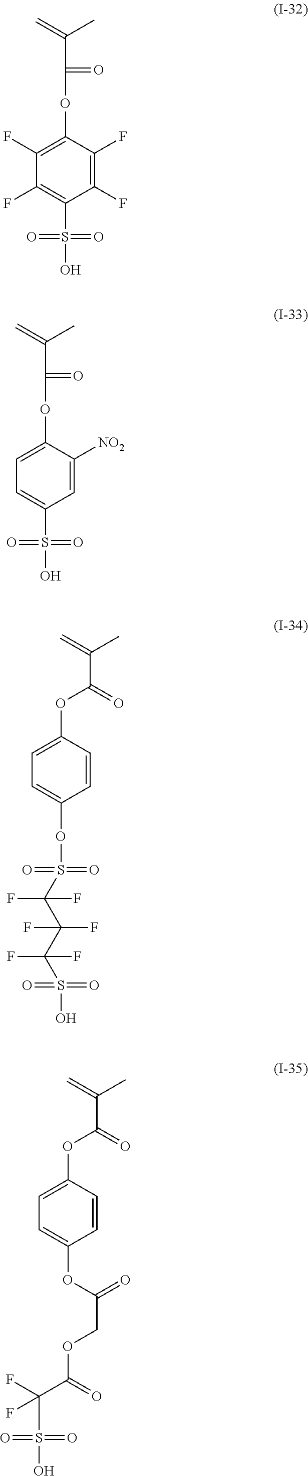

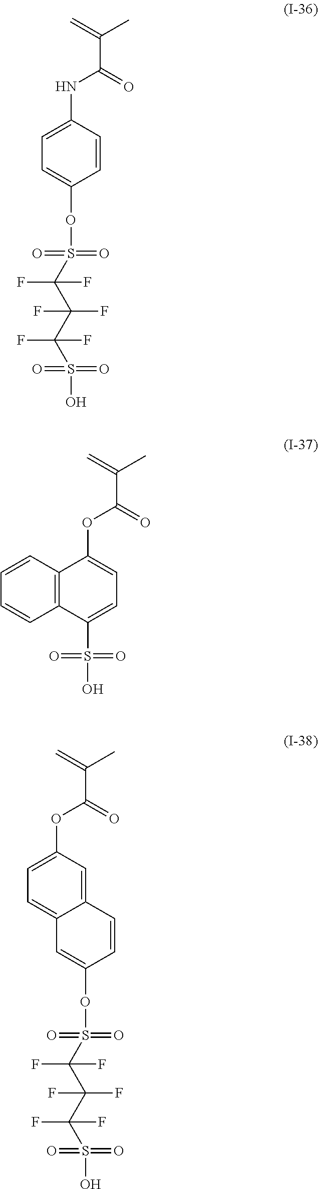

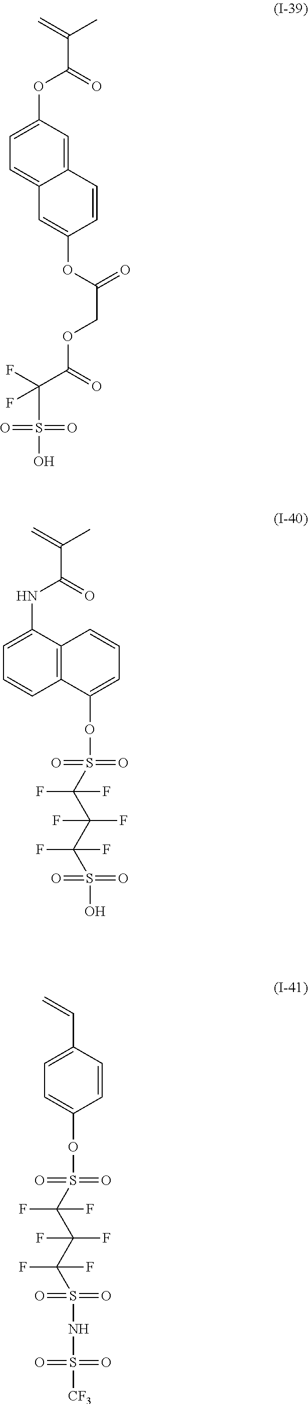

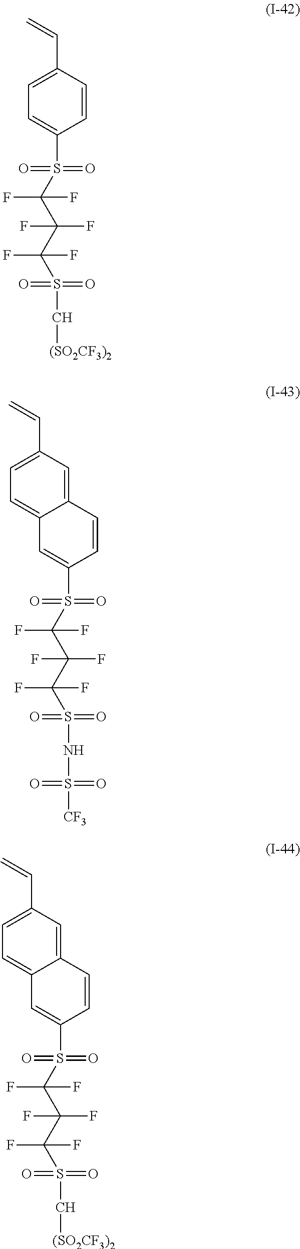

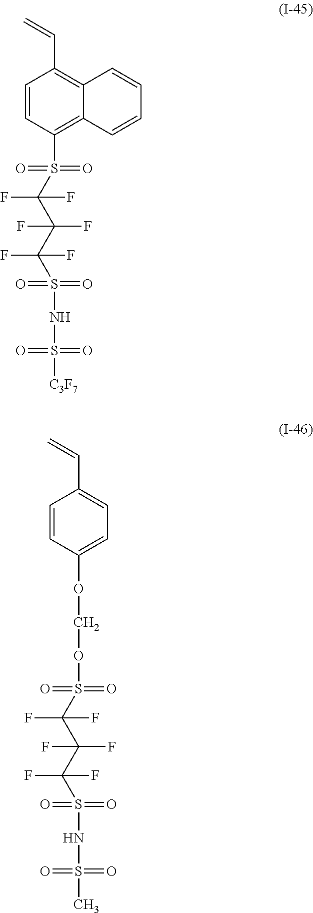

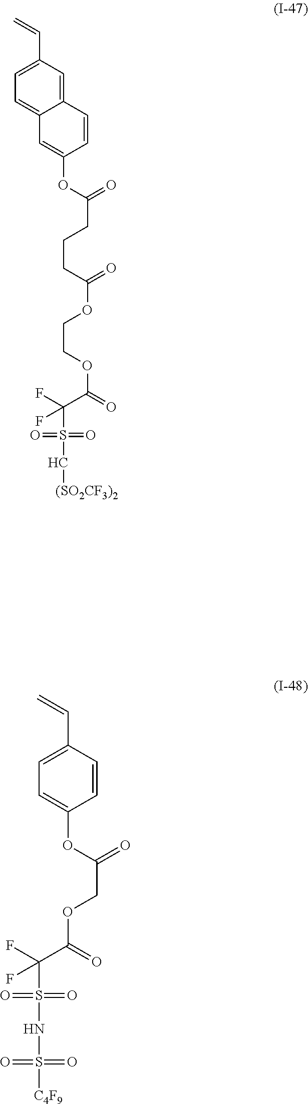

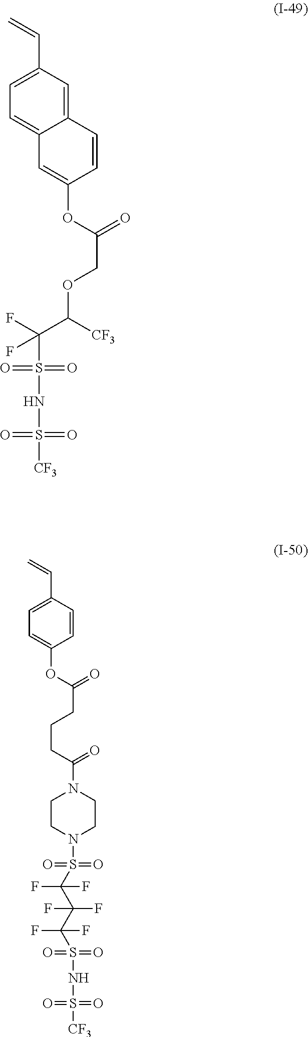

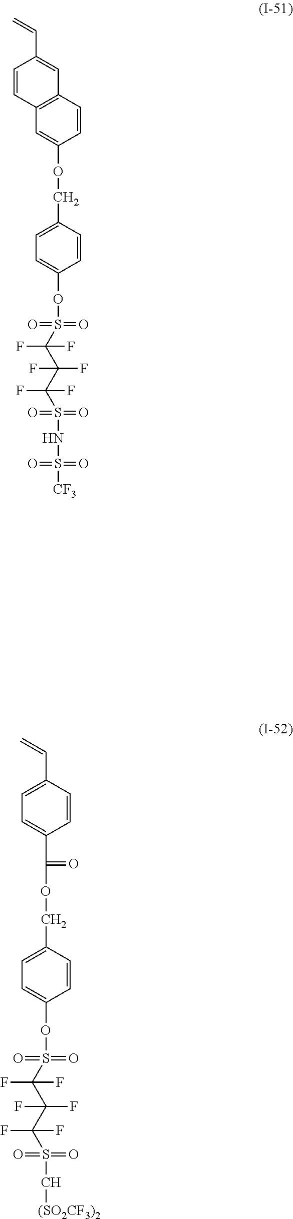

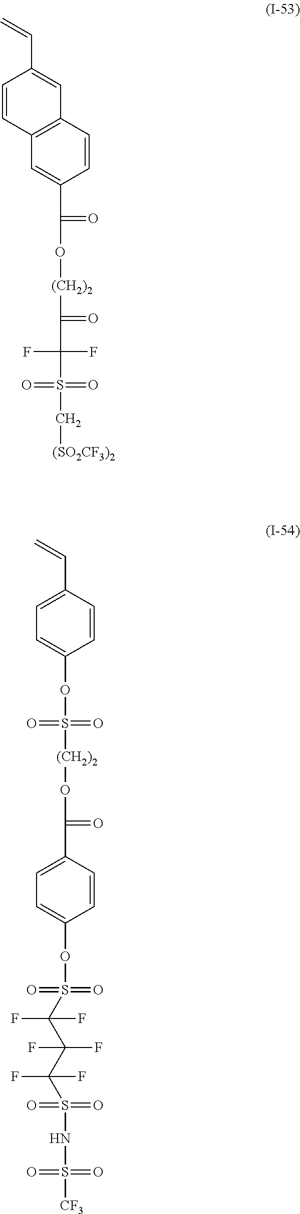

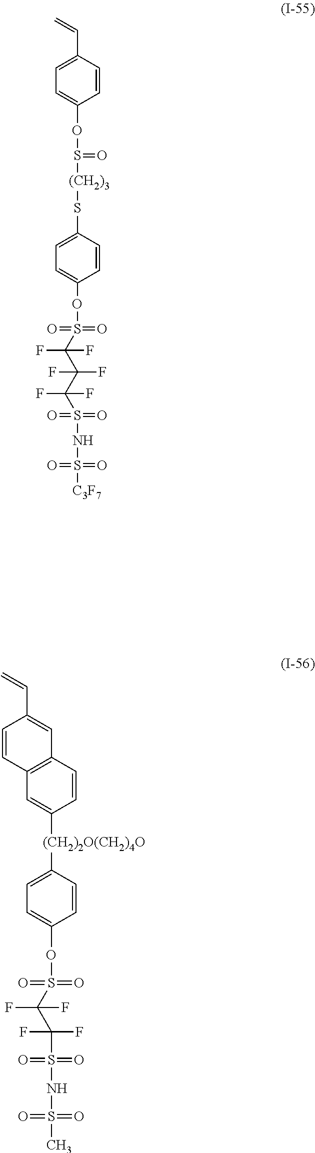

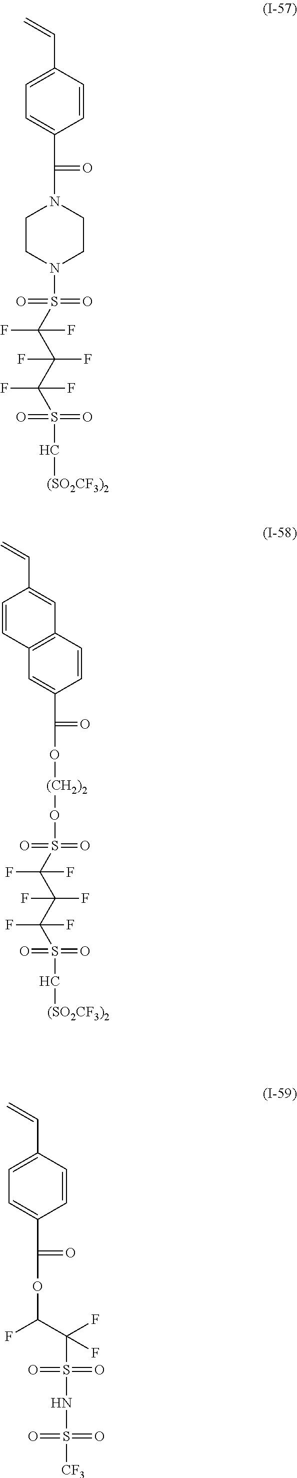

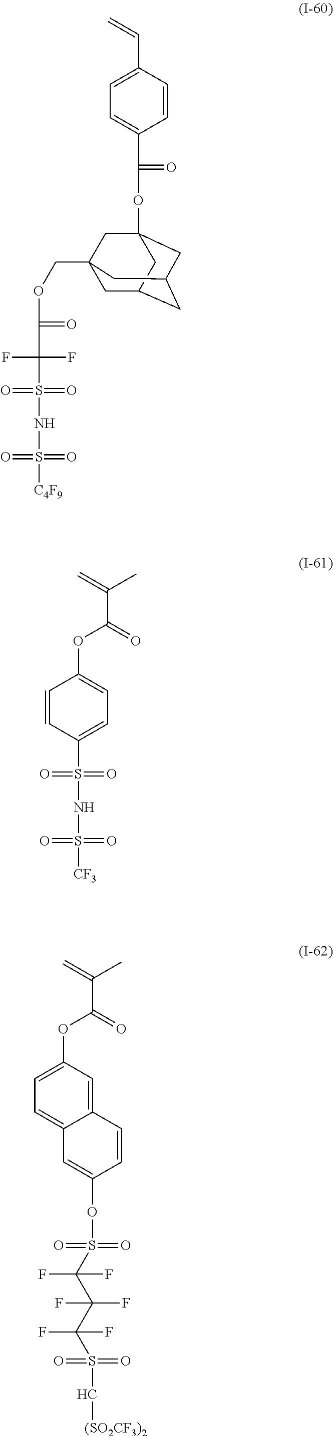

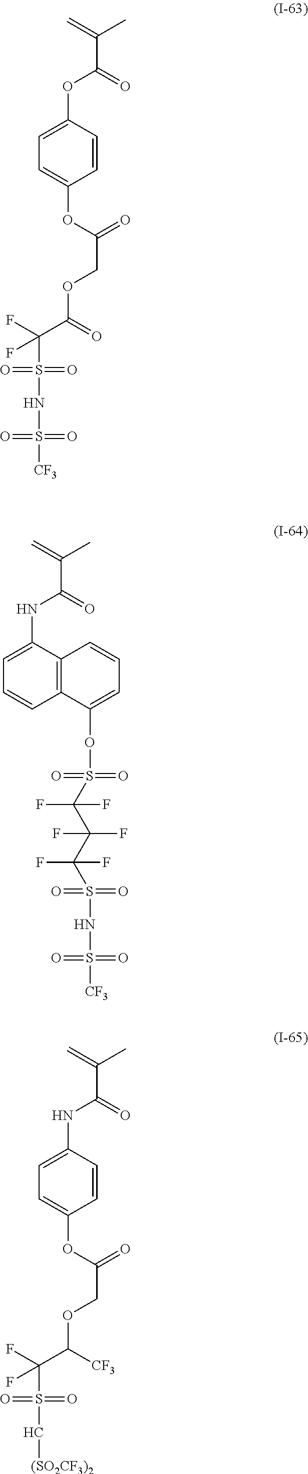

The general formula (II) will be described below.

In general formula (II), each of R₂₁, R₂₂ and R₂₃ independently represents a hydrogen atom, an alkyl group, a monovalent aliphatic hydrocarbon ring group, a halogen atom, a cyano group or an alkoxycarbonyl group.

The alkyl group is an optionally substituted linear or branched alkyl group, preferably an optionally substituted alkyl group having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred. An alkyl group having 3 or less carbon atoms is most preferred.

The alkyl group contained in the alkoxycarbonyl group is preferably the same as the alkyl group mentioned above with respect to R₂₁, R₂₂ and R₂₃.

As the monovalent aliphatic hydrocarbon ring group, there can be mentioned an optionally substituted mono- or polycycloalkyl group. An optionally substituted monocyclic monovalent aliphatic hydrocarbon ring group having 3 to 8 carbon atoms, such as a cyclopropyl group, a cyclopentyl group or a cyclohexyl group, is preferred.

As the halogen atom, there can be mentioned a fluorine atom, a chlorine atom, a bromine atom or an iodine atom. A fluorine atom is especially preferred.

As preferred substituents that can be introduced in these groups, there can be mentioned, for example, those explained with respect to R₁₁, R₁₂ and R₁₃ as set forth above.

In general formula (II), each of R₂₁, R₂₂ and R₂₃ preferably represents a hydrogen atom, an alkyl group or a halogen atom, especially preferably a hydrogen atom, a methyl group, an ethyl group, a trifluoromethyl group (—CF₃), a hydroxymethyl group (—CH₂—OH), a chloromethyl group (—CH₂—Cl) and a fluorine atom (—F).

X₂₁ represents —O—, —S—, —CO—, —SO₂—, —NR— (R represents a hydrogen atom or an alkyl group), a bivalent nitrogen-containing nonaromatic heterocyclic group or a group composed of a combination of these.

In —NR—, the alkyl group represented by R is an optionally substituted linear or branched alkyl group. Particular examples of such alkyl groups are the same as mentioned above with respect to the alkyl groups represented by R₂₁, R₂₂ and R₂₃. Most preferably, R is a hydrogen atom, a methyl group or an ethyl group.

The above bivalent nitrogen-containing nonaromatic heterocyclic group refers to a nonaromatic heterocyclic group, preferably 3- to 8-membered, containing at least one nitrogen atom. For example, there can be mentioned any of the structures set forth above as examples with respect to X₁₁ to X₁₃ of general formula (I).

Preferably, X₂₁ is —O—, —CO— or —NR— (R represents a hydrogen atom or an alkyl group) or a group composed of a combination of these. —COO— and —CONR— (R represents a hydrogen atom or an alkyl group) are especially preferred.

L₂₁ represents an alkylene group, an alkenylene group, a cycloalkylene group or a group composed of a combination of two or more of these, provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group, a bivalent aromatic ring group or a group composed of a combination of these.

As the alkylene group represented by L₂₁, for example, those explained with respect to L₁₁ above can be exemplified.

As the alkenylene group, there can be mentioned a group resulting from the introduction of a double bond in any position of the alkylene group described above in connection with L₂₁.

As the cycloalkylene group represented by L₂₁, for example, those explained with respect to L₁₁ above can be exemplified.

As the bivalent aromatic ring group represented by L₂₁, for example, those explained with respect to L₁₁ above can be exemplified.

Most preferably, L₂₁ is an alkylene group, a cycloalkylene group or a group composed of two or more of these combined through —COO—, —O— or —CONH— as a connecting group (for example, -alkylene group-O-alkylene group-, -alkylene group-OCO-alkylene group-, -cycloalkylene group-O-alkylene group-, -alkylene group-CONH-alkylene group- and the like).

Each of X₂₂ and X₂₃ independently represents a single bond, —O—, —S—, —CO—, —SO₂—, —NR— (R represents a hydrogen atom or an alkyl group), a bivalent nitrogen-containing nonaromatic heterocyclic group or a group composed of a combination of these.

Particular examples of the —NR— and bivalent nitrogen-containing nonaromatic heterocyclic group represented by X₂₂ and X₂₃ are the same as mentioned above in connection with X₂₁. Preferred examples are also the same.

X₂₂ is preferably a single bond, —S—, —O—, —CO—, —SO₂— or a group composed of a combination of these, most preferably a single bond, —S—, —COO— or —OSO₂—.

X₂₃ is preferably —O—, —CO—, —SO₂— or a group composed of a combination of these, most preferably —OSO₂—.

Ar₂ represents a bivalent aromatic ring group or a group composed of a combination of a bivalent aromatic ring group and an alkylene group.

A substituent may be introduced in the bivalent aromatic ring group. As preferred examples of the bivalent aromatic ring group, there can be mentioned, for example, an arylene group having 6 to 18 carbon atoms, such as a phenylene group, a tolylene group or a naphthylene group, and a bivalent aromatic ring group containing a heteroring, such as thiophene, furan, pyrrole, benzothiophene, benzofuran, benzopyrrole, triazine, imidazole, benzimidazole, triazole, thiadiazole or thiazole.

Preferred substituents that can be introduced in the above groups are, for example, the alkyl group mentioned in connection with R₂₁ to R₂₃, an alkoxy group such as a methoxy group, an ethoxy group, a hydroxyethoxy group, a propoxy group, a hydroxypropoxy group or a butoxy group and an aryl group such as a phenyl group.

As a preferred example of the group composed of a combination of a bivalent aromatic ring group and an alkylene group, there can be mentioned an aralkylene group composed of a combination of any of the above-mentioned bivalent aromatic ring groups and, for example, an alkylene group having 1 to 8 carbon atoms (may be linear or branched), such as a methylene group, an ethylene group, a propylene group, a butylene group, a hexylene group or an octylene group.

Ar₂ is preferably an aralkylene group composed of a combination of any of the optionally substituted arylene groups having 6 to 18 carbon atoms and an alkylene group having 1 to 4 carbon atoms. A phenylene group, a naphthylene group, a biphenylene group or a phenylene group substituted with a phenyl group are most preferred.

L₂₂ represents an alkylene group, an alkenylene group, a cycloalkylene group, a bivalent aromatic ring group or a group composed of a combination of two or more of these, provided that the hydrogen atoms of these groups are partially or entirely substituted with a substituent selected from among a fluorine atom, a fluoroalkyl group, a nitro group and a cyano group, and provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group or a group composed of a combination of these.

Preferably, L₂₂ is an alkylene group, bivalent aromatic ring group or group composed of a combination of these whose hydrogen atoms are partially or entirely substituted with a fluorine atom or a fluoroalkyl group (more preferably a perfluoroalkyl group). An alkylene group and bivalent aromatic ring group at least partially or entirely substituted with a fluorine atom are especially preferred. L₂₂ is most preferably an alkylene group or bivalent aromatic ring group, 30 to 100% of the hydrogen atoms of which are substituted with a fluorine atom.

As the alkylene group represented by L₂₂, for example, those explained with respect to L₁₁ above can be exemplified.

As the alkenylene group, there can be mentioned a group resulting from the introduction of a double bond in any position of the above alkylene group.

The cycloalkylene group may be monocyclic or polycyclic. As preferred examples thereof, there can be mentioned, for example, cycloalkylene groups each having 3 to 17 carbon atoms, such as a cyclobutylene group, a cyclopentylene group, a cyclohexylene group, a norbornanylene group, an adamantylene group or a diadamantanylene group.

Particular examples of the bivalent aromatic ring group are the same as set forth above with respect to the bivalent aromatic ring group as a connecting group represented by L₂₁.

Particular examples of the —NR— and bivalent nitrogen-containing nonaromatic heterocyclic group as connecting groups represented by L₂₂ are the same as mentioned above in connection with X₂₁. Preferred examples are also the same.

As preferred particular examples of the structures represented by L₂₂, there can be mentioned those set forth above with respect to L₁₂ of general formula (I).

Z₂ represents the same as set forth with respect to Z₁ in general formula (I). The above description regarding Z₁ also applies to Z₂.

With respect to the polymerizable monomer units corresponding to the repeating units of general formula (II), examples thereof will be shown below as acids formed by the cleavage of a cation upon exposure to actinic rays or radiation.

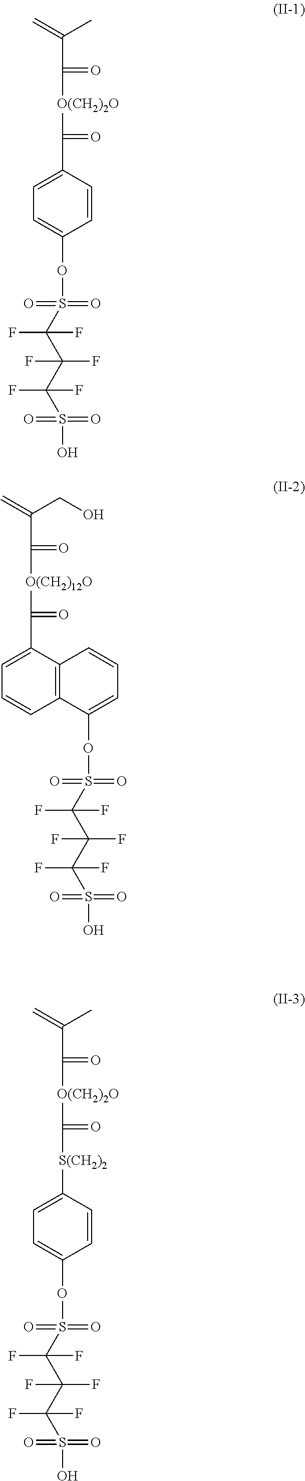

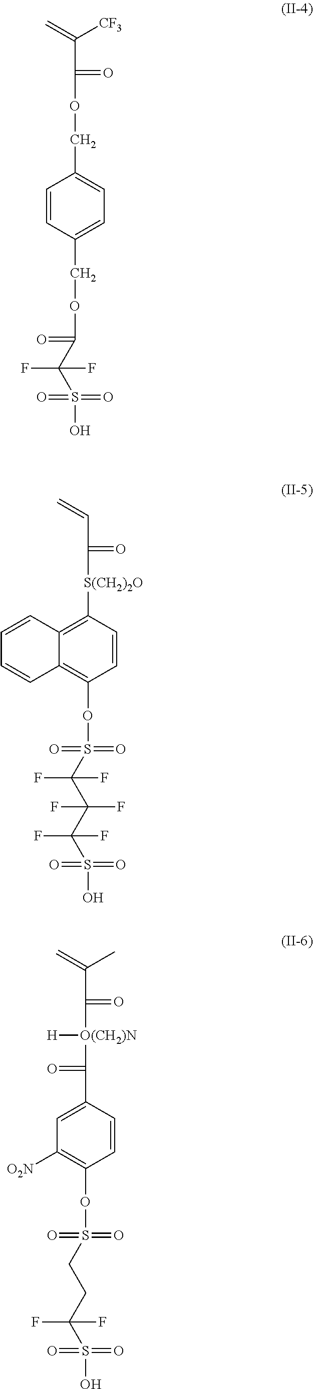

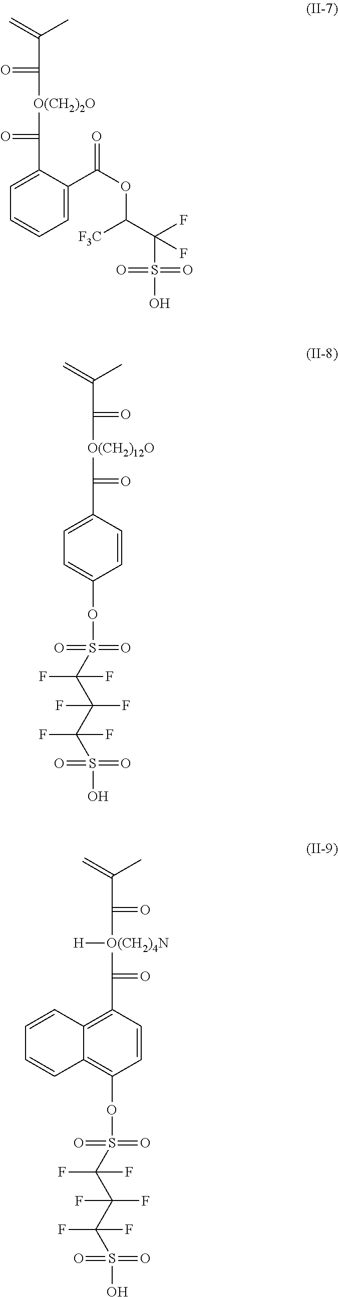

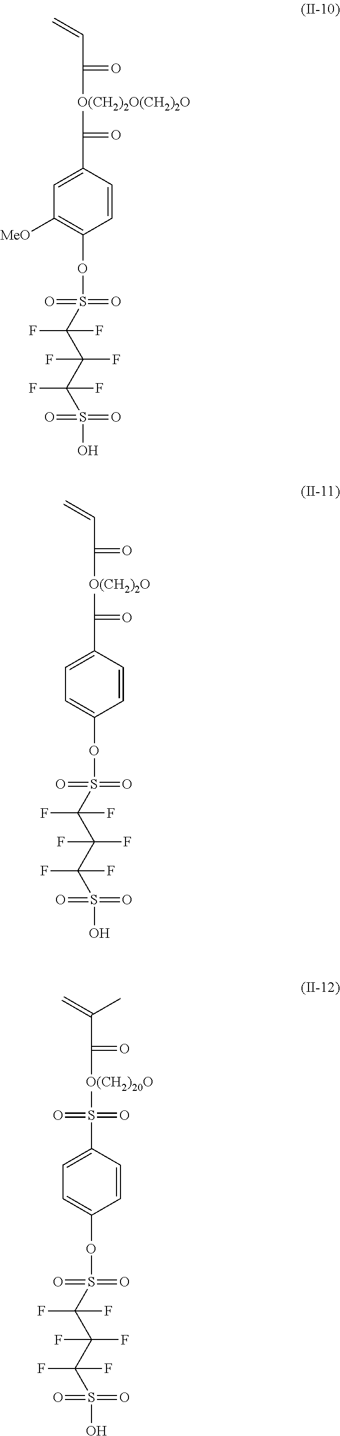

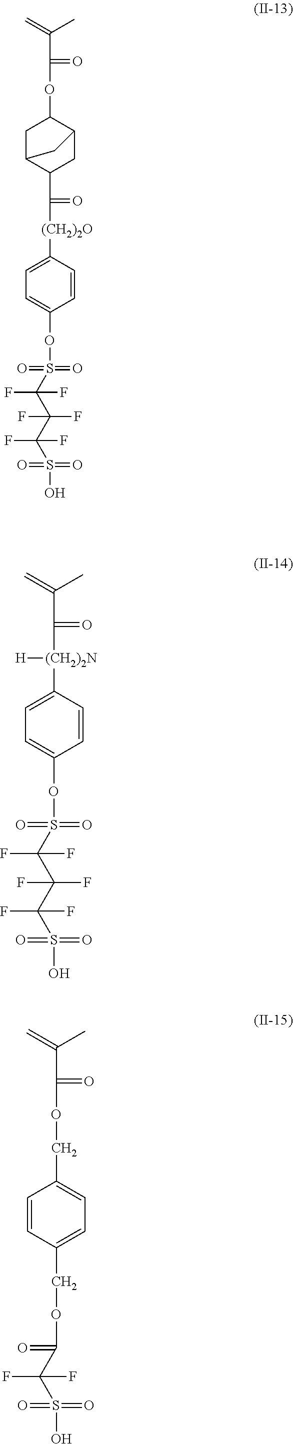

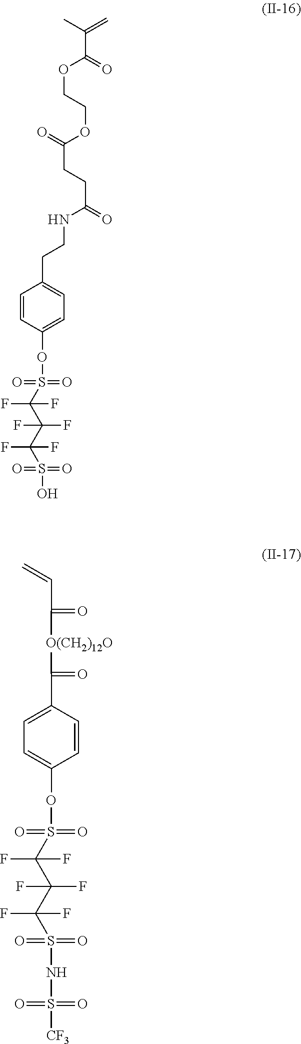

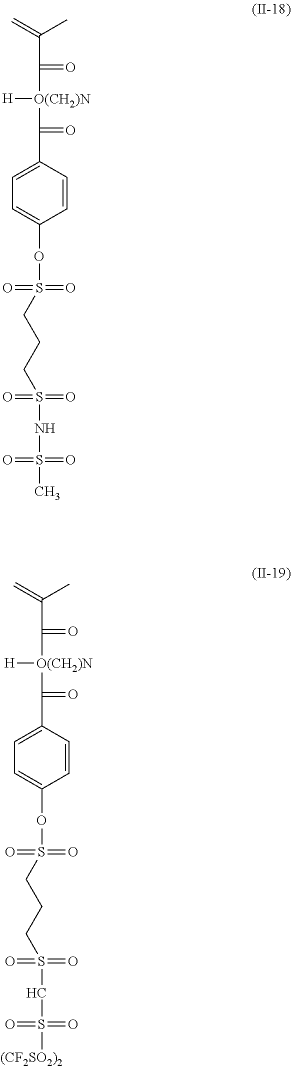

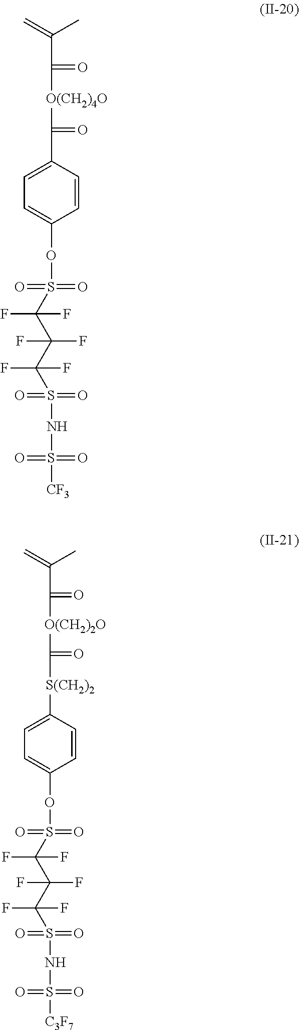

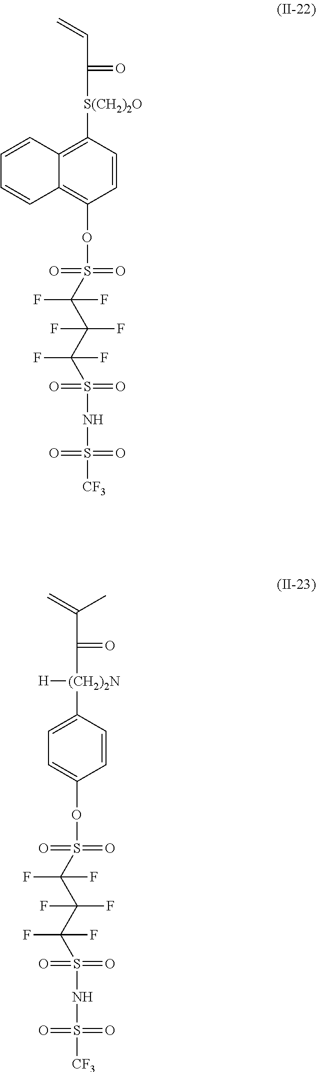

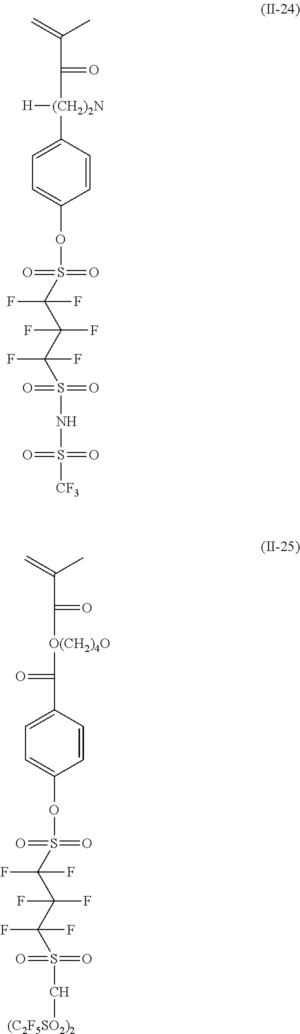

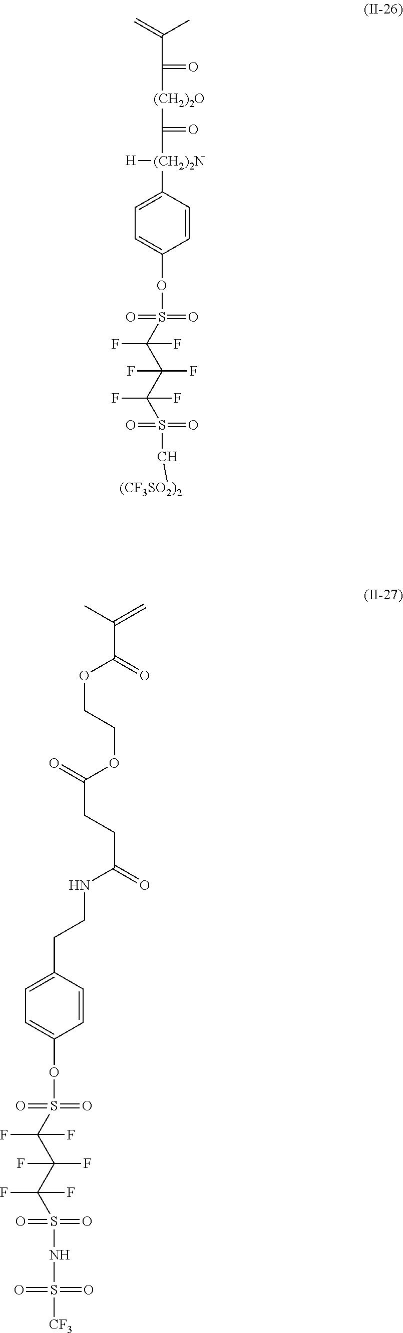

Moreover, the repeating unit (A) in its other form may be any of repeating units wherein an aromatic ring is contained in the side chain excluding the cation counter to the acid anion, expressed by formulae other than general formulae (I) and (II).

With respect to the polymerizable monomer units corresponding to the repeating units (A), examples thereof will be shown below as acids formed by the cleavage of a cation upon exposure to actinic rays or radiation.

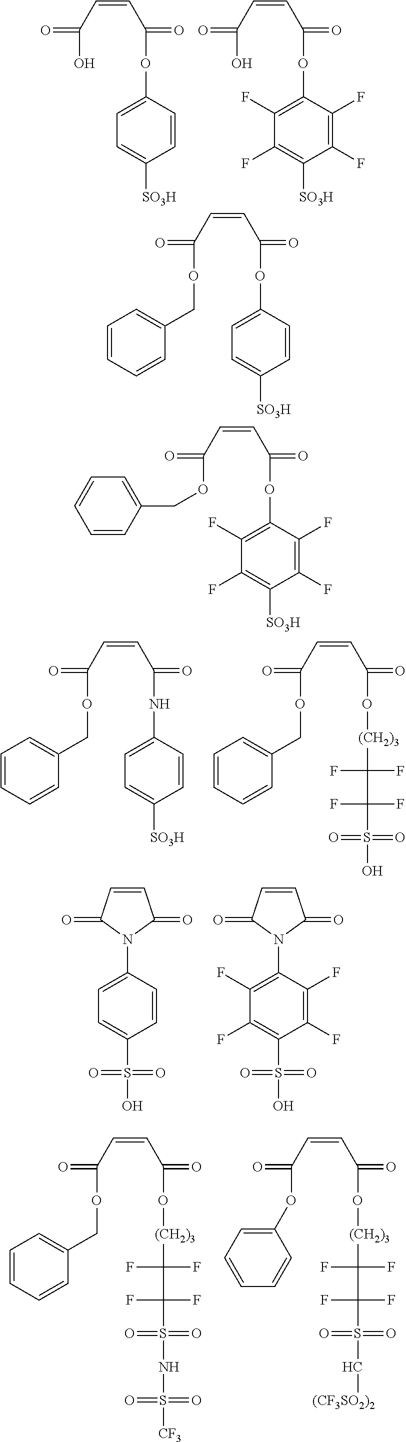

The repeating units of general formula (III) below are also preferred as the repeating unit (A).

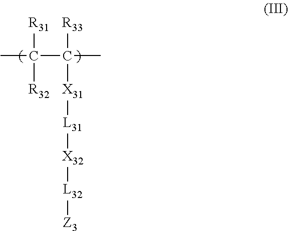

In general formula (III), each of R₃₁, R₃₂ and R₃₃ independently represents a hydrogen atom, an alkyl group, a cycloalkyl group, a halogen atom, a cyano group or an alkoxycarbonyl group.

The alkyl group is an optionally substituted linear or branched alkyl group, preferably an optionally substituted alkyl group having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred. An alkyl group having 3 or less carbon atoms is most preferred.

The alkyl group contained in the alkoxycarbonyl group is preferably the same as the alkyl group mentioned above with respect to R₃₁, R₃₂ and R₃₃.

As the cycloalkyl group, there can be mentioned an optionally substituted mono- or polycycloalkyl group. An optionally substituted cycloalkyl group having 3 to 8 carbon atoms, such as a cyclopropyl group, a cyclopentyl group or a cyclohexyl group, is preferred.

As the halogen atom, there can be mentioned a fluorine atom, a chlorine atom, a bromine atom or an iodine atom. A fluorine atom is especially preferred.

As preferred substituents that can be introduced in these groups, there can be mentioned, for example, those explained with respect to R₁₁, R₁₂ and R₁₃ as set forth above.

In general formula (III), each of R₃₁, R₃₂ and R₃₃ preferably represents a hydrogen atom, an alkyl group or a halogen atom, especially preferably a hydrogen atom, a methyl group, an ethyl group, a trifluoromethyl group (—CF₃), a hydroxymethyl group (—CH₂—OH), a chloromethyl group (—CH₂—Cl) and a fluorine atom (—F).

Each of X₃₁ and X₃₂ independently represents a single bond, —O—, —S—, —CO—, —SO₂—, —NR— (R represents a hydrogen atom or an alkyl group), a bivalent nitrogen-containing nonaromatic heterocyclic group or a group composed of a combination of these.

In —NR—, the alkyl group represented by R is an optionally substituted linear or branched alkyl group. Particular examples of such alkyl groups are the same as mentioned above with respect to the alkyl groups represented by R₃₁, R₃₂ and R₃₃. Most preferably, R is a hydrogen atom, a methyl group or an ethyl group.

The above bivalent nitrogen-containing nonaromatic heterocyclic group refers to a nonaromatic heterocyclic group, preferably 3- to 8-membered, containing at least one nitrogen atom. For example, there can be mentioned any of the structures set forth above as examples with respect to X₁₁ to X₁₃ of general formula (I).

Preferably, X₃₁ is a single bond, —O—, —CO— or —NR— (R represents a hydrogen atom or an alkyl group) or a group composed of a combination of these. —COO— and —CONR— (R represents a hydrogen atom or an alkyl group) are especially preferred.

Preferably, X₃₂ is a single bond, —O—, —CO—, —SO₂— or a bivalent nitrogen-containing nonaromatic heterocyclic group or a group composed of a combination of these. —COO—, —OSO₂— and a group composed of a combination of a bivalent nitrogen-containing nonaromatic heterocyclic group and —SO₂— are especially preferred.

L₃₁ represents a single bond, an alkylene group, an alkenylene group, a cycloalkylene group or a group composed of a combination of two or more of these, provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group or a group composed of a combination of these.

As the alkylene group represented by L₃₁, for example, those explained with respect to L₁₁ above can be exemplified.

As the alkenylene group, there can be mentioned a group resulting from the introduction of a double bond in any position of the alkylene group represented by L₃₁ above.

As the cycloalkylene group represented by L₃₁, for example, those explained with respect to L₁₁ above can be exemplified.

Particular examples of the —NR— and bivalent nitrogen-containing nonaromatic heterocyclic group are the same as mentioned above in connection with X₃₁. Preferred examples are also the same.

Most preferably, L₃₁ is a single bond, an alkylene group, a cycloalkylene group or a group composed of two or more of these combined through —COO—, —O— or —CONH— as a connecting group (for example, -alkylene group-O-alkylene group-, -alkylene group-OCO-alkylene group-, -cycloalkylene group-O-alkylene group-, -alkylene group-CONH-alkylene group- and the like).

L₃₂ represents an alkylene group, an alkenylene group, a cycloalkylene group or a group composed of a combination of two or more of these, provided that the hydrogen atoms of these groups are partially or entirely substituted with a substituent selected from among a fluorine atom, a fluoroalkyl group, a nitro group and a cyano group, and provided that in the group composed of a combination, two or more groups combined together may be identical to or different from each other and may be linked to each other through, as a connecting group, —O—, —S—, —CO—, —SO₂—, —NR— (R represents a hydrogen atom or an alkyl group), a bivalent nitrogen-containing nonaromatic heterocyclic group or a group composed of a combination of these.

Preferably, L₃₂ is an alkylene group whose hydrogen atoms are partially or entirely substituted with a fluorine atom or a fluoroalkyl group (more preferably a perfluoroalkyl group). An alkylene group at least partially or entirely substituted with a fluorine atom are especially preferred. L₃₂ is most preferably an alkylene group, 30 to 100% of the hydrogen atoms of which are substituted with a fluorine atom.

As the alkylene group represented by L₃₂, for example, those explained with respect to L₁₁ above can be exemplified.

As the alkenylene group, there can be mentioned a group resulting from the introduction of a double bond in any position of the alkylene group above.

The cycloalkylene group may be monocyclic or polycyclic. As preferred examples thereof, there can be mentioned, for example, cycloalkylene groups each having 3 to 17 carbon atoms, such as a cyclobutylene group, a cyclopentylene group, a cyclohexylene group, a norbornanylene group, an adamantylene group or a diadamantanylene group.

Particular examples of the —NR— and bivalent nitrogen-containing nonaromatic heterocyclic group as connecting groups represented by L₃₂ are the same as mentioned above in connection with X₃₁. Preferred examples are also the same.

As preferred particular examples of the structures represented by L₃₂, there can be mentioned those set forth above with respect to L₁₂ of general formula (I).

Z₃ represents the same as set forth with respect to Z₁ in general formula (I). The above description regarding Z₁ also applies to Z₃.

With respect to the polymerizable monomer units corresponding to the repeating units of general formula (III), examples thereof will be shown below as acids formed by the cleavage of a cation upon exposure to actinic rays or radiation.

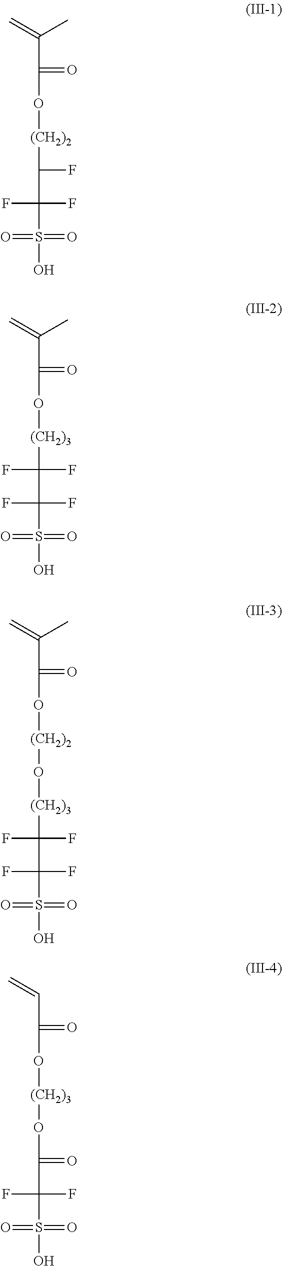

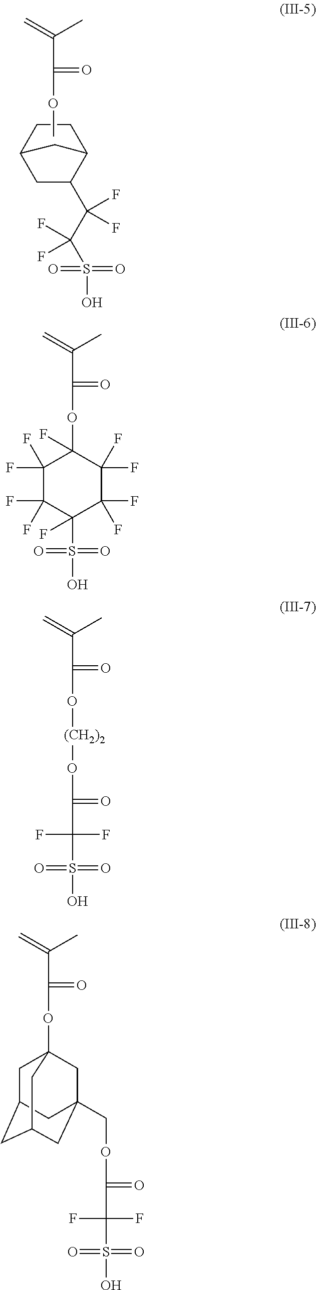

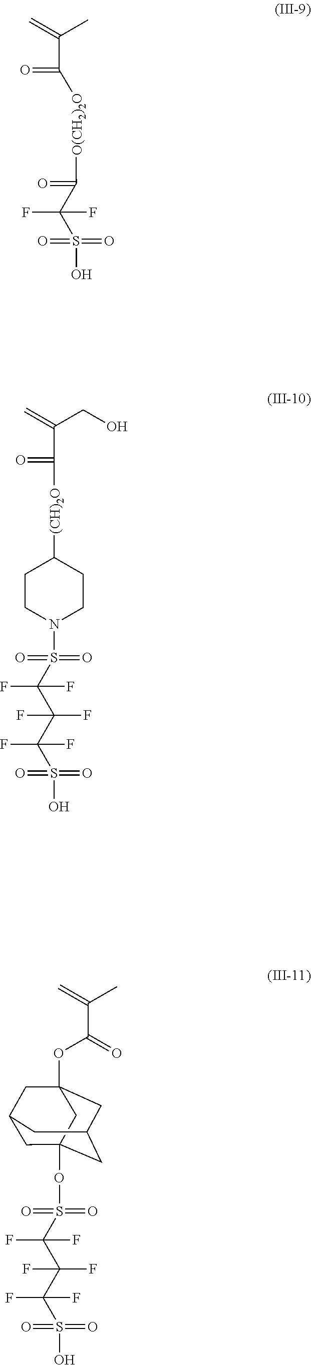

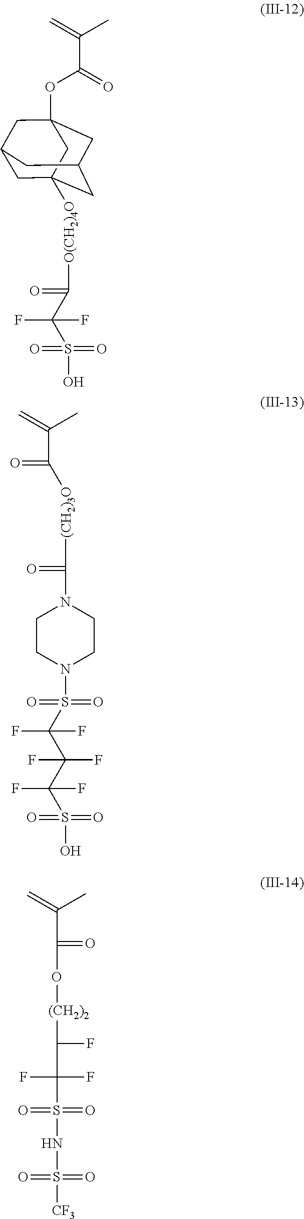

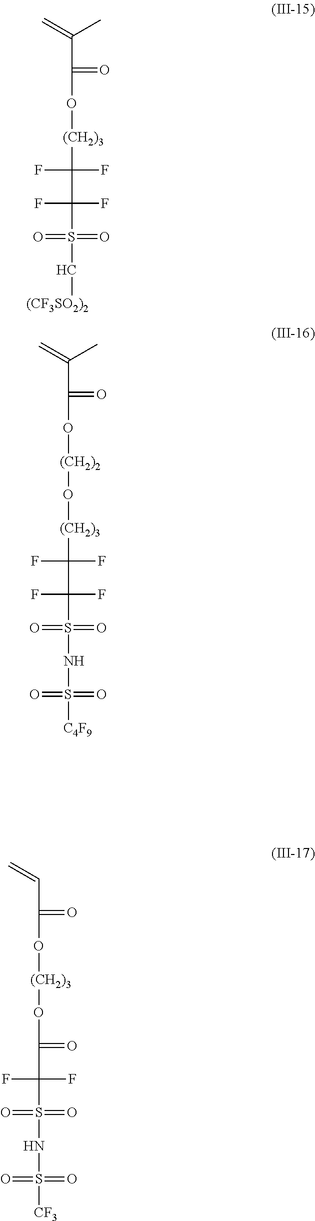

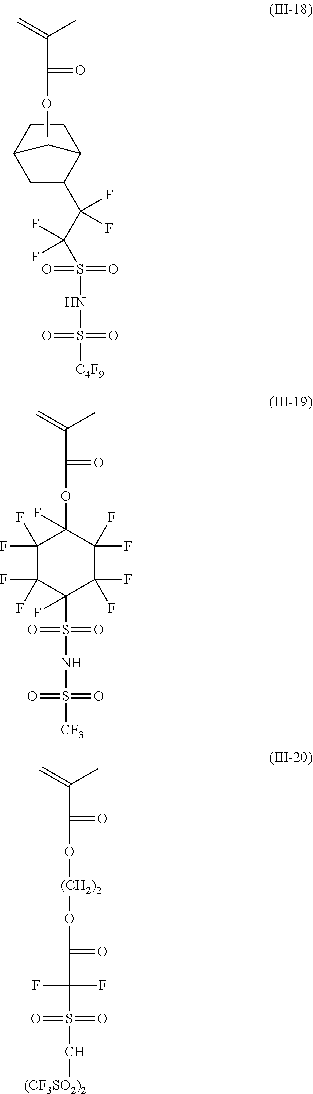

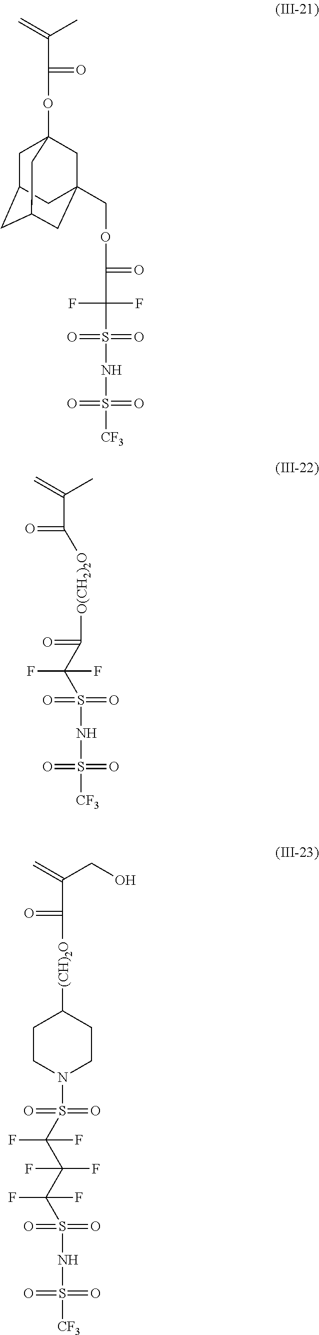

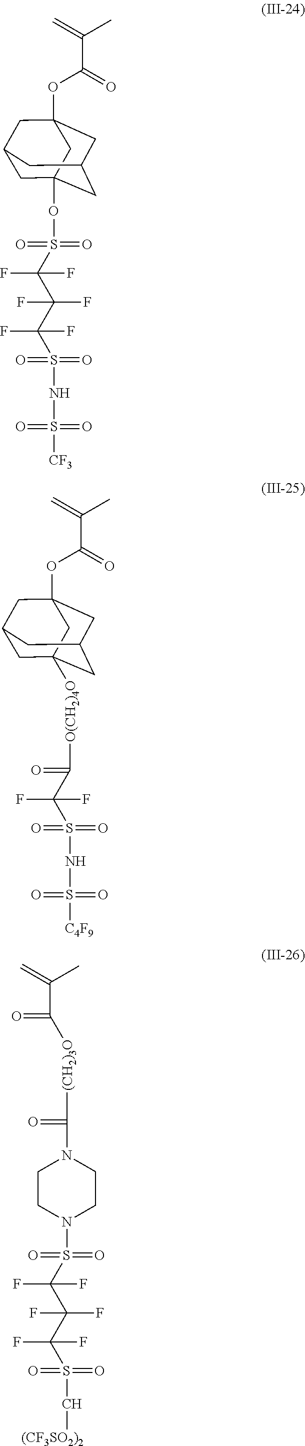

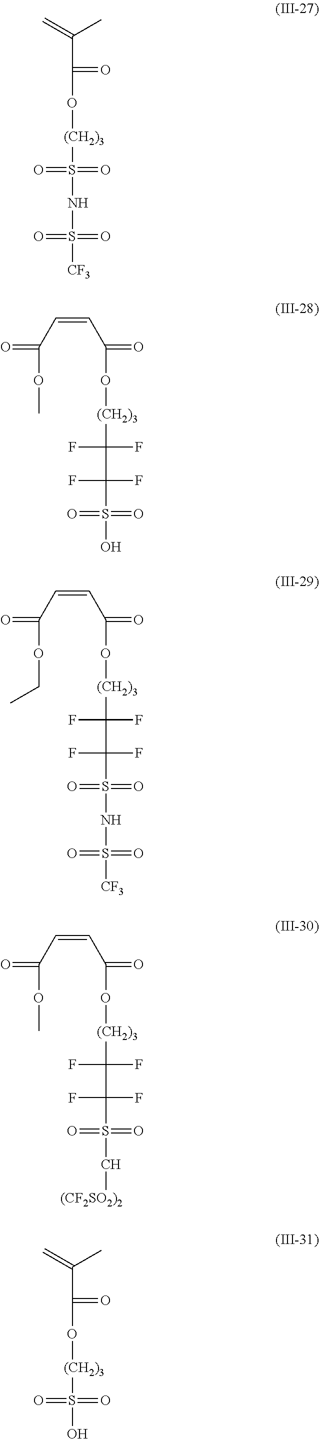

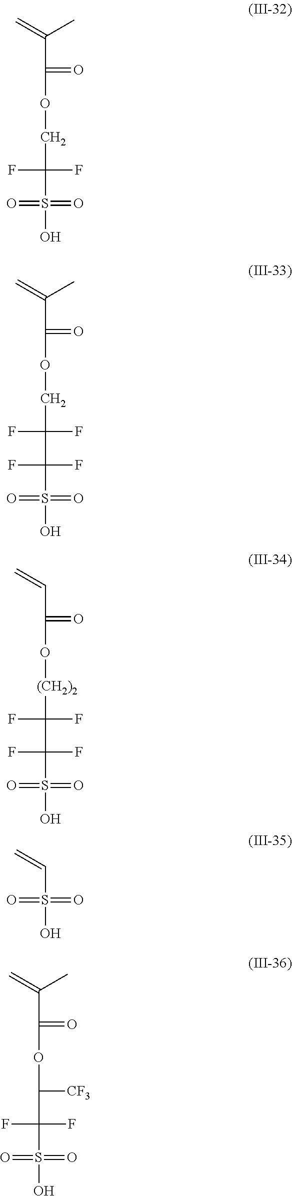

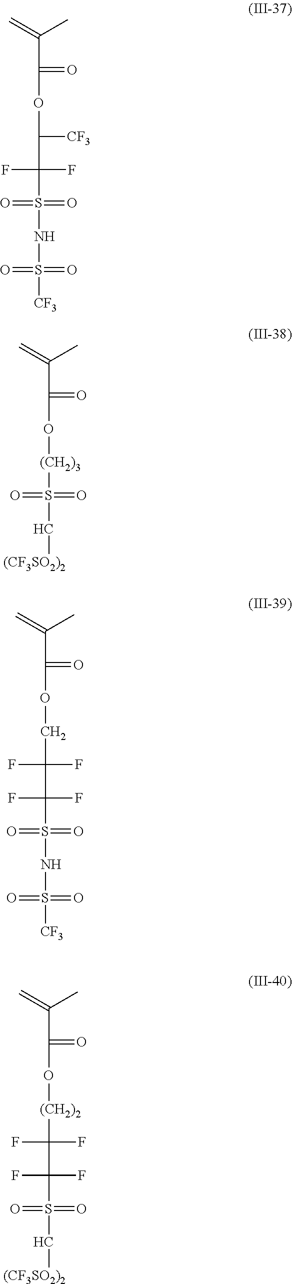

The polymerizable compound (M) corresponding to the repeating unit (A) can be synthesized, for example, in the following way. Firstly, a lithium, sodium or potassium salt of polymerizable compound containing an acid group; and a hydroxide, bromide or chloride of the cation with a monocyclic or polycyclic heterocycle containing a nitrogen atom are prepared. Secondly, these are made reacted with each other by a salt exchange method or a method using ion exchange resin. The polymerizable compound (M) corresponding to the repeating unit (A) are thus obtained.

The polymerizable compounds containing an acid group can be synthesized, for example, through the general sulfonating reaction or sulfonamidating reaction. For example, the polymerizable compounds can be obtained by either a method in which one of the sulfonyl halide moieties of a bissulfonyl halide compound is selectively reacted with an amine, an alcohol and the like to thereby form a sulfonamide bond or a sulfonic ester bond and thereafter the other sulfonyl halide moiety is hydrolyzed, or a method in which the ring of a cyclic sulfonic anhydride is opened by an amine or an alcohol. Further, the polymerizable compounds can be easily synthesized through the methods described in U.S. Pat. No. 5,554,664, J. Fluorine Chem. 105 (2000) 129-136 and J. Fluorine Chem. 116 (2002) 45-48.

Specific examples of the polymerizable compound (M) corresponding to the repeating unit (A) will be shown below. In Table 1, the specific examples are shown as combinations of cation structure and anion structure.

TABLE 1

| Polymerizable | Cation | Anion |
|---|---|---|
| compound (M) | structure | structure |
| M-I-1 | AZ-1 | I-1 |
| M-I-2 | AZ-17 | I-1 |
| M-I-3 | AZ-24 | I-1 |
| M-I-4 | AZ-25 | I-1 |
| M-I-5 | AZ-31 | I-1 |
| M-I-6 | AZ-38 | I-1 |
| M-I-7 | AZ-91 | I-1 |
| M-I-8 | AZ-113 | I-1 |
| M-I-9 | AZ-161 | I-1 |
| M-I-10 | AZ-183 | I-1 |
| M-I-11 | AZ-153 | I-1 |
| M-I-12 | AZ-155 | I-1 |
| M-I-13 | AZ-202 | I-1 |
| M-I-14 | AZ-210 | I-1 |
| M-I-15 | AZ-17 | I-2 |
| M-I-16 | AZ-1 | I-3 |
| M-I-17 | AZ-24 | I-3 |
| M-I-18 | AZ-31 | I-3 |
| M-I-19 | AZ-91 | I-3 |
| M-I-20 | AZ-161 | I-3 |
| M-I-21 | AZ-153 | I-3 |
| M-I-22 | AZ-202 | I-3 |
| M-I-23 | AZ-25 | I-3 |
| M-I-24 | AZ-1 | I-4 |
| M-I-25 | AZ-24 | I-5 |
| M-I-26 | AZ-25 | I-6 |
| M-I-27 | AZ-31 | I-7 |
| M-I-28 | AZ-38 | I-8 |
| M-I-29 | AZ-91 | I-9 |
| M-I-30 | AZ-113 | I-10 |
| M-I-31 | AZ-17 | I-11 |
| M-I-32 | AZ-24 | I-11 |
| M-I-33 | AZ-25 | I-11 |
| M-I-34 | AZ-38 | I-11 |
| M-I-35 | AZ-113 | I-11 |
| M-I-36 | AZ-183 | I-11 |
| M-I-37 | AZ-155 | I-11 |
| M-I-38 | AZ-210 | I-11 |
| M-I-39 | AZ-1 | I-11 |
| M-I-40 | AZ-161 | I-12 |
| M-I-41 | AZ-183 | I-13 |
| M-I-42 | AZ-153 | I-14 |
| M-I-43 | AZ-155 | I-15 |
| M-I-44 | AZ-202 | I-16 |
| M-I-45 | AZ-17 | I-17 |
| M-I-46 | AZ-25 | I-17 |
| M-I-47 | AZ-38 | I-17 |
| M-I-48 | AZ-113 | I-17 |
| M-I-49 | AZ-183 | I-17 |
| M-I-50 | AZ-155 | I-17 |
| M-I-51 | AZ-210 | I-17 |
| M-I-52 | AZ-24 | I-17 |
| M-I-53 | AZ-210 | I-18 |
| M-I-54 | AZ-1 | I-19 |
| M-I-55 | AZ-24 | I-19 |
| M-I-56 | AZ-31 | I-19 |
| M-I-57 | AZ-91 | I-19 |
| M-I-58 | AZ-161 | I-19 |
| M-I-59 | AZ-153 | I-19 |
| M-I-60 | AZ-1 | I-20 |
| M-I-61 | AZ-17 | I-21 |
| M-I-62 | AZ-24 | I-22 |
| M-I-63 | AZ-25 | I-23 |
| M-I-64 | AZ-31 | I-24 |
| M-I-65 | AZ-202 | I-25 |
| M-I-66 | AZ-17 | I-25 |
| M-I-67 | AZ-25 | I-25 |
| M-I-68 | AZ-38 | I-25 |
| M-I-69 | AZ-113 | I-25 |
| M-I-70 | AZ-183 | I-25 |
| M-I-71 | AZ-38 | I-26 |
| M-I-72 | AZ-91 | I-27 |
| M-I-73 | AZ-113 | I-28 |
| M-I-74 | AZ-161 | I-29 |
| M-I-75 | AZ-183 | I-30 |
| M-I-76 | AZ-153 | I-31 |
| M-I-77 | AZ-155 | I-32 |
| M-I-78 | AZ-202 | I-33 |
| M-I-79 | AZ-1 | I-34 |
| M-I-80 | AZ-24 | I-34 |
| M-I-81 | AZ-25 | I-34 |
| M-I-82 | AZ-31 | I-34 |
| M-I-83 | AZ-91 | I-34 |
| M-I-84 | AZ-161 | I-34 |
| M-I-85 | AZ-153 | I-34 |
| M-I-86 | AZ-202 | I-34 |
| M-I-87 | AZ-17 | I-34 |
| M-I-88 | AZ-210 | I-35 |
| M-I-89 | AZ-1 | I-36 |
| M-I-90 | AZ-17 | I-37 |
| M-I-91 | AZ-24 | I-38 |
| M-I-92 | AZ-25 | I-39 |
| M-I-93 | AZ-31 | I-40 |
| M-I-94 | AZ-1 | I-41 |
| M-I-95 | AZ-17 | I-41 |
| M-I-96 | AZ-24 | I-41 |
| M-I-97 | AZ-25 | I-41 |
| M-I-98 | AZ-31 | I-41 |
| M-I-99 | AZ-38 | I-41 |
| M-I-100 | AZ-91 | I-41 |
| M-I-101 | AZ-113 | I-41 |
| M-I-102 | AZ-161 | I-41 |
| M-I-103 | AZ-183 | I-41 |
| M-I-104 | AZ-153 | I-41 |
| M-I-105 | AZ-155 | I-41 |
| M-I-106 | AZ-202 | I-41 |
| M-I-107 | AZ-210 | I-41 |
| M-I-108 | AZ-38 | I-42 |
| M-I-109 | AZ-1 | I-43 |
| M-I-110 | AZ-24 | I-43 |
| M-I-111 | AZ-25 | I-43 |
| M-I-112 | AZ-31 | I-43 |
| M-I-113 | AZ-91 | I-43 |
| M-I-114 | AZ-161 | I-43 |
| M-I-115 | AZ-153 | I-43 |
| M-I-116 | AZ-202 | I-43 |
| M-I-117 | AZ-155 | I-44 |
| M-I-118 | AZ-210 | I-44 |
| M-I-119 | AZ-1 | I-44 |
| M-I-120 | AZ-24 | I-44 |
| M-I-121 | AZ-31 | I-44 |
| M-I-122 | AZ-91 | I-45 |
| M-I-123 | AZ-113 | I-46 |
| M-I-124 | AZ-161 | I-47 |
| M-I-125 | AZ-183 | I-48 |
| M-I-126 | AZ-153 | I-49 |
| M-I-127 | AZ-155 | I-50 |
| M-I-128 | AZ-202 | I-51 |
| M-I-129 | AZ-210 | I-52 |
| M-I-130 | AZ-1 | I-53 |
| M-I-131 | AZ-17 | I-54 |
| M-I-132 | AZ-24 | I-55 |
| M-I-133 | AZ-25 | I-56 |
| M-I-134 | AZ-31 | I-57 |
| M-I-135 | AZ-38 | I-58 |
| M-I-136 | AZ-91 | I-59 |
| M-I-137 | AZ-113 | I-60 |
| M-I-138 | AZ-91 | I-61 |
| M-I-139 | AZ-161 | I-61 |
| M-I-140 | AZ-153 | I-61 |
| M-I-141 | AZ-202 | I-61 |
| M-I-142 | AZ-17 | I-61 |
| M-I-143 | AZ-25 | I-62 |
| M-I-144 | AZ-38 | I-62 |
| M-I-145 | AZ-113 | I-62 |
| M-I-146 | AZ-183 | I-62 |
| M-I-147 | AZ-155 | I-62 |
| M-I-148 | AZ-1 | I-63 |
| M-I-149 | AZ-17 | I-64 |
| M-I-150 | AZ-24 | I-65 |
| M-I-151 | AZ-249 | I-1 |
| M-I-152 | AZ-249 | I-41 |
| M-I-153 | AZ-250 | I-1 |
| M-I-154 | AZ-250 | I-41 |
| M-I-155 | AZ-251 | I-1 |
| M-I-156 | AZ-251 | I-41 |
| M-I-157 | AZ-252 | I-61 |
| M-I-158 | AZ-253 | I-5 |
| M-I-159 | AZ-254 | I-11 |
| M-I-160 | AZ-255 | I-43 |
| M-I-161 | AZ-256 | I-1 |
| M-I-162 | AZ-257 | I-18 |
| M-I-163 | AZ-258 | I-31 |
| M-I-164 | AZ-259 | I-2 |
| M-I-165 | AZ-260 | I-15 |
| M-I-166 | AZ-261 | I-38 |
| M-I-167 | AZ-262 | I-17 |
| M-I-168 | AZ-263 | I-4 |
| M-I-169 | AZ-264 | I-45 |
| M-I-170 | AZ-265 | I-53 |
| M-I-171 | AZ-266 | I-1 |
| M-I-172 | AZ-267 | I-41 |
| M-I-173 | AZ-268 | I-19 |
| M-I-174 | AZ-269 | I-22 |
| M-I-175 | AZ-270 | I-1 |
| M-I-176 | AZ-271 | I-2 |
| M-I-177 | AZ-272 | I-1 |
| M-I-178 | AZ-273 | I-41 |
| M-I-179 | AZ-274 | I-43 |
| M-I-180 | AZ-275 | I-1 |
| M-I-181 | AZ-276 | I-11 |
| M-I-182 | AZ-277 | I-43 |
| M-I-183 | AZ-278 | I-61 |
| M-I-184 | AZ-279 | I-34 |
| M-II-1 | AZ-1 | II-1 |
| M-II-2 | AZ-17 | II-1 |
| M-II-3 | AZ-24 | II-1 |
| M-II-4 | AZ-25 | II-2 |
| M-II-5 | AZ-31 | II-2 |
| M-II-6 | AZ-38 | II-2 |
| M-II-7 | AZ-91 | II-3 |
| M-II-8 | AZ-113 | II-3 |
| M-II-9 | AZ-161 | II-3 |
| M-II-10 | AZ-183 | II-4 |
| M-II-11 | AZ-153 | II-4 |
| M-II-12 | AZ-155 | II-4 |
| M-II-13 | AZ-202 | II-5 |
| M-II-14 | AZ-210 | II-5 |
| M-II-15 | AZ-1 | II-5 |
| M-II-16 | AZ-17 | II-6 |
| M-II-17 | AZ-24 | II-6 |
| M-II-18 | AZ-25 | II-6 |
| M-II-19 | AZ-31 | II-7 |
| M-II-20 | AZ-38 | II-7 |
| M-II-21 | AZ-91 | II-7 |
| M-II-22 | AZ-113 | II-8 |
| M-II-23 | AZ-161 | II-8 |
| M-II-24 | AZ-183 | II-8 |
| M-II-25 | AZ-153 | II-9 |
| M-II-26 | AZ-155 | II-9 |
| M-II-27 | AZ-202 | II-9 |
| M-II-28 | AZ-210 | II-10 |
| M-II-29 | AZ-1 | II-10 |
| M-II-30 | AZ-17 | II-10 |
| M-II-31 | AZ-24 | II-11 |
| M-II-32 | AZ-25 | II-11 |
| M-II-33 | AZ-31 | II-11 |
| M-II-34 | AZ-38 | II-12 |
| M-II-35 | AZ-91 | II-12 |
| M-II-36 | AZ-113 | II-12 |
| M-II-37 | AZ-161 | II-13 |
| M-II-38 | AZ-183 | II-13 |
| M-II-39 | AZ-153 | II-13 |
| M-II-40 | AZ-155 | II-14 |
| M-II-41 | AZ-202 | II-14 |
| M-II-42 | AZ-210 | II-14 |
| M-II-43 | AZ-1 | II-15 |
| M-II-44 | AZ-17 | II-15 |
| M-II-45 | AZ-24 | II-15 |
| M-II-46 | AZ-25 | II-15 |
| M-II-47 | AZ-31 | II-15 |
| M-II-48 | AZ-38 | II-15 |
| M-II-49 | AZ-91 | II-15 |
| M-II-50 | AZ-113 | II-15 |
| M-II-51 | AZ-161 | II-15 |
| M-II-52 | AZ-183 | II-15 |
| M-II-53 | AZ-153 | II-15 |
| M-II-54 | AZ-155 | II-15 |
| M-II-55 | AZ-202 | II-15 |
| M-II-56 | AZ-210 | II-15 |
| M-II-57 | AZ-1 | II-16 |
| M-II-58 | AZ-17 | II-16 |
| M-II-59 | AZ-24 | II-16 |
| M-II-60 | AZ-25 | II-17 |
| M-II-61 | AZ-31 | II-17 |
| M-II-62 | AZ-38 | II-17 |
| M-II-63 | AZ-91 | II-18 |
| M-II-64 | AZ-113 | II-18 |
| M-II-65 | AZ-161 | II-18 |
| M-II-66 | AZ-183 | II-19 |
| M-II-67 | AZ-153 | II-19 |
| M-II-68 | AZ-155 | II-19 |
| M-II-69 | AZ-202 | II-20 |
| M-II-70 | AZ-210 | II-20 |
| M-II-71 | AZ-1 | II-20 |
| M-II-72 | AZ-17 | II-21 |
| M-II-73 | AZ-24 | II-21 |
| M-II-74 | AZ-25 | II-21 |
| M-II-75 | AZ-31 | II-22 |
| M-II-76 | AZ-38 | II-22 |
| M-II-77 | AZ-91 | II-22 |
| M-II-78 | AZ-1 | II-23 |
| M-II-79 | AZ-17 | II-23 |
| M-II-80 | AZ-24 | II-23 |
| M-II-81 | AZ-25 | II-23 |
| M-II-82 | AZ-31 | II-23 |
| M-II-83 | AZ-38 | II-23 |
| M-II-84 | AZ-91 | II-23 |
| M-II-85 | AZ-113 | II-23 |
| M-II-86 | AZ-161 | II-23 |
| M-II-87 | AZ-183 | II-23 |
| M-II-88 | AZ-153 | II-23 |
| M-II-89 | AZ-155 | II-23 |
| M-II-90 | AZ-202 | II-23 |
| M-II-91 | AZ-210 | II-23 |
| M-II-92 | AZ-113 | II-24 |
| M-II-93 | AZ-161 | II-24 |
| M-II-94 | AZ-183 | II-25 |
| M-II-95 | AZ-153 | II-25 |
| M-II-96 | AZ-155 | II-25 |
| M-II-97 | AZ-202 | II-26 |
| M-II-98 | AZ-210 | II-26 |
| M-II-99 | AZ-1 | II-27 |
| M-II-100 | AZ-17 | II-27 |
| M-II-101 | AZ-249 | II-15 |
| M-II-102 | AZ-250 | II-6 |
| M-II-103 | AZ-251 | II-4 |
| M-II-104 | AZ-252 | II-24 |
| M-II-105 | AZ-253 | II-23 |
| M-II-106 | AZ-254 | II-15 |
| M-II-107 | AZ-255 | II-17 |
| M-II-108 | AZ-256 | II-16 |
| M-II-109 | AZ-265 | II-1 |
| M-II-110 | AZ-266 | II-15 |
| M-II-111 | AZ-267 | II-8 |
| M-II-112 | AZ-268 | II-23 |
| M-II-113 | AZ-270 | II-15 |
| M-II-114 | AZ-272 | II-2 |
| M-II-115 | AZ-273 | II-23 |
| M-II-116 | AZ-275 | II-15 |
| M-II-117 | AZ-276 | II-15 |
| M-II-118 | AZ-277 | II-23 |
| M-III-1 | AZ-1 | III-1 |
| M-III-2 | AZ-17 | III-1 |
| M-III-3 | AZ-1 | III-2 |
| M-III-4 | AZ-17 | III-2 |
| M-III-5 | AZ-24 | III-2 |
| M-III-6 | AZ-25 | III-2 |
| M-III-7 | AZ-31 | III-2 |
| M-III-8 | AZ-38 | III-2 |
| M-III-9 | AZ-91 | III-2 |
| M-III-10 | AZ-113 | III-2 |
| M-III-11 | AZ-161 | III-2 |
| M-III-12 | AZ-183 | III-2 |
| M-III-13 | AZ-153 | III-2 |
| M-III-14 | AZ-155 | III-2 |
| M-III-15 | AZ-202 | III-2 |
| M-III-16 | AZ-210 | III-2 |
| M-III-17 | AZ-24 | III-3 |
| M-III-18 | AZ-25 | III-3 |
| M-III-19 | AZ-31 | III-4 |
| M-III-20 | AZ-38 | III-4 |
| M-III-21 | AZ-91 | III-5 |
| M-III-22 | AZ-113 | III-5 |
| M-III-23 | AZ-161 | III-6 |
| M-III-24 | AZ-183 | III-6 |
| M-III-25 | AZ-153 | III-7 |
| M-III-26 | AZ-155 | III-7 |
| M-III-27 | AZ-202 | III-8 |
| M-III-28 | AZ-210 | III-8 |
| M-III-29 | AZ-1 | III-9 |
| M-III-30 | AZ-17 | III-9 |
| M-III-31 | AZ-24 | III-10 |
| M-III-32 | AZ-25 | III-10 |
| M-III-33 | AZ-31 | III-11 |
| M-III-34 | AZ-38 | III-11 |
| M-III-35 | AZ-91 | III-12 |
| M-III-36 | AZ-113 | III-12 |
| M-III-37 | AZ-161 | III-13 |
| M-III-38 | AZ-183 | III-13 |
| M-III-39 | AZ-153 | III-14 |
| M-III-40 | AZ-155 | III-14 |
| M-III-41 | AZ-202 | III-14 |
| M-III-42 | AZ-210 | III-14 |
| M-III-43 | AZ-1 | III-14 |
| M-III-44 | AZ-17 | III-14 |
| M-III-45 | AZ-24 | III-14 |
| M-III-46 | AZ-25 | III-14 |
| M-III-47 | AZ-1 | III-15 |
| M-III-48 | AZ-17 | III-15 |
| M-III-49 | AZ-24 | III-15 |
| M-III-50 | AZ-25 | III-15 |
| M-III-51 | AZ-31 | III-15 |
| M-III-52 | AZ-38 | III-15 |
| M-III-53 | AZ-91 | III-15 |
| M-III-54 | AZ-113 | III-15 |
| M-III-55 | AZ-161 | III-15 |
| M-III-56 | AZ-183 | III-15 |
| M-III-57 | AZ-153 | III-15 |
| M-III-58 | AZ-155 | III-15 |
| M-III-59 | AZ-202 | III-15 |
| M-III-60 | AZ-210 | III-15 |
| M-III-61 | AZ-31 | III-16 |
| M-III-62 | AZ-38 | III-16 |
| M-III-63 | AZ-91 | III-17 |
| M-III-64 | AZ-113 | III-17 |
| M-III-65 | AZ-161 | III-18 |
| M-III-66 | AZ-183 | III-18 |
| M-III-67 | AZ-153 | III-19 |
| M-III-68 | AZ-155 | III-19 |
| M-III-69 | AZ-202 | III-20 |
| M-III-70 | AZ-210 | III-20 |
| M-III-71 | AZ-1 | III-21 |
| M-III-72 | AZ-17 | III-21 |
| M-III-73 | AZ-24 | III-22 |
| M-III-74 | AZ-25 | III-22 |
| M-III-75 | AZ-31 | III-23 |
| M-III-76 | AZ-38 | III-23 |
| M-III-77 | AZ-91 | III-24 |
| M-III-78 | AZ-113 | III-24 |
| M-III-79 | AZ-161 | III-25 |
| M-III-80 | AZ-183 | III-25 |
| M-III-81 | AZ-153 | III-26 |
| M-III-82 | AZ-155 | III-26 |
| M-III-83 | AZ-1 | III-27 |
| M-III-84 | AZ-17 | III-27 |
| M-III-85 | AZ-24 | III-27 |
| M-III-86 | AZ-25 | III-27 |
| M-III-87 | AZ-31 | III-27 |
| M-III-88 | AZ-38 | III-27 |
| M-III-89 | AZ-91 | III-27 |
| M-III-90 | AZ-113 | III-27 |
| M-III-91 | AZ-161 | III-27 |
| M-III-92 | AZ-183 | III-27 |
| M-III-93 | AZ-153 | III-27 |
| M-III-94 | AZ-155 | III-27 |
| M-III-95 | AZ-202 | III-27 |
| M-III-96 | AZ-210 | III-27 |
| M-III-97 | AZ-1 | III-28 |
| M-III-98 | AZ-17 | III-28 |
| M-III-99 | AZ-24 | III-29 |
| M-III-100 | AZ-25 | III-29 |
| M-III-101 | AZ-31 | III-30 |
| M-III-102 | AZ-38 | III-30 |
| M-III-103 | AZ-91 | III-31 |
| M-III-104 | AZ-113 | III-31 |
| M-III-105 | AZ-1 | III-32 |
| M-III-106 | AZ-17 | III-32 |
| M-III-107 | AZ-24 | III-32 |
| M-III-108 | AZ-25 | III-32 |
| M-III-109 | AZ-31 | III-32 |
| M-III-110 | AZ-38 | III-32 |
| M-III-111 | AZ-91 | III-32 |
| M-III-112 | AZ-113 | III-32 |
| M-III-113 | AZ-121 | III-32 |
| M-III-114 | AZ-183 | III-32 |
| M-III-115 | AZ-153 | III-32 |
| M-III-116 | AZ-155 | III-32 |
| M-III-117 | AZ-202 | III-32 |
| M-III-118 | AZ-210 | III-32 |
| M-III-119 | AZ-161 | III-33 |
| M-III-120 | AZ-183 | III-33 |
| M-III-121 | AZ-153 | III-34 |
| M-III-122 | AZ-155 | III-34 |
| M-III-123 | AZ-202 | III-35 |
| M-III-124 | AZ-210 | III-35 |
| M-III-125 | AZ-1 | III-36 |
| M-III-126 | AZ-17 | III-36 |
| M-III-127 | AZ-24 | III-36 |
| M-III-128 | AZ-25 | III-36 |
| M-III-129 | AZ-31 | III-36 |
| M-III-130 | AZ-38 | III-36 |
| M-III-131 | AZ-91 | III-36 |
| M-III-132 | AZ-113 | III-36 |
| M-III-133 | AZ-161 | III-36 |
| M-III-134 | AZ-183 | III-36 |
| M-III-135 | AZ-153 | III-37 |
| M-III-136 | AZ-155 | III-37 |
| M-III-137 | AZ-202 | III-37 |
| M-III-138 | AZ-210 | III-37 |
| M-III-139 | AZ-1 | III-37 |
| M-III-140 | AZ-17 | III-37 |
| M-III-141 | AZ-24 | III-37 |
| M-III-142 | AZ-25 | III-37 |
| M-III-143 | AZ-31 | III-37 |
| M-III-144 | AZ-38 | III-37 |
| M-III-145 | AZ-91 | III-38 |
| M-III-146 | AZ-113 | III-38 |
| M-III-147 | AZ-161 | III-39 |
| M-III-148 | AZ-183 | III-39 |
| M-III-149 | AZ-153 | III-40 |
| M-III-150 | AZ-155 | III-40 |
| M-III-151 | AZ-249 | III-2 |
| M-III-152 | AZ-249 | III-37 |
| M-III-153 | AZ-250 | III-2 |
| M-III-154 | AZ-250 | III-37 |
| M-III-155 | AZ-251 | III-2 |
| M-III-156 | AZ-251 | III-32 |
| M-III-157 | AZ-252 | III-12 |
| M-III-158 | AZ-253 | III-27 |
| M-III-159 | AZ-254 | III-36 |
| M-III-160 | AZ-255 | III-9 |
| M-III-161 | AZ-256 | III-14 |
| M-III-162 | AZ-257 | III-37 |
| M-III-163 | AZ-258 | III-3 |
| M-III-164 | AZ-259 | III-2 |
| M-III-165 | AZ-260 | III-1 |
| M-III-166 | AZ-261 | III-17 |
| M-III-167 | AZ-262 | III-21 |
| M-III-168 | AZ-263 | III-8 |
| M-III-169 | AZ-264 | III-28 |
| M-III-170 | AZ-265 | III-24 |
| M-III-171 | AZ-266 | III-2 |
| M-III-172 | AZ-267 | III-37 |
| M-III-173 | AZ-268 | III-22 |
| M-III-174 | AZ-269 | III-2 |
| M-III-175 | AZ-270 | III-2 |
| M-III-176 | AZ-271 | III-37 |
| M-III-177 | AZ-272 | III-2 |
| M-III-178 | AZ-273 | III-37 |
| M-III-179 | AZ-274 | III-37 |
| M-III-180 | AZ-275 | III-15 |
| M-III-181 | AZ-276 | III-2 |
| M-III-182 | AZ-277 | III-15 |
| M-III-183 | AZ-278 | III-7 |
| M-III-184 | AZ-279 | III-10 |

The resin (P) may contain either one kind of the repeating unit (A) or two or more kinds thereof.

The content of repeating unit (A) in the resin (P), based on all the repeating units of the resin, is preferably in the range of 0.5 to 80 mol %, more preferably 1 to 60 mol % and further more preferably 3 to 40 mol %.

[Repeating Unit (B)]

The resin (P) may further contain a repeating unit (B) that is different from the repeating unit (A) and is configured to decompose when acted on by an acid to thereby generate an alkali-soluble group (hereinafter may be referred to as a “repeating unit containing an acid-decomposable group”).

As the alkali soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group and the like.

As preferred alkali soluble groups, there can be mentioned a phenolic hydroxyl group, a carboxyl group, a fluoroalcohol group (preferably hexafluoroisopropanol group) and a sulfonate group.

The acid-decomposable group is preferably a group as obtained by substituting the hydrogen atom of any of these alkali soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂) (OR₃₉) and the like.

In the formulae, each of R₃₆ to R₃₉ independently represents an alkyl group, a cycloalkyl group, a monovalent aromatic ring group, a combination of an alkylene group and a monovalent aromatic ring group or an alkenyl group. R₃₆ and R₃₇ may be bonded with each other to thereby form a ring structure.

Each of R₀₁ to R₀₂ independently represents a hydrogen atom, an alkyl group, a cycloalkyl group, a monovalent aromatic ring group, a combination of an alkylene group and a monovalent aromatic ring group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit (B) is more preferably any of those of general formula (V) below.

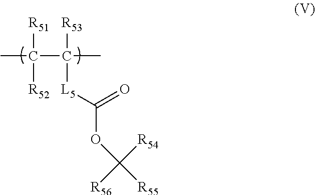

In general formula (V),

each of R₅₁, R₅₂ and R₅₃ independently represents a hydrogen atom, an alkyl group, a monovalent aliphatic hydrocarbon ring group, a halogen atom, a cyano group or an alkoxycarbonyl group, provided that R₅₂ may be bonded to L₅ to thereby form a ring (preferably a 5- or 6-membered ring), which R₅₂ in this instance is an alkylene group.

L₅ represents a single bond or a bivalent connecting group. When a ring is formed in cooperation with R₅₂, L₅ is a trivalent connecting group.

R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and R₅₅ and R₅₆ are not simultaneously hydrogen atoms.

General formula (V) will be described in greater detail below.

As a preferred alkyl group represented by each of R₅₁ to R₅₃ in general formula (V), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred, and an alkyl group having up to 3 carbon atoms is most preferred.

The alkyl group contained in the alkoxycarbonyl group is preferably the same as that represented by each of R₅₁ to R₅₃ above.

The cycloalkyl group may be monocyclic or polycyclic. An optionally substituted cycloalkyl group having 3 to 8 carbon atoms, such as a cyclopropyl group, a cyclopentyl group or a cyclohexyl group, is preferred.

As the halogen atom, there can be mentioned a fluorine atom, a chlorine atom, a bromine atom or an iodine atom. A fluorine atom is most preferred.

As preferred substituents that can be introduced in these groups, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

When R₅₂ is an alkylene group, the alkylene group is preferably an alkylene group having 1 to 8 carbon atoms, such as a methylene group, an ethylene group, a propylene group, a butylene group, a hexylene group or an octylene group. An alkylene group having 1 to 4 carbon atoms is more preferred, and an alkylene group having 1 or 2 carbon atoms is most preferred.

In formula (V), each of R₅₁ and R₅₃ is more preferably a hydrogen atom, an alkyl group or a halogen atom, most preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is more preferably a hydrogen atom, an alkyl group, a halogen atom or an alkylene group (forming a ring in cooperation with L₅), most preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring in cooperation with L₅) or an ethylene group (forming a ring in cooperation with L₅).

As the bivalent connecting group represented by L₅, there can be mentioned an alkylene group, a bivalent aromatic ring group, —COO-L₁-, —O-L₁-, a group composed of a combination of two or more of these, and the like. L₁ represents an alkylene group, a cycloalkylene group, a bivalent aromatic ring group or a group composed of a combination of an alkylene group and a bivalent aromatic ring group.

L₅ is preferably a single bond, —COO-L₁- (in which L₁ represents an alkylene group, or a bivalent aromatic ring group. When in the case the composition is exposed to ArF excimer lazer, L₅ is more preferably a single bond or —COO-L₁- from the viewpoint of low absorption at 193 nm region. L₁ is preferably an alkylene group having 1 to 5 carbon atoms, more preferably a methylene group or a propylene group.

The alkyl group represented by each of R₅₄ to R₅₆ is preferably an alkyl group having 1 to 20 carbon atoms, more preferably 1 to 10 carbon atoms. An alkyl group having 1 to 4 carbon atoms, such as a methyl group, an ethyl group, an n-propyl group, an isopropyl group, an n-butyl group, an isobutyl group or a t-butyl group, is most preferred.

The cycloalkyl group represented by each of R₅₅ and R₅₆ preferably has 3 to 20 carbon atoms. It may be a monocyclic one, such as a cyclopentyl group or a cyclohexyl group, or a polycyclic one, such as a norbornyl group, an adamantyl group, a tetracyclodecanyl group or a tetracyclododecanyl group.

The ring formed by the mutual bonding of R₅₅ and R₅₆ preferably has 3 to 20 carbon atoms. The ring may be a monocyclic one, such as a cyclopentyl group or a cyclohexyl group, or a polycyclic one, such as a norbornyl group, an adamantyl group, a tetracyclodecanyl group or a tetracyclododecanyl group. When a ring is formed by the mutual bonding of R₅₅ and R₅₆, R₅₄ is preferably an alkyl group having 1 to 3 carbon atoms, more preferably a methyl group or an ethyl group.

The monovalent aromatic ring group represented by each of R₅₅ and R₅₆ preferably has 6 to 20 carbon atoms. As such, there can be mentioned, for example, a phenyl group, a naphthyl group and the like. When either R₅₅ or R₅₆ is a hydrogen atom, the other is preferably a monovalent aromatic ring group.

When in the case the composition is exposed to ArF excimer lazer, it is preferred that each of R₅₅ and R₅₆ independently represents a hydrogen atom, an alkyl group or a cycloalkyl group from the viewpoint of lowering the absorption at 193 nm region.

In the synthesis of the monomers corresponding to the repeating units of general formula (V), any of general methods of synthesizing an ester containing a polymerizable group can be used, and the synthetic method is not particularly limited.

Particular examples of the repeating units (B) represented by general formula (V) will be shown below, which however in no way limit the scope of the present invention. In the formulae, Rx and Xa1 each represents H, CH₃, CF₃, or CH₂OH. Each of Rxa and Rxb independently represents an alkyl group having 1 to 4 carbon atoms. Z represents a substitutent and p represents an integer of 0 or greater.

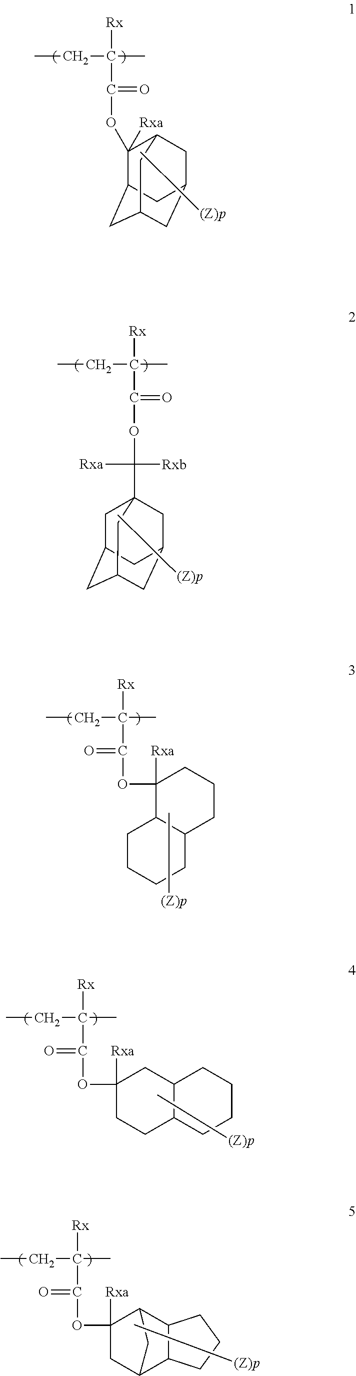

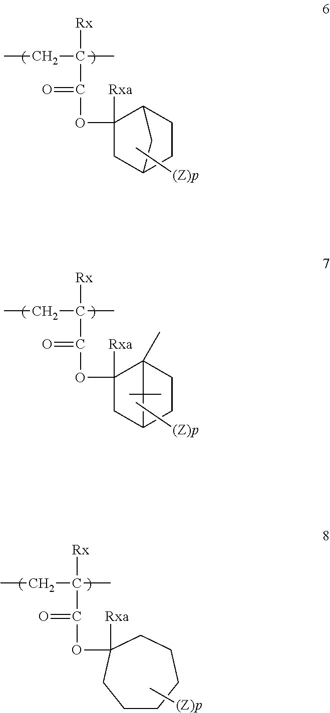

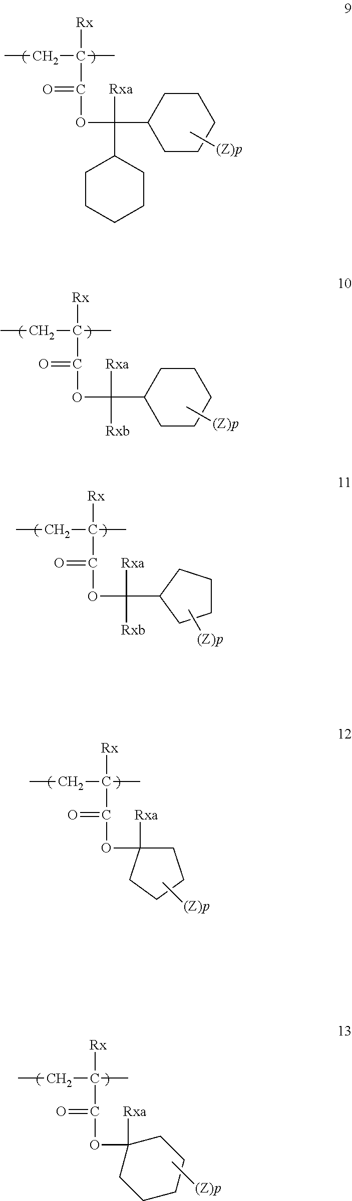

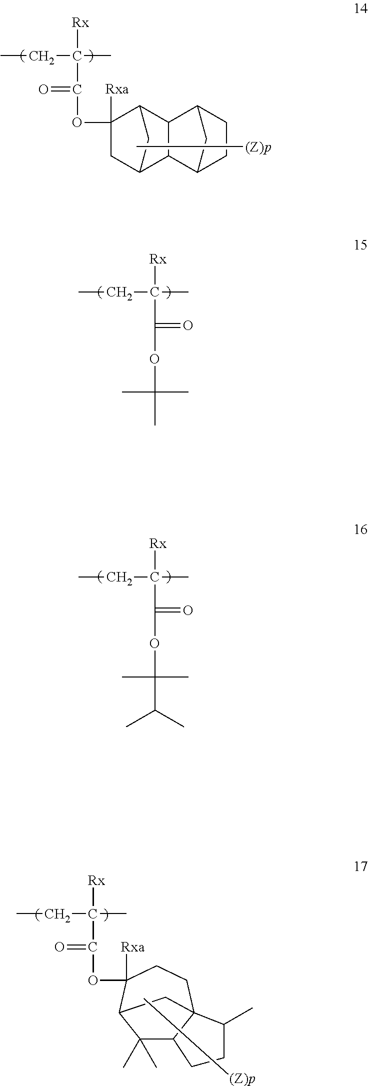

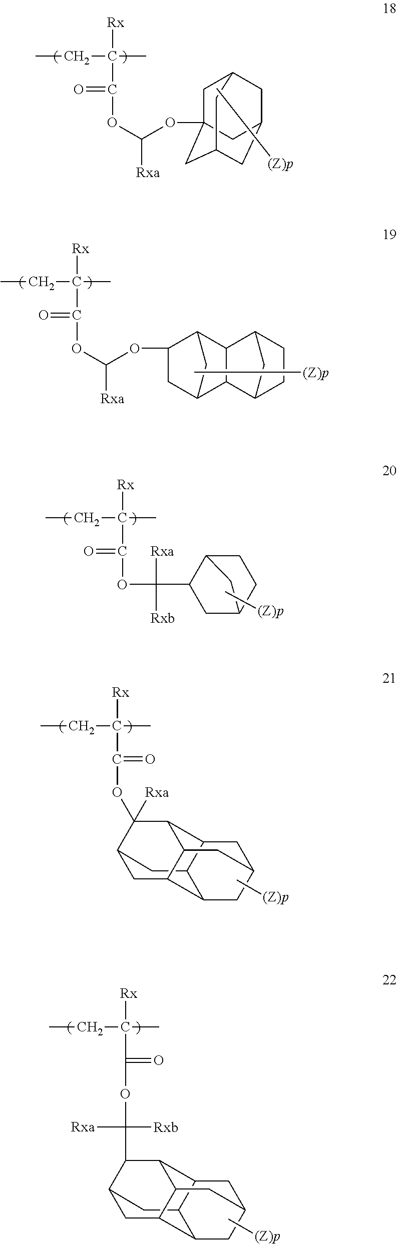

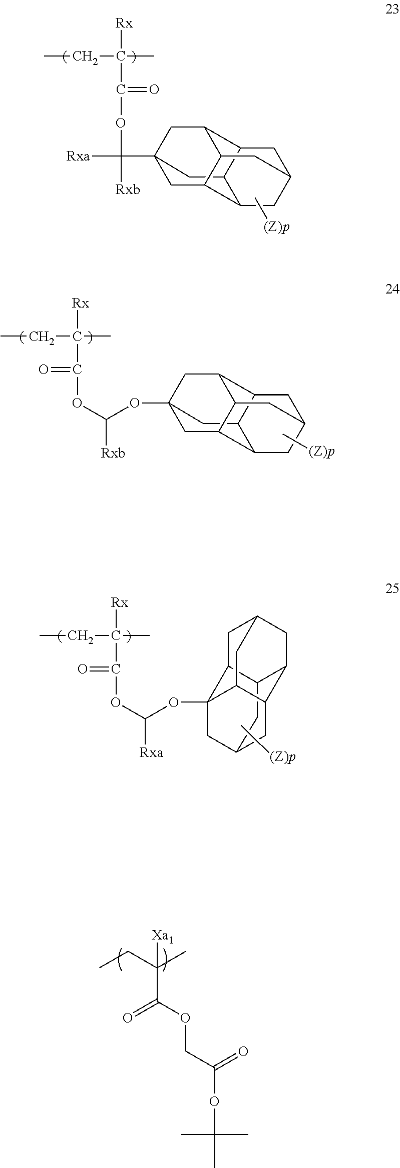

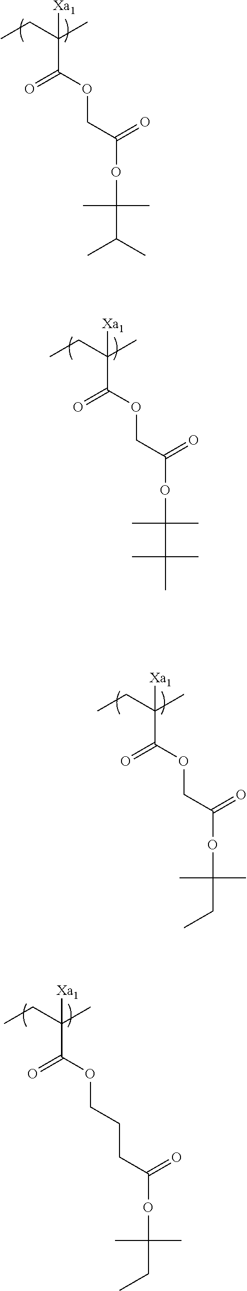

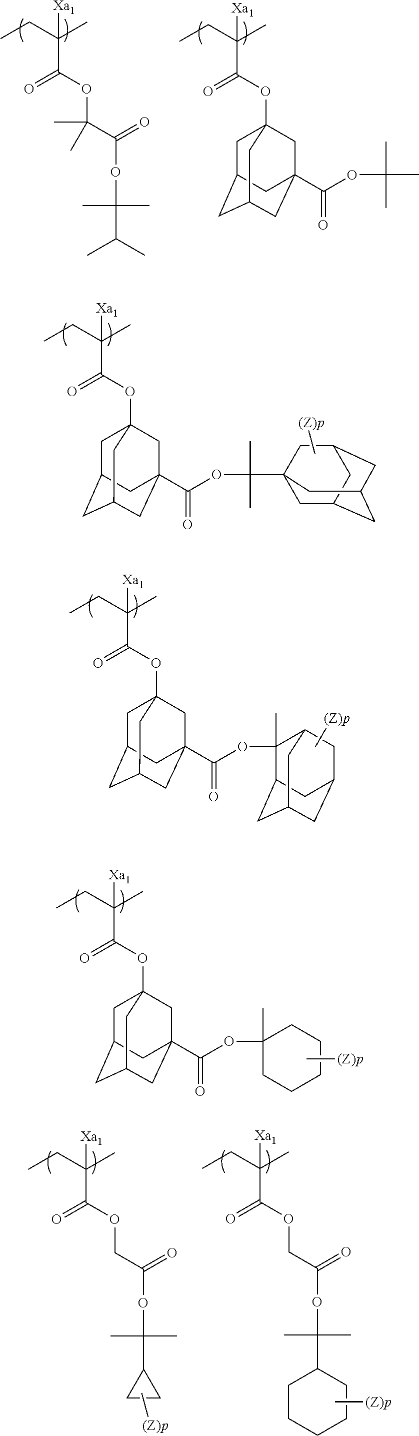

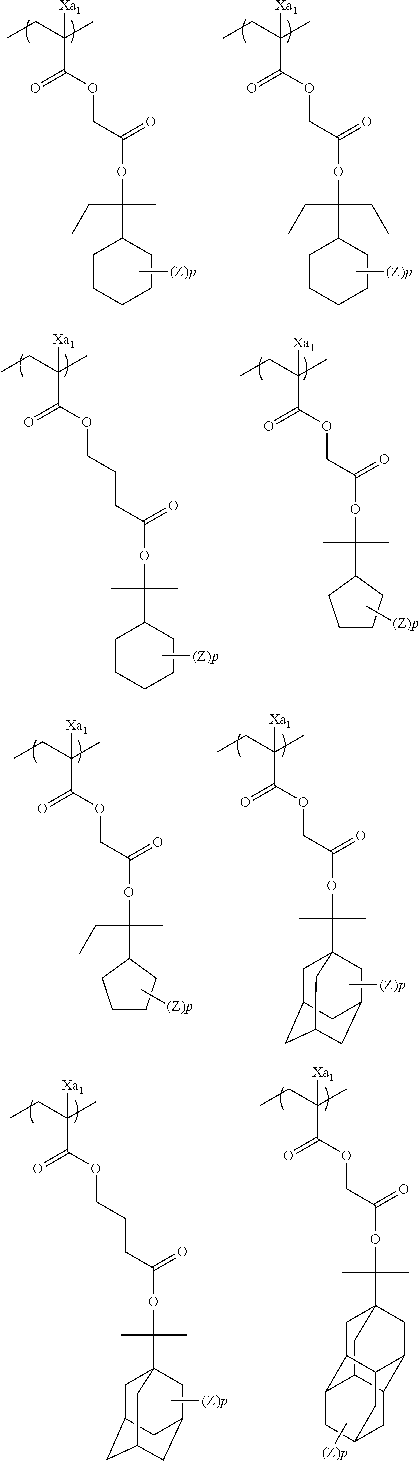

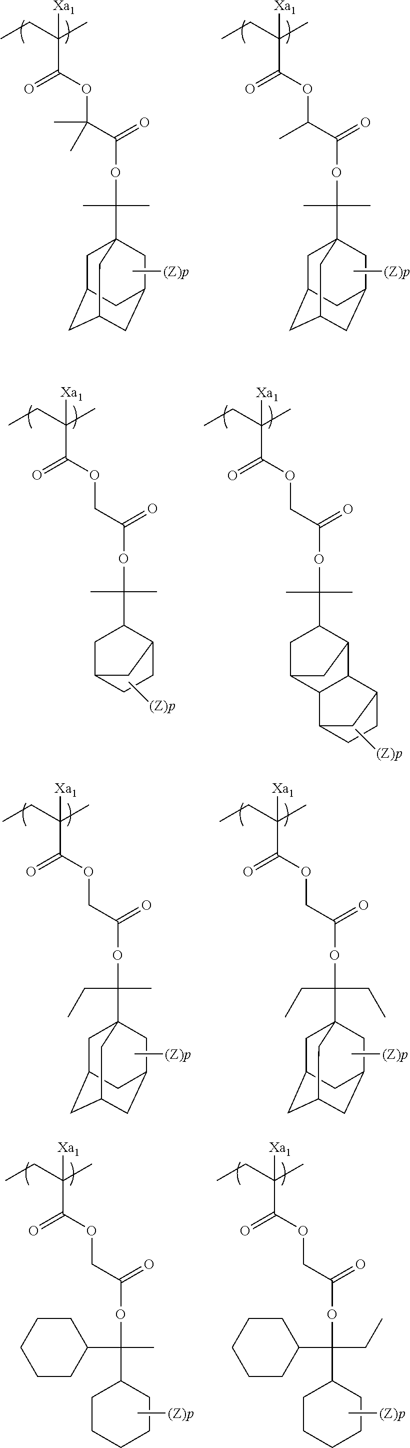

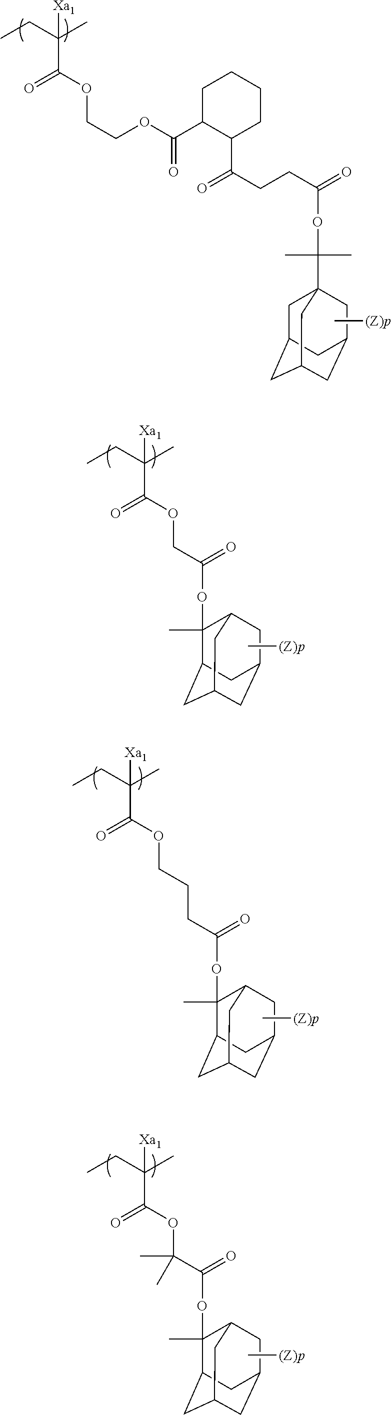

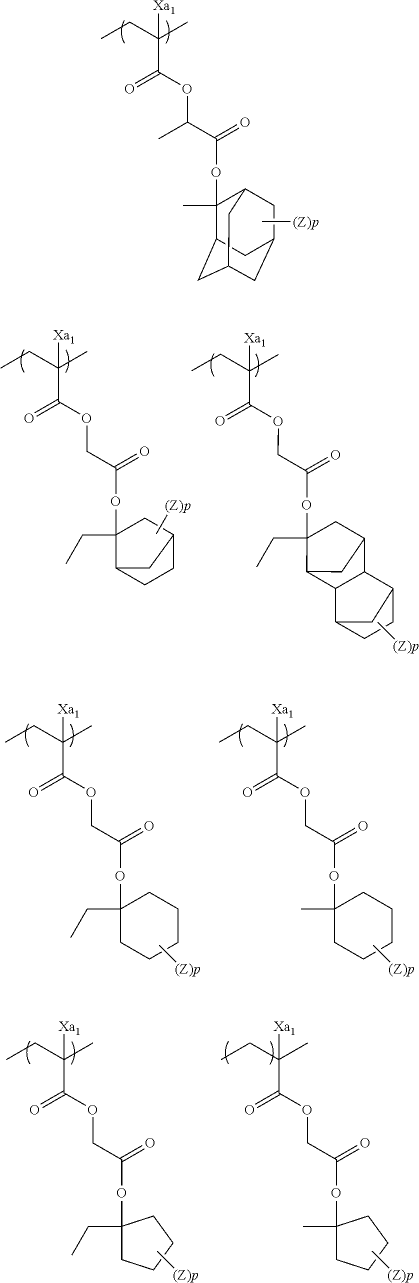

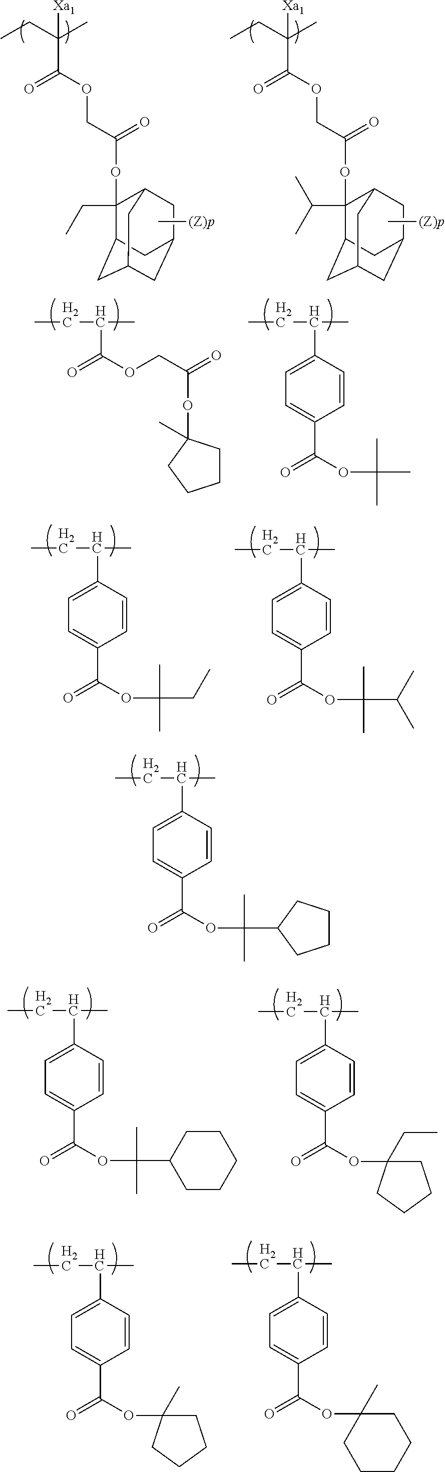

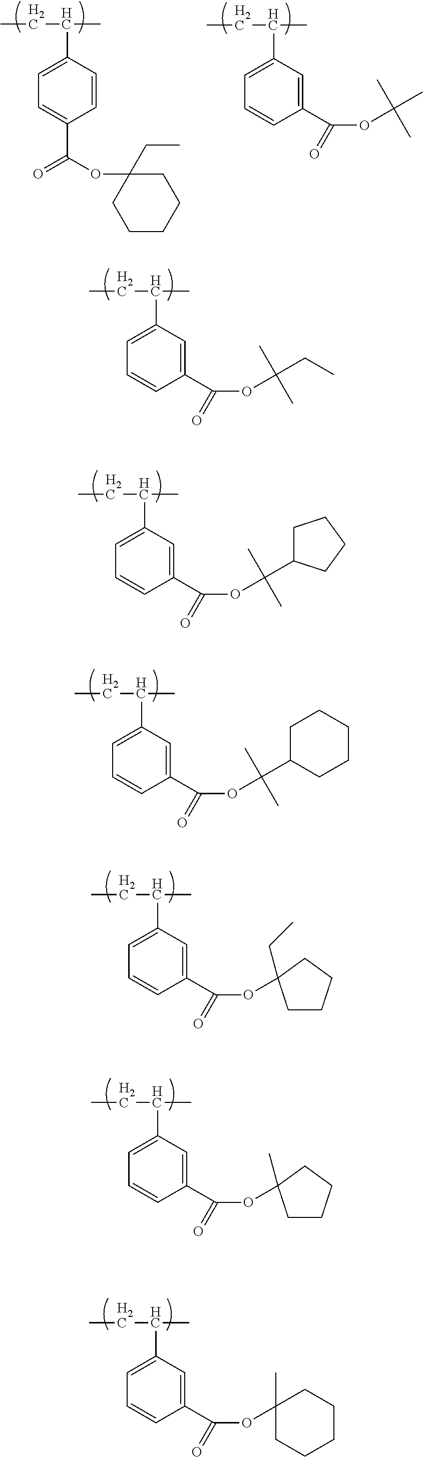

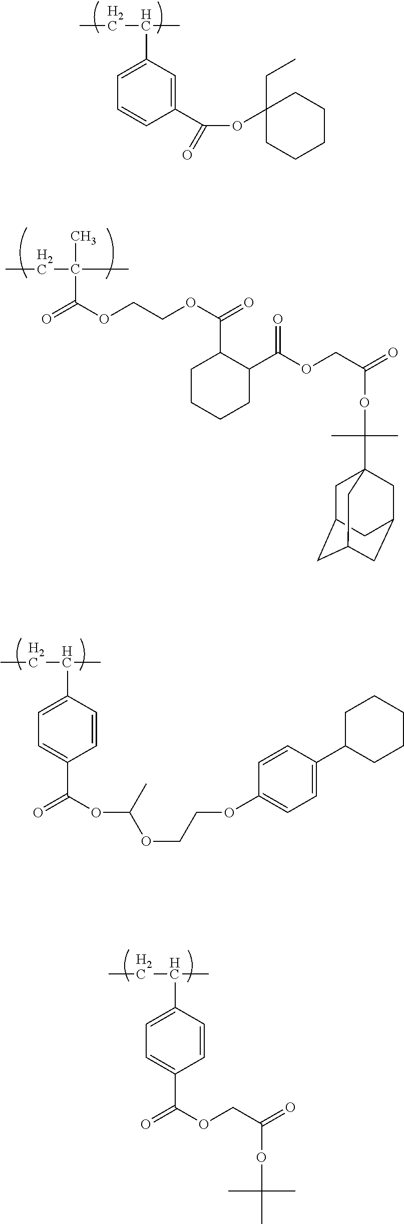

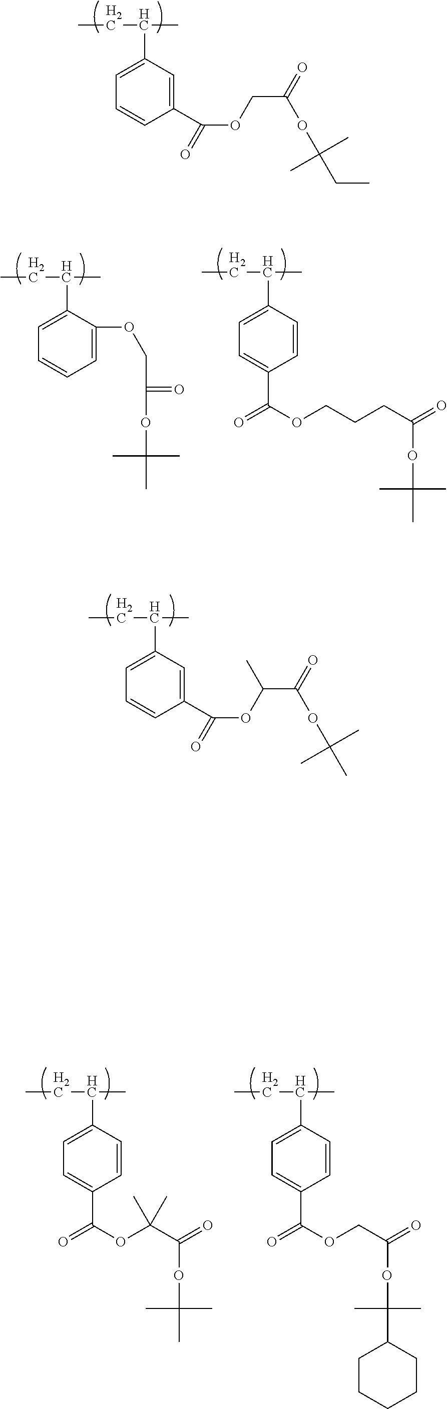

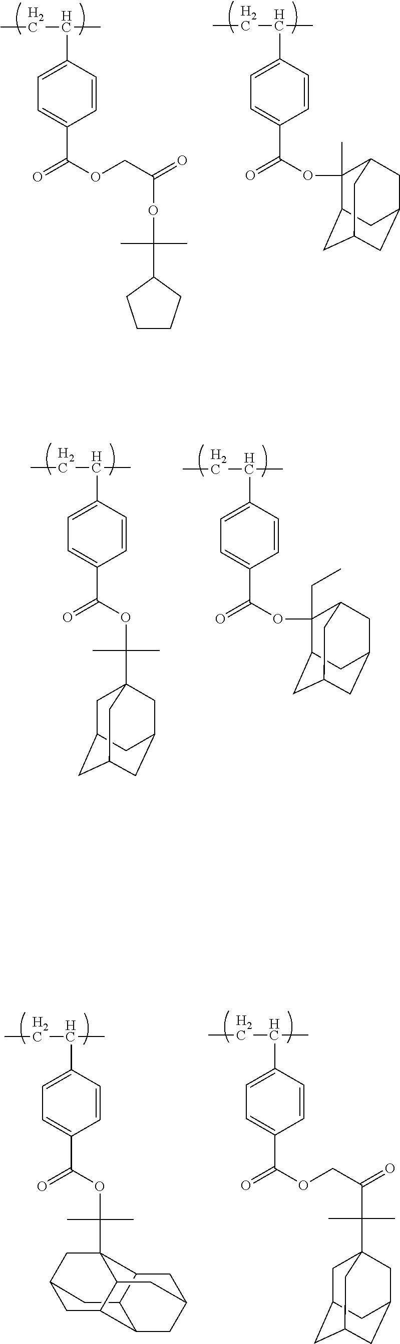

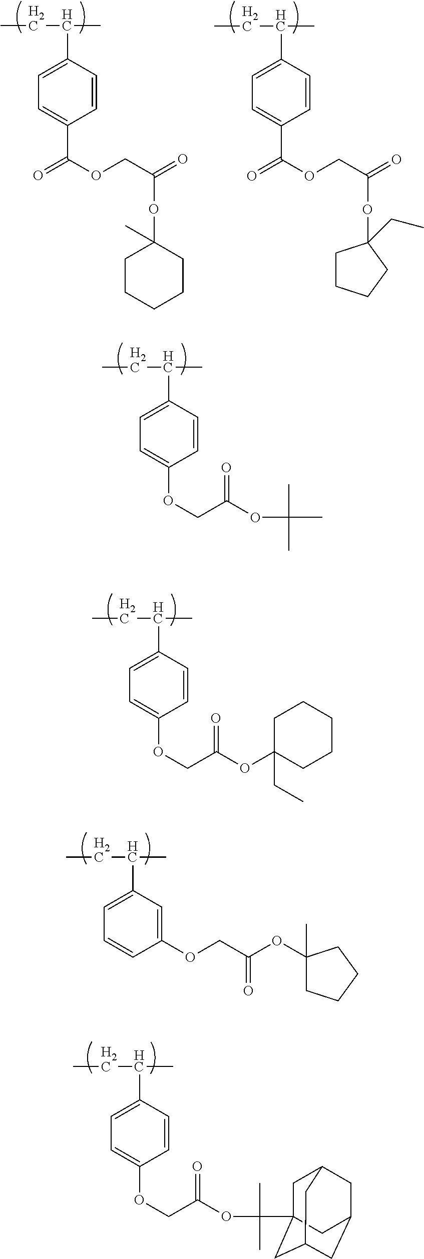

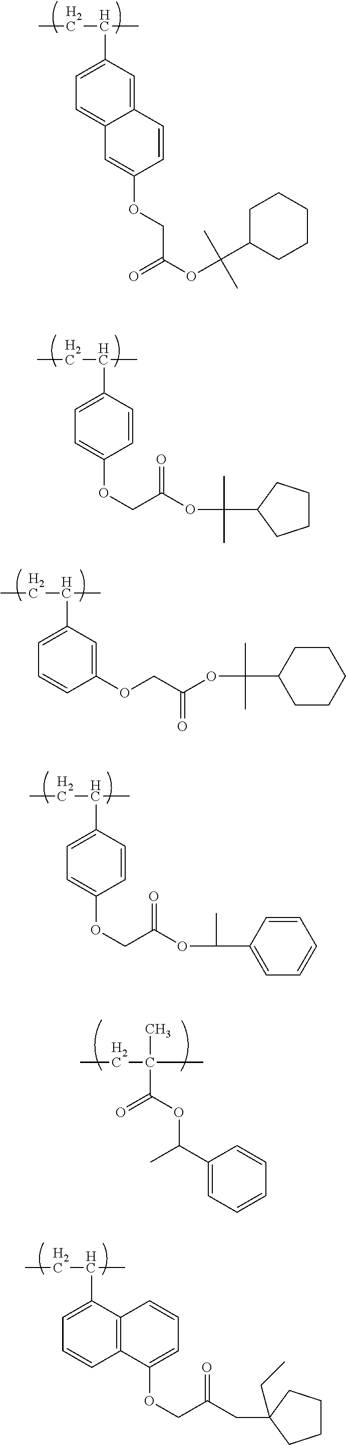

The resin (P) may contain the repeating unit represented by general formula (VI) below as the repeating unit (B). Such embodiments are especially preferred when the composition is exposed to electron beam or EUV light.

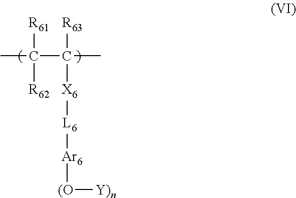

In general formula (VI), each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring (preferably a 5- or 6-membered ring), which R₆₂ in this instance is an alkylene group.

X₆ represents a single bond, —COO—, or —CONR₆₄-(in which R₆₄ represents a hydrogen atom or an alkyl group). L₆ represents a single bond or an alkylene group. Ar₆ represents a bivalent aromatic ring group.

Y, or each of Ys independently, represents a hydrogen atom or a group that is configured to be cleaved when acted on by an acid, provided that at least one of Ys is a group that is configured to be cleaved when acted on by an acid.

In the formula, n is an integer of 1 to 4.

General formula (VI) will be described in greater detail below.

The alkyl group represented by each of R₆₁ to R₆₃ of general formula (VI) is preferably an optionally substituted alkyl group having 20 or less carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having 8 or less carbon atoms is more preferred.

The alkyl group contained in the alkoxycarbonyl group is preferably the same as the alkyl group mentioned above with respect to R₆₁ to R₆₃.

The cycloalkyl group may be monocyclic or polycyclic. An optionally substituted cycloalkyl ring group having 3 to 8 carbon atoms, such as a cyclopropyl group, a cyclopentyl group or a cyclohexyl group, is preferred.

As the halogen atom, there can be mentioned a fluorine atom, a chlorine atom, a bromine atom or an iodine atom. A fluorine atom is preferred.

When R₆₂ represents an alkylene group, the alkylene group is preferably an optionally substituted alkylene group having 1 to 8 carbon atoms, such as a methylene group, an ethylene group, a propylene group, a butylene group, a hexylene group or an octylene group.

As the alkyl group represented by R₆₄, the same as described for the alkyl group represented by R₆₁ to R₆₃ can be exemplified.

X₆ preferably represents a single bond, —COO— or —CONH— and more preferably a single bond or —COO—.

As the alkylene group represented by L₆, the one having 1 to 8 carbon atoms such as a methylene group, an ethylene group, a propylene group, a butylene group, a hexylene group or an octylene group is preferably employed.

Ar₆ represents a bivalent aromatic ring group. Substituents may be introduced in the bivalent aromatic ring groups. As preferred examples thereof, there can be mentioned, for example, an arylene group having 6 to 18 carbon atoms, such as a phenylene group, a tolylene group or a naphthylene group, and a bivalent aromatic ring group containing a heteroring, such as thiophene, furan, pyrrole, benzothiophene, benzofuran, benzopyrrole, triazine, imidazole, benzimidazole, triazole, thiadiazole or thiazole.

Particular examples of the substituents that can be introduced in the above alkyl group, cycloalkyl group, alkoxycarbonyl group, alkylene group and bivalent aromatic ring group are the same as set forth above with respect to the R₅₁ to R₅₃ of general formula (V).

In the formula, n is preferably 1 or 2, more preferably 1.

Each of n Ys independently represents a hydrogen atom or a group that is configured to be cleaved by the action of an acid, provided that at least one of n Ys is a group that is configured to be cleaved by the action of an acid.

As the group that is configured to be cleaved by the action of an acid, Y, there can be mentioned those set forth above by way of example,

namely, —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), —CH(R₃₆)(Ar) and the like. In these formulae, R₃₆ to R₃₉, R₀₁ and R₀₂ are as defined above.

In the formulae, each of R₃₆ to R₃₉ independently represents an alkyl group, a cycloalkyl group, an aryl group, an aralkyl group or an alkenyl group. R₃₆ and R₃₇ may be bonded with each other to thereby form a ring structure.

Each of R₀₁ and R₀₂ independently represents a hydrogen atom, an alkyl group, a cycloalkyl group, an aryl group, an aralkyl group or an alkenyl group.

Ar represents an aryl group.

The alkyl groups represented by R₃₆ to R₃₉ and R₀₁ and R₀₂ each preferably have 1 to 8 carbon atoms. For example, there can be mentioned a methyl group, an ethyl group, a propyl group, an n-butyl group, a sec-butyl group, a hexyl group, an octyl group and the like.

The cycloalkyl groups represented by R₃₆ to R₃₉ and R₀₁ and R₀₂ may be monocyclic or polycyclic. The monocyclic alkyl groups are preferably cycloalkyl groups having 3 to 8 carbon atoms. As such, there can be mentioned, for example, a cyclopropyl group, a cyclobutyl group, a cyclopentyl group, a cyclohexyl group, a cyclooctyl group and the like. The polycyclic alkyl groups are preferably cycloalkyl groups having 6 to 20 carbon atoms. As such, there can be mentioned, for example, an adamantyl group, a norbornyl group, an isobornyl group, a camphonyl group, a dicyclopentyl group, an α-pinel group, a tricyclodecanyl group, a tetracyclododecyl group, an androstanyl group and the like. With respect to these, the carbon atoms of each of the cycloalkyl groups may be partially substituted with a heteroatom, such as an oxygen atom.

The aryl groups represented by R₃₆ to R₃₉, R₀₁ and R₀₂ and Ar each preferably have 6 to 10 carbon atoms. For example, there can be mentioned a phenyl group, a naphthyl group, an anthryl group and the like. Further, aryl groups containing heteroring such as thiophene, furan, pyrrole, benzothiophene, benzofuran, benzopyrrole, triazine, imidazole, benzimidazole, triazole, thiadiazole or thiazole can also be exemplified.

The aralkyl groups represented by R₃₆ to R₃₉, R₀₁ and R₀₂ each preferably have 7 to 12 carbon atoms. For example, there can be mentioned a benzyl group, a phenethyl group, a naphthylmethyl group and the like.

The alkenyl groups represented by R₃₆ to R₃₉, R₀₁ and R₀₂ each preferably have 2 to 8 carbon atoms. For example, there can be mentioned a vinyl group, an allyl group, a butenyl group, a cyclohexenyl group and the like.

The ring formed by mutual bonding of R₃₆ and R₃₇ may be monocyclic or polycyclic. The monocyclic structure is preferably a cycloalkane structure having 3 to 8 carbon atoms. As such, there can be mentioned, for example, a cyclopropane structure, a cyclobutane structure, a cyclopentane structure, a cyclohexane structure, a cycloheptane structure, a cyclooctane structure or the like. The polycyclic structure is preferably a cycloalkane structure having 6 to 20 carbon atoms. As such, there can be mentioned, for example, an adamantane structure, a norbornane structure, a dicyclopentane structure, a tricyclodecane structure, a tetracyclododecane structure or the like. With respect to these, the carbon atoms of each of the cycloalkane structure may be partially substituted with a heteroatom, such as an oxygen atom.

Each of the groups represented by R₃₆ to R₃₉, R₀₁, R₀₂, R₀₃, Ar and Ar₁ may have one or more substituents. As the substituent, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group or the like. Preferably, the number of carbon atoms of each of the substituents is up to 8.

The group Y that is eliminated by the action of an acid more preferably has any of the structures of general formula (VI-A) below.

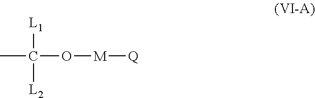

In the formula, each of L₁ and L₂ independently represents a hydrogen atom, an alkyl group, a cycloalkyl group, a monovalent aromatic ring group or a group consisting of an alkylene group combined with a monovalent aromatic ring group.

M represents a single bond or a bivalent connecting group.

Q represents an alkyl group, a cycloalkyl group optionally containing a heteroatom, a monovalent aromatic ring group optionally containing a heteroatom, an amino group, an ammonium group, a mercapto group, a cyano group or an aldehyde group.

At least two of Q, M and L₁ may be bonded to each other to thereby form a ring (preferably, a 5-membered or 6-membered ring).

The alkyl groups represented by L₁ and L₂ are, for example, alkyl groups having 1 to 8 carbon atoms. As preferred examples thereof, there can be mentioned a methyl group, an ethyl group, a propyl group, an n-butyl group, a sec-butyl group, a hexyl group and an octyl group.

The monovalent aliphatic hydrocarbon ring groups represented by L₁ and L₂ are, for example, aliphatic hydrocarbon ring groups each having 3 to 15 carbon atoms. As preferred examples thereof, there can be mentioned a cyclopentyl group, a cyclohexyl group, a norbornyl group, an adamantyl group and the like.

The monovalent aromatic ring groups represented by L₁ and L₂ are, for example, aryl groups having 6 to 15 carbon atoms. As preferred examples thereof, there can be mentioned a phenyl group, a tolyl group, a naphthyl group, an anthryl group and the like.

The groups each consisting of an alkylene group combined with a monovalent aromatic ring group, represented by L₁ and L₂ are, for example, those having 6 to 20 carbon atoms. There can be mentioned aralkyl groups, such as a benzyl group and a phenethyl group.

The bivalent connecting group represented by M is, for example, an alkylene group (e.g., a methylene group, an ethylene group, a propylene group, a butylene group, a hexylene group, an octylene group, etc.), a bivalent aliphatic hydrocarbon ring group (e.g., a cyclopentylene group, a cyclohexylene group, an adamantylene group, etc.), an alkenylene group (e.g., an ethylene group, a propenylene group, a butenylene group, etc.), a bivalent aromatic ring group (e.g., a phenylene group, a tolylene group, a naphthylene group, etc.), —S—, —O—, —CO—, —SO₂—, —N(R₀)— or a bivalent connecting group resulting from combination of these groups. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group and the like).

The alkyl group represented by Q is the same as mentioned above with respect to L₁ and L₂.

As the aliphatic hydrocarbon ring group containing no heteroatom and monovalent aromatic ring group containing no heteroatom respectively contained in the monovalent aliphatic hydrocarbon ring group optionally containing a heteroatom and monovalent aromatic ring group optionally containing a heteroatom both represented by Q, there can be mentioned, for example, the cycloalkyl group and monovalent aromatic ring group mentioned above as being represented by each of L₁ and L₂. Preferably, each thereof has 3 to 15 carbon atoms.

As the cycloalkyl group containing a heteroatom and monovalent aromatic ring group containing a heteroatom, there can be mentioned, for example, groups having a heterocyclic structure, such as thiirane, cyclothiorane, thiophene, furan, pyrrole, benzothiophene, benzofuran, benzopyrrole, triazine, imidazole, benzimidazole, triazole, thiadiazole, thiazole and pyrrolidone. However, the above cycloalkyl groups and monovalent aromatic ring groups are not limited to these as long as a structure generally known as a heteroring (ring formed by carbon and a heteroatom or ring formed by heteroatoms) is included.

As the ring that may be formed by the mutual bonding of at least two of Q, M and L₁, there can be mentioned one resulting from the mutual bonding of at least two of Q, M and L₁ so as to form, for example, a propylene group or a butylene group and the subsequent formation of a 5-membered or 6-membered ring containing an oxygen atom.

In general formula (VI-A), a substituent may be introduced in each of the groups represented by L₁, L₂, M and Q. As the substituent, there can be mentioned, for example, any of those set forth above as being optionally introduced in R₃₆ to R₃₉, R₀₁, R₀₂ and Ar. Preferably, the number of carbon atoms of each of the substituents is up to 8.

The groups of the formula -M-Q are preferably groups each composed of 1 to 30 carbon atoms, more preferably groups each composed of 5 to 20 carbon atoms.

Particular examples of the repeating units (B) represented by general formula (V) will be shown below, which however in no way limit the scope of the present invention.

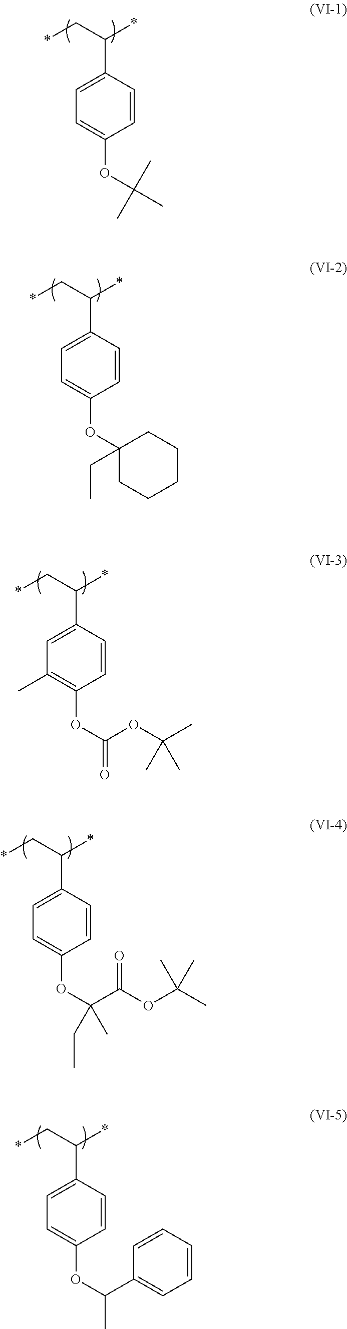

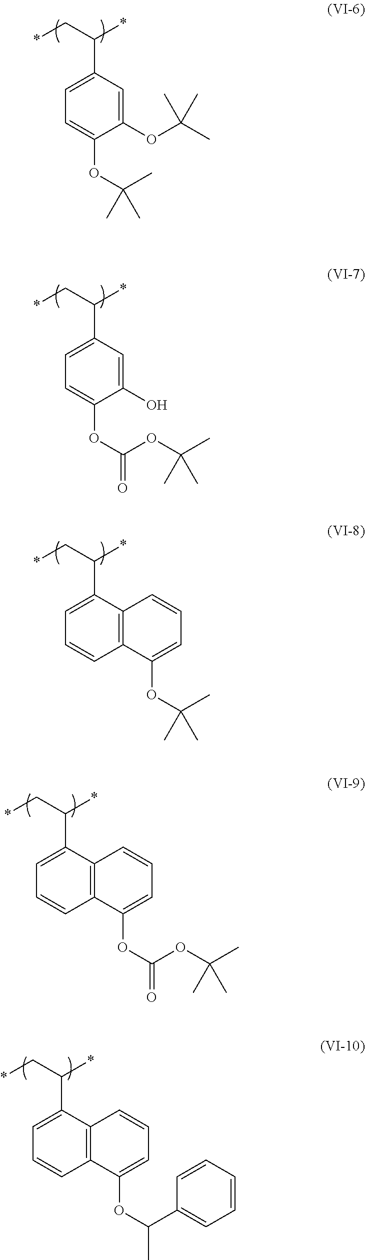

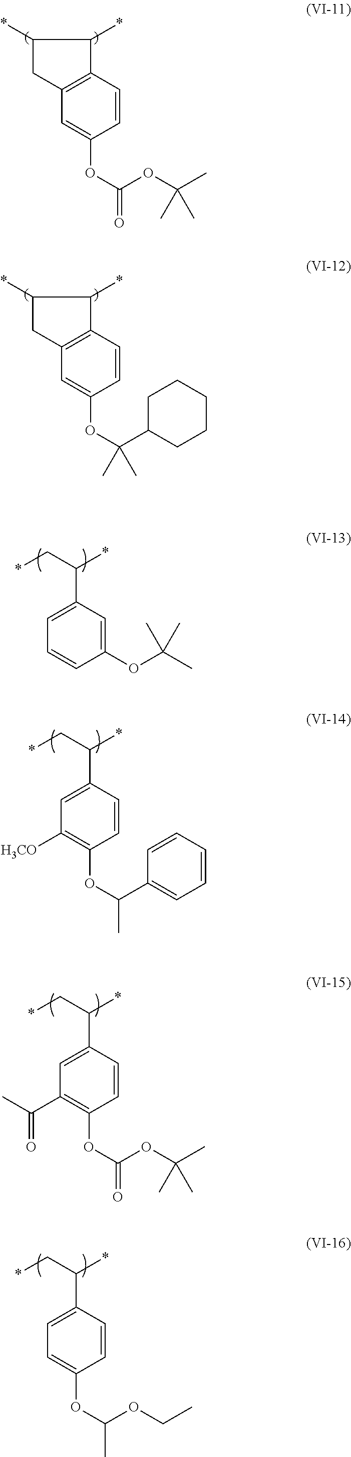

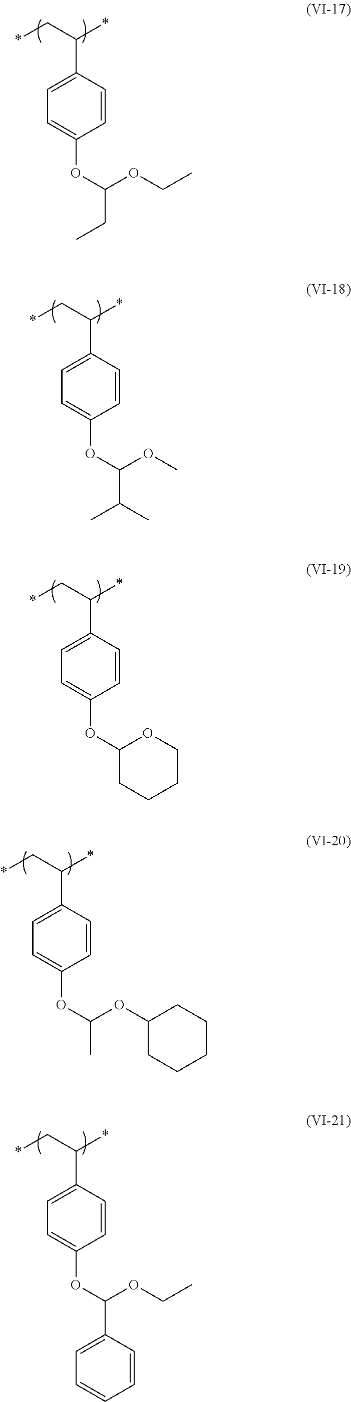

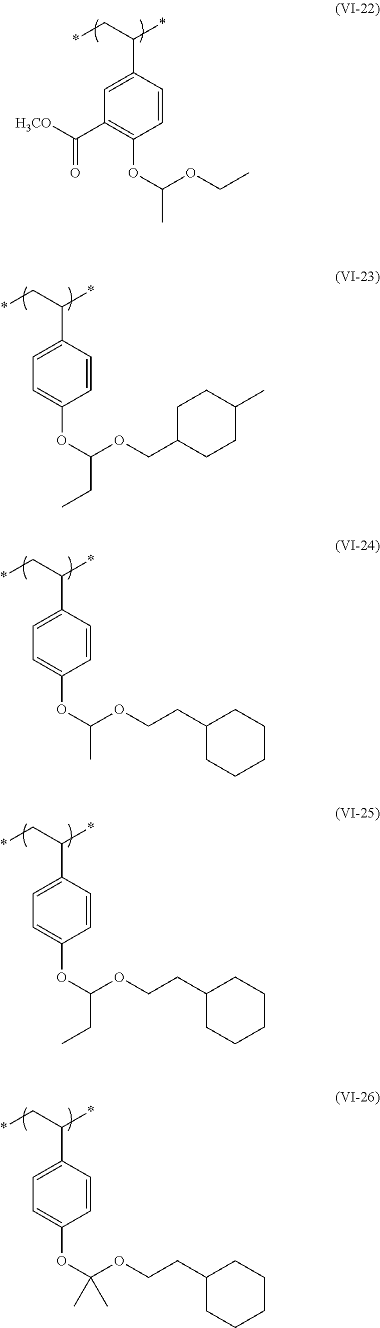

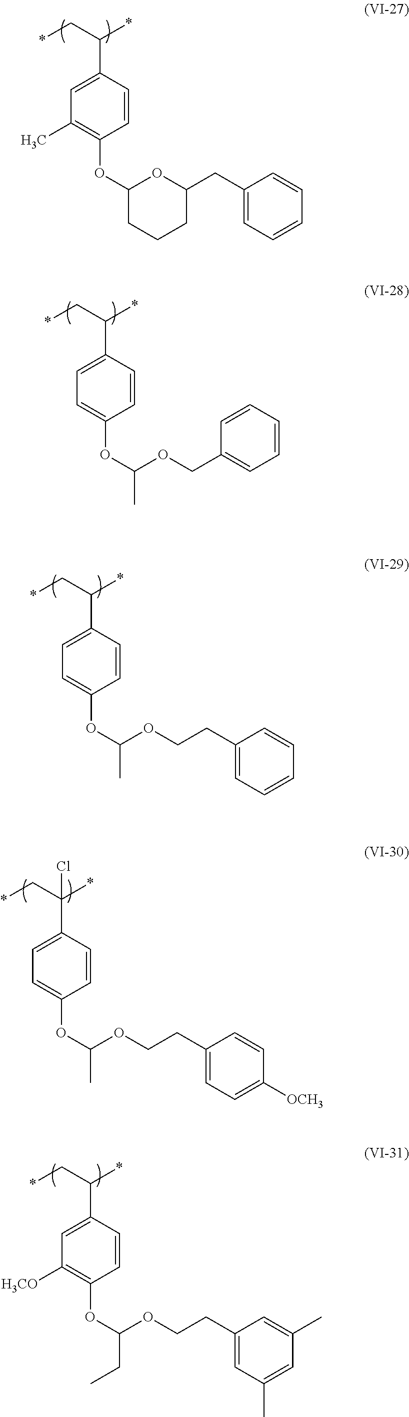

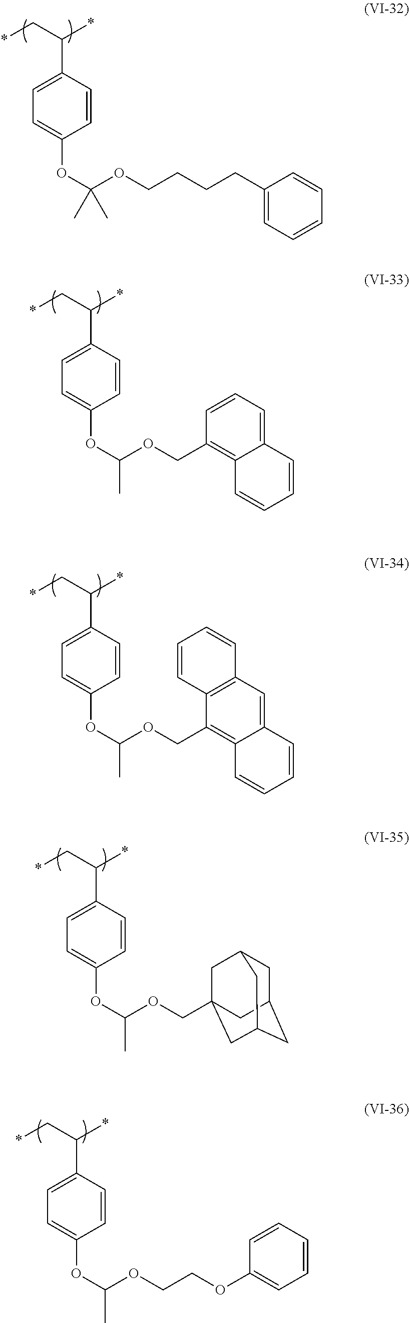

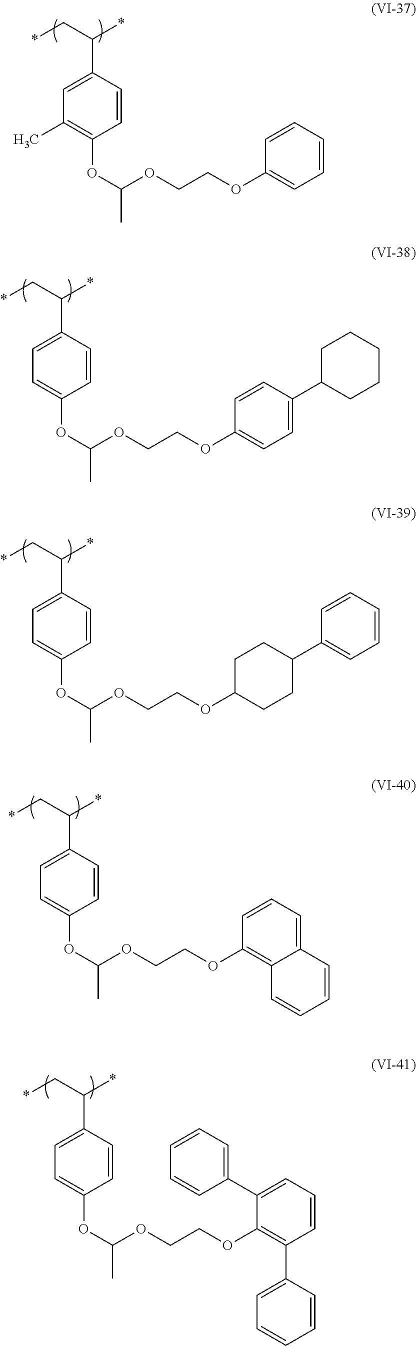

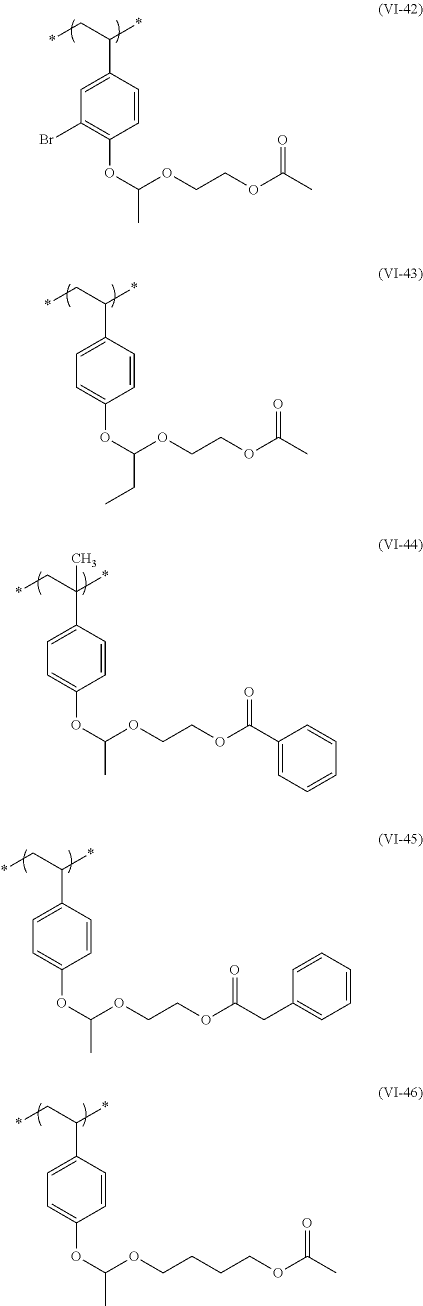

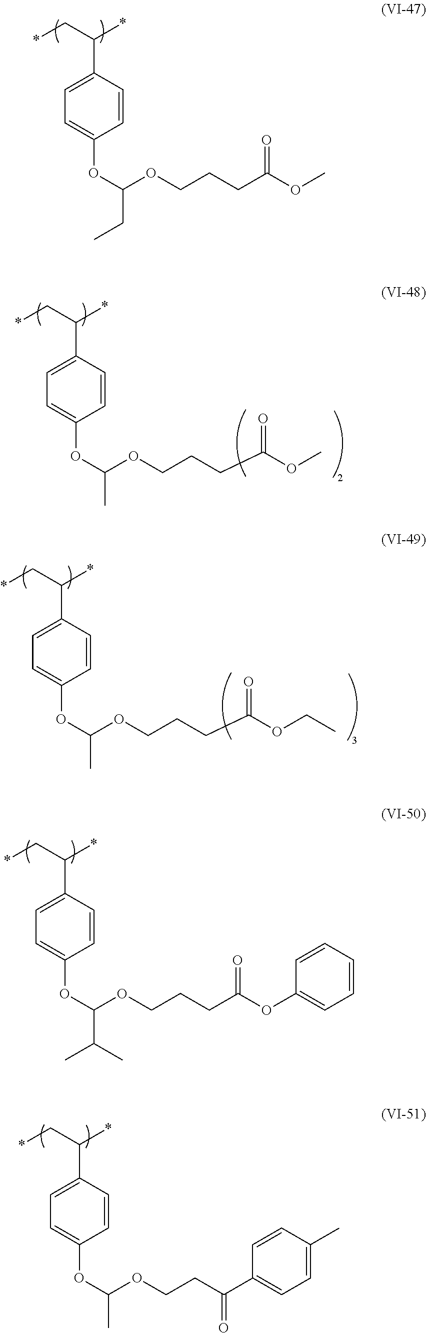

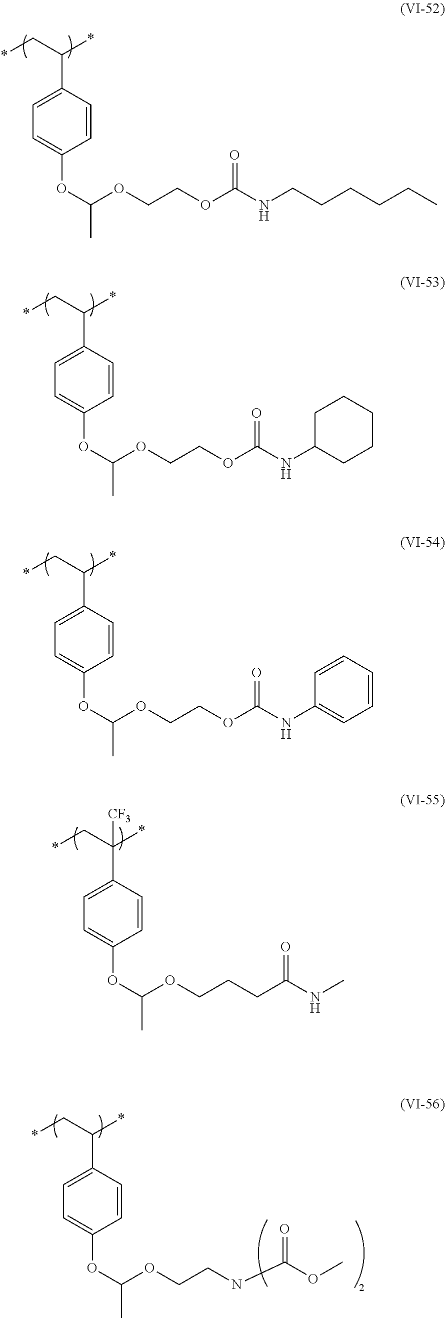

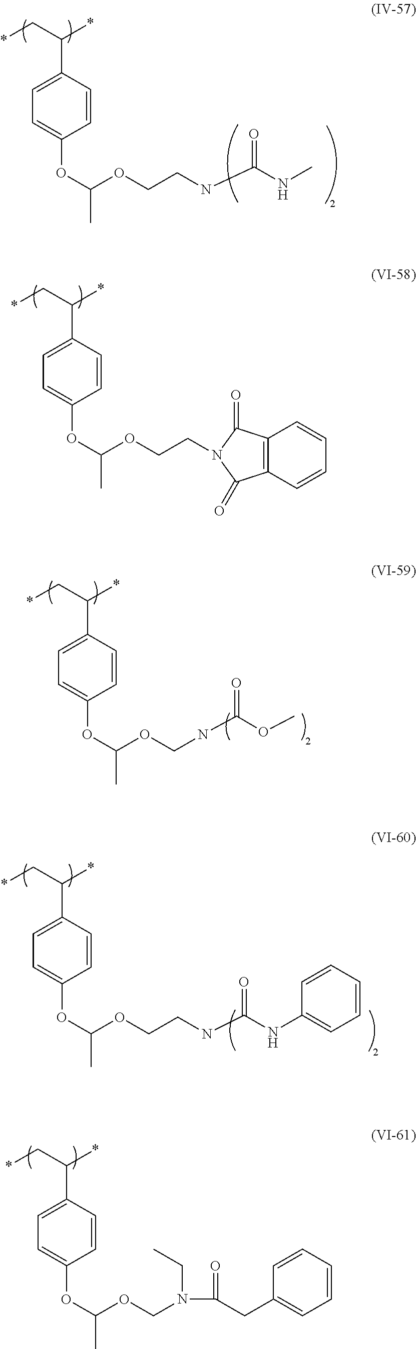

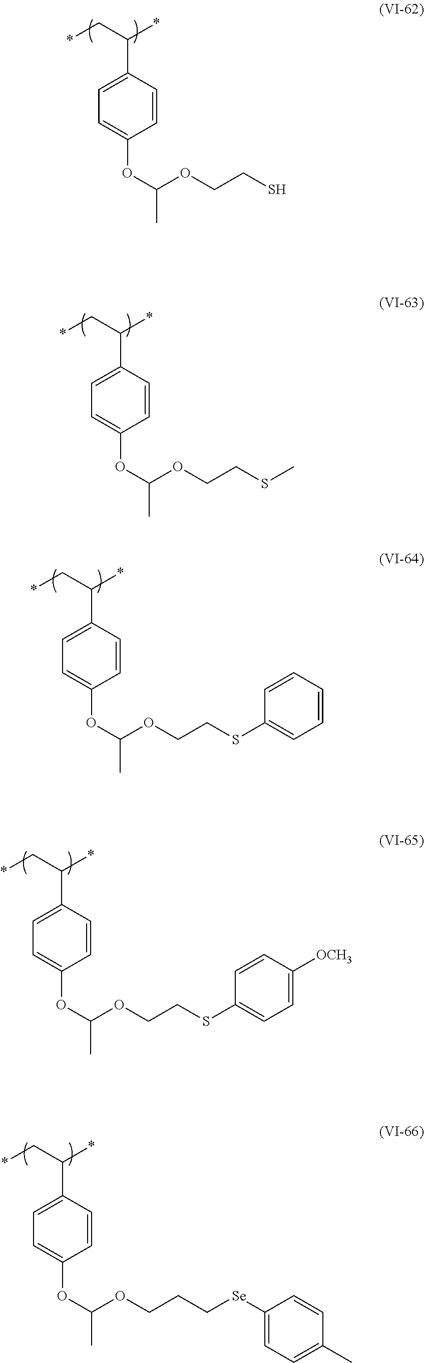

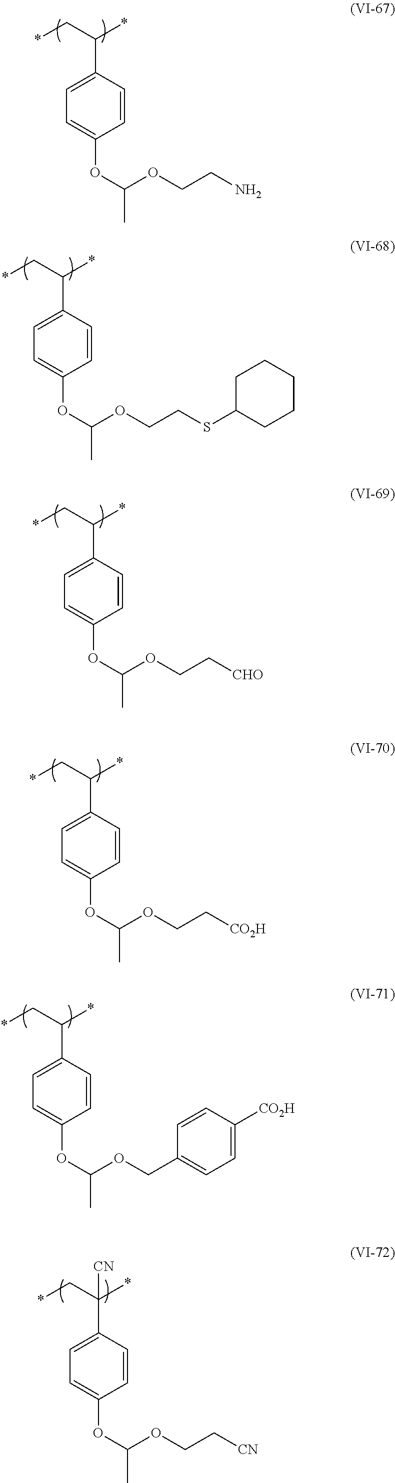

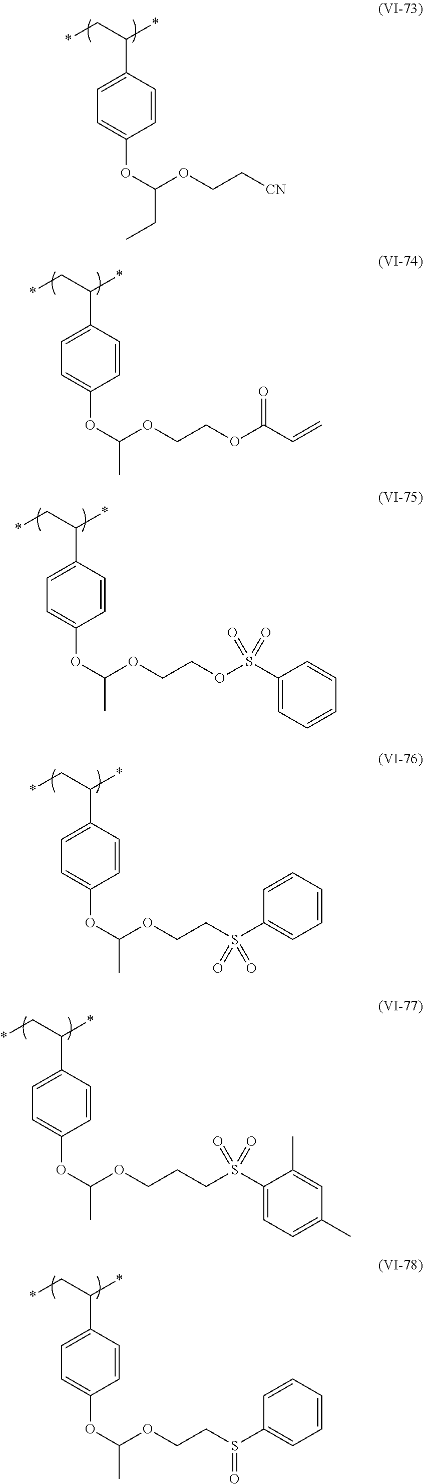

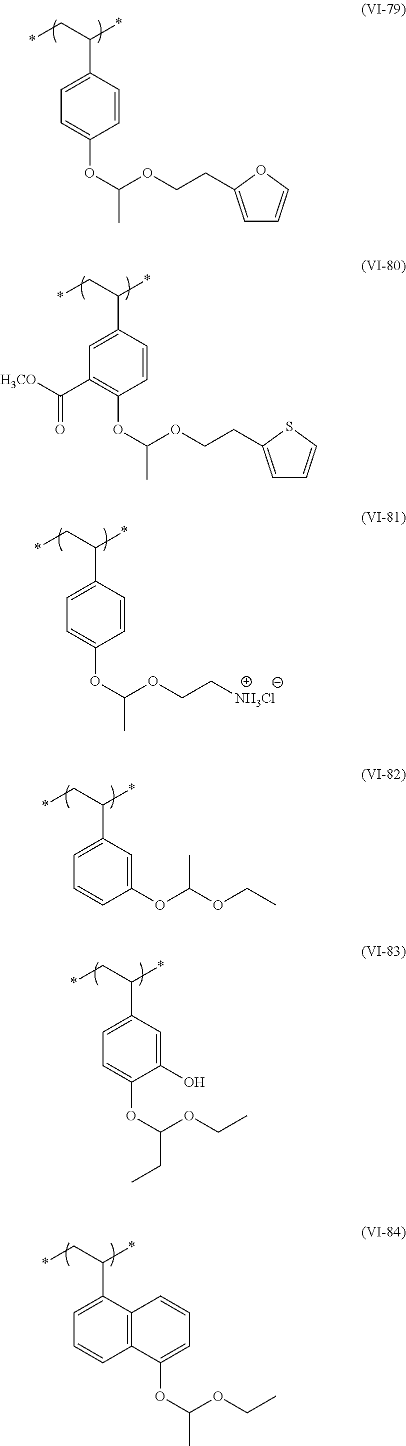

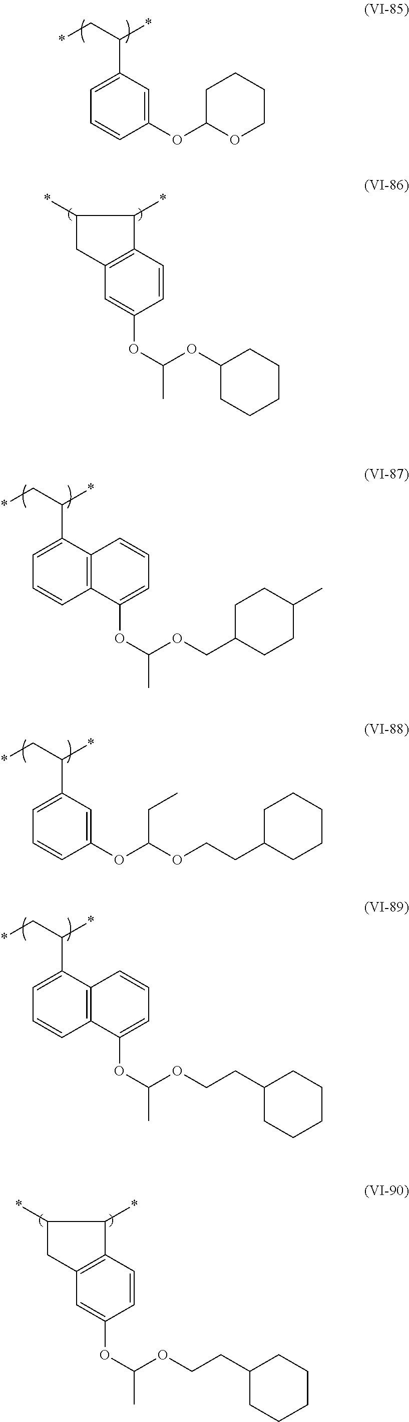

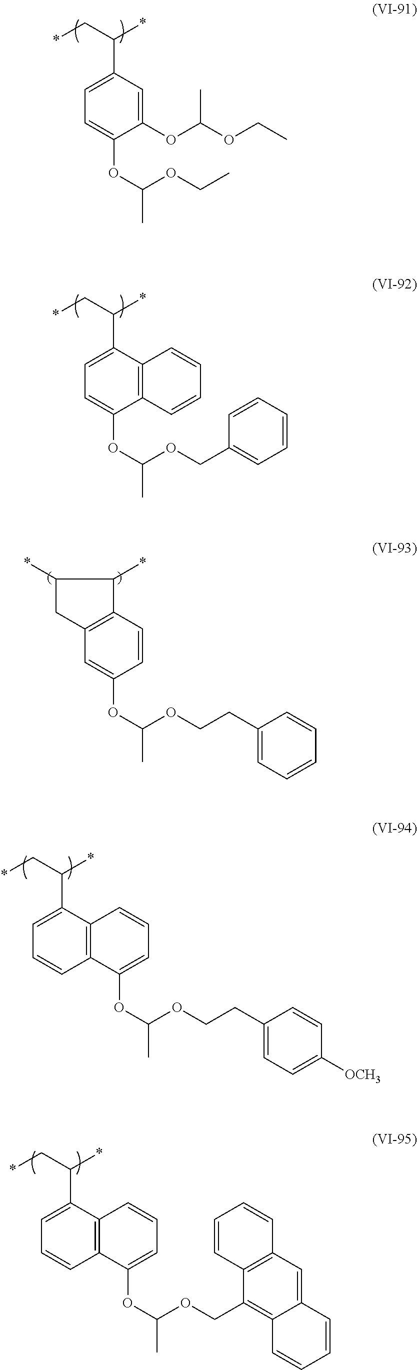

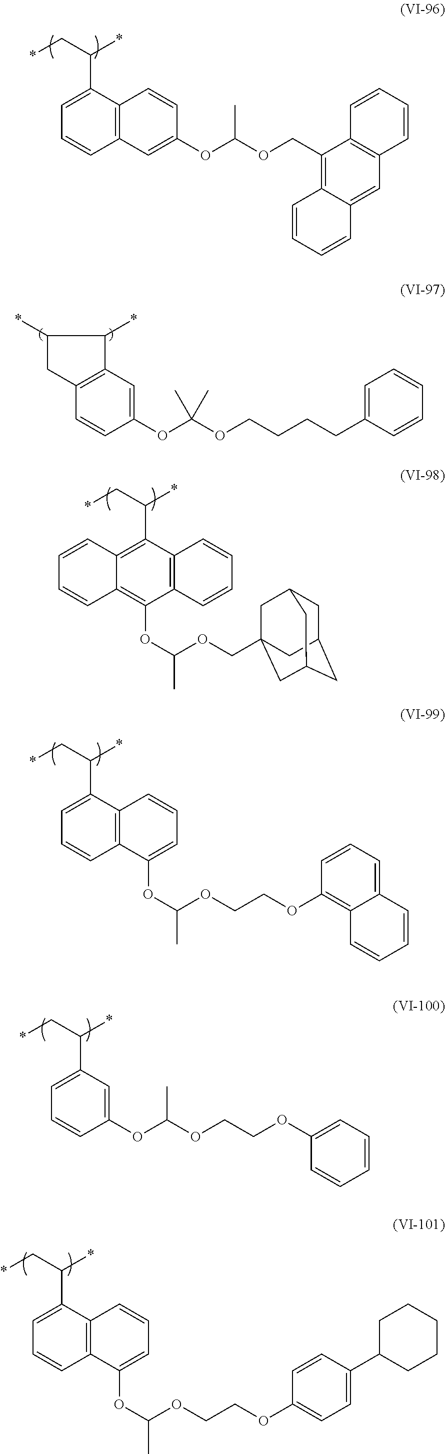

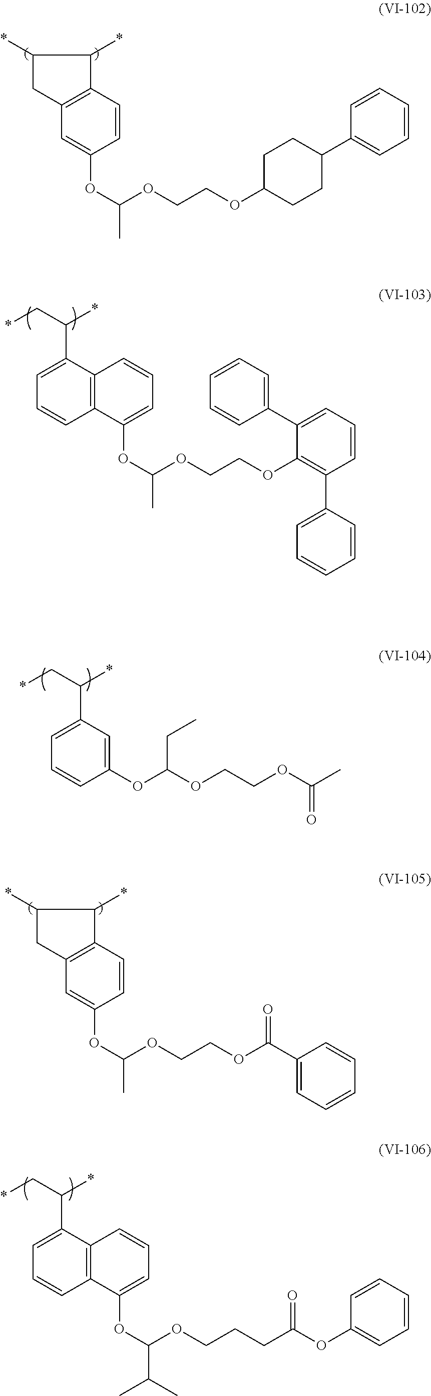

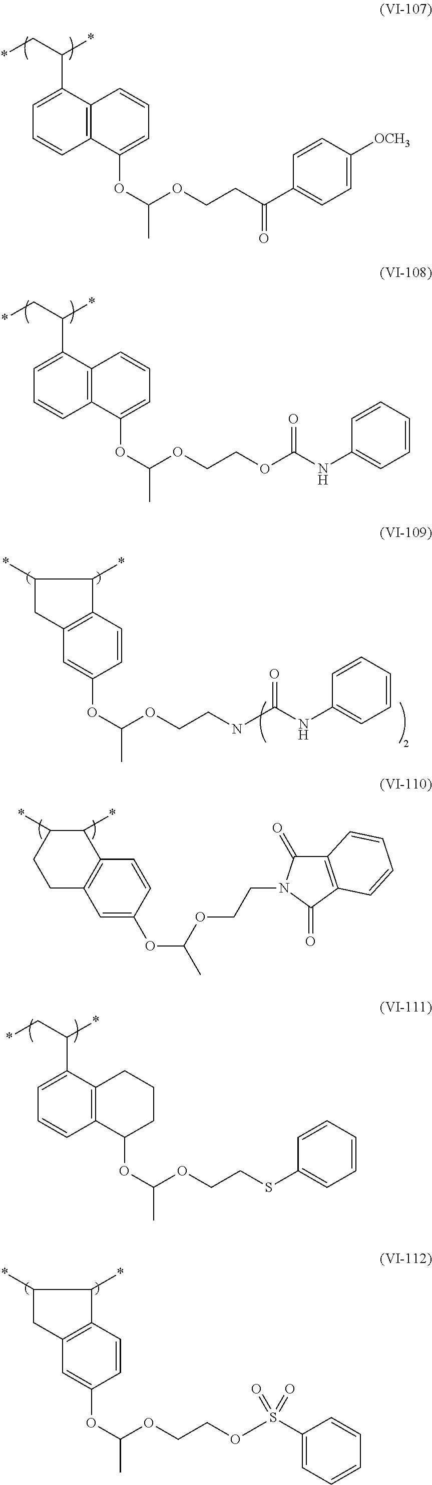

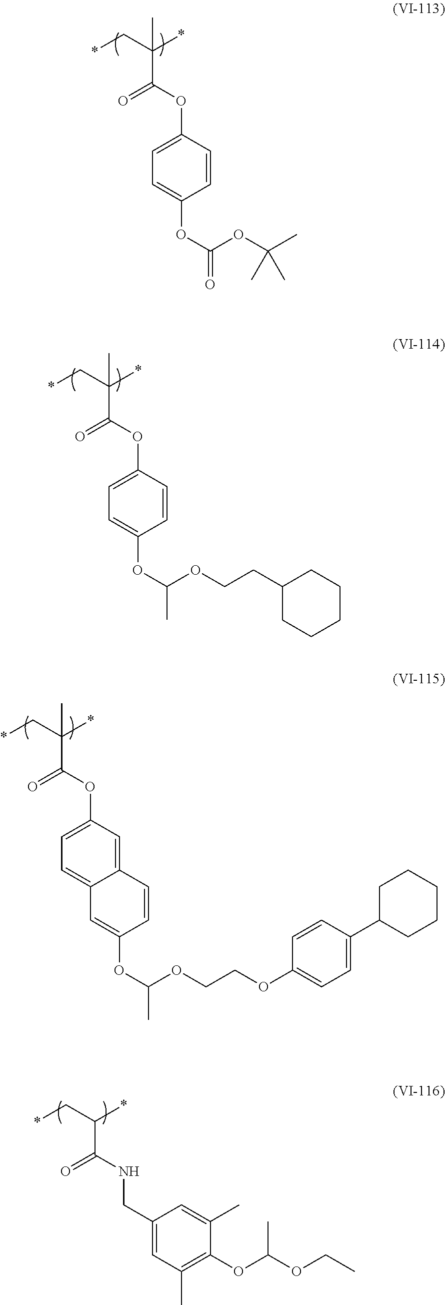

When the resin (P) contains the repeating unit (B), the content of repeating unit (B) in the resin (P) of the present invention, based on all the repeating units of the resin, is preferably in the range of 5 to 90 mol %, more preferably 10 to 80 mol % and further more preferably 20 to 70 mol %.

[Repeating Unit (C)]

The resin (P) may further contain a repeating unit (C) that contains a group that is configured to decompose when acted on by an alkali developer to thereby increase its rate of dissolution in the alkali developer.

As the group that is configured to decompose when acted on by an alkali developer to thereby increase its rate of dissolution in the alkali developer, there can be mentioned, for example, a lactone structure, phenylester structure and the like.

The repeating unit (C) is more preferably any of those of general formula (AII) below.

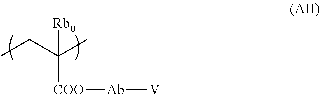

In the general formula (AII),

Rb₀ represents a hydrogen atom, a halogen atom or an optionally substituted alkyl group (preferably having 1 to 4 carbon atoms).

As a preferred substituent optionally contained in the alkyl group represented by Rb₀, there can be mentioned a hydroxyl group or a halogen atom. As the halogen atom represented by Rb₀, there can be mentioned a fluorine atom, a chlorine atom, a bromine atom or an iodine atom. The Rb₀ is preferably a hydrogen atom, a methyl group, a hydroxymethyl group or a trifluoromethyl group. A hydrogen atom and a methyl group are especially preferred.

Ab represents a single bond, an alkylene group, a bivalent connecting group with a cycloalkyl structure of a single ring or multiple rings, an ether group, an ester group, a carbonyl group, or a bivalent connecting group resulting from combination thereof. A single bond and a bivalent connecting group of the formula -Ab₁-CO₂— are preferred.

Ab₁ is a linear or branched alkylene group or a cycloalkylene group of a single ring or multiple rings, being preferably a methylene group, an ethylene group, a cyclohexylene group, an adamantylene group or a norbornylene group.

V represents a group that is configured to decompose when acted on by an alkali developer to thereby increase its rate of dissolution in the alkali developer. The group is preferably a group having an ester bond, more preferably a group having a lactone structure.

Any groups having a lactone structure can be employed as long as a lactone structure is possessed therein. However, lactone structures of a 5 to 7-membered ring are preferred, and in particular, those resulting from condensation of lactone structures of a 5 to 7-membered ring with other cyclic structures effected in a fashion to form a bicyclo structure or spiro structure are preferred. The possession of repeating units having a lactone structure represented by any of the following general formulae (LC1-1) to (LC1-17) is more preferred. The lactone structures may be directly bonded to the principal chain of the resin. Preferred lactone structures are those of the formulae (LC1-1), (LC1-4), (LC1-5), (LC1-6), (LC1-13) and (LC1-14).

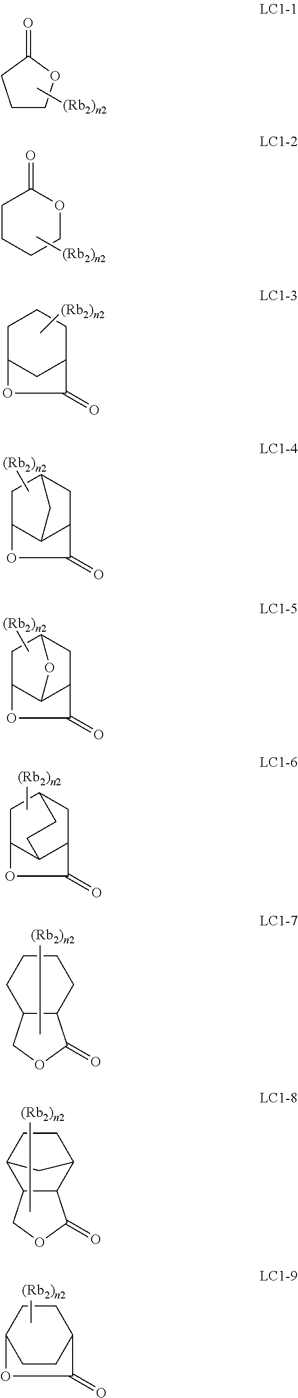

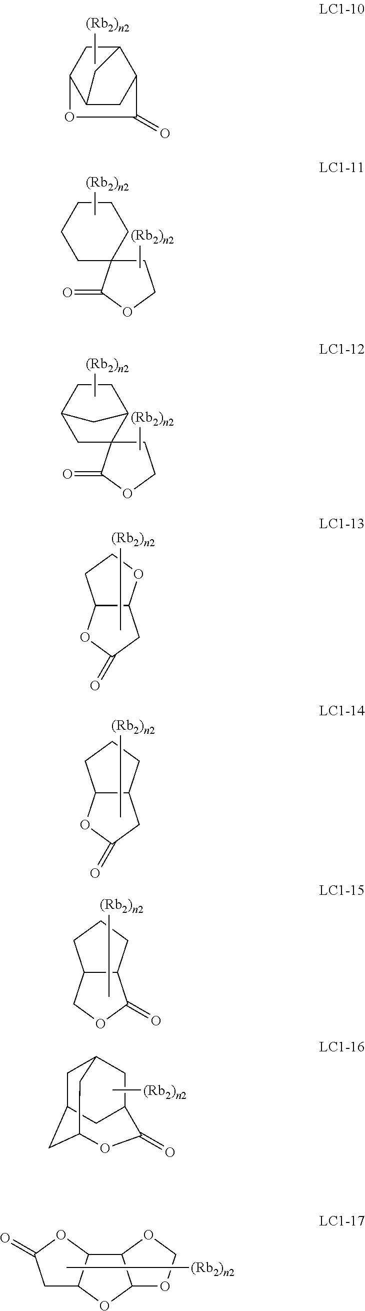

The presence of a substituent (Rb₂) on the portion of the lactone structure is optional. As a preferred substituent (Rb₂), there can be mentioned an alkyl group having 1 to 8 carbon atoms, a monovalent aliphatic hydrocarbon ring group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group and the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded with each other to thereby form a ring.

The repeating unit having a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or higher, more preferably 95% or higher.

The content ratio of the repeating unit (C) based on all the repeating units of the resin (P) is preferably in the range of 0.5 to 80 mol %, more preferably 1 to 60 mol % and still more preferably 2 to 40 mol %. The repeating unit (C) can be used either individually or in combination. The use of specified lactone structures would ensure improvement in the line edge roughness and development defect.

Specific examples of the repeating units (C) of the resin (P) will be shown below, which however in no way limit the scope of the present invention. In the formulae, Rx represents H, CH₃, CH₂OH or CF₃.

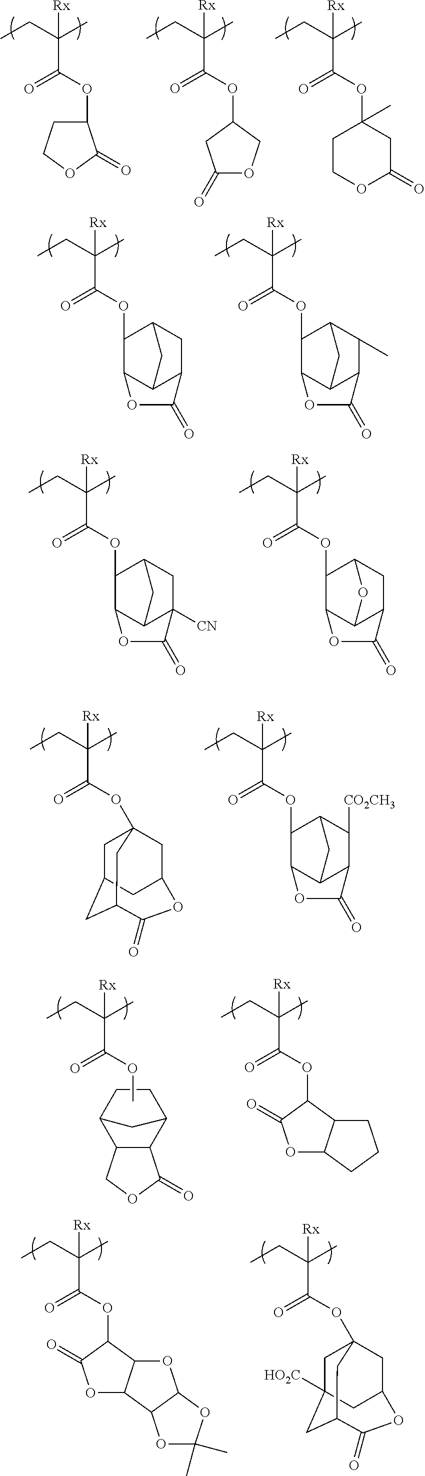

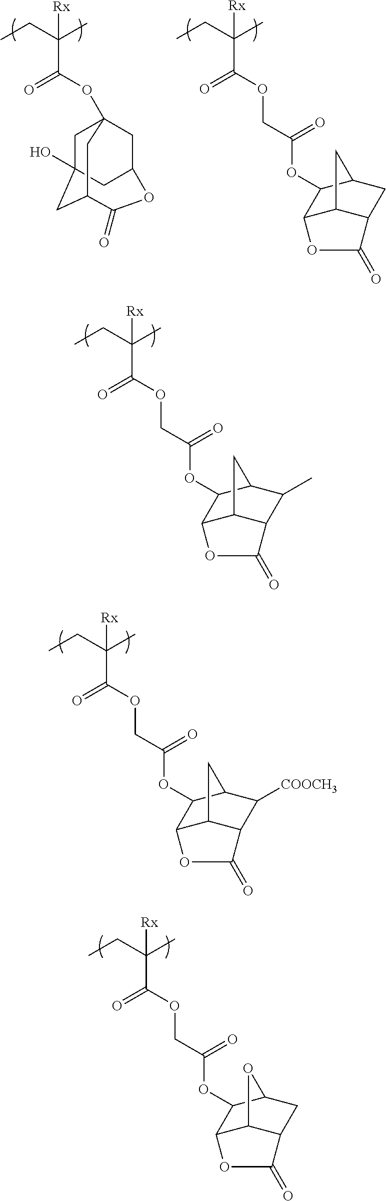

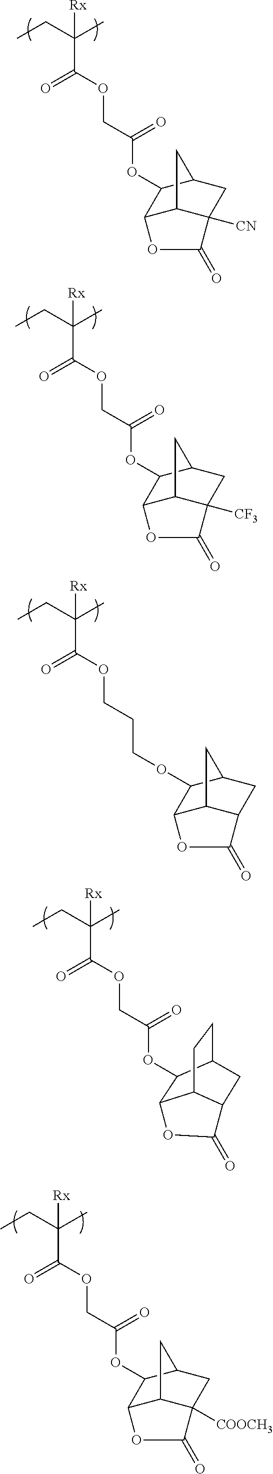

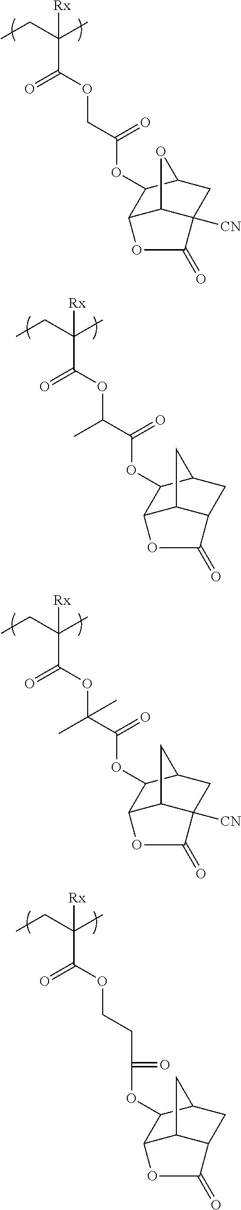

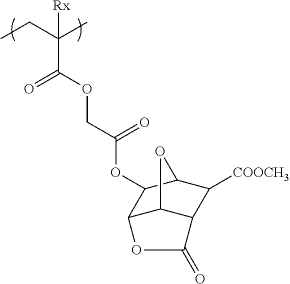

[Repeating Unit (D)]

The resin (P) according to the present invention preferably contains a repeating unit (D) containing an alkali-soluble group. As the alkali-soluble group, there can be mentioned a phenolic hydroxyl group, a carboxyl group, a sulfonamido group, a sulfonylimido group, a bissulfonylimido group or an aliphatic alcohol substituted at its α-position with an electron withdrawing group (for example, a hexafluoroisopropanol group).

When the exposure is performed using an ArF excimer laser, it is preferred to contain a repeating unit containing a carboxyl group. The incorporation of the repeating unit containing an alkali-soluble group increases the resolution in contact hole usage. The repeating unit containing an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a mono- or polycyclohydrocarbon structure. The repeating unit of acrylic acid or methacrylic acid is especially preferred.

The content ratio of the repeating unit having an alkali-soluble group based on all the repeating units of the resin (P) is preferably in the range of 1 to 20 mol %, more preferably 1 to 15 mol % and still more preferably 1 to 10 mol %.

Specific examples of the repeating units having an alkali-soluble group will be shown below, which however in no way limit the scope of the present invention.

In the formulae, Rx represents H, CH₃, CH₂OH or CF₃.

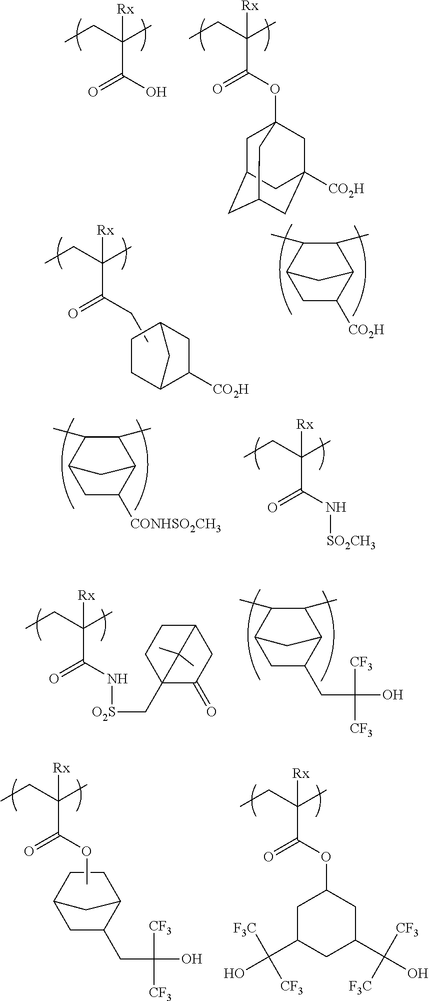

When the composition of the present invention is exposed to a KrF excimer laser light, electron beams, X-rays or high-energy light rays of wavelength 50 nm or shorter (for example, EUV), it is preferred for this resin to contain any of the repeating units of general formula (IV) below.

The inventors have found that the sensitivity of the composition of the present invention can be enhanced by using the acid-decomposable resin containing any of the repeating units of general formula (IV) in combination with any of the aforementioned repeating unit (A). The reason therefor is not necessarily apparent. However, the inventors presume that the reason would be that a chain reaction described in J. Org. Chem. 2005, 70, 6809-6819 is likely to occur, so that the amount of generated acid from the repeating unit (A) is increased.

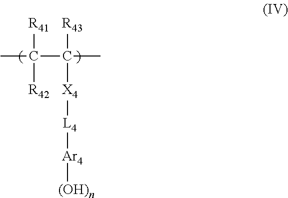

In the formula, each of R₄₁, R₄₂ and R₄₃ independently represents a hydrogen atom, an alkyl group, a cycloalkyl group, a halogen atom, a cyano group or an alkoxycarbonyl group, provided that R₄₂ may be bonded to Ar₄ to thereby form a ring (preferably a 5- or 6-membered ring), which R₄₂ in this instance is an alkylene group.

X₄ represents a single bond, —COO—, or —CONR₆₄-(in which R₆₄ represents a hydrogen atom or an alkyl group). L₄ represents a single bond or an alkylene group.

Ar₄ represents a bivalent aromatic ring group; and n is an integer of 1 to 4.

Particular examples of the alkyl group, monovalent aliphatic hydrocarbon ring group, halogen atom and alkoxycarbonyl group represented by each of R₄₁, R₄₂ and R₄₃ of formula (IV) and also particular examples of the substituents that can be introduced in these groups are the same as set forth above in connection with general formula (V).

Ar₄ represents a bivalent aromatic ring group. A substituent may be introduced in the bivalent aromatic ring group. As preferred examples of the bivalent aromatic ring group, there can be mentioned, for example, an arylene group having 6 to 18 carbon atoms, such as a phenylene group, a tolylene group, a naphthylene group or an anthracenylene group, and a bivalent aromatic ring group containing a heteroring, such as thiophene, furan, pyrrole, benzothiophene, benzofuran, benzopyrrole, triazine, imidazole, benzimidazole, triazole, thiadiazole or thiazole.

Preferred substituents that can be introduced in these groups include an alkyl group, an alkoxy group such as a methoxy group, an ethoxy group, a hydroxyethoxy group, a propoxy group, a hydroxypropoxy group or a butoxy group and an aryl group such as a phenyl group, as mentioned in connection with R₅₁ to R₅₃.

As the alkyl group represented by R₆₄, the same as described for the alkyl group represented by R₆₁ to R₆₃ can be exemplified.

X₄ preferably represents a single bond, —COO— or —CONH— and more preferably a single bond or —COO—.

As the alkylene group represented by L₄, the one having 1 to 8 carbon atoms such as a methylene group, an ethylene group, a propylene group, a butylene group, a hexylene group or an octylene group is preferably employed.

Ar₄ is more preferably an optionally substituted arylene group having 6 to 18 carbon atoms. A phenylene group, a naphthylene group and a biphenylene group are most preferred.

The content ratio of the repeating units with alkali-soluble groups of general formula (IV) is preferably in the range of 3 to 90 mol %, more preferably 5 to 80 mol % and further more preferably 7 to 70 mol %, based on all the repeating units of the resin (P).

Specific examples of the repeating units with alkali-soluble groups of general formula (IV) will be shown below, which however in no way limit the scope of the present invention. In the following formulae, a represents an integer of 0 to 2.

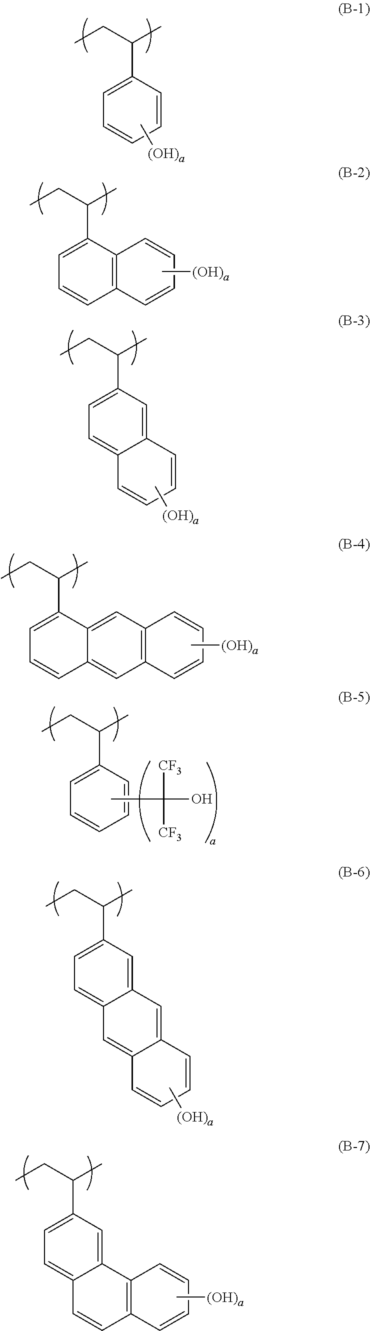

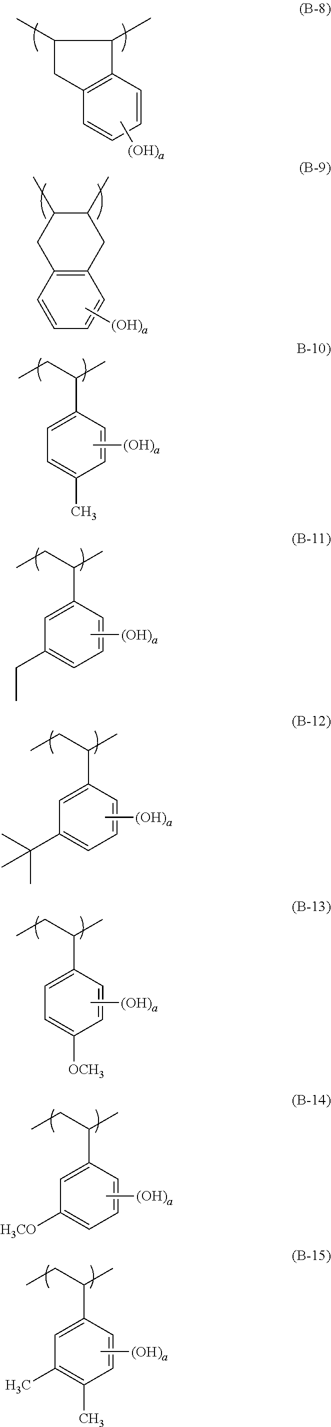

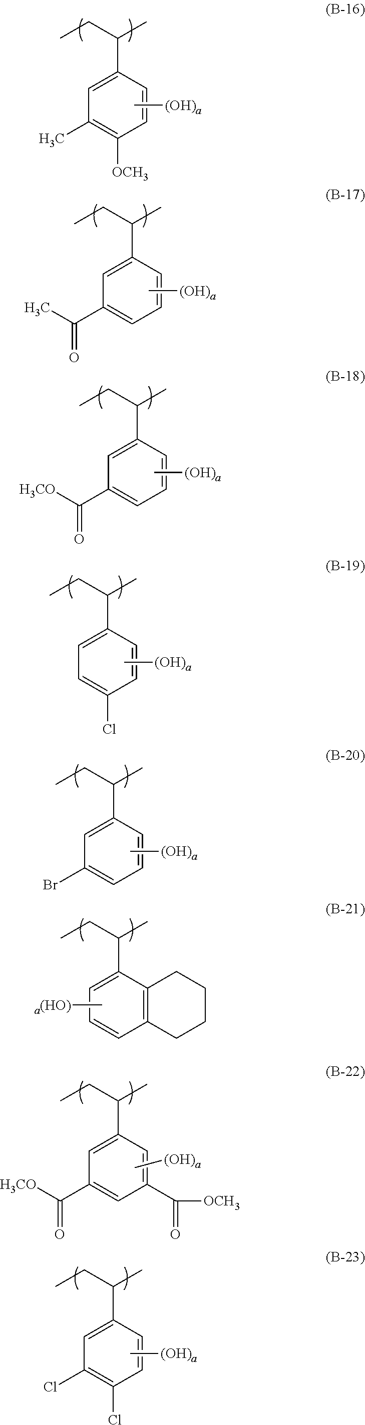

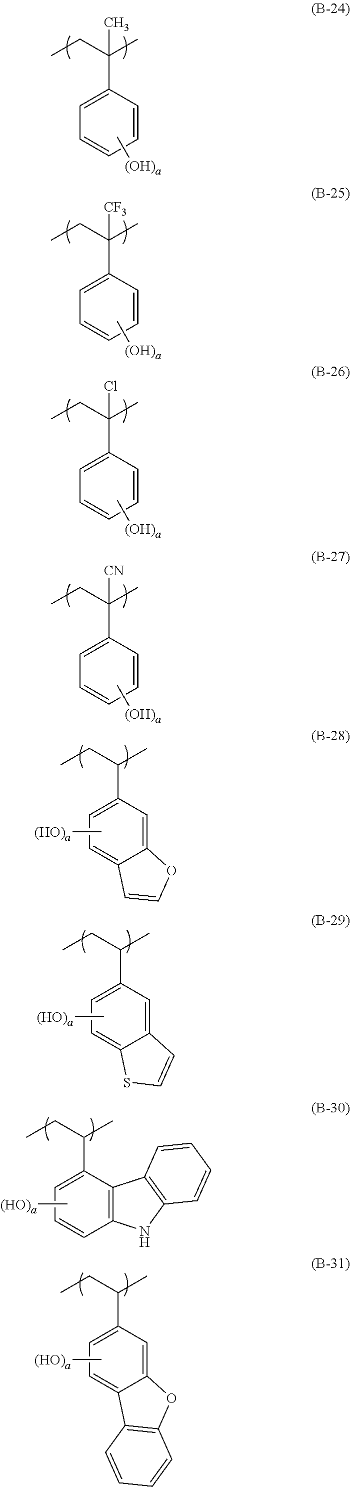

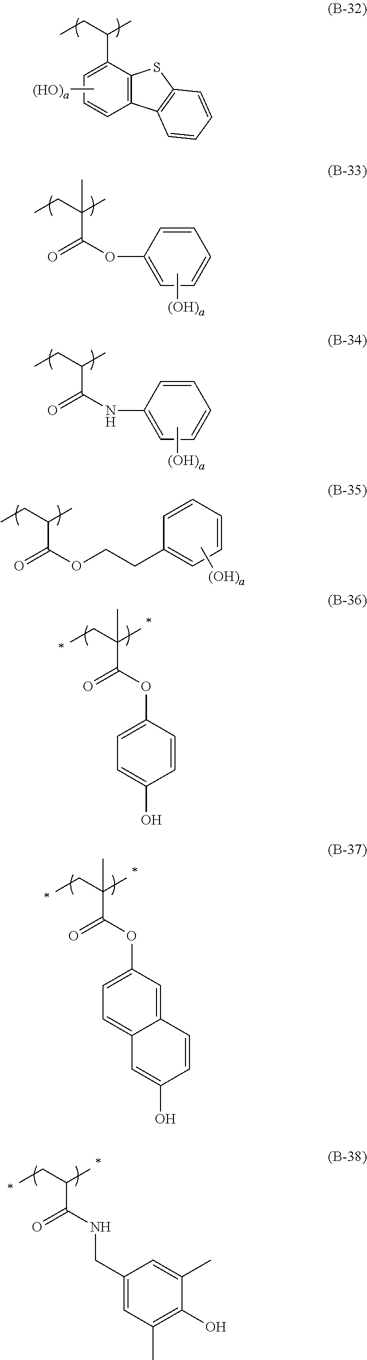

[Other Repeating Units]

The resin (P) may further contain a repeating unit that contains a hydroxyl group or a cyano group other than the repeating units mentioned above. The containment of this repeating unit would realize enhancements of adhesion to substrate and developer affinity. The repeating unit containing a hydroxyl group or a cyano group is preferably a repeating unit with a structure of alicyclic hydrocarbon substituted with a hydroxyl group or a cyano group, and preferably has no acid-decomposable group. In the alicyclic hydrocarbon structure substituted with a hydroxyl group or a cyano group, the alicyclic hydrocarbon structure preferably consists of an adamantyl group, a diamantyl group or a norbornane group. As preferred alicyclic hydrocarbon structures substituted with a hydroxyl group or a cyano group, there can be mentioned the partial structures of general formulae (VIIa) to (VIId) below.

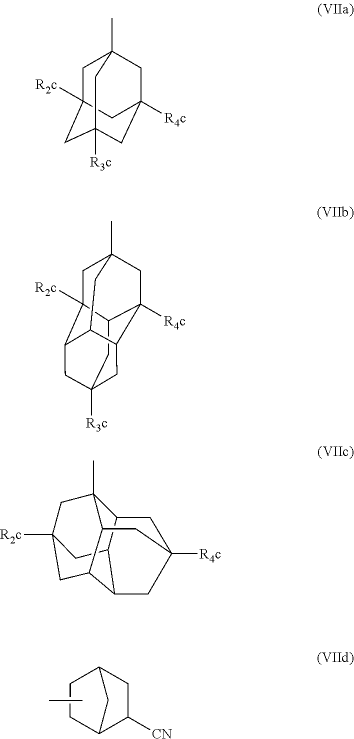

In the general formulae (VIIa) to (VIIc),

each of R₂c to R₄c independently represents a hydrogen atom, a hydroxyl group or a cyano group, providing that at least one of the R₂c to R₄c represents a hydroxyl group or a cyano group.

Preferably, one or two of the R₂c to R₄c are hydroxyl groups and the remainder is a hydrogen atom. In the general formula (VIIa), more preferably, two of the R₂c to R₄c are hydroxyl groups and the remainder is a hydrogen atom.

As the repeating units having any of the partial structures of the general formulae (VIIa) to (VIId), there can be mentioned those of the following general formulae (AIIa) to (AIId).

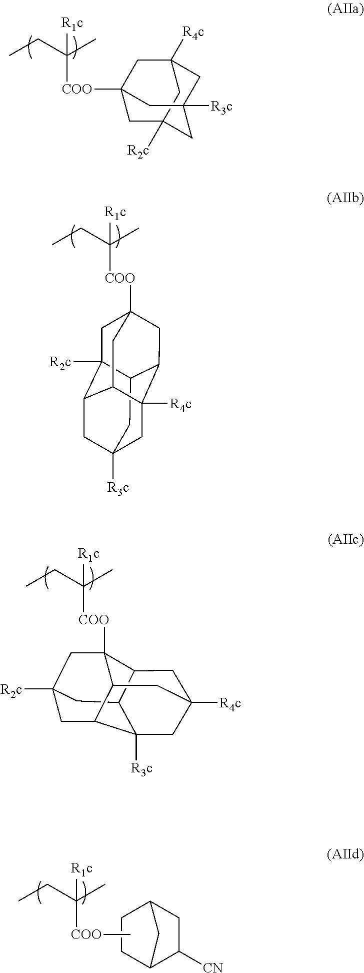

In the general formulae (AIIa) to (AIId),

R₁c represents a hydrogen atom, a methyl group, a trifluoromethyl group or a hydroxymethyl group.

R₂c to R₄c have the same meaning as those of the general formulae (VIIa) to (VIIc).

Specific examples of the repeating units containing a hydroxyl group or a cyano group will be shown below, which however in no way limit the scope of the present invention.

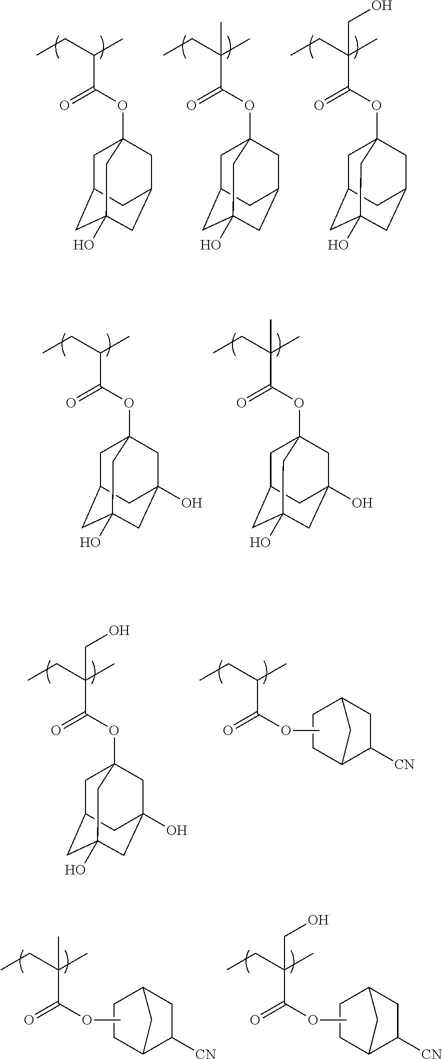

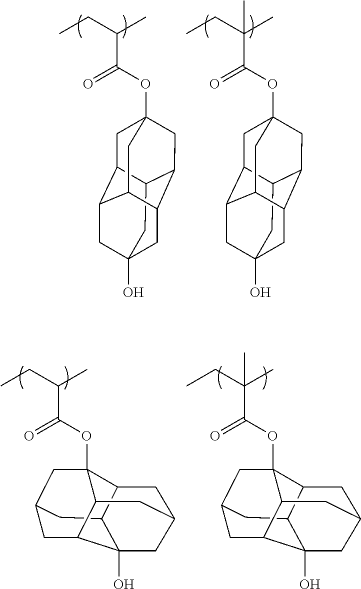

Resin (P) according to the present invention can further contain a repeating unit that has a structure of alicyclic hydrocarbon having no polar group, exhibiting no acid decomposability. As such a repeating unit, there can be mentioned any of the repeating units of general formula (VII) below.

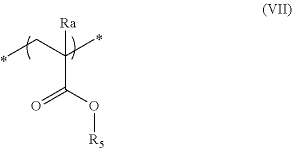

In general formula (VII), R₅ represents a hydrocarbon group having at least one alicyclic hydrocarbon structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group. Ra preferably represents a hydrogen atom, a methyl group, a trifluoromethyl group, a hydroxymethyl group and the like, more preferably a hydrogen atom and a methyl group.

The alicyclic hydrocarbon structures contained in R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5,2,1,0^{2,6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group protected by a protective group and an amino group protected by a protective group. The halogen atom is preferably a bromine, chlorine or fluorine atom, and the alkyl group is preferably a methyl, ethyl, butyl or t-butyl group. The alkyl group may further have a substituent. As the optional further substituent, there can be mentioned a halogen atom, an alkyl group, a hydroxyl group protected by a protective group or an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl or 2-methoxyethoxymethyl group. The substituted ethyl group is preferably a 1-ethoxyethyl or 1-methyl-1-methoxyethyl group. The acyl group is preferably an aliphatic acyl group having 1 to 6 carbon atoms, such as a formyl, acetyl, propionyl, butyryl, isobutyryl, valeryl or pivaloyl group. The alkoxycarbonyl group is, for example, an alkoxycarbonyl group having 1 to 4 carbon atoms.

The content ratio of any of the repeating units that have a structure of alicyclic hydrocarbon having no polar group, exhibiting no acid decomposability, based on all the repeating units of resin (P), is preferably in the range of 1 to 40 mol %, more preferably 1 to 20 mol %.

Specific examples of the repeating units that have a structure of alicyclic hydrocarbon having no polar group, exhibiting no acid decomposability will be shown below, which however in no way limit the scope of the present invention. In the formulae, Ra represents H, CH₃, CH₂OH or CF₃.

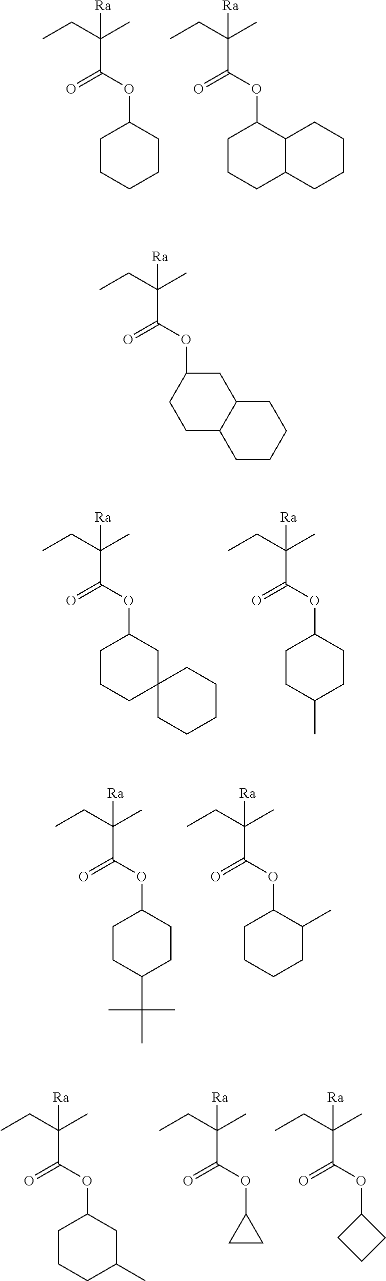

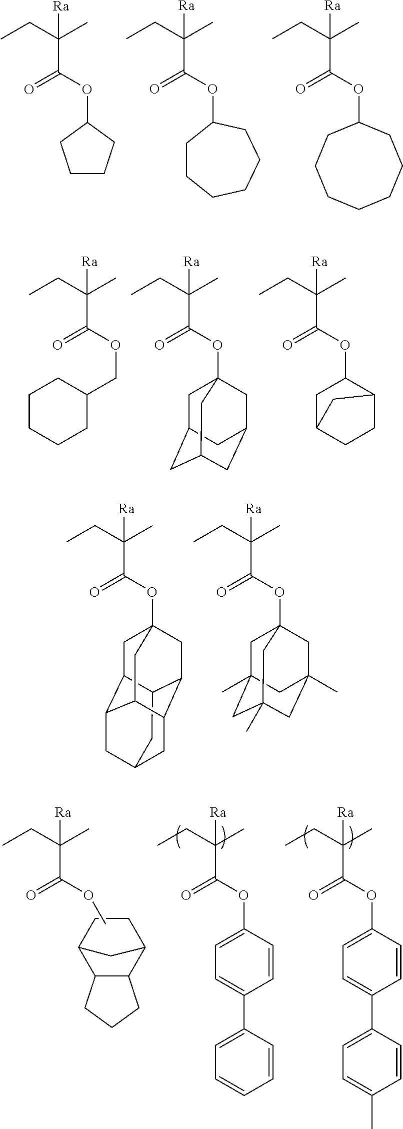

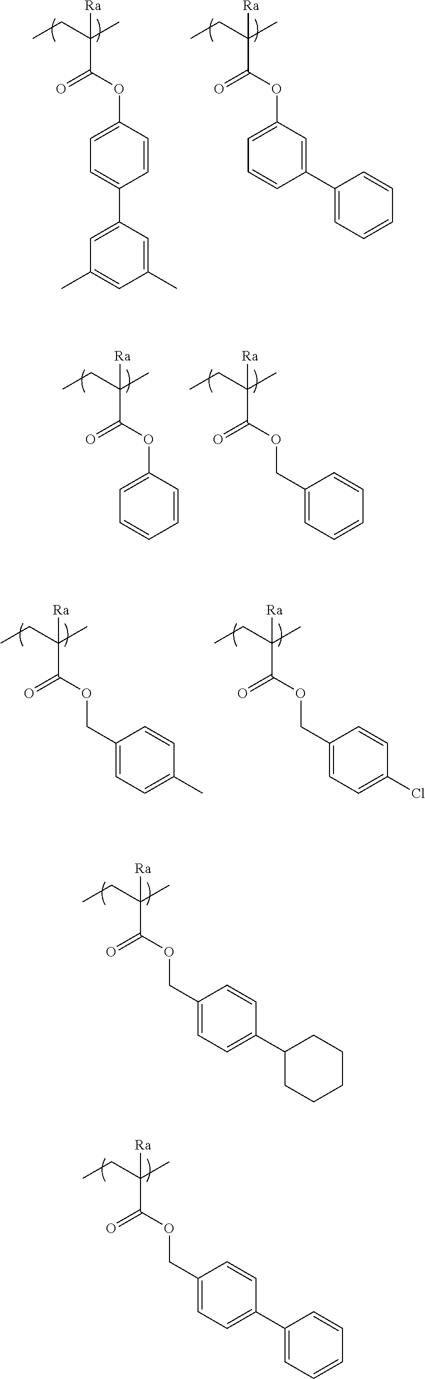

Resin (P) may have, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

The use of such repeating structural units would enable fine regulation of the required properties of resin (A), especially: (1) solubility in applied solvents, (2) film forming easiness (glass transition point), (3) alkali developability, (4) film thinning (selections of hydrophilicity/hydrophobicity and alkali-soluble group), (5) adhesion of unexposed area to substrate, and (6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters, styrenes, crotonic esters and the like.

In addition, any unsaturated compound capable of addition polymerization that is copolymerizable with monomers corresponding to the above various repeating structural units may be copolymerized therewith.

The molar ratios of individual repeating structural units contained in resin (P) are appropriately determined from the viewpoint of regulation of not only the dry etching resistance of the resist but also the standard developer adaptability, substrate adhesion, resist profile and generally required properties of the resist such as the resolving power, heat resistance and sensitivity.

The resin (P) according to the present invention may have any of the random, block, comb and star configurations.

The resin (P) can be synthesized by, for example, the radical, cation or anion polymerization of unsaturated monomers corresponding to given structures. Further, the intended resin can be obtained by first polymerizing unsaturated monomers corresponding to the precursors of given structures and thereafter carrying out a polymer reaction.

For example, as general synthetic methods, there can be mentioned a batch polymerization method in which an unsaturated monomer and a polymerization initiator are dissolved in a solvent and heated so as to accomplish polymerization, a dropping polymerization method in which a solution of unsaturated monomer and polymerization initiator is dropped into a heated solvent over a period of 1 to 10 hours, etc. The dropping polymerization method is preferred.

As the solvents for use in polymerization, there can be mentioned, for example, those employable in the preparation of the actinic-ray- or radiation-sensitive resin composition to be described hereinafter. It is preferred to perform the polymerization with the use of the same solvent as employed in the composition of the present invention. This inhibits any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, the polymerization may be carried out in the presence of a chain transfer agent (for example, an alkyl mercaptan and the like).

The concentration during the reaction is generally in the range of 5 to 70 mass %, preferably 10 to 50 mass %. The reaction temperature is generally in the range of 10° to 150° C., preferably 30° to 120° C. and more preferably 40° to 100° C.

The reaction time is generally in the range of 1 to 48 hours, preferably 1 to 24 hours and further more preferably 1 to 12 hours.

After the completion of the reaction, the mixture is allowed to stand still to cool to room temperature and purified. In the purification, use is made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc. and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents and the like. Of these, it is preferred to employ a solvent containing at least an alcohol (especially methanol and the like) or water as the precipitation or re-precipitation solvent.

The amount of precipitation or re-precipitation solvent used is generally in the range of 100 to 10,000 parts by mass, preferably 200 to 2000 parts by mass and more preferably 300 to 1000 parts by mass per 100 parts by mass of the polymer solution, according to intended efficiency, yield, etc.

The temperature at which the precipitation or re-precipitation is carried out is generally in the range of about 0° to 50° C., preferably about room temperature (for example, about 20° to 35° C.), according to efficiency and operation easiness. The operation of precipitation or re-precipitation can be carried out by a publicly known method, such as a batch or continuous method, with the use of a common mixing vessel, such as an agitation vessel.

The polymer obtained by the precipitation or re-precipitation is generally subjected to common solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. at ordinary pressure or reduced pressure (preferably reduced pressure).

Alternatively, after the resin precipitation and separation, the obtained resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to thereby precipitate a resin (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby precipitate a resin solid (step d) and separating the precipitated resin (step e).

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

The molecular weight of the resin (P) according to the present invention is not particularly limited.

Preferably, the weight average molecular weight thereof is in the range of 1000 to 100,000. It is more preferably in the range of 1500 to 60,000, most preferably 2000 to 30,000. The regulation of the weight average molecular weight to 1000 to 100,000 would prevent deteriorations of heat resistance and dry etching resistance and also prevent deterioration of developability and increase of viscosity leading to poor film forming property. Herein, the weight average molecular weight of the resin refers to the molecular weight in terms of polystyrene molecular weight measured by GPC (carrier: THF or N-methyl-2-pyrrolidone (NMP)).

The molecular weight dispersity (Mw/Mn) of the resin is preferably in the range of 1.00 to 5.00, more preferably 1.03 to 3.50 and further more preferably 1.05 to 2.50. The lower the molecular weight distribution, the more excellent the resolving power and resist profile and the smoother the side wall of the resist pattern to thereby attain an excellence in roughness.

In the present invention, a single type of resin (P) can be used alone, or two or more types of resins (P) can be used in combination. The content of resin (P) in the actinic-ray- or radiation-sensitive resin composition of the present invention based on the total solids thereof is preferably in the range of 30 to 100 mass %, more preferably 50 to 100 mass % and most preferably 70 to 100 mass %.

More preferred particular examples of resins (P) will be shown below, which however in no way limit the scope of the present invention.

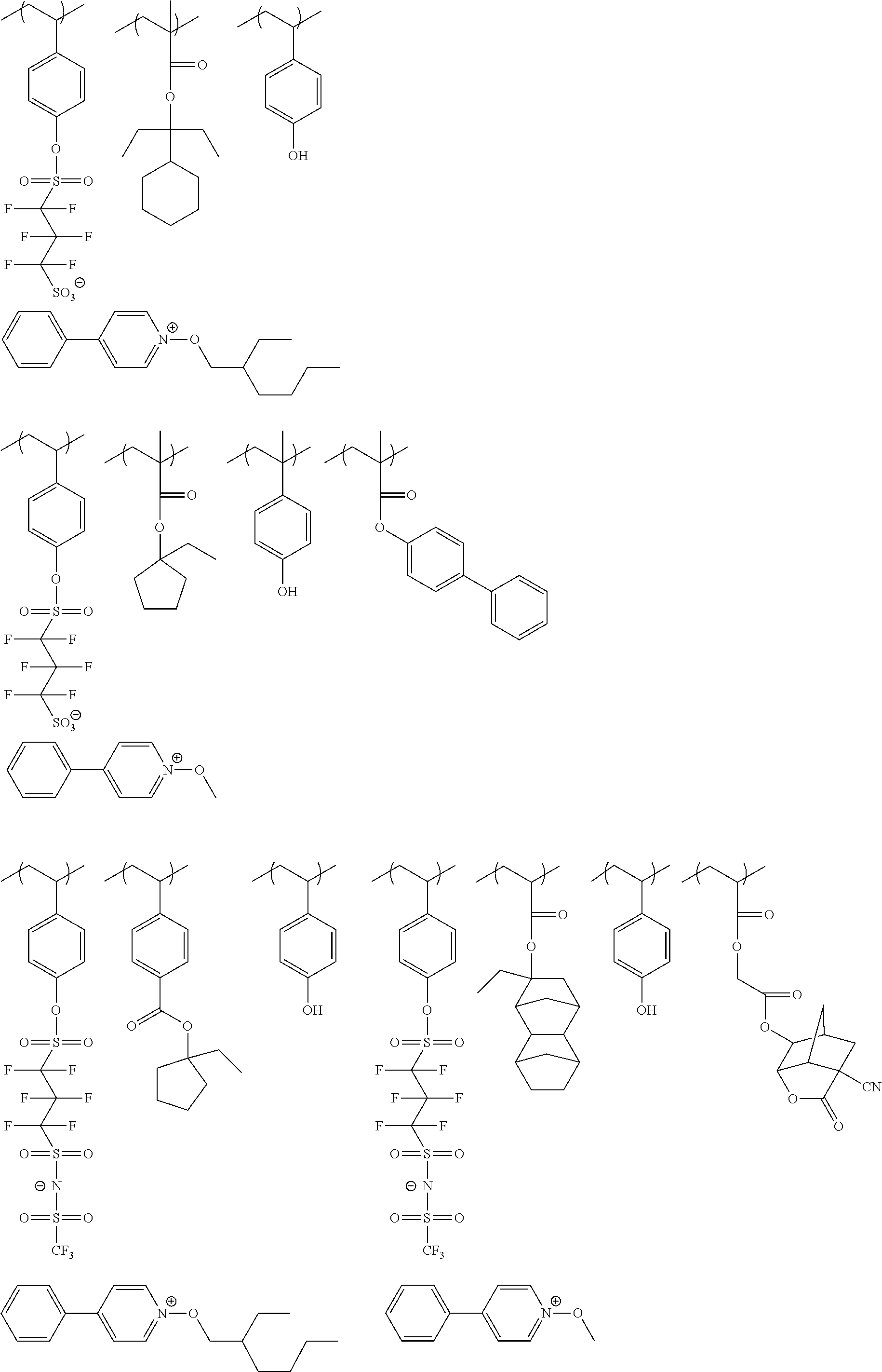

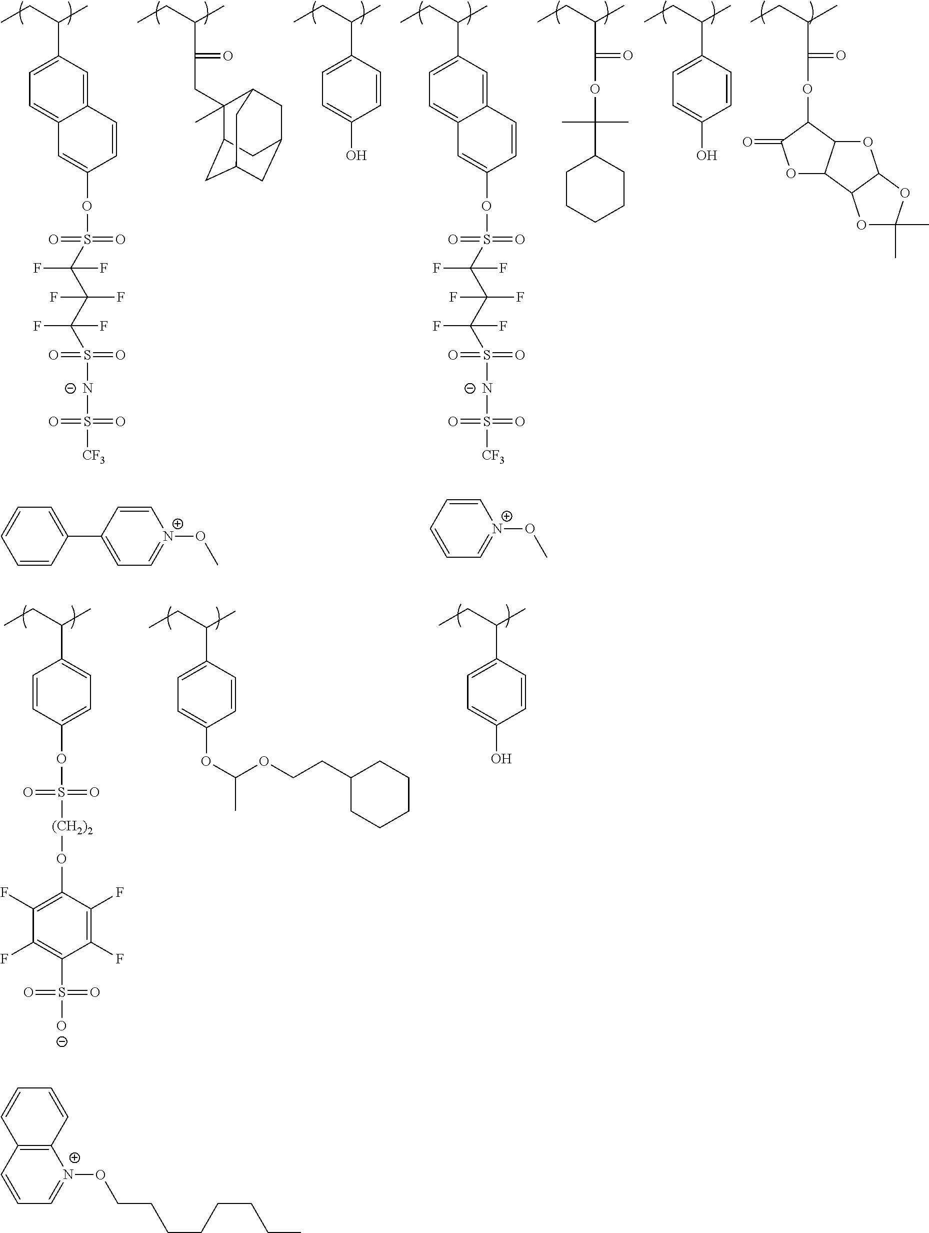

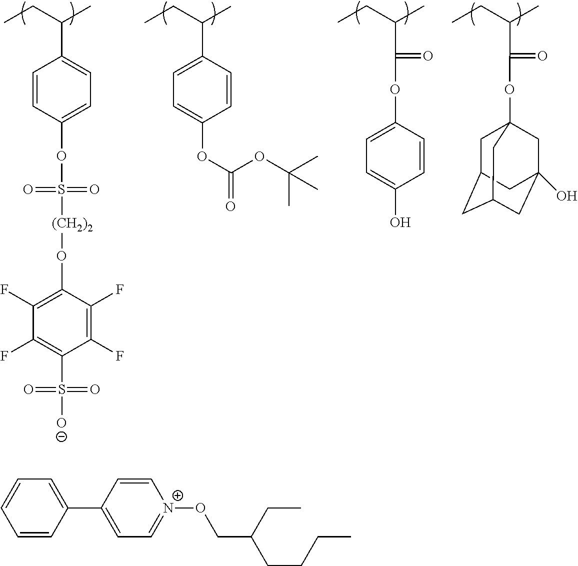

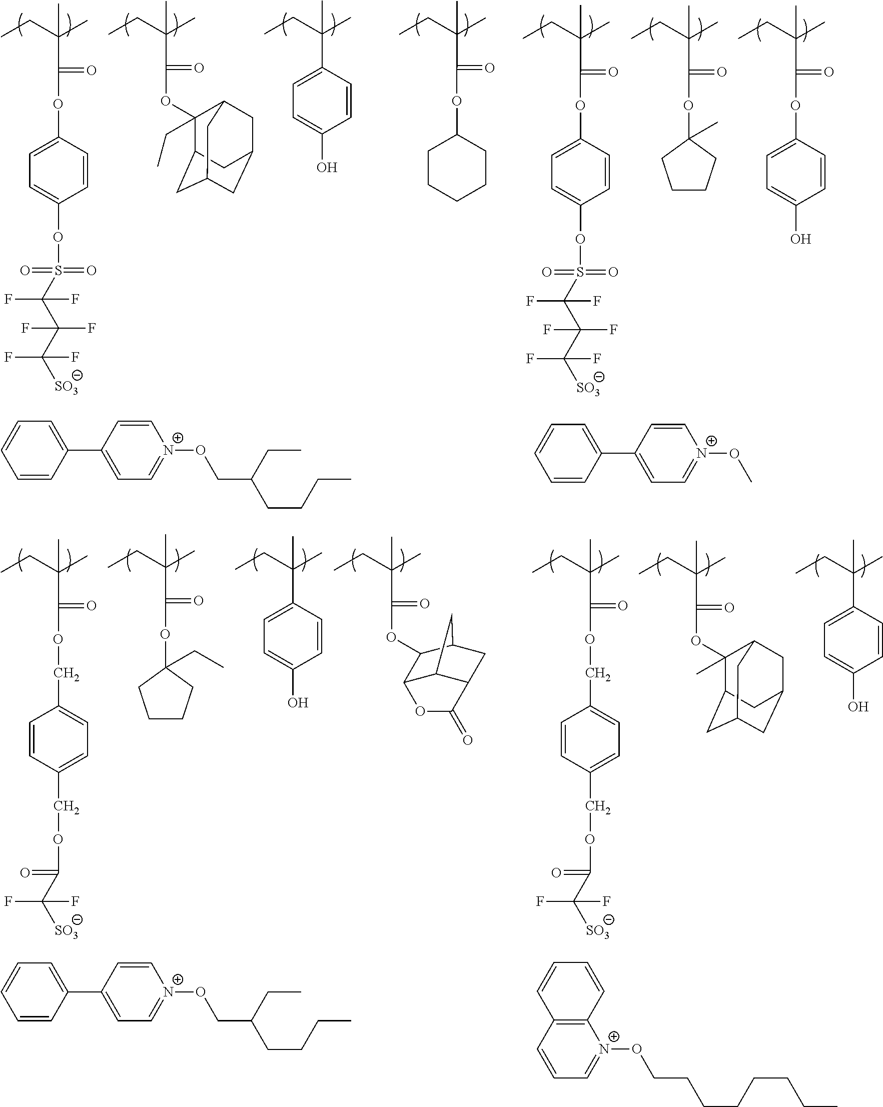

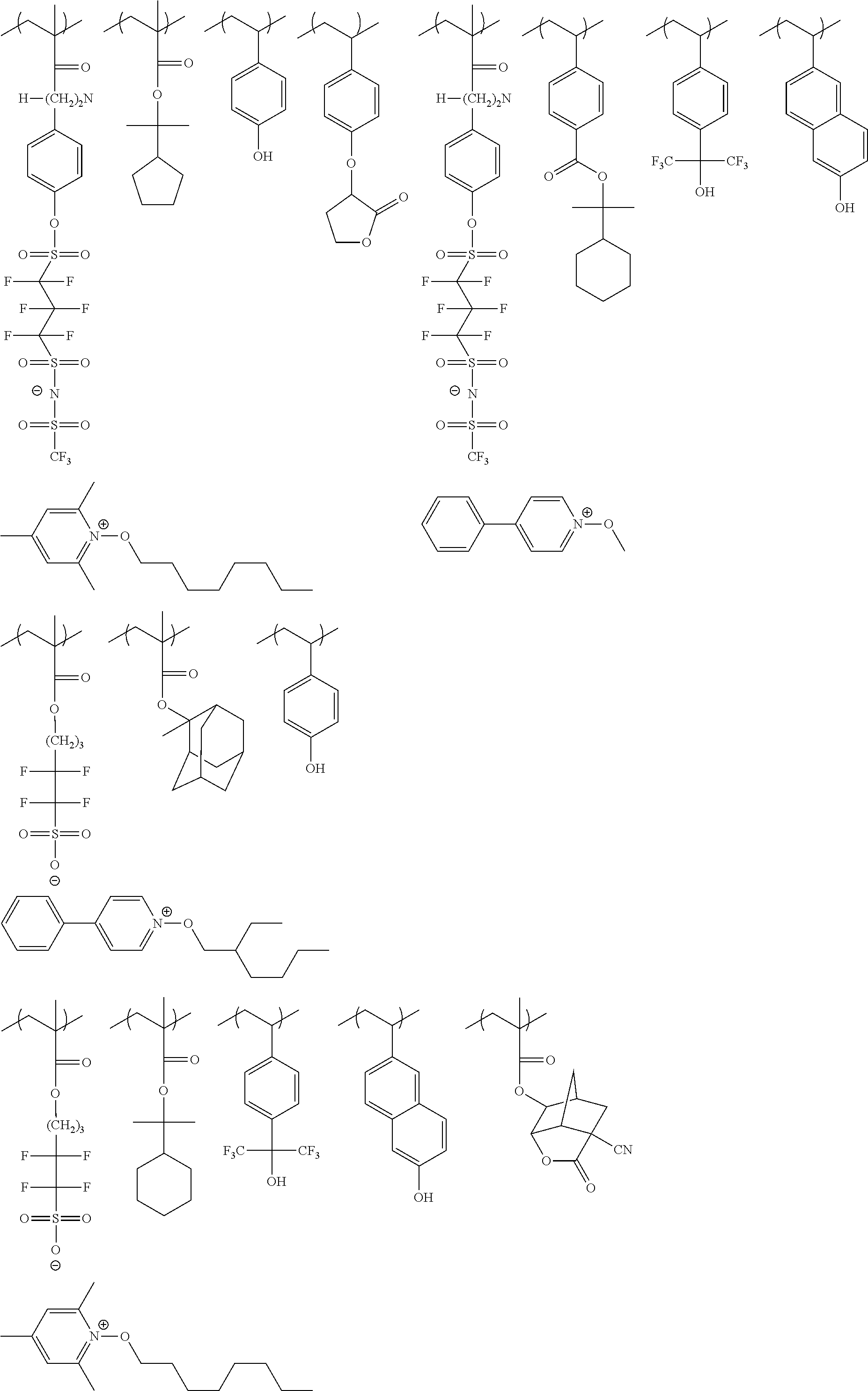

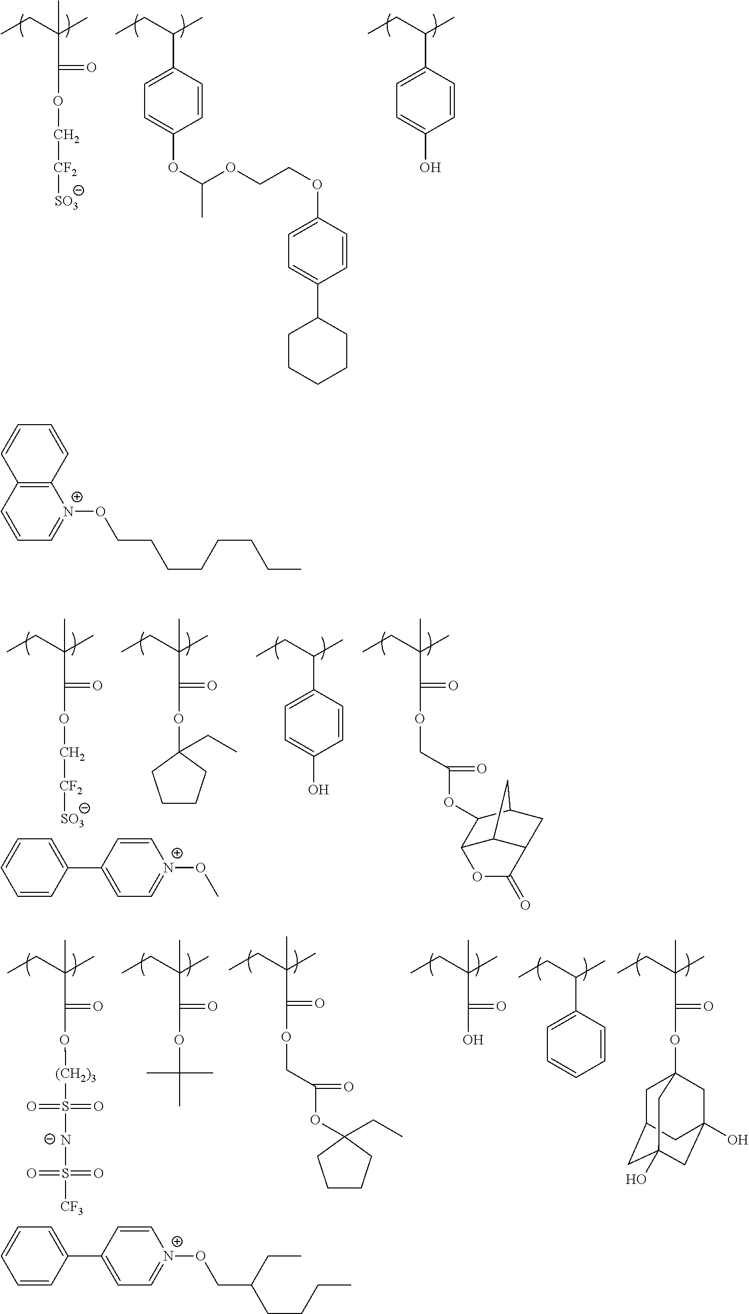

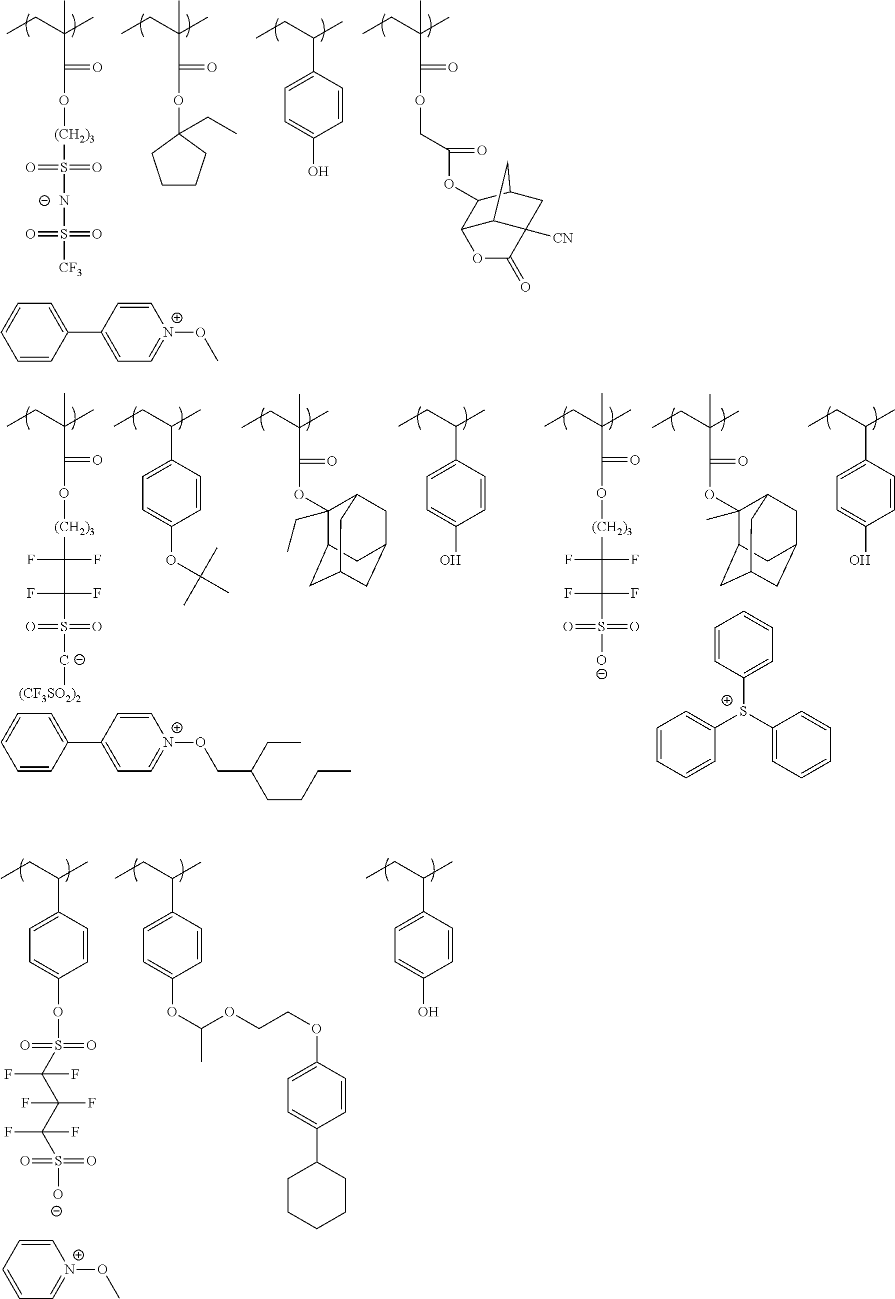

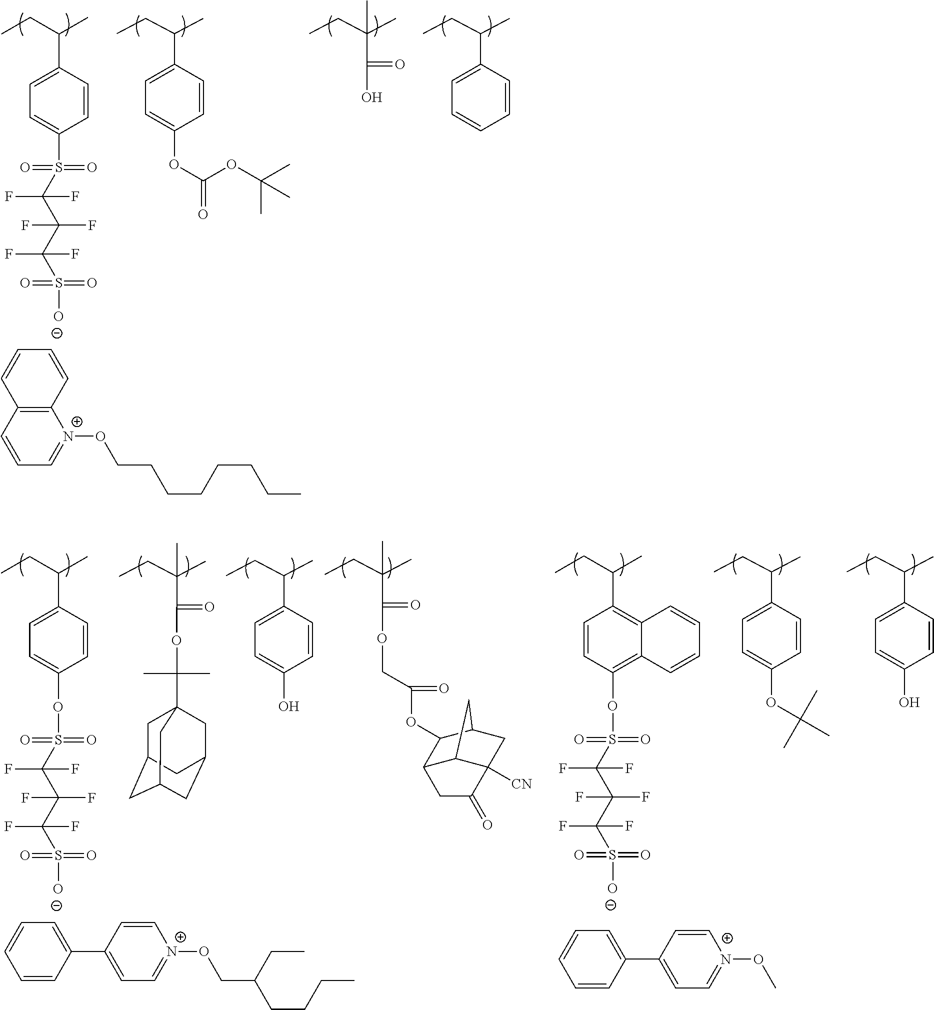

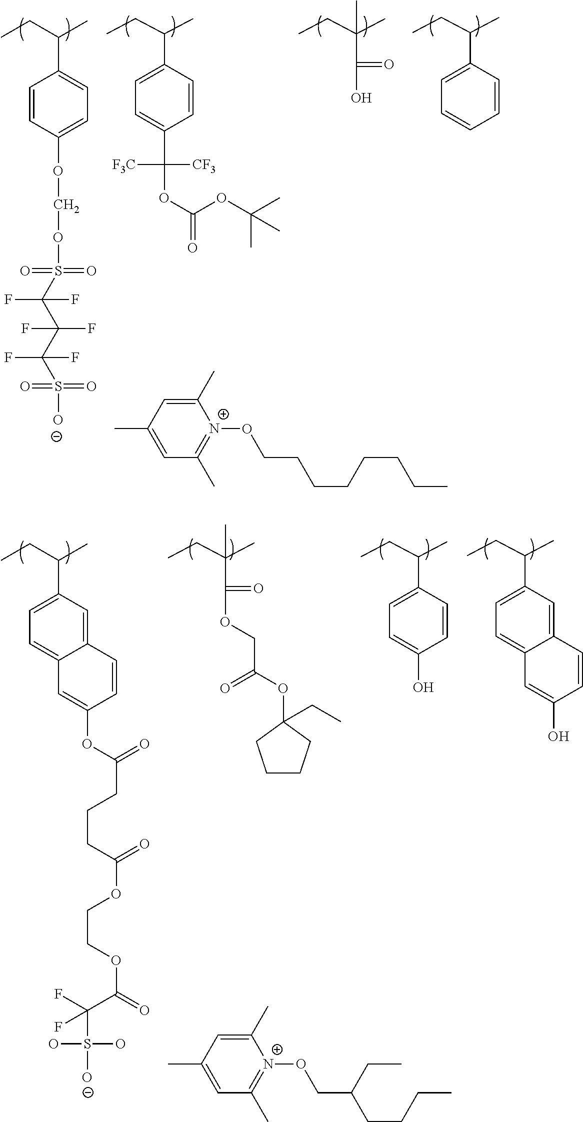

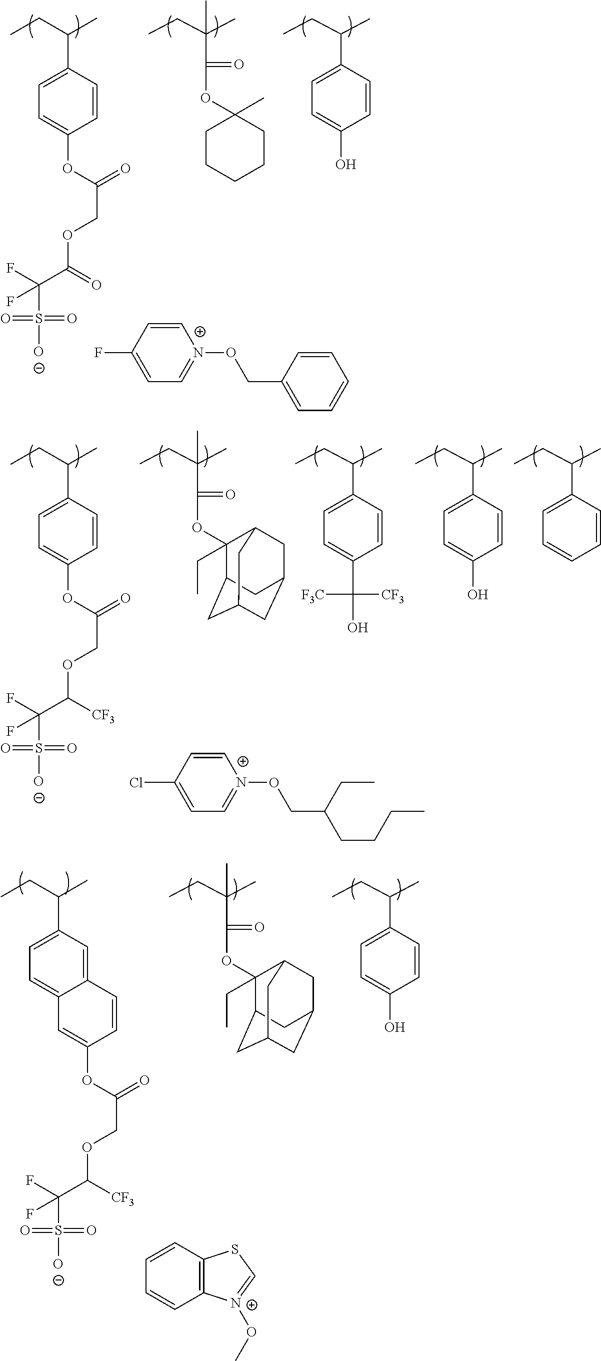

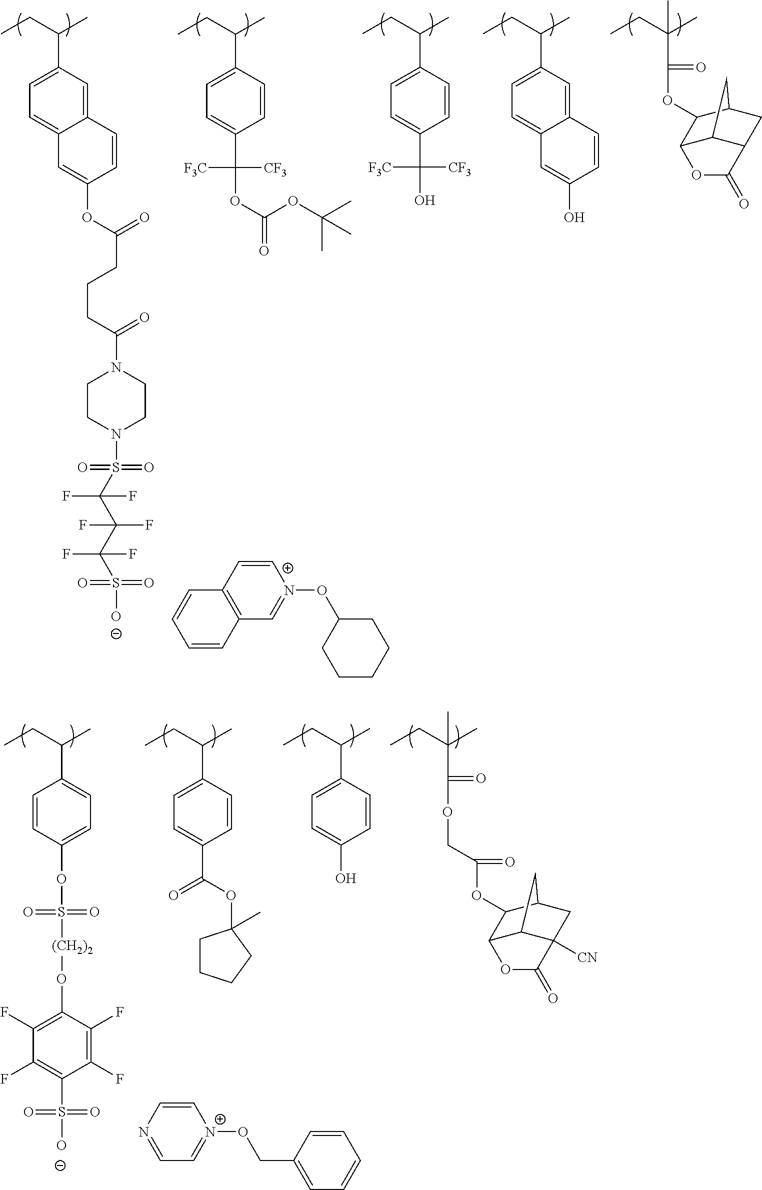

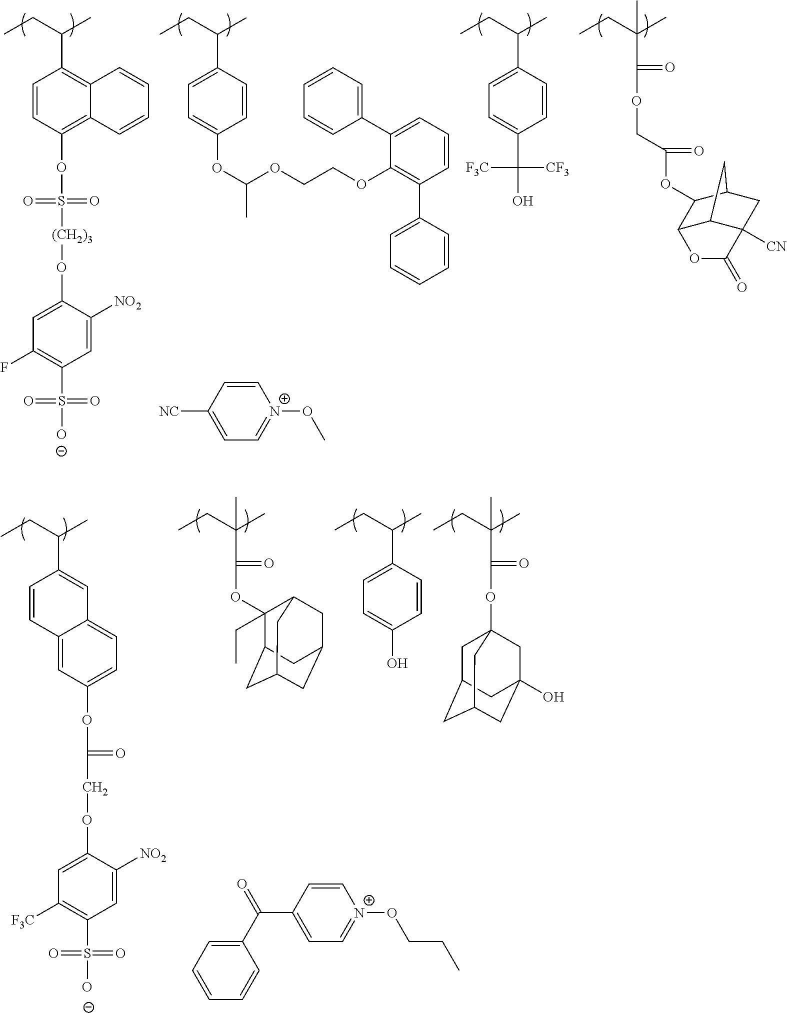

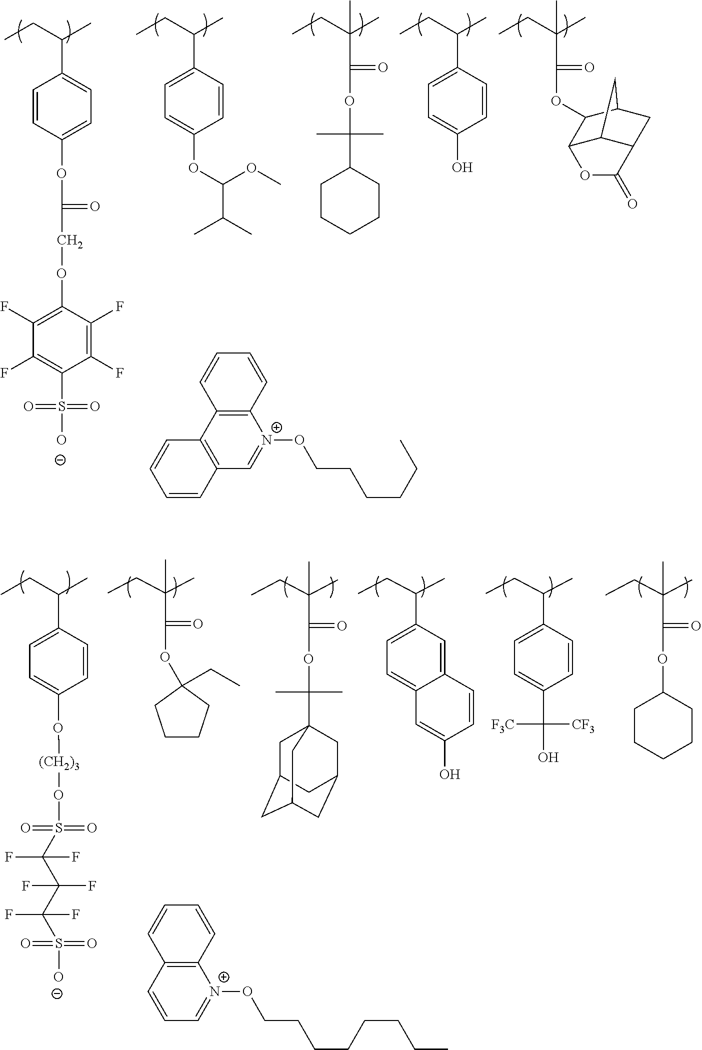

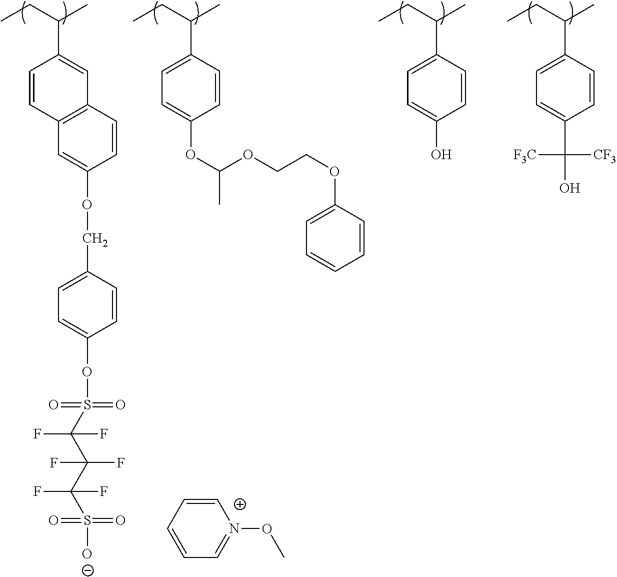

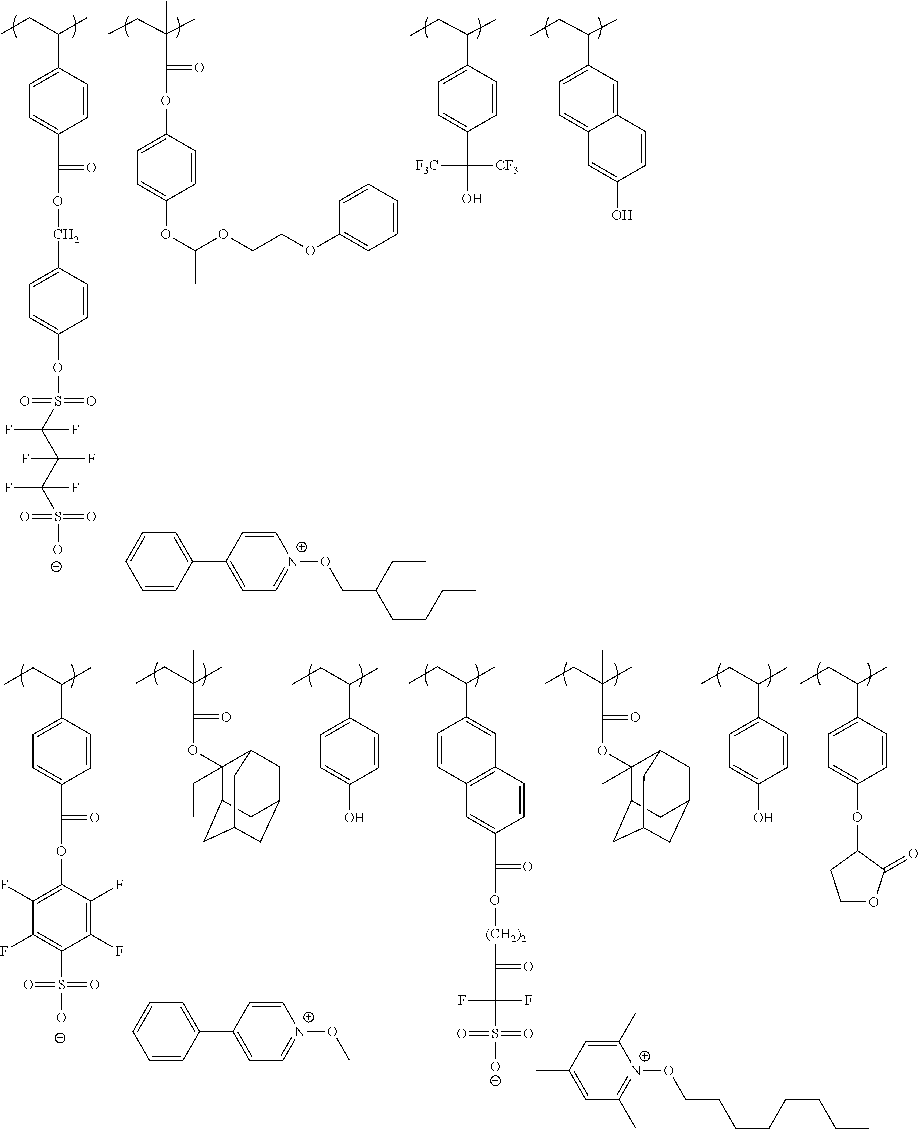

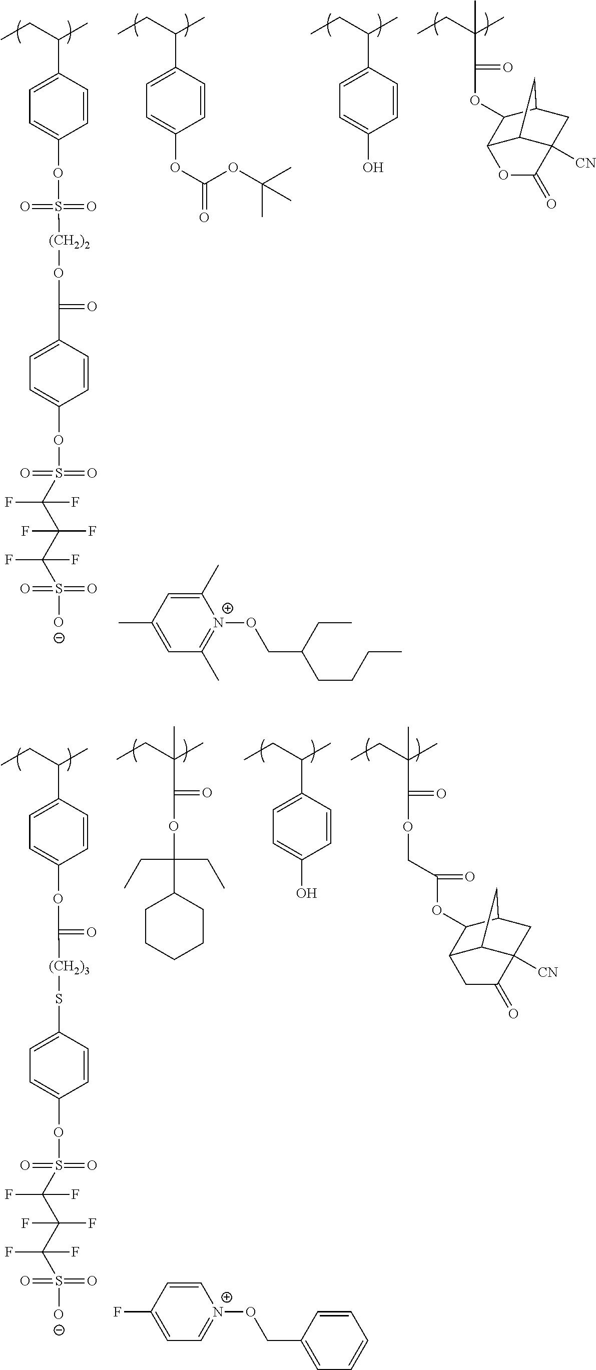

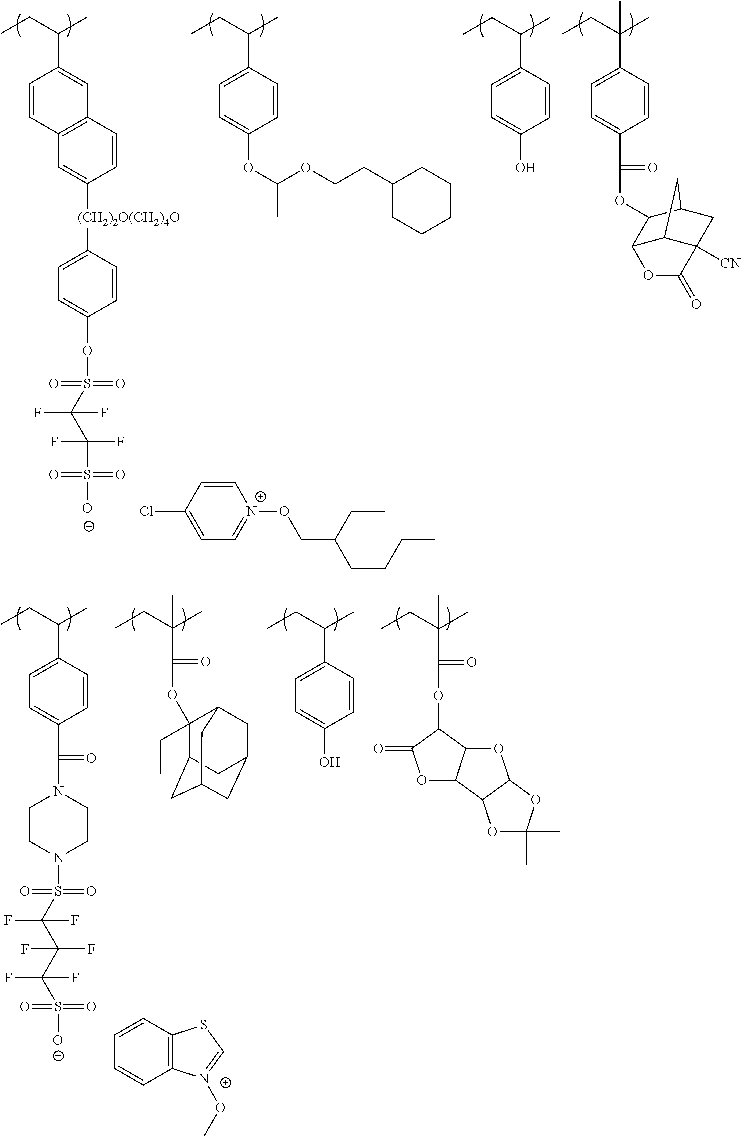

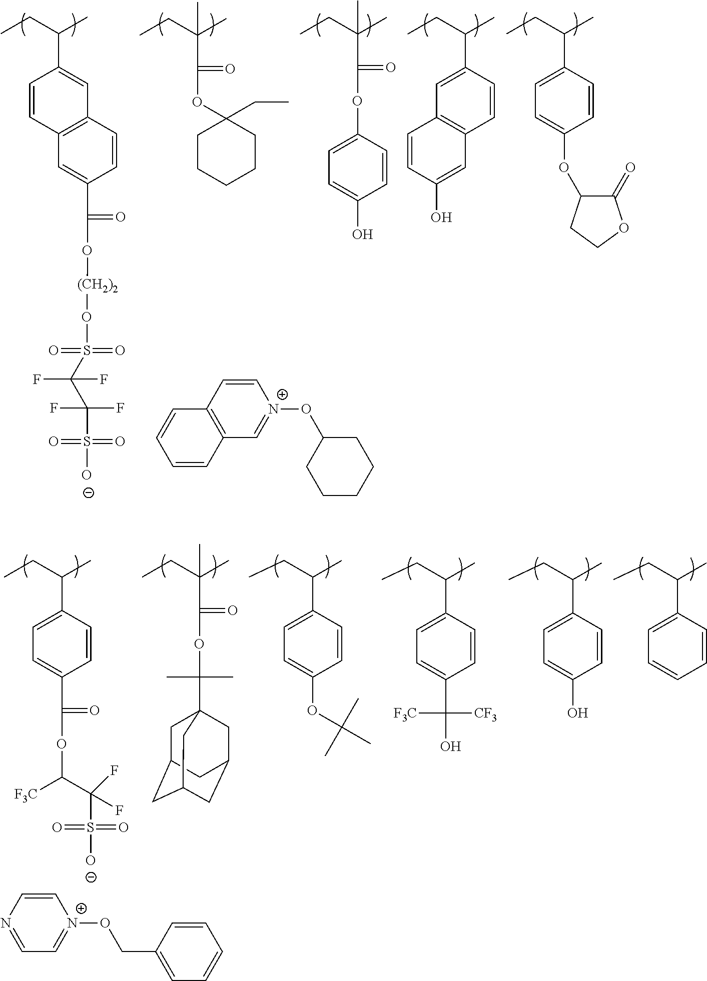

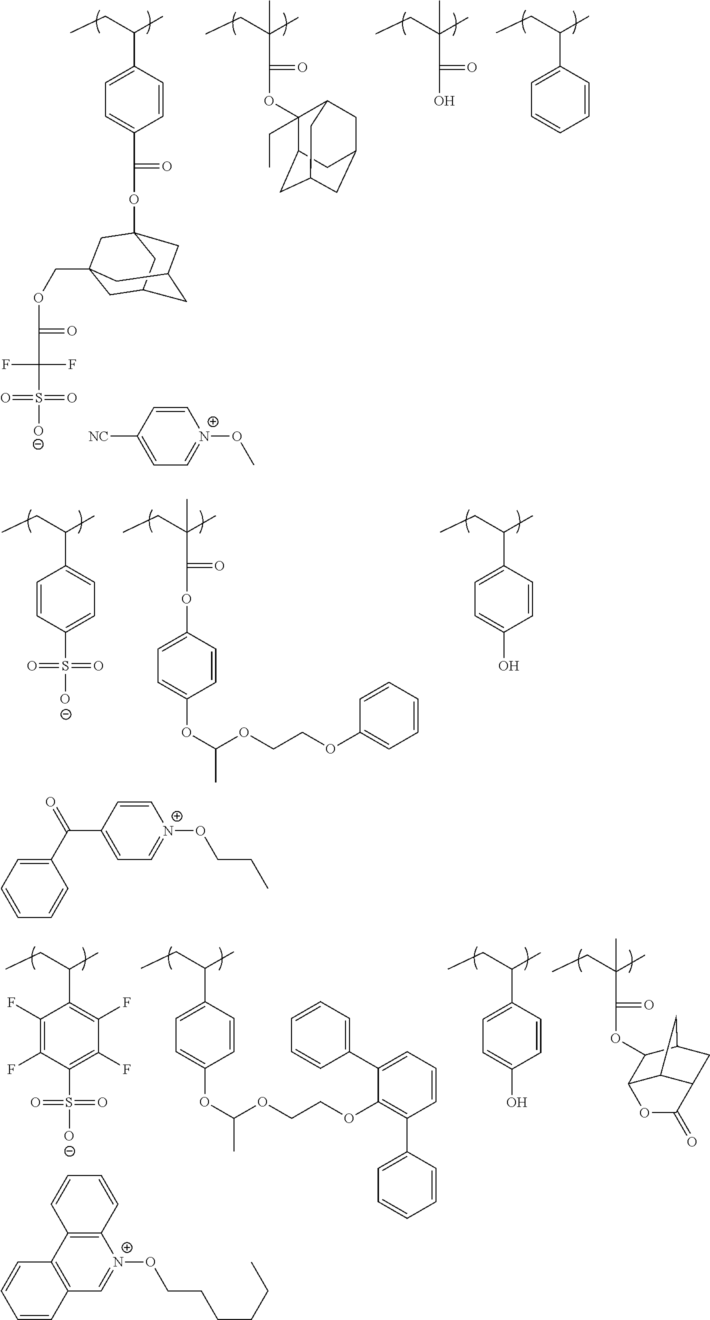

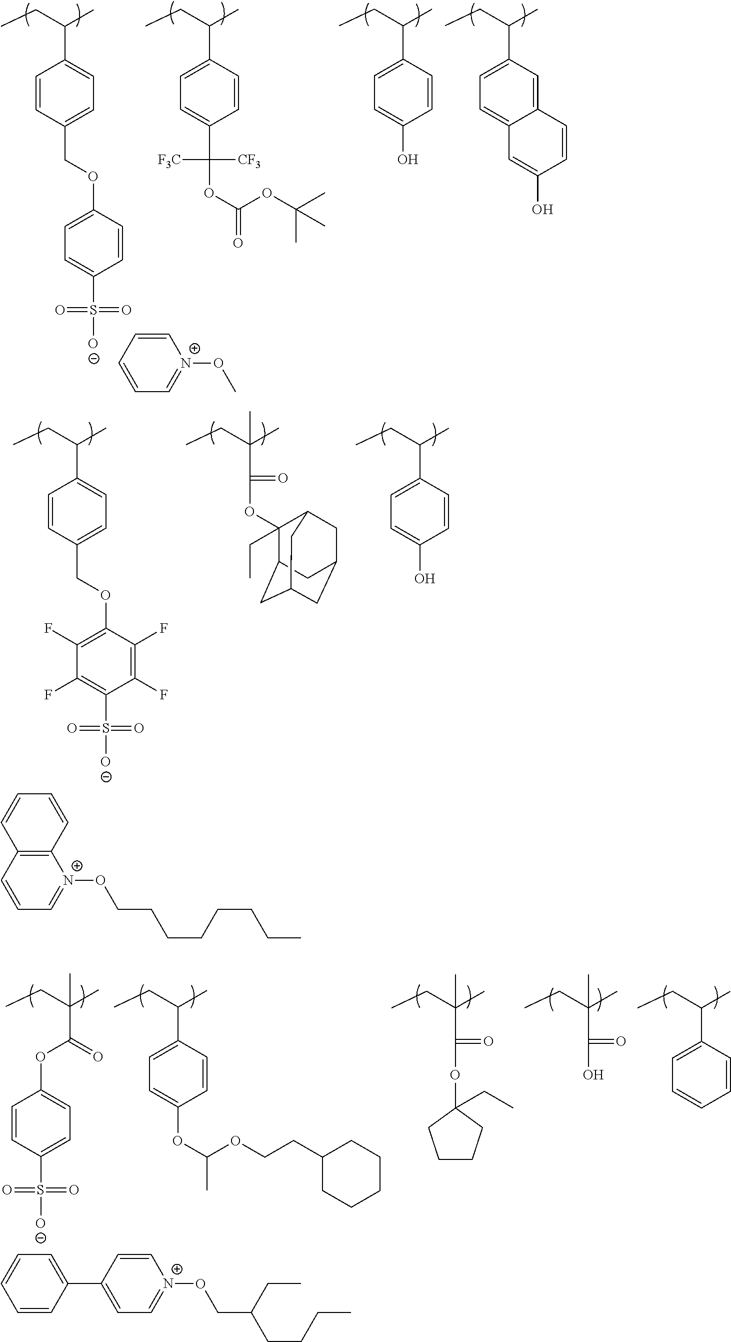

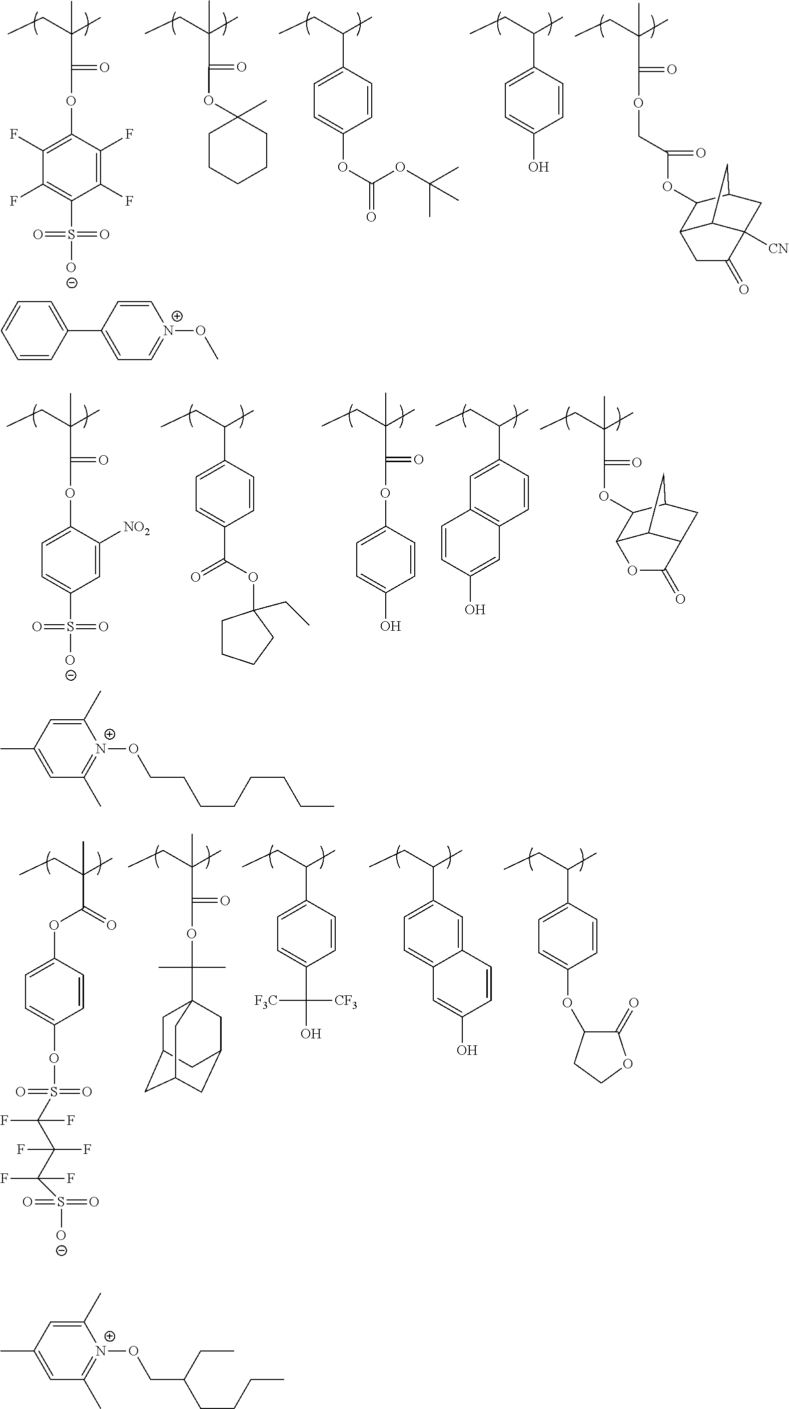

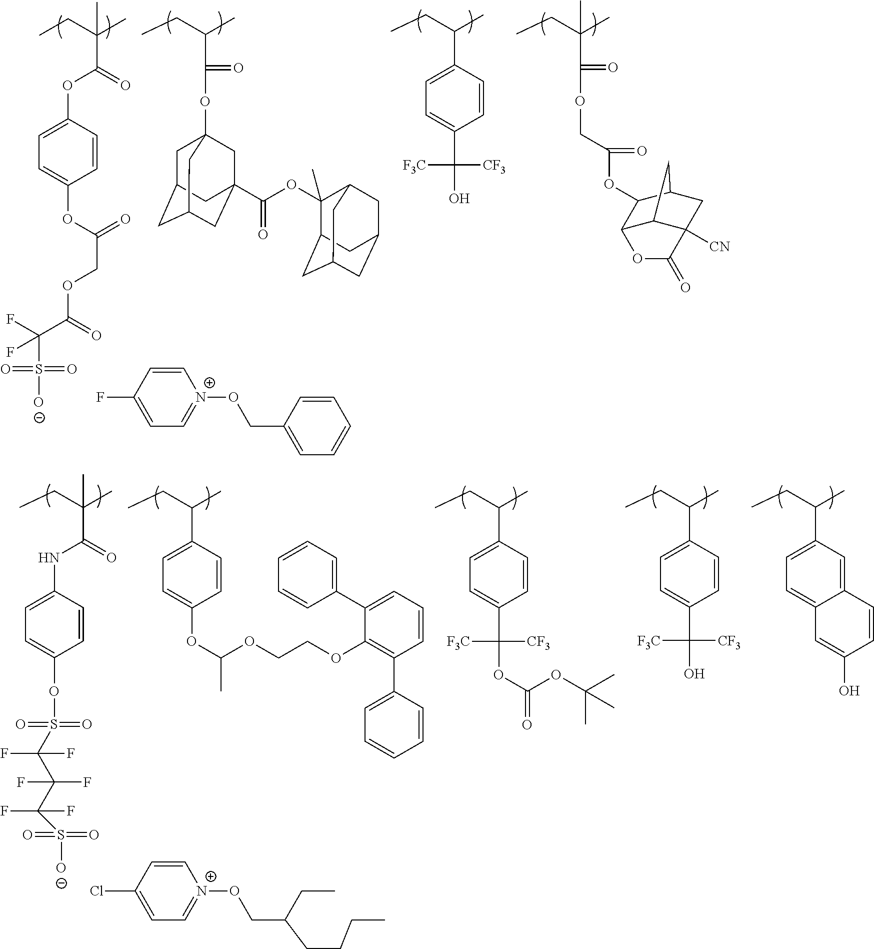

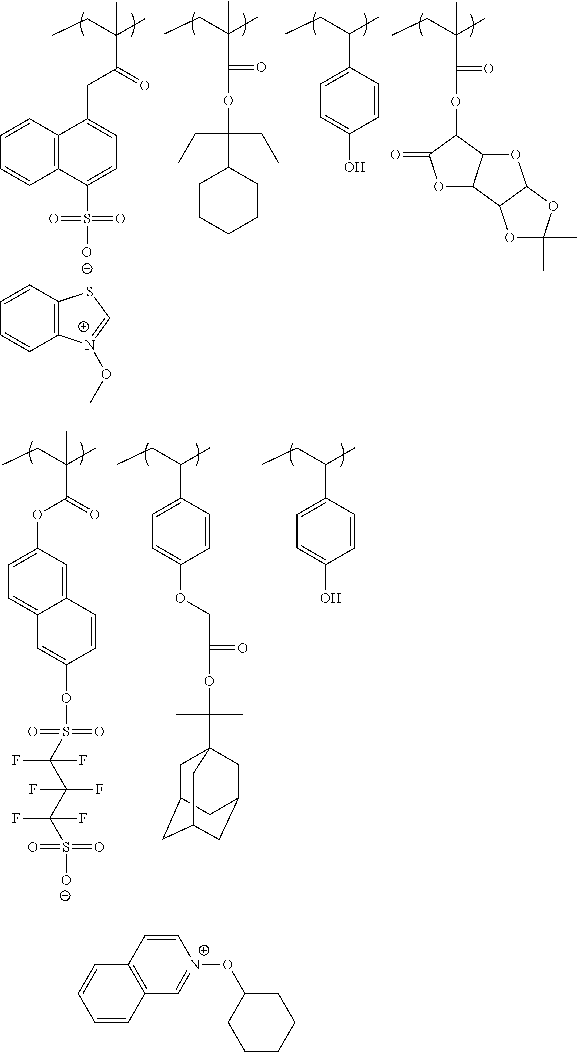

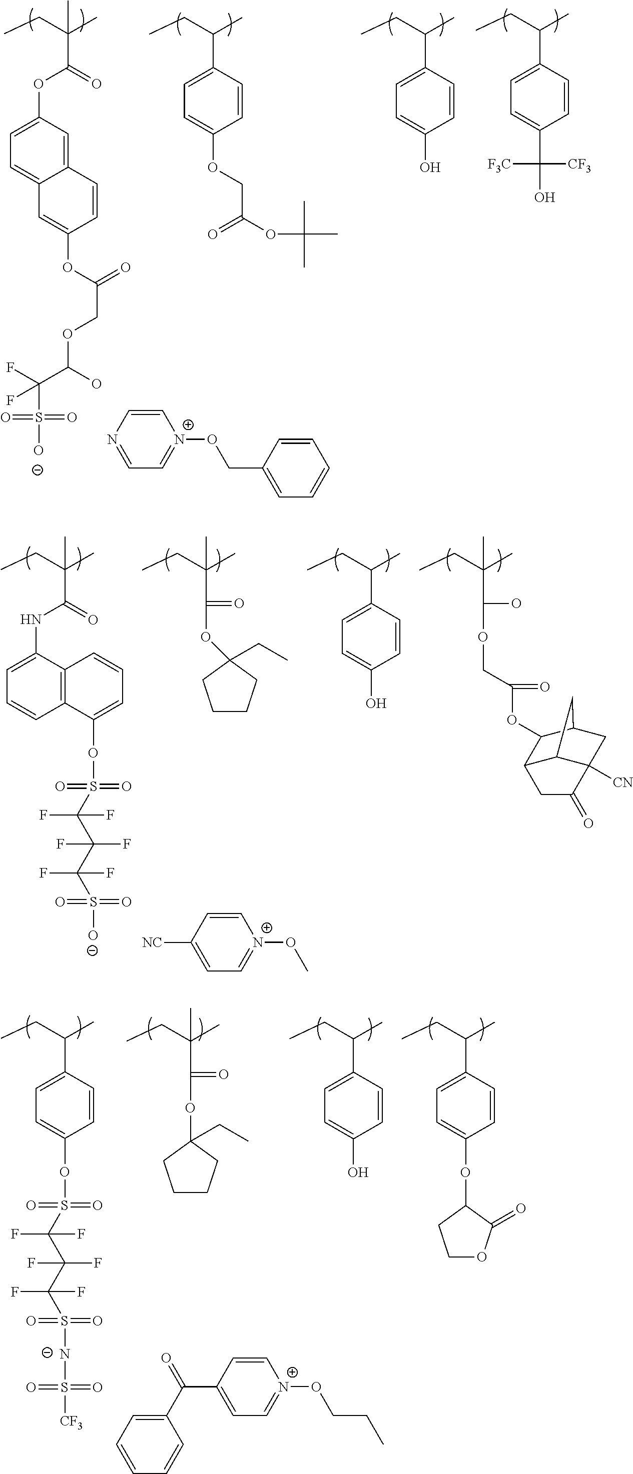

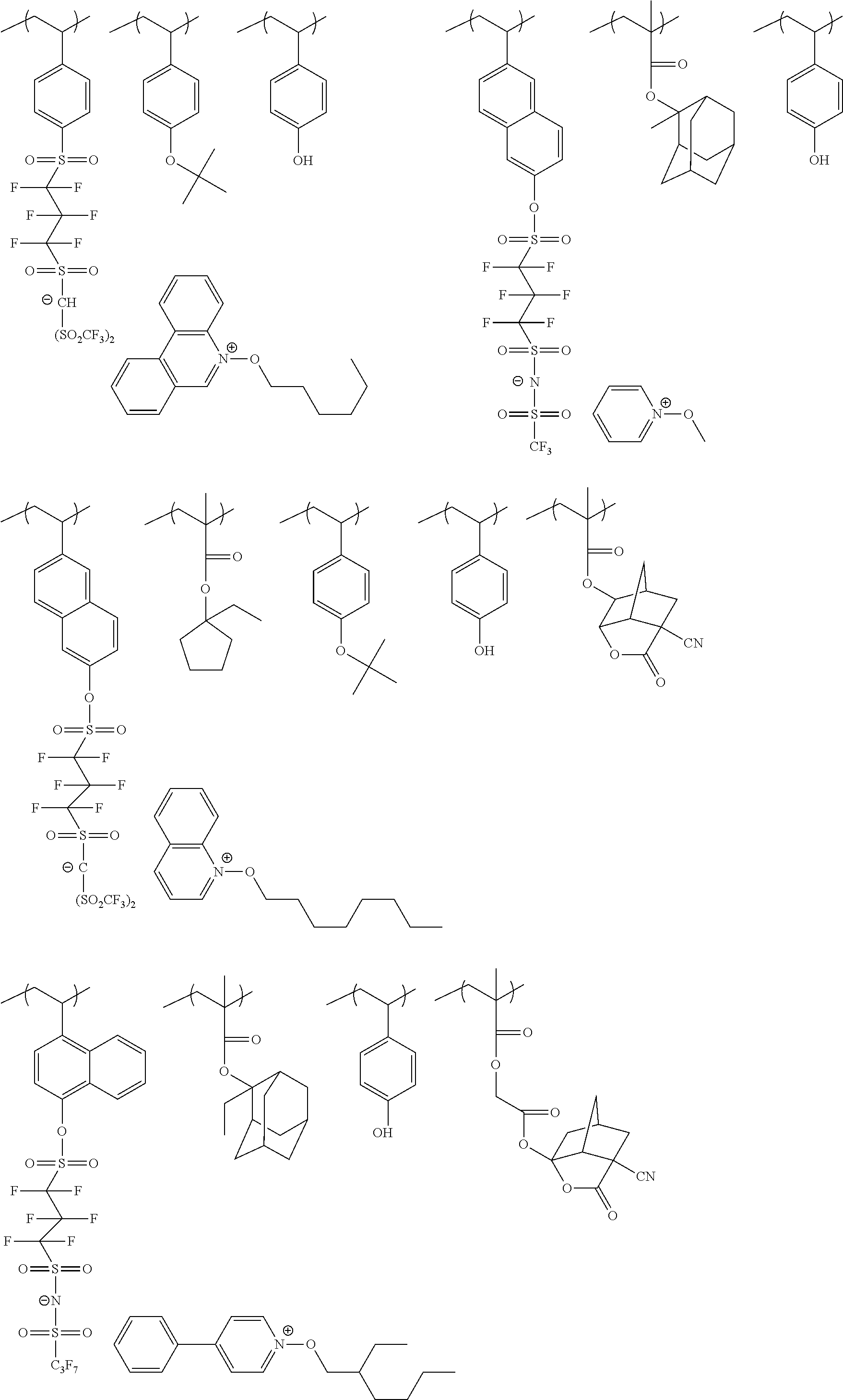

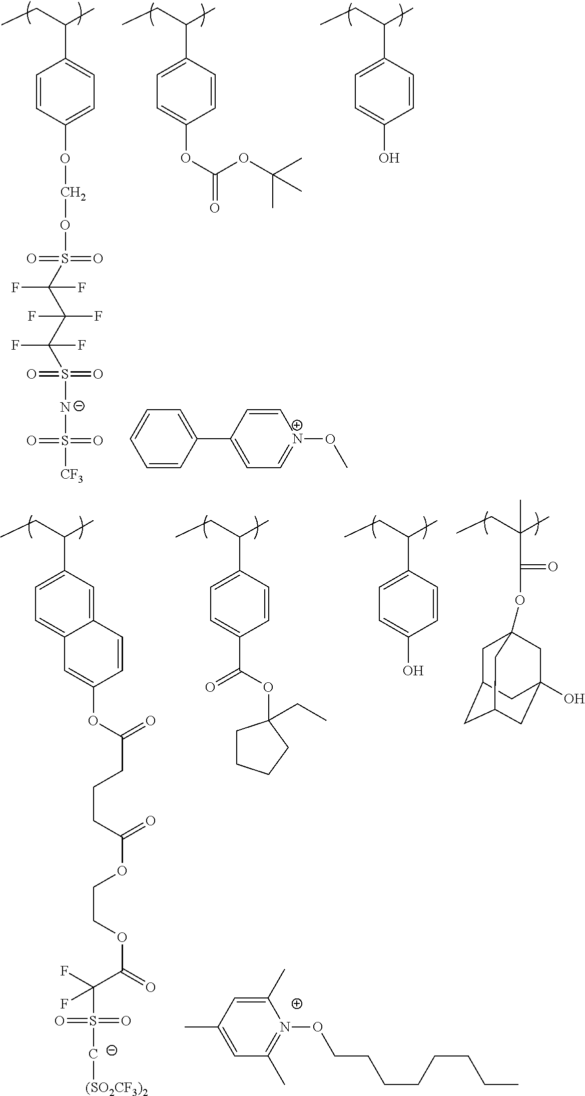

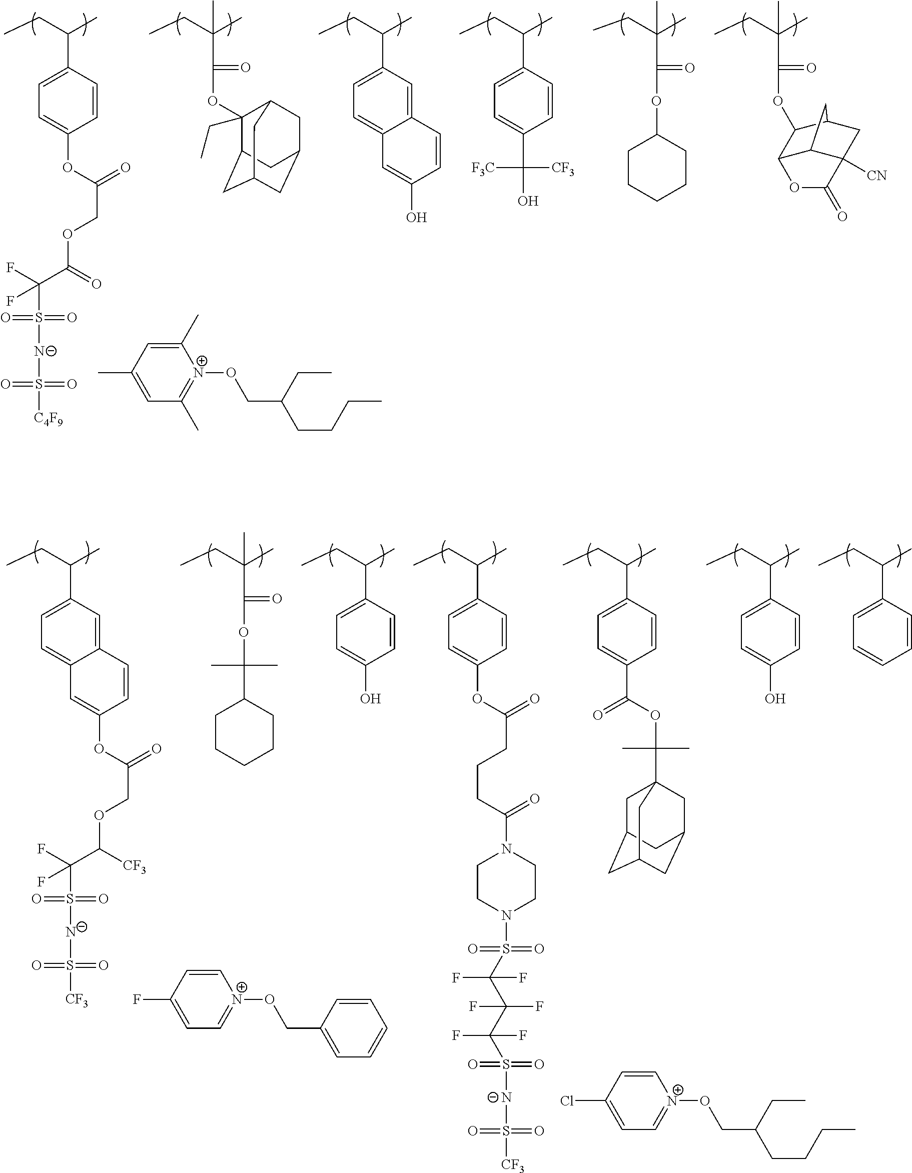

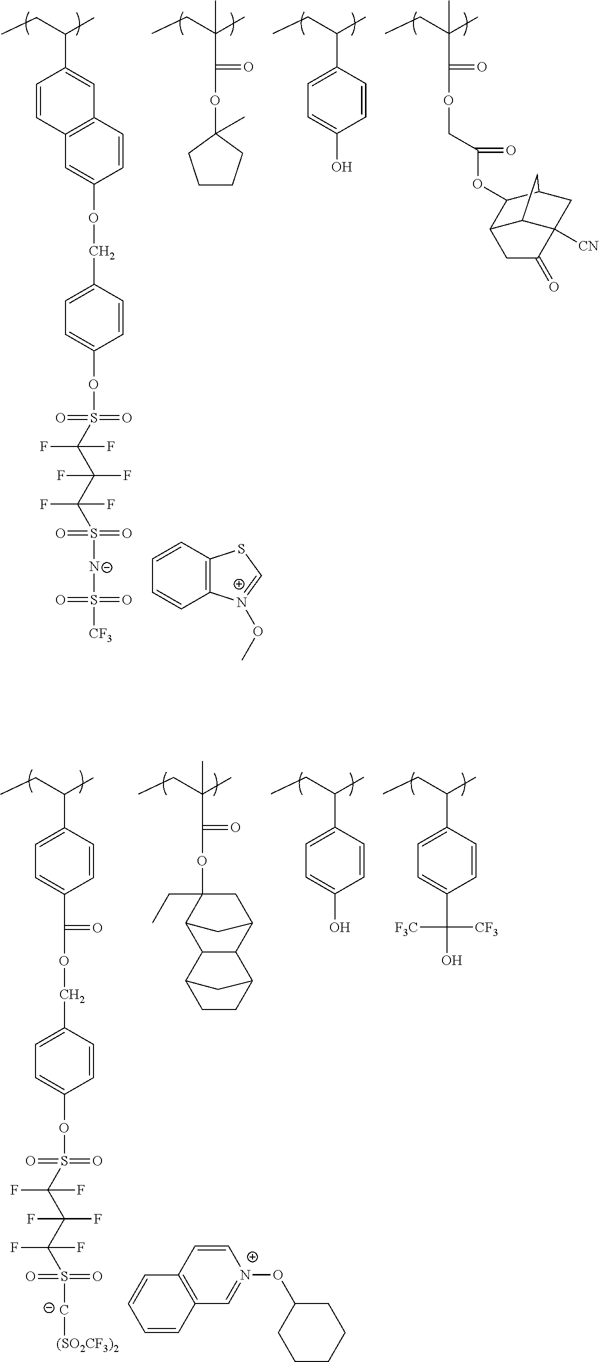

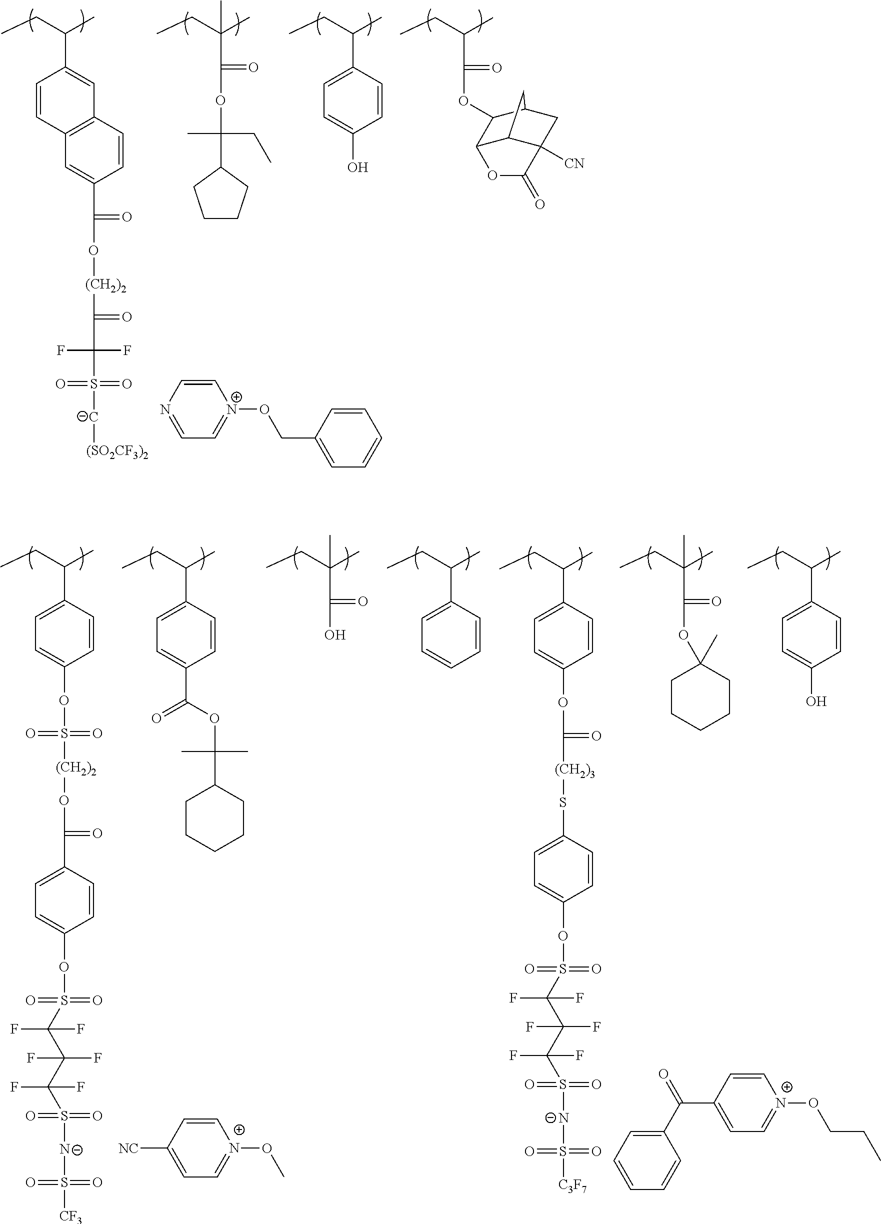

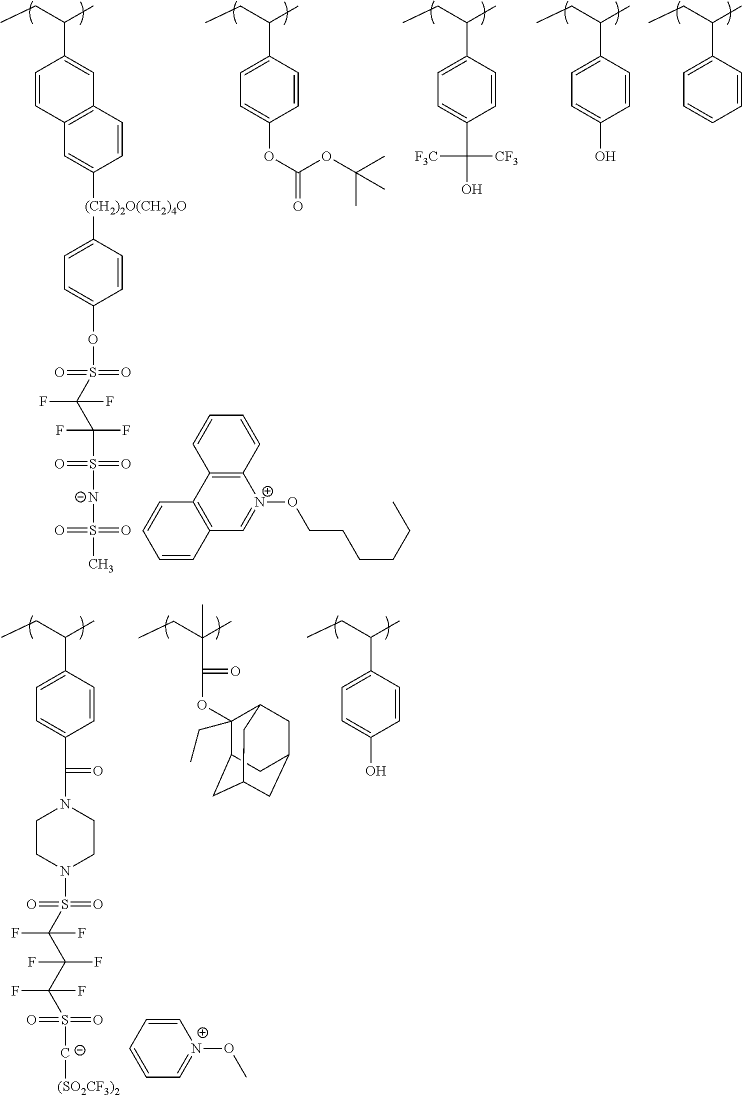

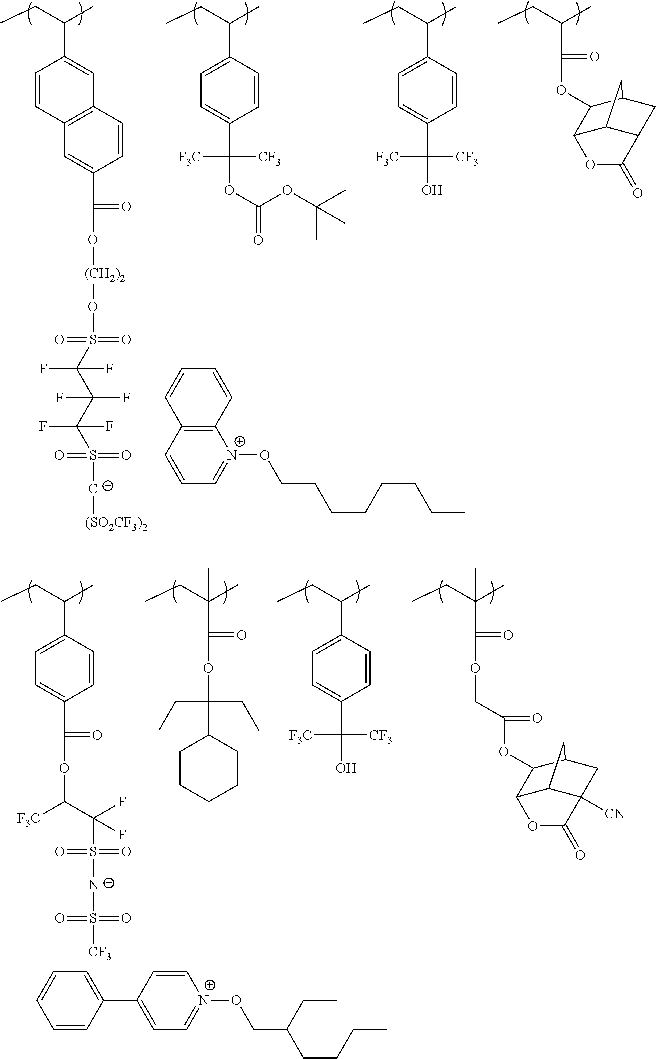

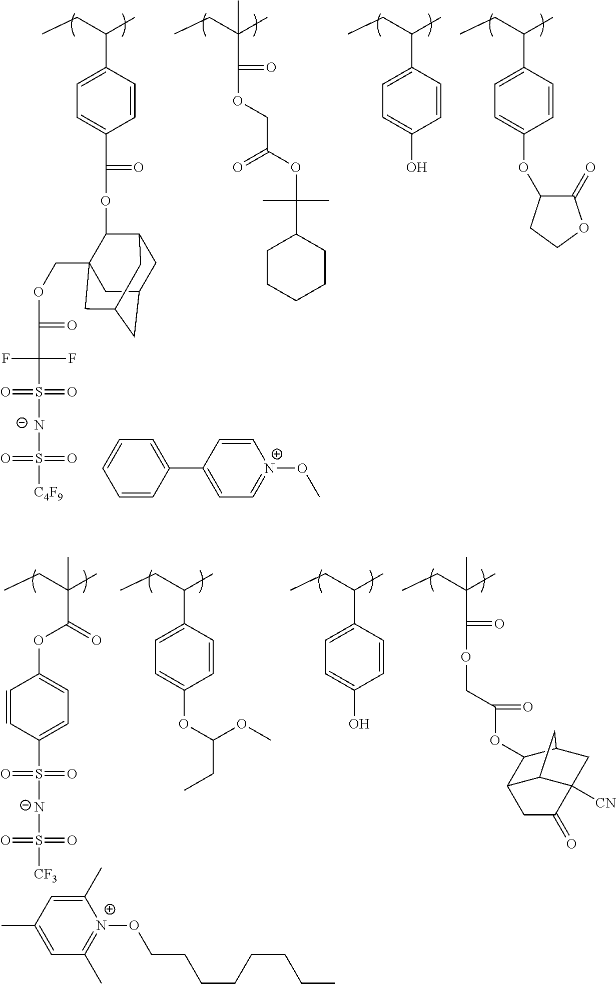

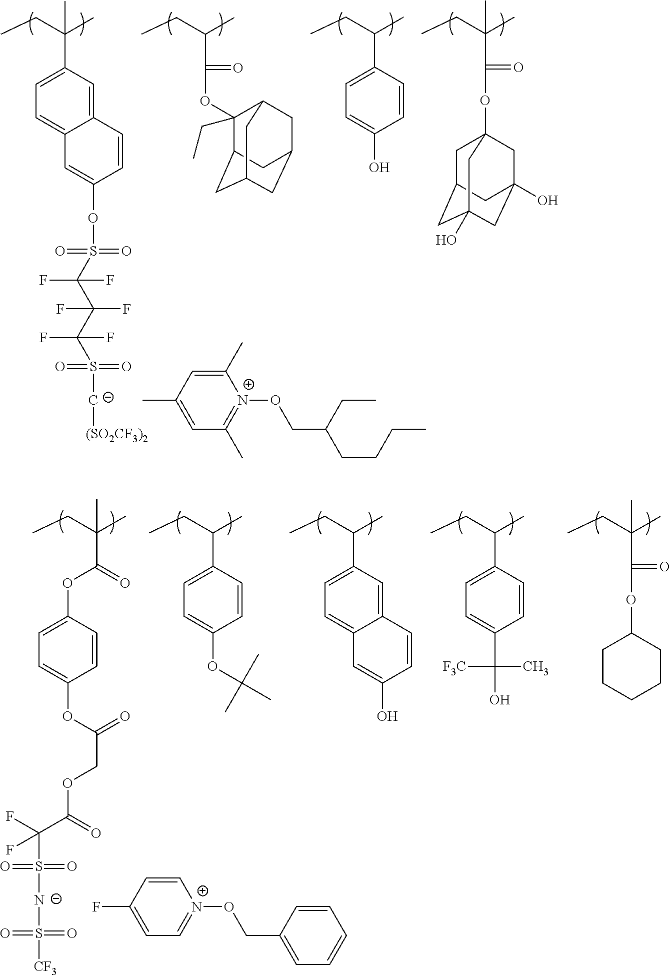

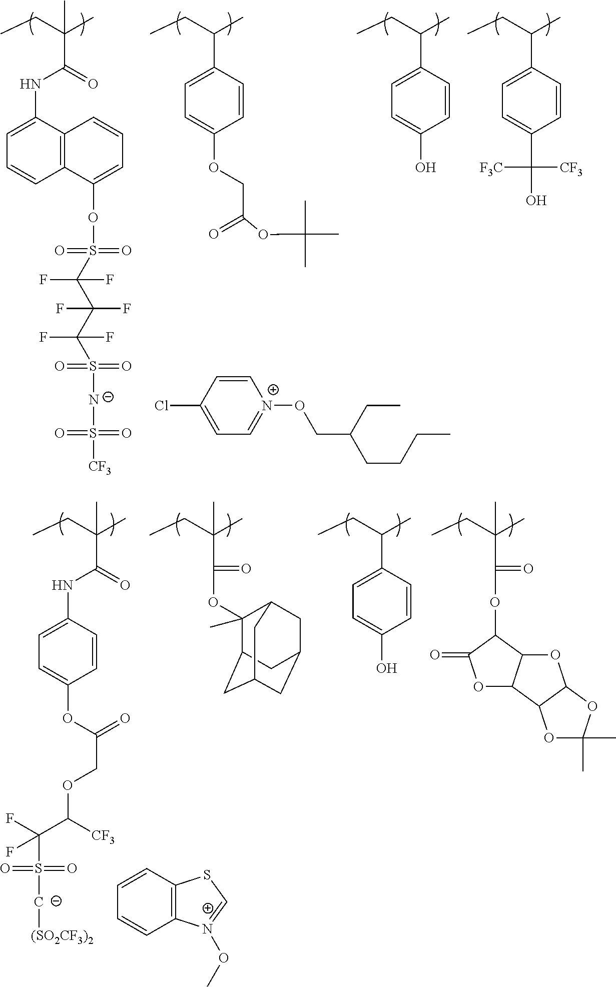

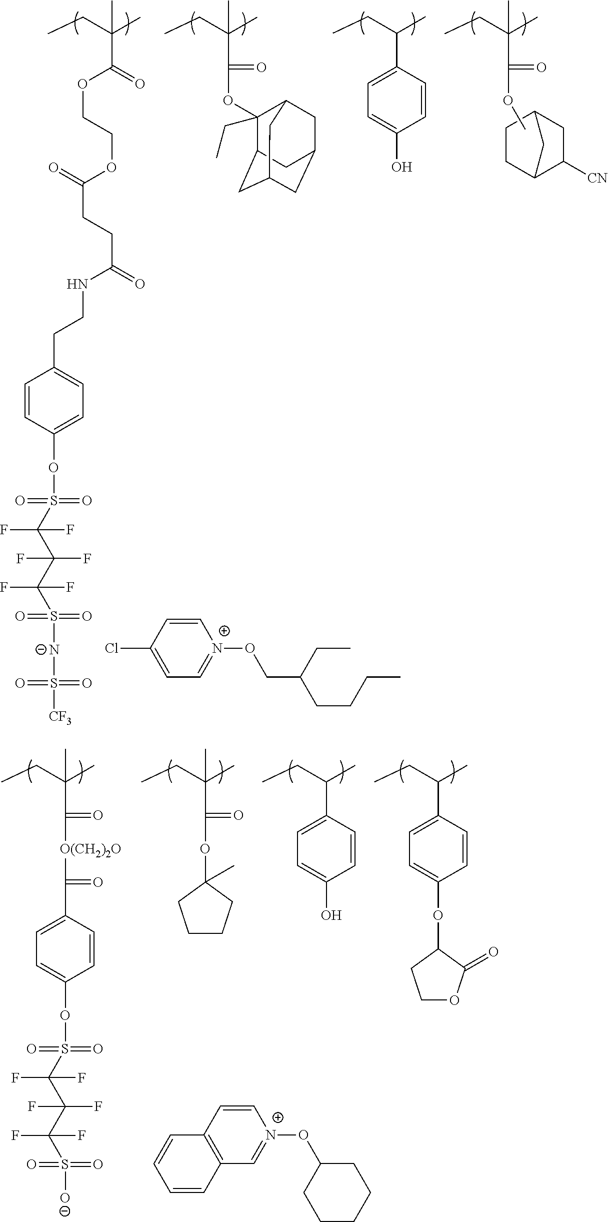

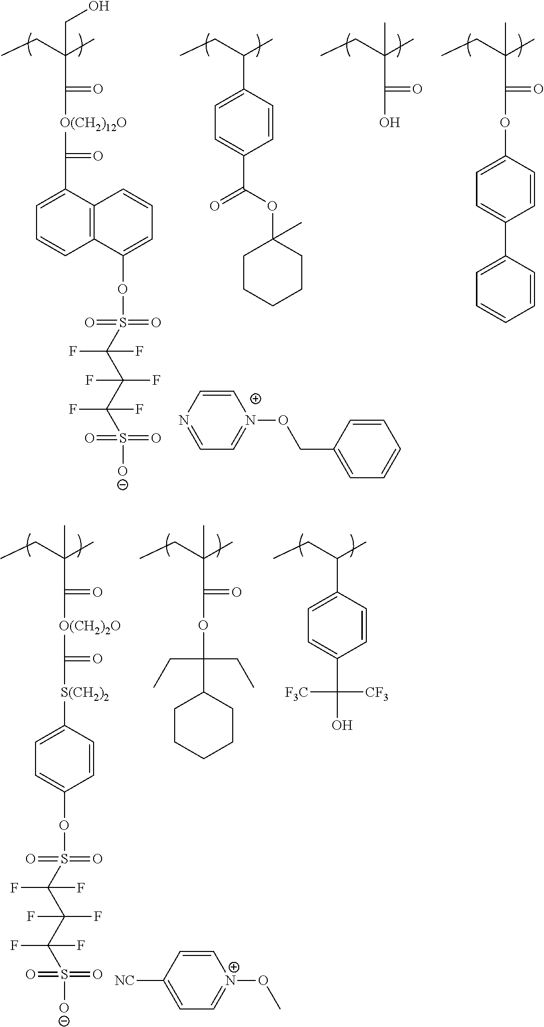

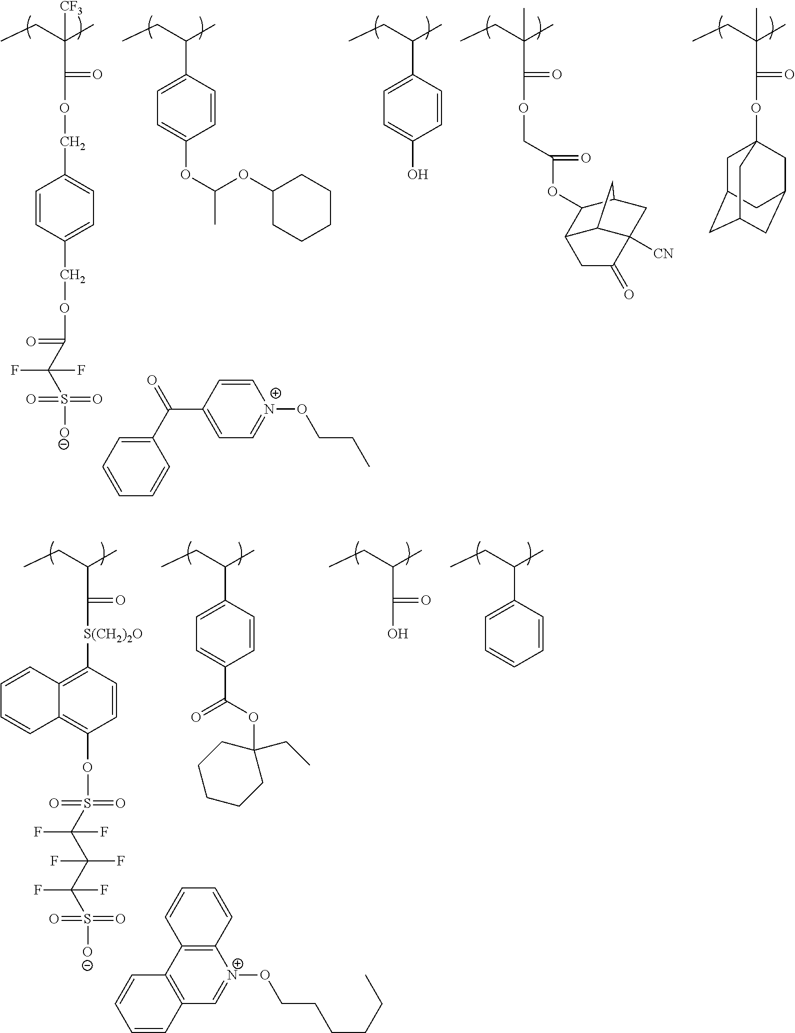

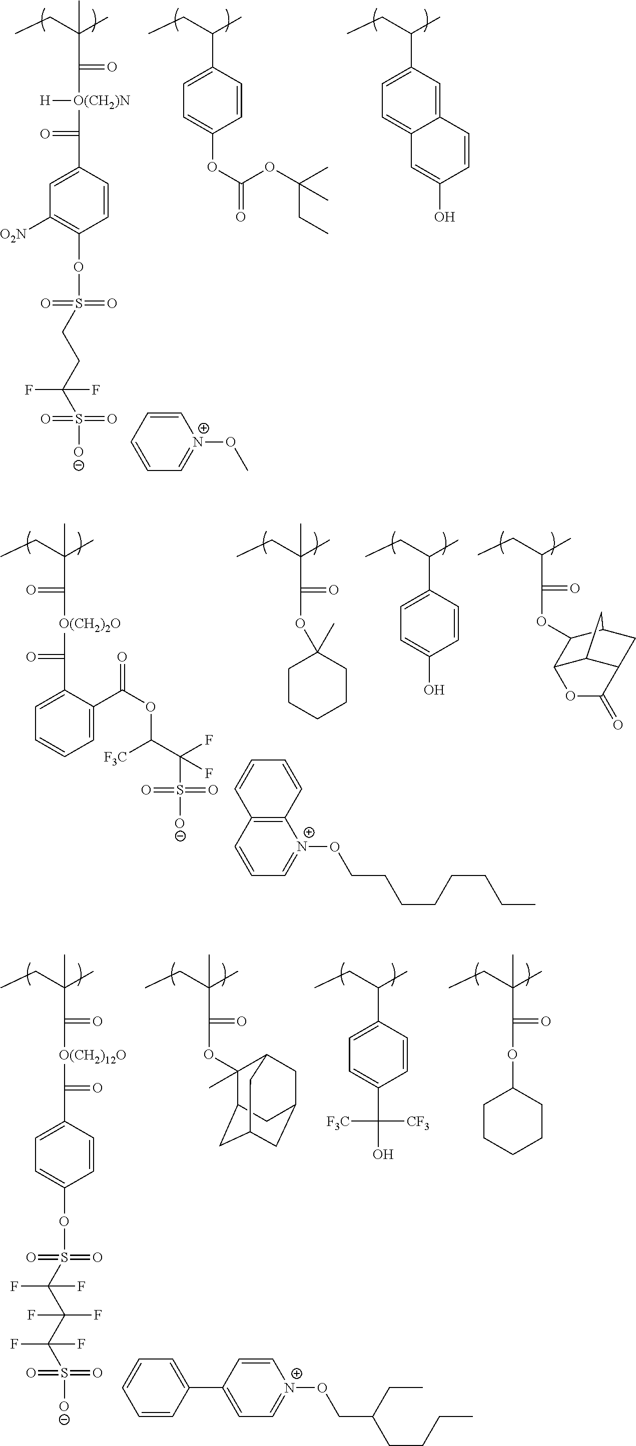

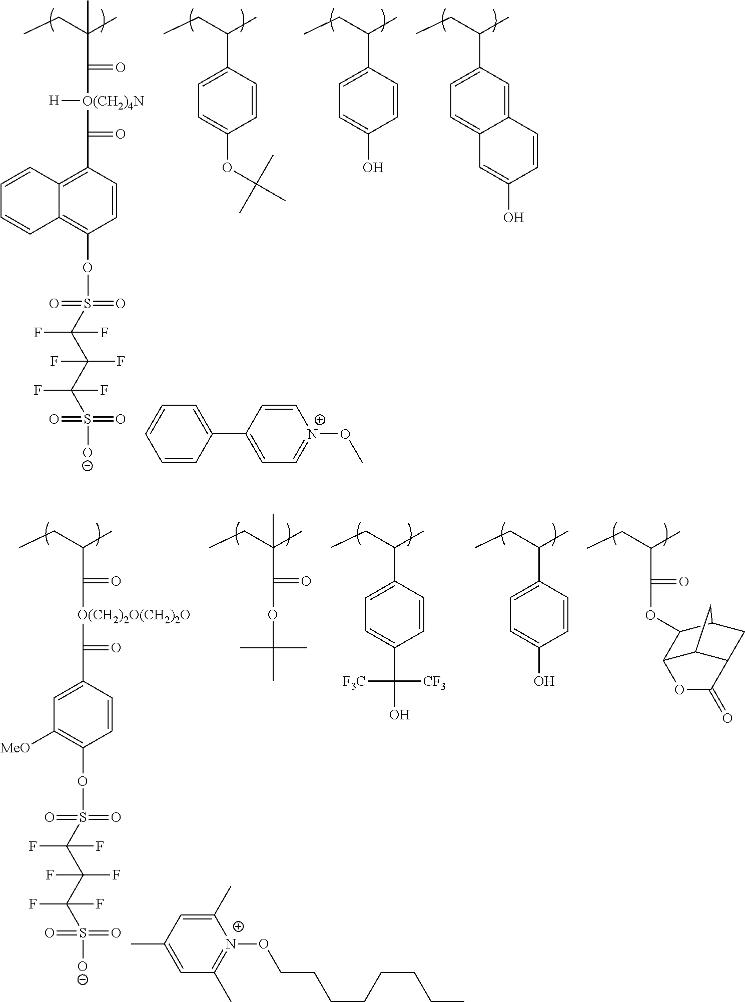

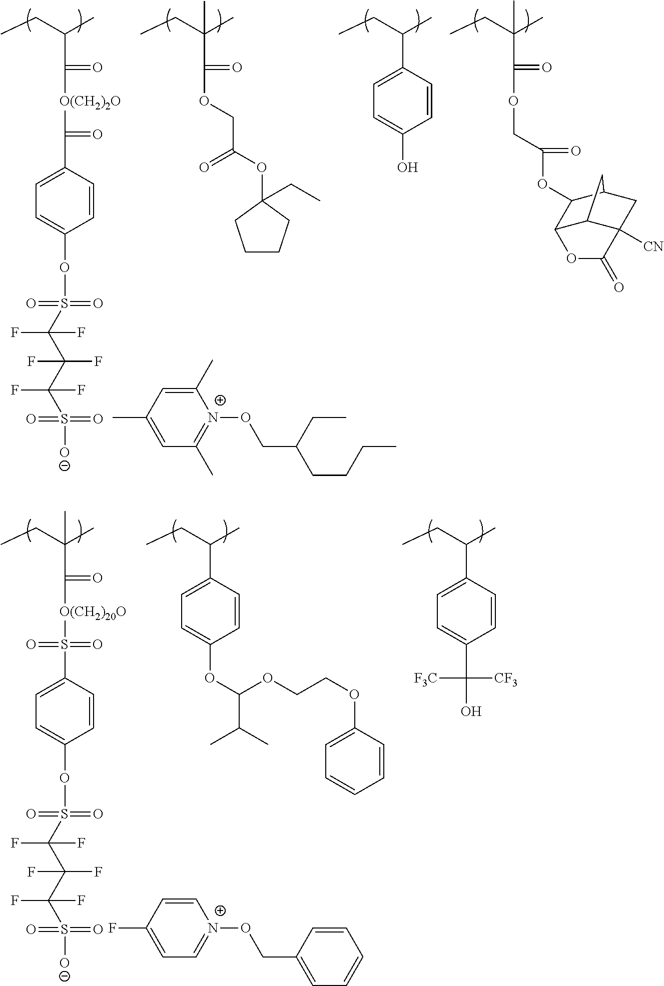

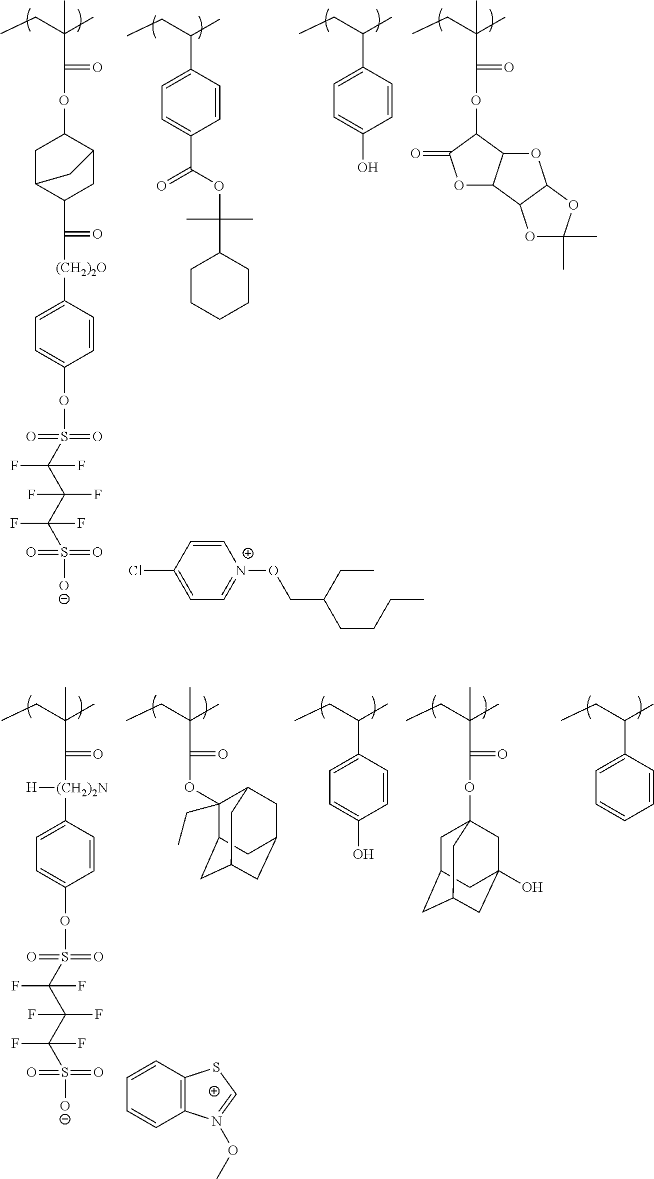

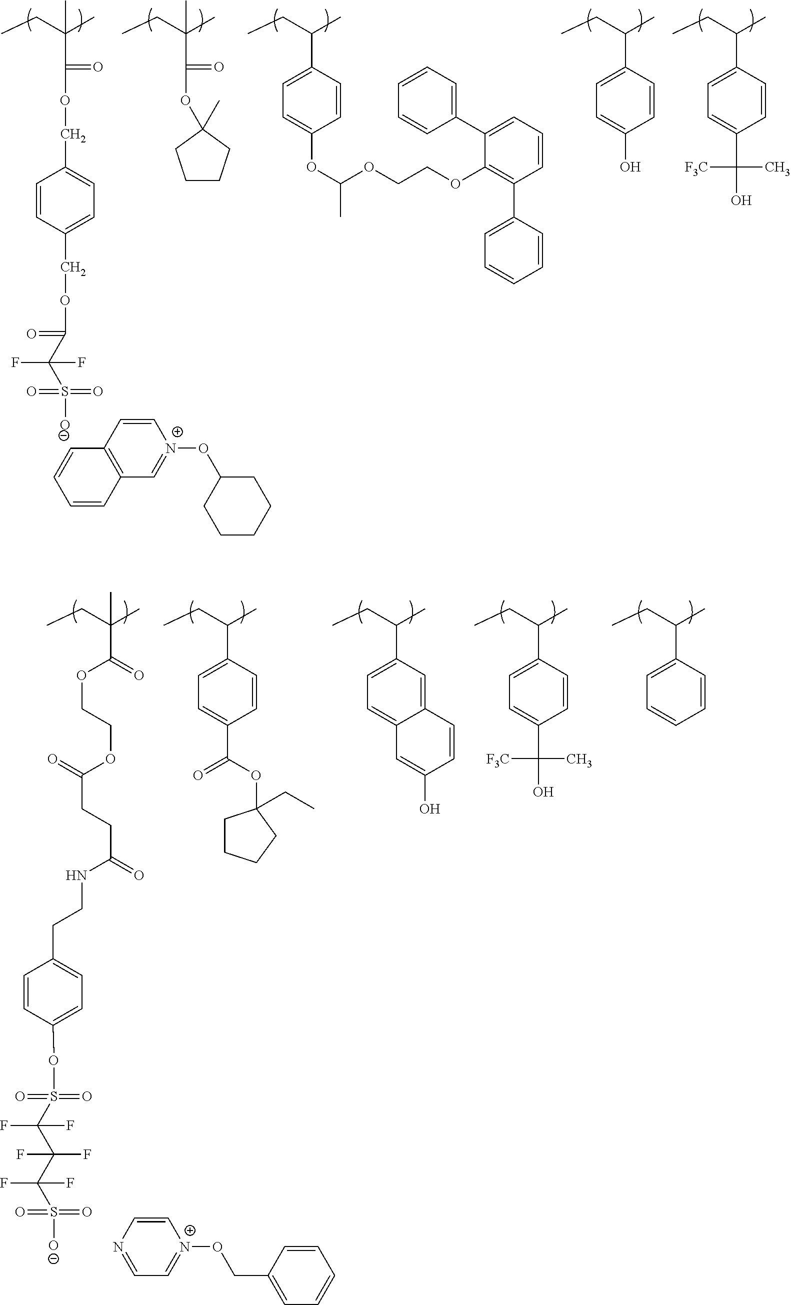

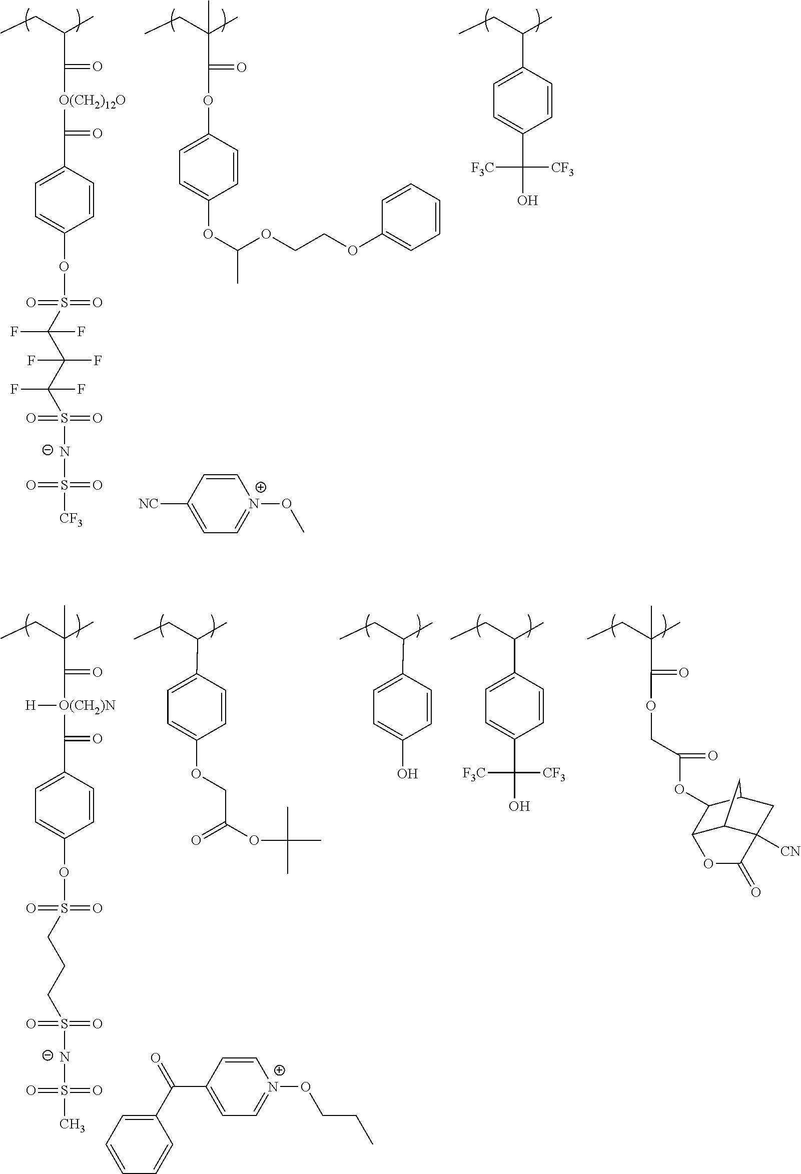

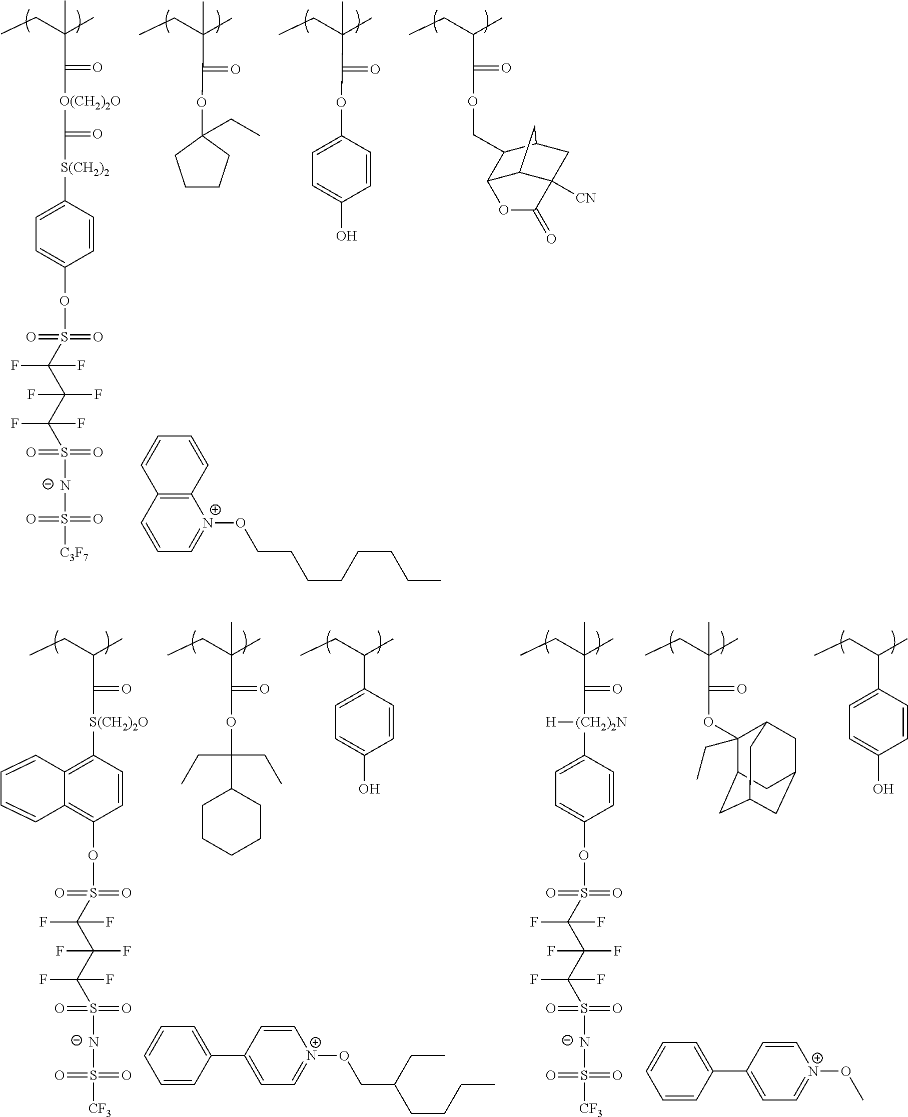

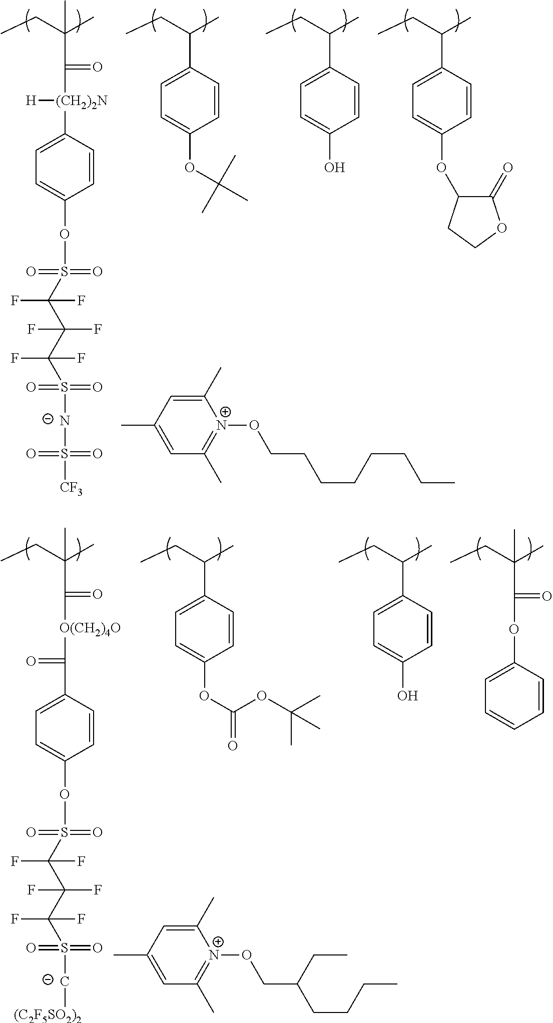

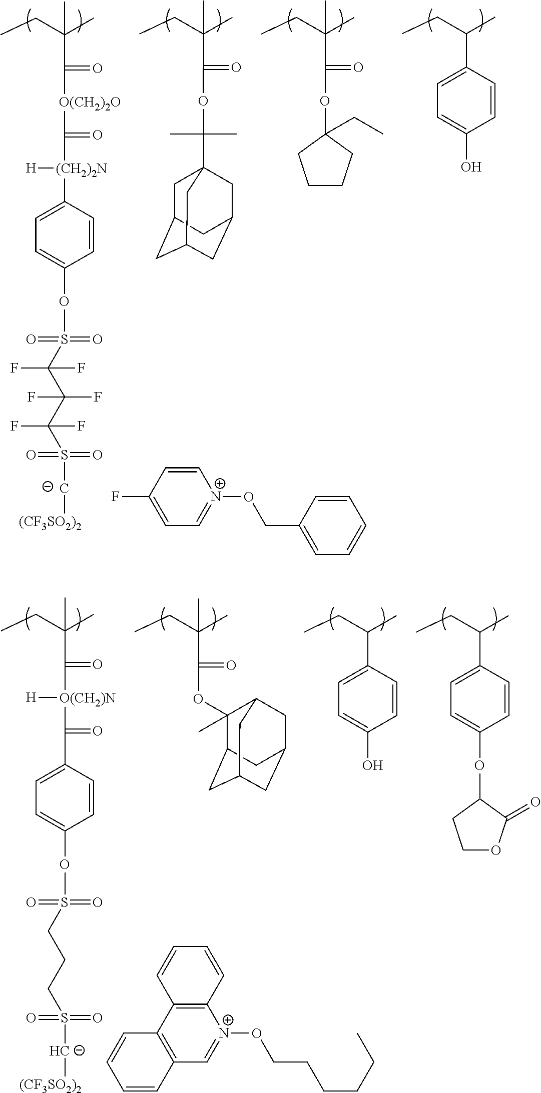

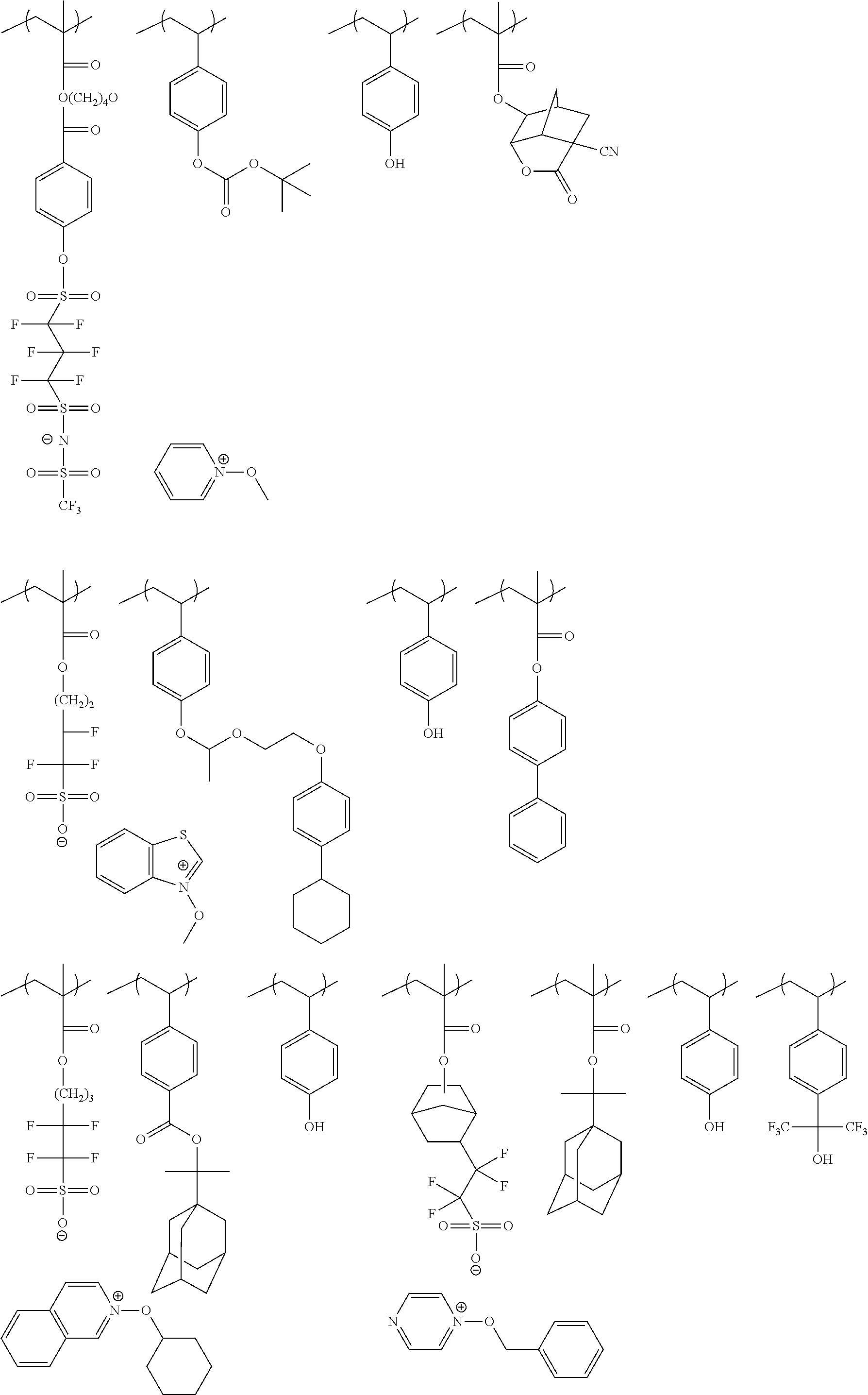

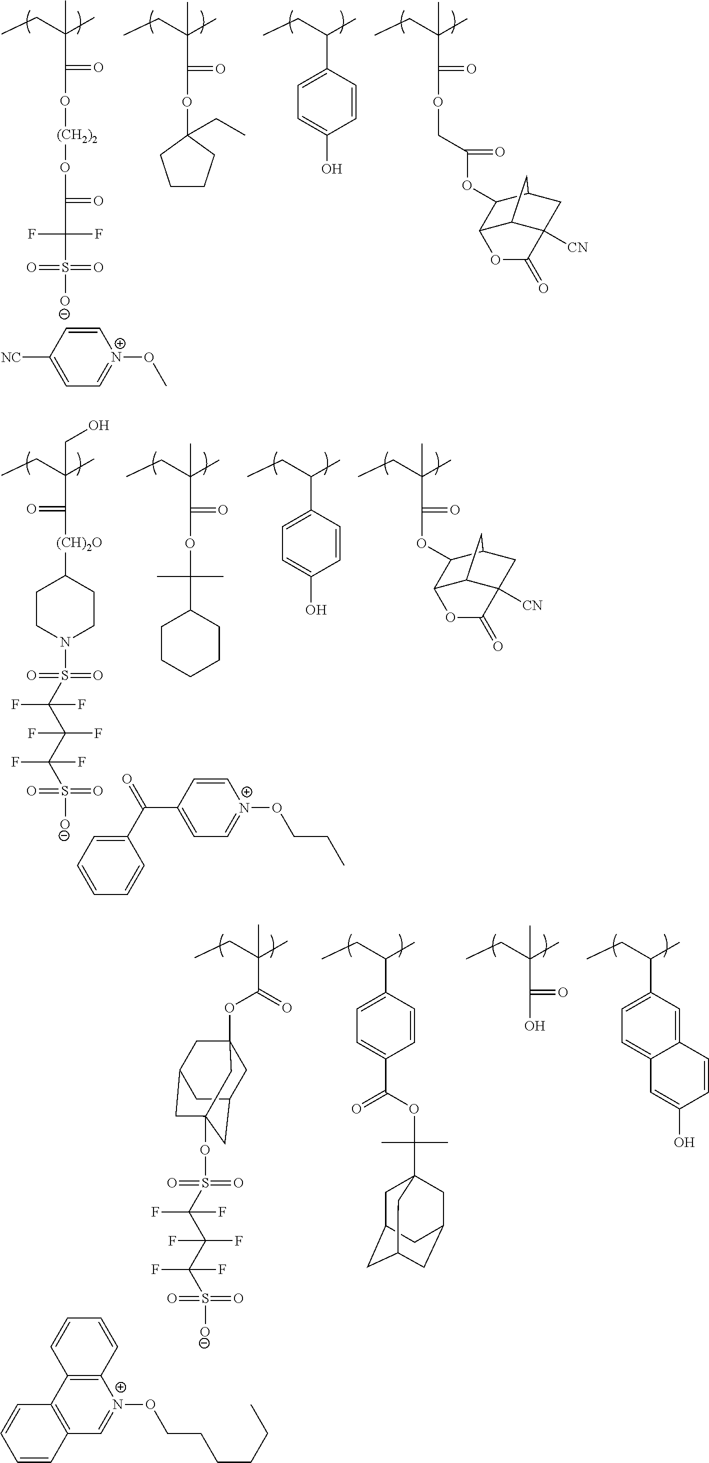

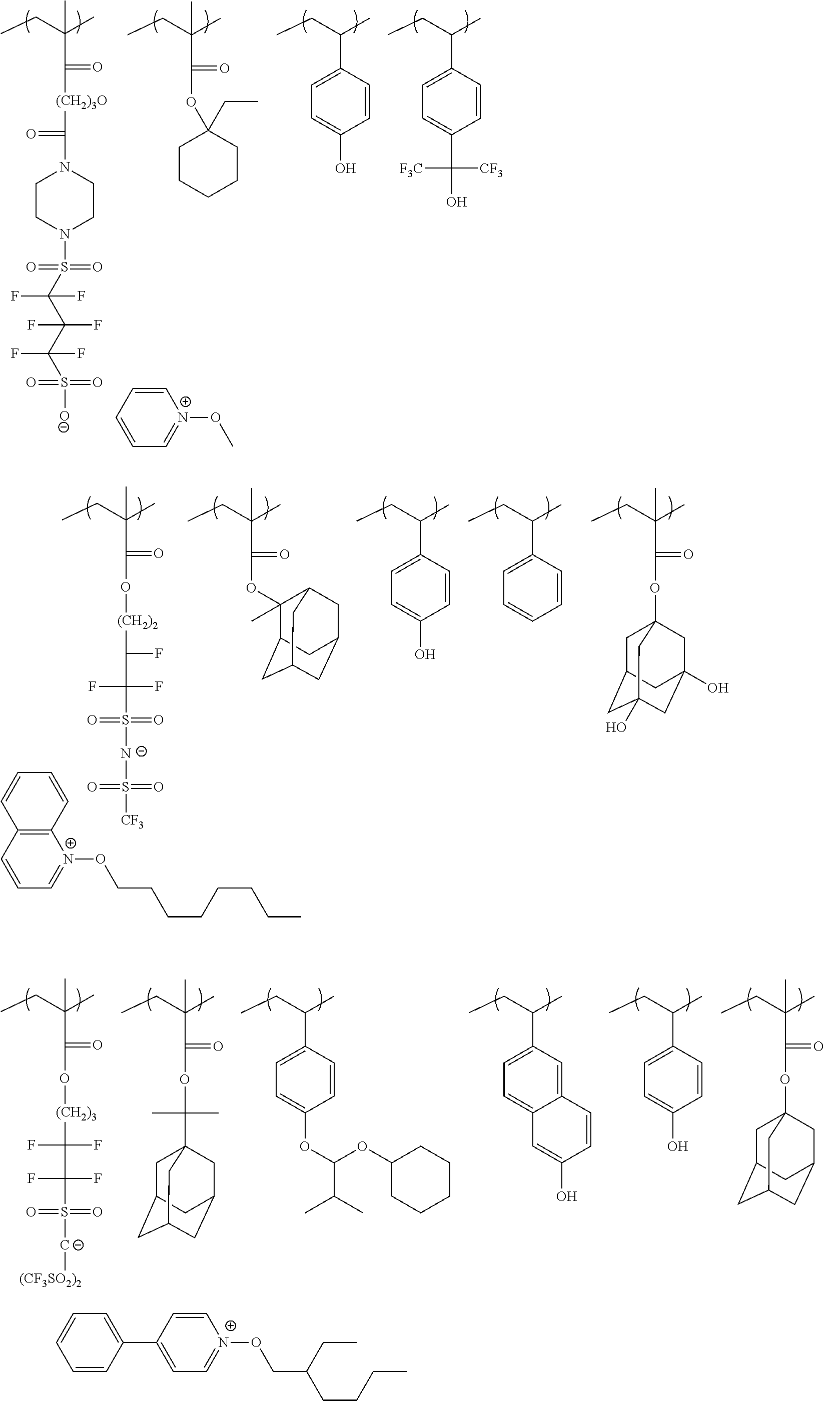

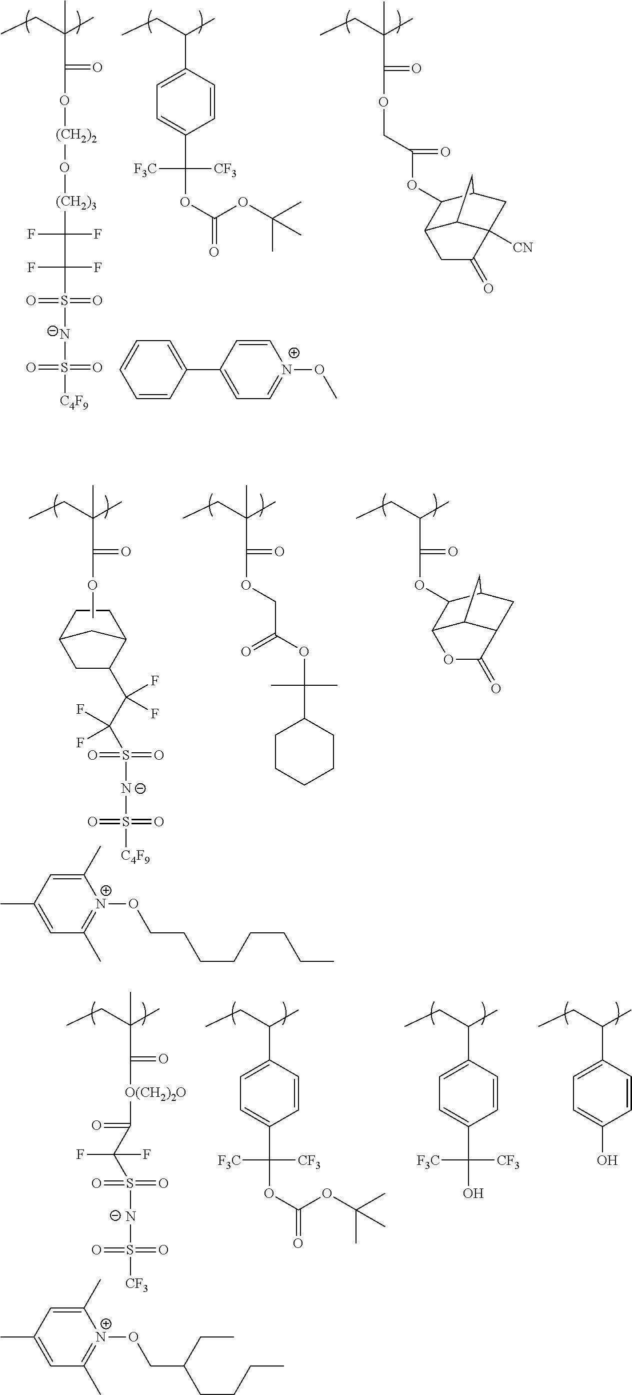

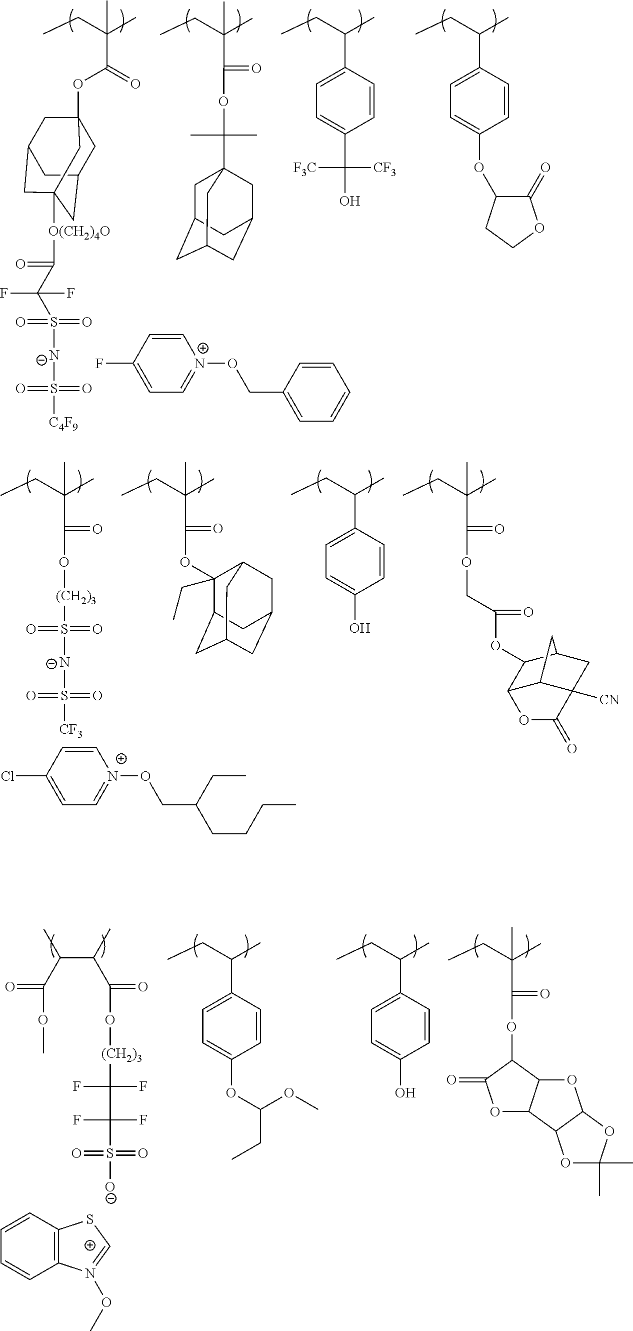

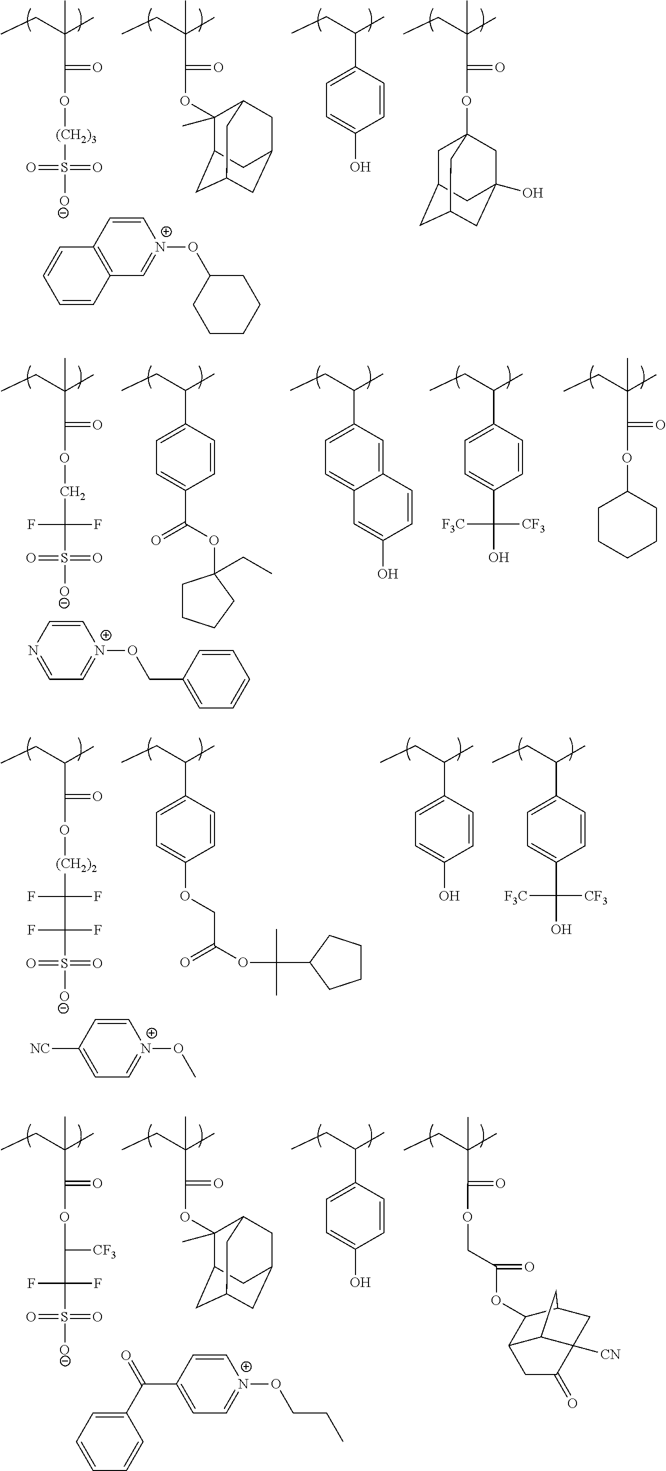

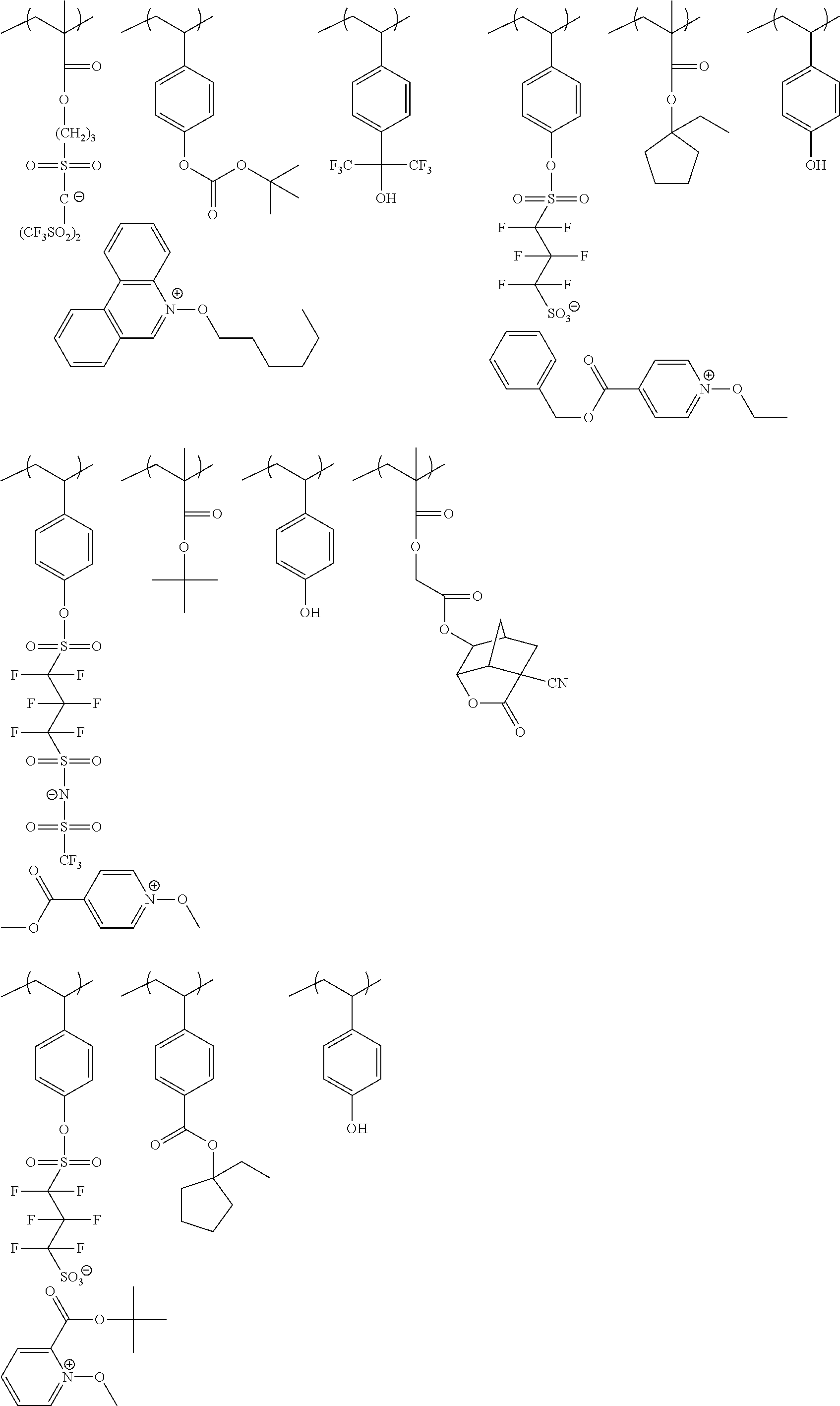

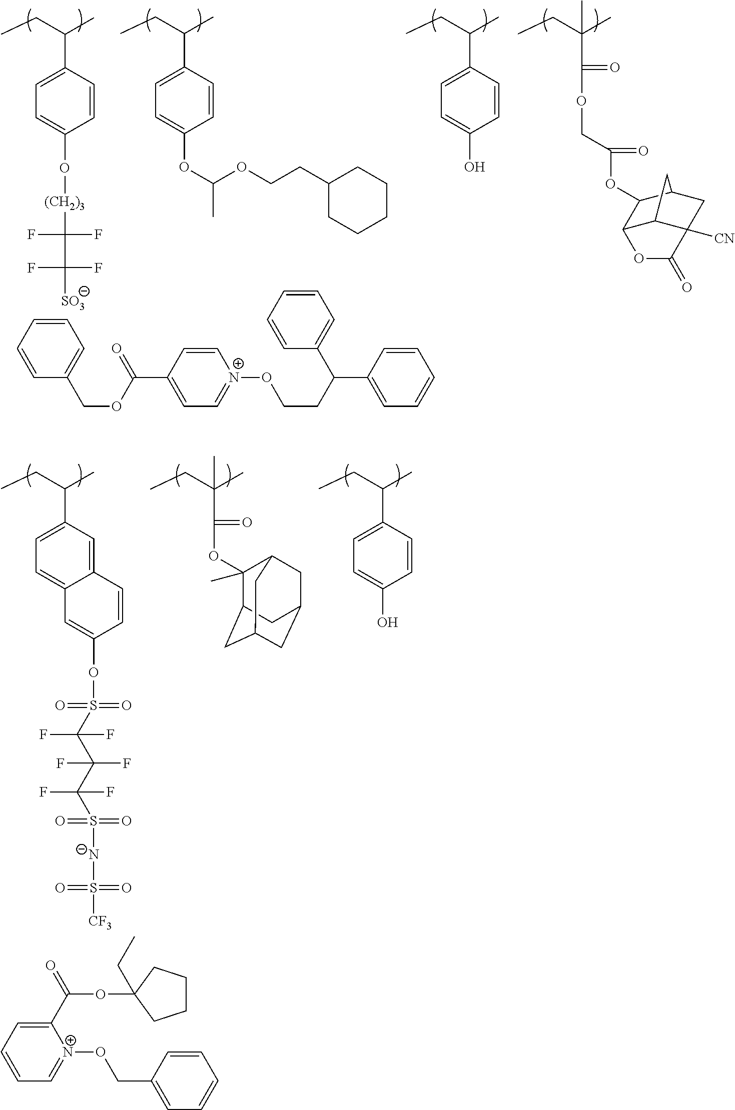

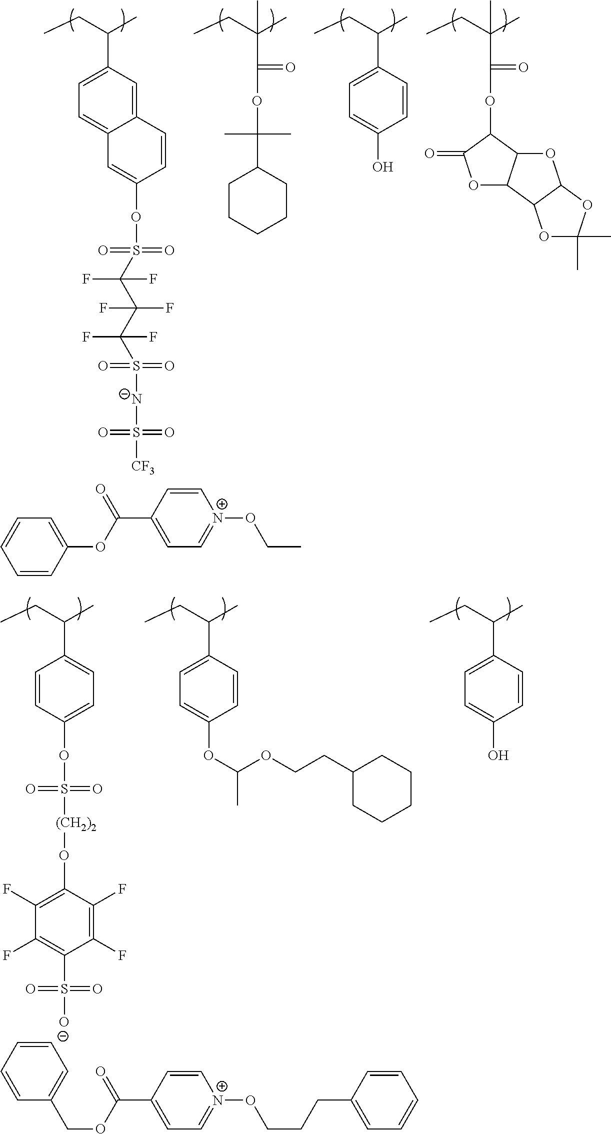

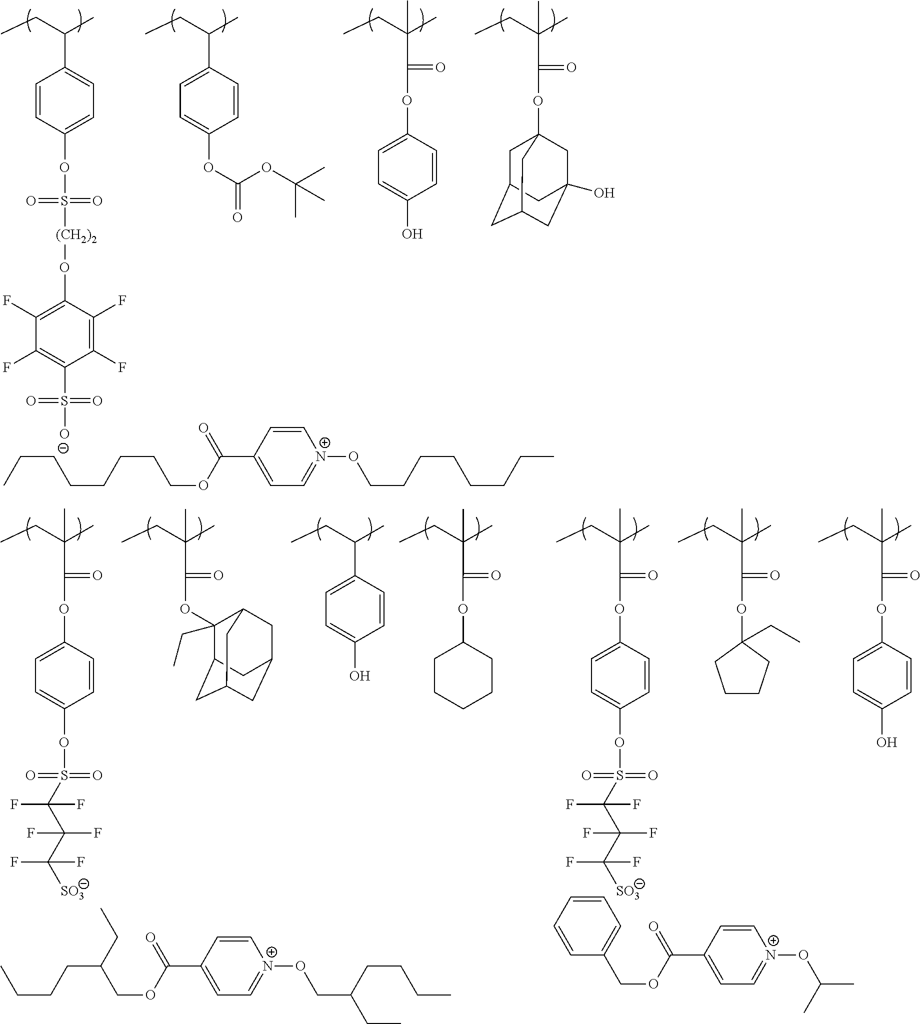

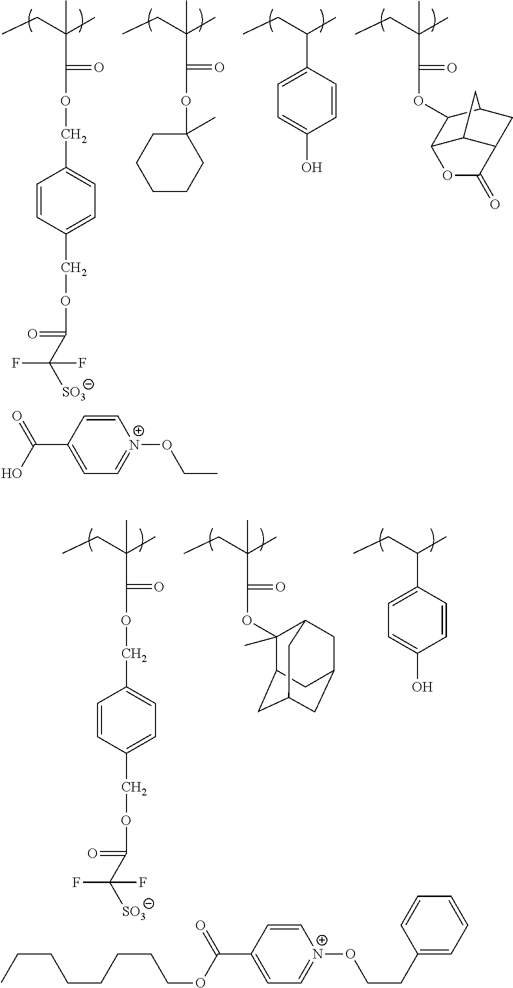

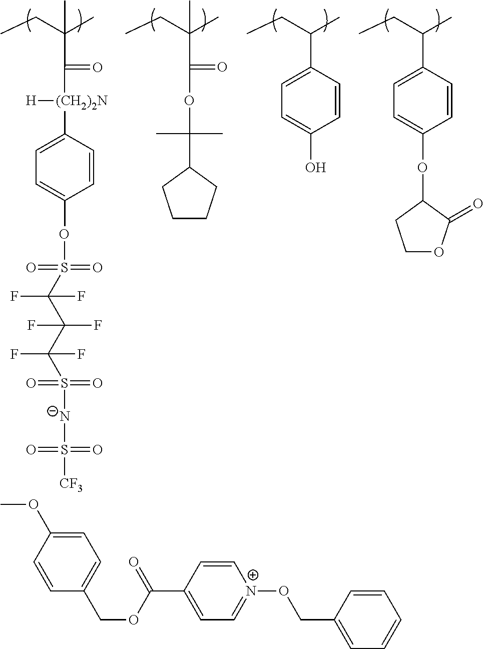

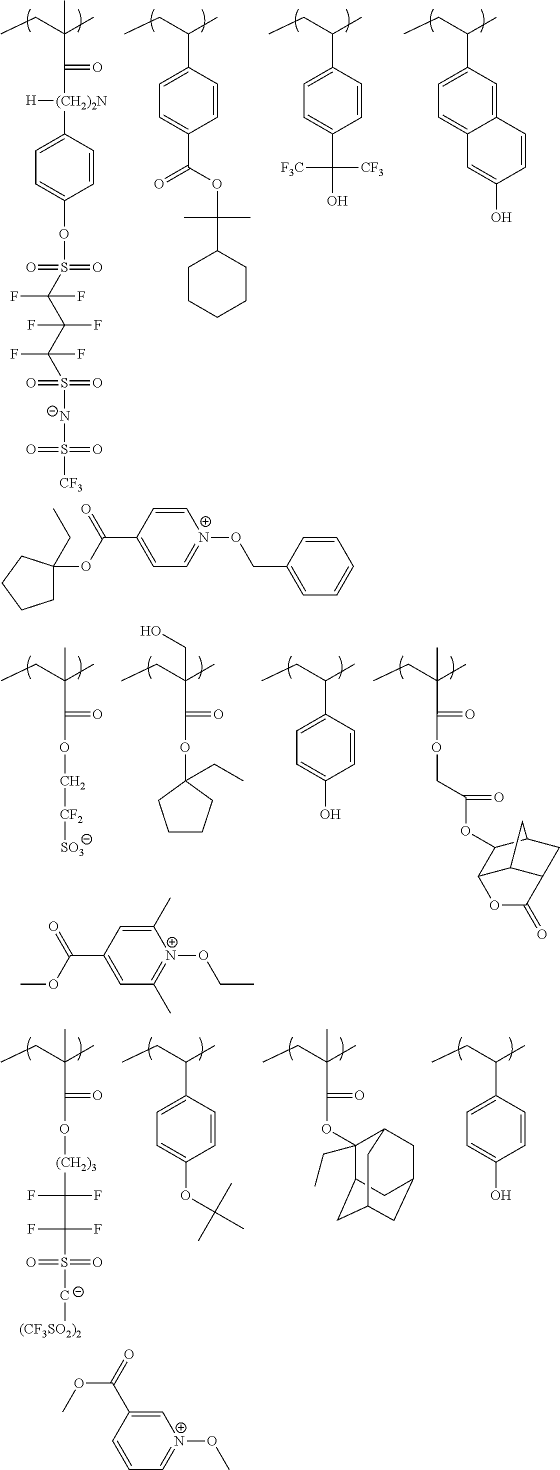

Furthermore according to necessity, the actinic-ray- or radiation-sensitive resin composition of the present invention can be loaded with a resin that is configured to decompose when acted on by an acid to thereby increase its dissolution rate in an alkali aqueous solution, a compound that is configured to generate an acid when exposed to actinic rays or radiation (low-molecular photoacid generator (conventional)), a basic compound, a low-molecular compound containing a group that is configured to be cleaved when acted on by an acid, a surfactant, a substance that is configured to decompose when acted on by an acid to thereby generate an acid stronger than carboxylic acid, etc.

<Resin that is Configured to Decompose when Acted on by an Acid to Thereby Increase its Rate of Dissolution in an Alkali Aqueous Solution>

The actinic-ray- or radiation-sensitive resin composition of the present invention may contain, except the resin (P), a resin that is configured to decompose when acted on by an acid to thereby increase its rate of dissolution in an alkali aqueous solution.

The resin that is configured to decompose when acted on by an acid to thereby increase its rate of dissolution in an alkali aqueous solution (hereinafter also referred to as an “acid-decomposable resin”) is a resin provided at its principal chain or side chain or both thereof with a group that is configured to decompose by the action of an acid to thereby generate an alkali soluble group (acid-decomposable group). The resin provided at its side chain with an acid-decomposable group is preferred.

The acid-decomposable resin can be obtained by either reacting a precursor of acid-decomposable group with an alkali-soluble resin, or copolymerizing an alkali-soluble resin monomer having an acid-decomposable group bonded thereto with any of various monomers, as described in, for example, European Patent No. 254853 and JP-A's 2-25850, 3-223860 and 4-251259.

It is preferred for the acid-decomposable group to be, for example, a group as obtained by, in a resin having an alkali-soluble group such as —COOH or —OH, substituting the hydrogen atom of the alkali soluble group with a group that is configured to be cleaved by the action of an acid.

Preferred particular examples of the acid-decomposable groups are the same as set forth above with respect to the resins (P) of the present invention (for example, acid-decomposable groups mentioned above with respect to the repeating unit (B) of the resin (P)).

The resins having alkali-soluble groups are not particularly limited. For example, there can be mentioned poly(o-hydroxystyrene), poly(m-hydroxystyrene), poly(p-hydroxystyrene), copolymers of these, a hydrogenated poly(hydroxystyrene), poly(hydroxystyrene) polymers having substituents of the structures shown below, a resin having phenolic hydroxyl, a styrene-hydroxystyrene copolymer, an α-methylstyrene-hydroxystyrene copolymer, an alkali-soluble resin having a hydroxystyrene structure unit such as a hydrogenated novolak resin, and an alkali-soluble resin comprising a repeating unit containing a carboxyl group such as (meth)acrylic acid or norbornene carboxylic acid.

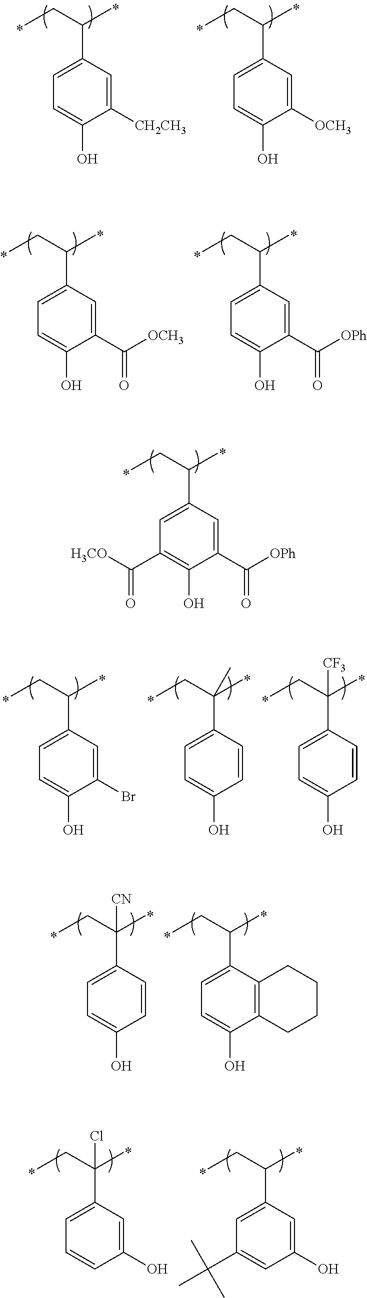

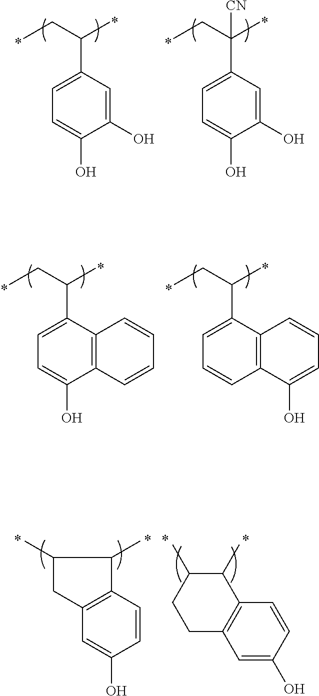

The alkali dissolution rate of these alkali-soluble resins as measured in a 2.38 mass % tetramethylammonium hydroxide (TMAH) solution (23° C.) is preferably 17 nm/sec or greater. The alkali dissolution rate is most preferably 33 nm/sec or greater.

The content of acid-decomposable groups can be expressed as the quotient of the formula X/(X+Y) in which X is the number of repeating units containing groups decomposable by an acid in the resin and Y is the number of repeating units containing alkali-soluble groups not protected by any acid-cleavable group in the resin. The content is preferably in the range of 0.01 to 0.7, more preferably 0.05 to 0.50 and further more preferably 0.05 to 0.40.

The preferred ranges of the molecular weight and dispersity of acid-decomposable resins are the same as those of the resin (P).

Two or more types of acid-decomposable resins may be used in combination.

The amount of acid-decomposable resins, except the resin (P), contained in the actinic-ray- or radiation-sensitive resin composition of the present invention is preferably in the range of 0 to 70 mass %, more preferably 0 to 50 mass % and further more preferably 0 to 30 mass % based on the total solids of the composition.

<Compound that is Configured to Generate an Acid when Exposed to Actinic Rays or Radiation (Low-Molecular acid Generator)>

The actinic-ray- or radiation-sensitive resin composition of the present invention essentially contains the resin with a photoacid generating structure (P). Except the resin (P), a low-molecular compound that is configured to generate an acid when exposed to actinic rays or radiation (hereinafter also referred to as an “acid generator” or “photoacid generator”) may be contained in the composition.

As such an acid generator, use can be made of a member appropriately selected from among a photoinitiator for photocationic polymerization, a photoinitiator for photoradical polymerization, a photo-achromatic agent and photo-discoloring agent for dyes, any of generally known compounds that when exposed to actinic rays or radiation, generate an acid, employed in microresists, etc., and mixtures thereof.

For example, as the acid generator, there can be mentioned a diazonium salt, a phosphonium salt, a sulfonium salt, an iodonium salt, an imide sulfonate, an oxime sulfonate, diazosulfone, disulfone or o-nitrobenzyl sulfonate. As particular examples of these, there can be mentioned, for example, those set forth in Sections [0164] to [0248] of US Patent Application Publication No. 2008/0241737 A1.

Further, as the low-molecular acid generators, use can be made of the salts containing a cation with a monocyclic or polycyclic heterocycle containing a nitrogen atom and an arbitrary anion.

When an acid generator, except the resin with a photoacid generating structure (P), is used in the actinic-ray- or radiation-sensitive resin composition of the present invention, a single type of acid generator can be used alone, or two or more types of acid generators can be used in combination. The content of acid generator(s) in the composition, based on the total solids of the composition of the present invention, is preferably in the range of 0 to 20 mass %, more preferably 0 to 10 mass % and further more preferably 0 to 7 mass %. Although these acid generators are not essential components in the present invention, they are generally used in an amount of 0.01 mass % or more in order to attain the effect of the addition thereof.

<Basic Compound>

The actinic-ray- or radiation-sensitive resin composition of the present invention preferably contains a basic compound.

The basic compound is preferably a nitrogen-containing organic compound.

Useful basic compounds are not particularly limited. However, for example, the compounds of categories (1) to (5) below are preferably used.

(1) Compounds of General Formula (BS-1) Below

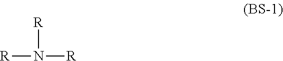

In general formula (BS-1), each of Rs independently represents any of a hydrogen atom, an alkyl group (linear or branched), a cycloalkyl group (monocyclic or polycyclic), an aryl group and an aralkyl group, provided that in no event all the three Rs are hydrogen atoms.

The number of carbon atoms of the alkyl group represented by R is not particularly limited. However, it is generally in the range of 1 to 20, preferably 1 to 12.

The number of carbon atoms of the cycloalkyl group represented by R is not particularly limited. However, it is generally in the range of 3 to 20, preferably 5 to 15.

The number of carbon atoms of the aryl group represented by R is not particularly limited. However, it is generally in the range of 6 to 20, preferably 6 to 10. In particular, an aryl group, such as a phenyl group, a naphthyl group and the like, can be mentioned.

The number of carbon atoms of the aralkyl group represented by R is not particularly limited. However, it is generally in the range of 7 to 20, preferably 7 to 11. In particular, an aralkyl group, such as a benzyl group and the like, can be mentioned.

In the alkyl group, cycloalkyl group, aryl group and aralkyl group represented by R, a hydrogen atom thereof may be replaced by a substituent. As the substituent, there can be mentioned, for example, an alkyl group, a monovalent aliphatic hydrocarbon ring group, an aryl group, an aralkyl group, an alkoxy group, an aryloxy group, an alkylcarbonyloxy group, an alkyloxycarbonyl group and the like.

In the compounds of general formula (BS-1), it is preferred that only one of the three Rs be a hydrogen atom, and also that none of the Rs be a hydrogen atom.

Specific examples of the compounds of General Formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline and the like.

Any of the compounds of general formula (BS-1) in which at least one of the Rs is a hydroxylated alkyl group can be mentioned as a preferred form of compound. Specific examples of the compounds include triethanolamine, N,N-dihydroxyethylaniline and the like.

With respect to the alkyl group represented by R, an oxygen atom may be present in the alkyl chain to thereby form an oxyalkylene chain. The oxyalkylene chain preferably consists of —CH₂CH₂O—. As particular examples thereof, there can be mentioned tris(methoxyethoxyethyl)amine, compounds shown in column 3 line 60 et seq. of U.S. Pat. No. 6,040,112 and the like.

(2) Compounds with Nitrogen-Containing Heterocyclic Structure

The heterocyclic structure optionally may have aromaticity. It may have a plurality of nitrogen atoms, and also may have a heteroatom other than nitrogen. For example, there can be mentioned compounds with an imidazole structure (2-phenylbenzoimidazole, 2,4,5-triphenylimidazole and the like), compounds with a piperidine structure (N-hydroxyethylpiperidine, bis(1,2,2,6,6-pentamethyl-4-piperidyl) sebacate and the like), compounds with a pyridine structure (4-dimethylaminopyridine and the like) and compounds with an antipyrine structure (antipyrine, hydroxyantipyrine and the like).

Further, compounds with two or more ring structures can be appropriately used. For example, there can be mentioned 1,5-diazabicyclo[4.3.0]non-5-ene, 1,8-diazabicyclo[5.4.0]-undec-7-ene and the like.

(3) Amine Compounds with Phenoxy Group

The amine compounds with a phenoxy group are those having a phenoxy group at the end of the alkyl group of each amine compound opposite to the nitrogen atom. The phenoxy group may have a substituent, such as an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group and the like.

Compounds having at least one oxyalkylene chain between the phenoxy group and the nitrogen atom are preferred. The number of oxyalkylene chains in each molecule is preferably in the range of 3 to 9, more preferably 4 to 6. Among the oxyalkylene chains, —CH₂CH₂O— is preferred.

Particular examples thereof include 2-[2-{2-(2,2-dimethoxy-phenoxyethoxy)ethyl}-bis-(2-methoxyethyl)]-amine, compounds (C1-1) to (C3-3) shown in section [0066] of US 2007/0224539 A1 and the like.

(4) Ammonium Salts

Ammonium salts can also be appropriately used.

Hydroxides and carboxylates are preferred. Preferred particular examples thereof are tetraalkylammonium hydroxides, such as tetrabutylammonium hydroxide.

(5) Compound that is Configured to Increase its Basicity when Acted on by an Acid

The compound that is configured to increase its basicity when acted on by an acid can also be used as a type of basic compound. As an example thereof, there can be mentioned compounds with the structure of general formula (A) below. These compounds per se exhibit low basicity because of the presence of an electron withdrawing ester bond adjacent to the N atom. However, when an acid acts on the compounds, it is construed that the moiety —C(Rb)(Rb)(Rb) is first decomposed and subsequently the ester bond moiety is decarbonated, so that the moiety of the electron withdrawing ester bond is removed, thereby exhibiting a substantial basicity.

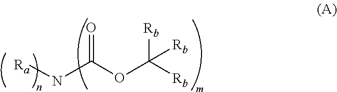

In general formula (A), Ra represents a hydrogen atom, an alkyl group, a monovalent aliphatic hydrocarbon ring group, an aryl group or an aralkyl group. When n=2, two Ra's may be identical to or different from each other, and two Ra's may be bonded to each other to thereby form a bivalent heterocyclic hydrocarbon group (preferably up to 20 carbon atoms) or a derivative thereof.

Each of Rb's independently represents a hydrogen atom, an alkyl group, a monovalent aliphatic hydrocarbon ring group, an aryl group or an aralkyl group, provided that in the formula —C(Rb)(Rb)(Rb), three Rb's are not simultaneously hydrogen atoms.

At least two Rb's may be bonded to each other to thereby form an alicyclic hydrocarbon group, an aromatic hydrocarbon group, a heterocyclic hydrocarbon group or a derivative thereof.

In the formula, n is an integer of 0 to 2, and m is an integer of 1 to 3, provided that n+m=3.

In general formula (A), each of the alkyl groups, monovalent aliphatic hydrocarbon ring groups, aryl groups and aralkyl groups represented by Ra and Rb may be substituted with a functional group, such as a hydroxyl group, a cyano group, an amino group, a pyrrolidino group, a piperidino group, a morpholino group or an oxo group, as well as an alkoxy group or a halogen atom.

As the alkyl group, monovalent aliphatic hydrocarbon ring group, aryl group and aralkyl group represented by Ra and/or Rb (these alkyl group, cycloalkyl group, aryl group and aralkyl group may be substituted with the above functional group, an alkoxy group or a halogen atom), there can be mentioned, for example:

a group derived from a linear or branched alkane such as methane, ethane, propane, butane, pentane, hexane, heptane, octane, nonane, decane, undecane, or dodecane; and the group derived from the alkane and substituted with, for example, one or more cycloalkyl groups;

a group derived from cycloalkane such as cyclobutane, cyclopentane, cyclohexane, cycloheptane, cyclooctane, norbornane, adamantane, or noradamantane; and the group derived from the cycloalkane and substituted with, for example, one or more linear or branched alkyl group;

a group derived from aromatic compound such as benzene, naphthalene, or anthracene; and the group derived from the atomatic compound and substituted with, for example, one or more linear or branched alkyl group;

a group derived from heterocyclic compound such as pyrrolidine, piperidine, morpholine, tetrahydrofuran, tetrahydropyrane, indole, indoline, quinoline, perhydroquinoline, indazole, or benzimidazole; the group derived from heterocyclic compound and substituted with one or more linear or branched alkyl group or a group derived from the aromatic compound;

a group derived from linear or branched alkane and substituted with, for example, a group derived from aromatic compound;

a group derived from cycloalkane and substituted with, for example, a group derived from aromatic compound; or

each of these groups substituted with a functional group such as a hydroroxyl group, a cyano group, an amino group, a pyrrolidino group, a piperidino group, a morpholino group, or an oxo group.

As the bivalent heterocyclic hydrocarbon group (preferably 2 to 20 carbon atoms) formed by the mutual bonding of Ra's or derivative thereof, there can be mentioned, for example, a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline or 1,5,9-triazacyclododecane; a group as obtained by substituting the above heterocyclic-compound-derived group with at least one or at least one type of linear or branched-alkane-derived group, cycloalkane-derived group, aromatic-compound-derived group, heterocyclic-compound-derived group or functional group, such as a hydroxyl group, a cyano group, an amino group, a pyrrolidino group, a piperidino group, a morpholino group or an oxo group; and the like.

Particularly preferred examples of the compound configured to increase its basicity upon an action of acid will be shown below, which however in no way limit the scope of the present invention.

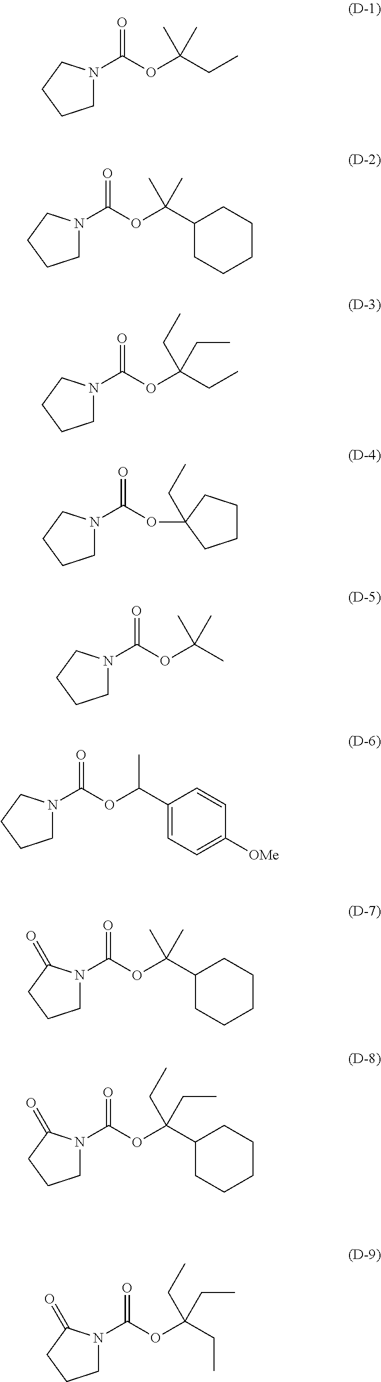

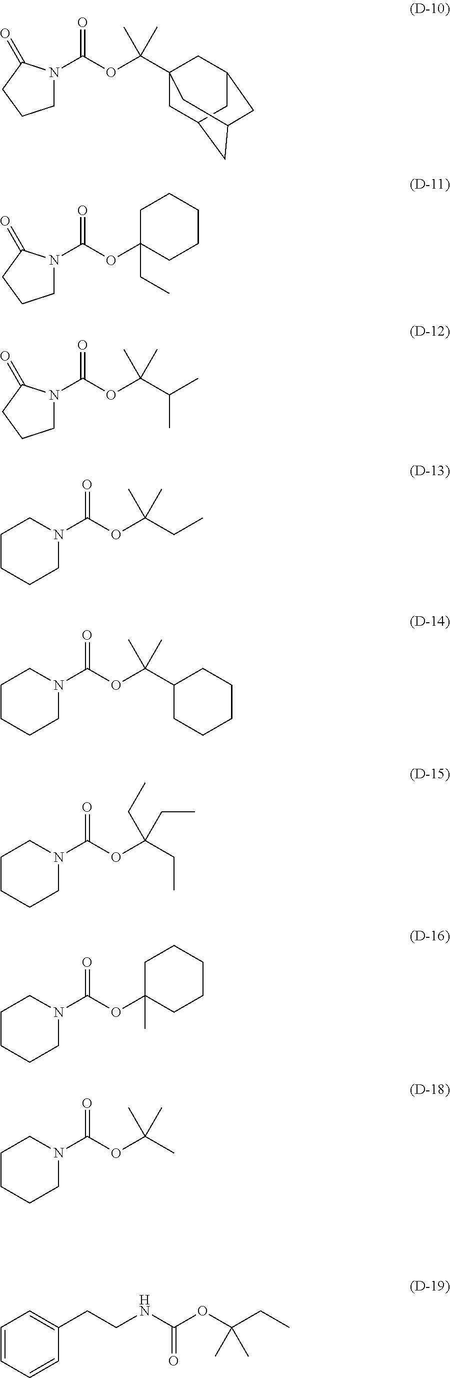

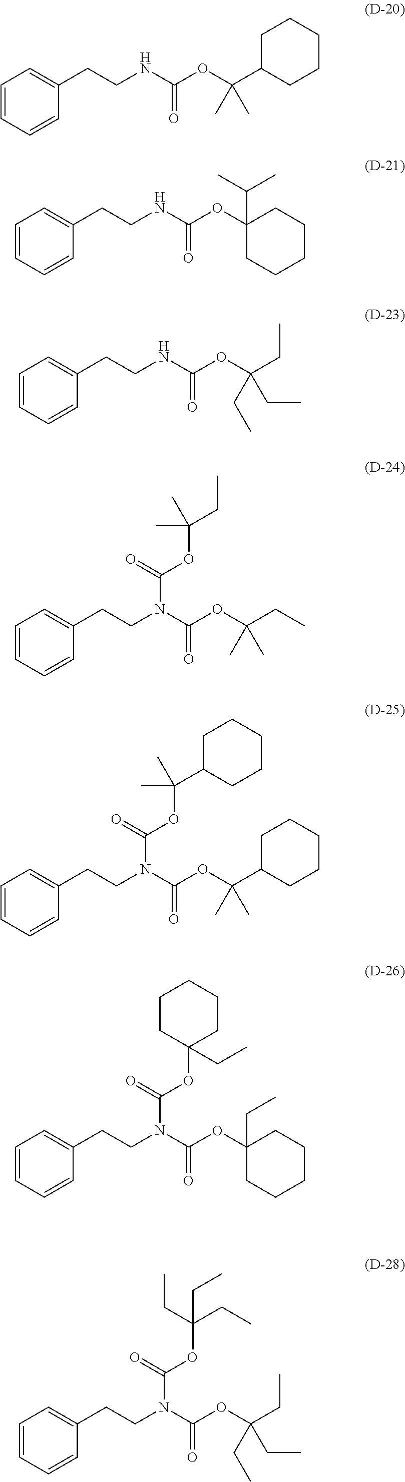

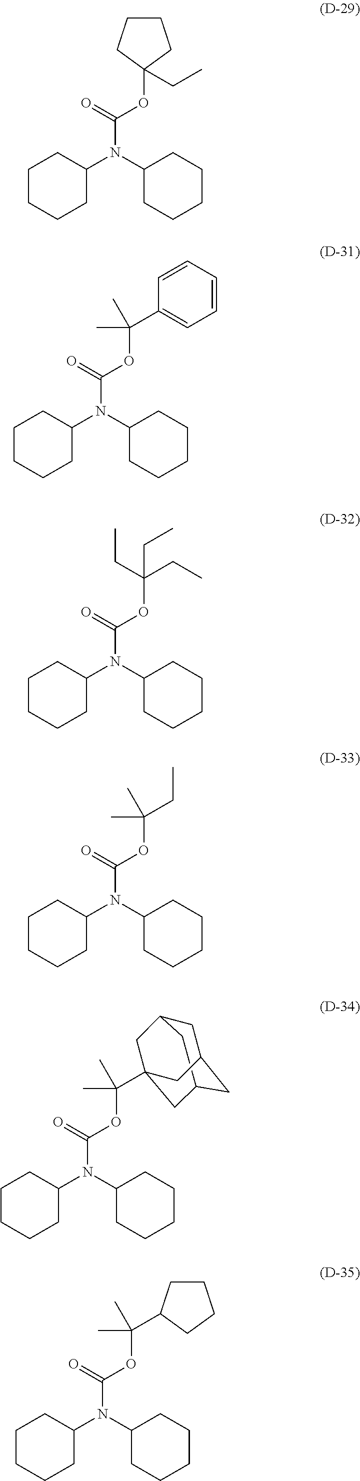

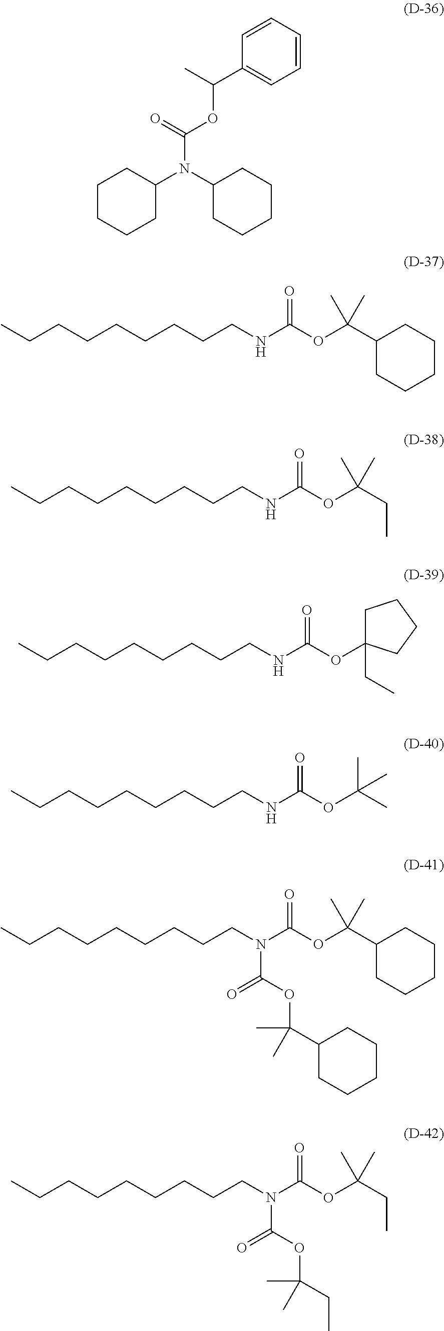

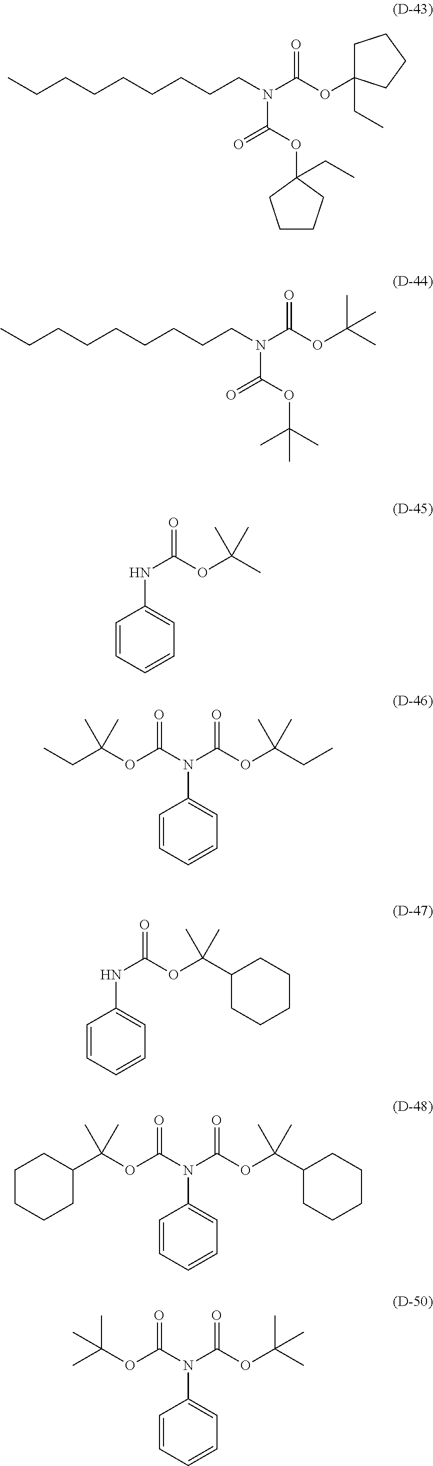

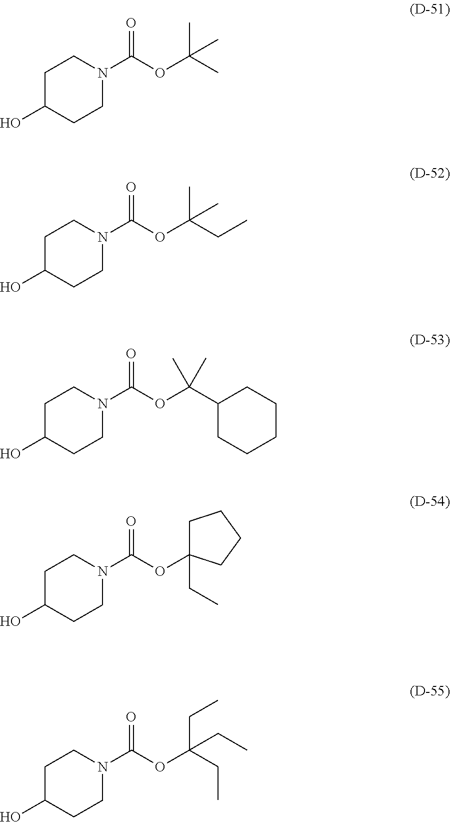

The compounds of general formula (A) can be easily synthesized from commercially available amines by the methods described in, for example, Protective Groups in Organic Synthesis, the fourth edition. The most general method comprises causing a bicarbonic ester or a haloformic ester to act on commercially available amines. In the formulae, X represents a halogen atom.

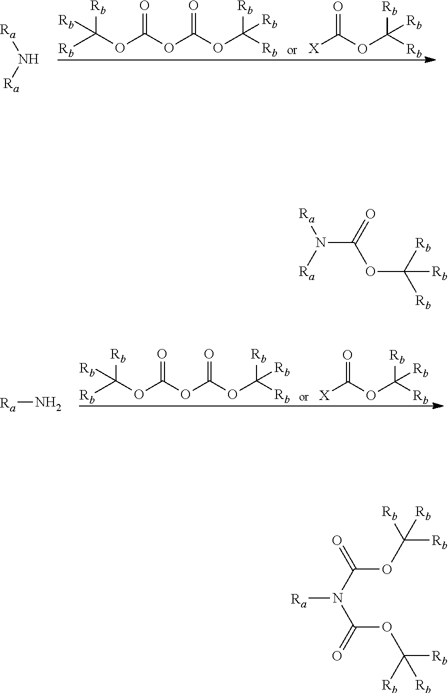

As other compounds usable in the composition of the present invention, there can be mentioned the compounds synthesized in Examples of JP-A-2002-363146, the compounds described in Paragraph [0108] of JP-A-2007-298569, and the like.

These basic compounds can be used alone or in combination.

The amount of basic compound used is generally in the range of 0.001 to 10 mass %, preferably 0.01 to 5 mass % based on the solid contents of the composition of the invention.

With respect to the ratio of the acid generator to basic compound in the composition, preferably, the acid generator/basic compound (molar ratio)=2.5 to 300.

The reason for this is that the molar ratio is preferred to be 2.5 or higher from the viewpoint of sensitivity and resolving power. The molar ratio is preferred to be 300 or below from the viewpoint of the inhibition of any resolving power deterioration due to thickening of resist pattern over time from exposure to heating treatment. The acid generator/basic compound (molar ratio) is more preferably in the range of 5.0 to 200, still more preferably 7 to 150.

With respect to the above molar ratio, the acid generator refers to the sum of repeating unit (A) contained in the resin (P) and above-mentioned acid generators other than those of the resin (P).

<Low-Molecular Compound Containing a Group that is Configured to Decompose when Acted on by Acid or Alkali>

The composition of the present invention can be loaded with a low-molecular compound containing a group that is configured to decompose when acted on by an acid or alkali (provided that the above-mentioned compound that is configured to decompose when acted on by an acid to thereby increase its basicity is excluded). The group that is configured to decompose when acted on by an acid or alkali is not particularly limited. However, an acetal group, a carbonate group, a carbamate group, a tertiary ester group, a tertiary hydroxyl group, a hemiaminal ether group and a lactone structure are preferred. A carbamate group and a hemiaminal ether group are most preferred.

When the composition is exposed to an electron beam or EUV light, it is preferred to contain a compound with a structure resulting from substitution of a phenolic hydroxyl group of phenol compound with an acid-decomposable group. The phenol compound preferably contains 1 to 9, more preferably 2 to 6, phenol skeletons.

Specific examples thereof will be shown below, which in no way limit the scope of the present invention.

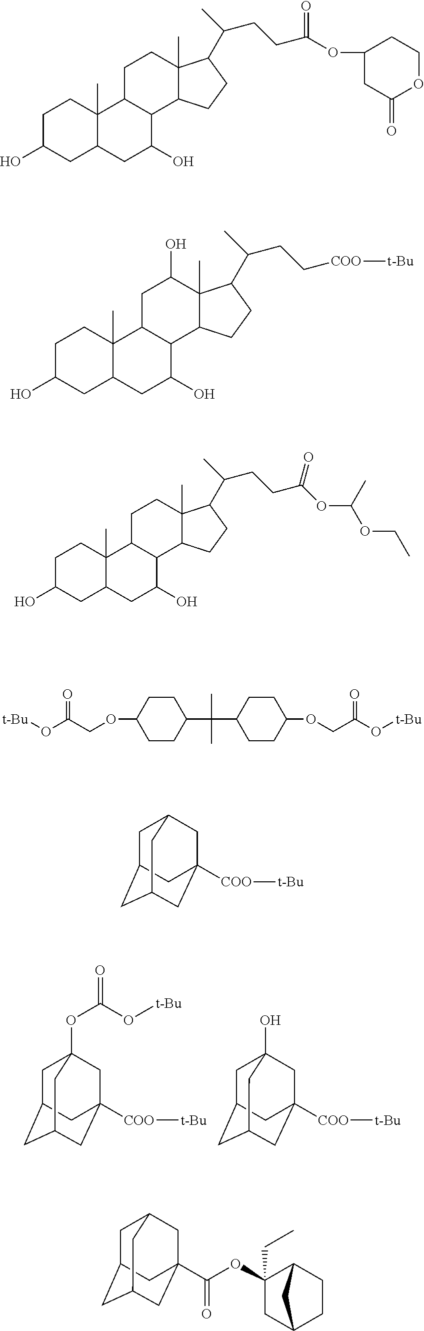

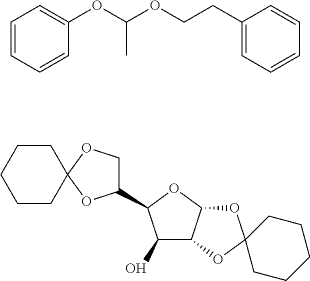

The low-molecular compound containing a group that is configured to decompose when acted on by an acid or alkali may be any of commercially available products or any of those synthesized by heretofore known methods.

<Surfactant>

The composition of the present invention may further contain a surfactant. When the composition contains a surfactant, the surfactant is preferably a fluorinated and/or siliconized surfactant.

As such a surfactant, there can be mentioned Megafac F176 or Megafac R08 produced by Dainippon Ink & Chemicals, Inc., PF656 or PF6320 produced by OMNOVA SOLUTIONS, INC., Troy Sol S-366 produced by Troy Chemical Co., Ltd., Florad FC430 produced by Sumitomo 3M Ltd., polysiloxane polymer KP-341 produced by Shin-Etsu Chemical Co., Ltd., and the like.

Surfactants other than these fluorinated and/or siliconized surfactants can also be used. In particular, the other surfactants include polyoxyethylene alkyl ethers, polyoxyethylene alkyl aryl ethers and the like.

Moreover, generally known surfactants can also be appropriately used. As useful surfactants, there can be mentioned, for example, those described in section [0273] et seq of US 2008/0248425 A1.

These surfactants may be used alone or in combination.

The amount of surfactant added is preferably in the range of 0 to 2 mass %, more preferably 0.0001 to 2 mass %, further more preferably 0.0005 to 1 mass %, based on the total solids of the composition.

On the other hand, it is also preferred to reduce the amount of surfactant added to 10 ppm or less, or nil. This enhances the localization of hydrophobic resins in the surface portion, with the result that the hydrophobicity of the surface of the resist film can be increased, thereby enhancing the water tracking property in the stage of liquid-immersion exposure.

<Solvent>

The solvent that is usable in the preparation of the composition is not particularly limited as long as it can dissolve the components of the composition. As the solvent, there can be mentioned, for example, an alkylene glycol monoalkyl ether carboxylate, an alkylene glycol monoalkyl ether, an alkyl lactate, a cyclolactone, a linear or cyclic ketone, an alkylene carbonate, an alkyl carboxylate, an alkyl alkoxyacetate, an alkyl pyruvate and the like. As other useful solvents, there can be mentioned, for example, those described in section [0244] et seq. of US 2008/0248425 A1 and the like.

As preferred alkylene glycol monoalkyl ether carboxylates, there can be mentioned, for example, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

As preferred alkylene glycol monoalkyl ethers, there can be mentioned, for example, propylene glycol monomethyl ether, propylene glycol monoethyl ether, propylene glycol monopropyl ether, propylene glycol monobutyl ether, ethylene glycol monomethyl ether and ethylene glycol monoethyl ether.

As preferred alkyl lactates, there can be mentioned, for example, methyl lactate, ethyl lactate, propyl lactate and butyl lactate.

As preferred alkyl alkoxypropionates, there can be mentioned, for example, ethyl 3-ethoxypropionate, methyl 3-methoxypropionate, methyl 3-ethoxypropionate and ethyl 3-methoxypropionate.

As preferred cyclolactones, there can be mentioned, for example, β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

As preferred chain or cyclic ketones, there can be mentioned, for example, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

As preferred alkylene carbonates, there can be mentioned, for example, propylene carbonate, vinylene carbonate, ethylene carbonate and butylene carbonate.

As preferred alkyl carboxylate, there can be mentioned, for example, butyl acetate.

As preferred alkyl alkoxyacetates, there can be mentioned, for example, acetic acid 2-methoxyethyl ester, acetic acid 2-ethoxyethyl ester, acetic acid 2-(2-ethoxyethoxy)ethyl ester, acetic acid 3-methoxy-3-methylbutyl ester and acetic acid 1-methoxy-2-propyl ester.

As preferred alkyl pyruvates, there can be mentioned, for example, methyl pyruvate, ethyl pyruvate and propyl pyruvate.

As a preferably employable solvent, there can be mentioned 2-heptanone, cyclopentanone, γ-butyrolactone, cyclohexanone, butyl acetate, ethyl lactate, ethylene glycol monoethyl ether acetate, propylene glycol monomethyl ether acetate, propylene glycol monomethyl ether, ethyl 3-ethoxypropionate, ethyl pyruvate, acetic acid 2-ethoxyethyl ester, acetic acid 2-(2-ethoxyethoxy)ethyl ester or propylene carbonate. Especially preferred solvents are propylene glycol monomethyl ether acetate and propylene glycol monomethyl ether.

These solvents may be used alone or in combination. When a plurality of solvents are mixed together, it is preferred to mix a hydroxylated solvent with a non-hydroxylated solvent. The mass ratio of hydroxylated solvent to non-hydroxylated solvent is in the range of 1/99 to 99/1, preferably 10/90 to 90/10 and more preferably 20/80 to 60/40.

The hydroxylated solvent is preferably an alkylene glycol monoalkyl ether. The non-hydroxylated solvent is preferably an alkylene glycol monoalkyl ether carboxylate.

The ratio of solvents used to the total mass of the composition of the present invention can be appropriately regulated in accordance with desired film thickness, etc. Generally, the ratio is regulated so that the concentration of the total solids of the composition falls within the range of 0.5 to 30 mass %, preferably 1.0 to 20 mass % and more preferably 1.5 to 10 mass %.

<Substance that is Configured to Decompose when Acted on by Acid to Thereby Generate Acid Stronger than Carboxylic Acid>

The composition of the present invention may be loaded with a substance that is configured to decompose when acted on by acid to thereby generate an acid stronger than carboxylic acid (hereinafter also referred to as an “acid amplifier”).

It is preferred for the acid generated by the acid amplifier to exhibit a high acid strength. In particular, the dissociation constant (pKa) of the acid is preferably 3 or below, more preferably 2 or below. It is preferred for the acid generated by the acid amplifier to be sulfonic acid.

The acid amplifiers described in International Publication Nos. 95/29968 and 98/24000, JP-A's H8-305262, H9-34106 and H8-248561, Jpn. PCT National Publication No. H8-503082, U.S. Pat. No. 5,445,917, Jpn. PCT National Publication No. H8-503081, U.S. Pat. Nos. 5,534,393, 5,395,736, 5,741,630, 5,334,489, 5,582,956, 5,578,424, 5,453,345 and 5,445,917, European Patent Nos. 665,960, 757,628 and 665,961, U.S. Pat. No. 5,667,943 and JP-A's H10-1508, H10-282642, H9-512498, 2000-62337, 2005-17730 and 2008-209889, etc. can be used individually or in combination as the acid amplifier according to the present invention.

In particular, the compounds of general formulae (1) to (6) below are preferred.

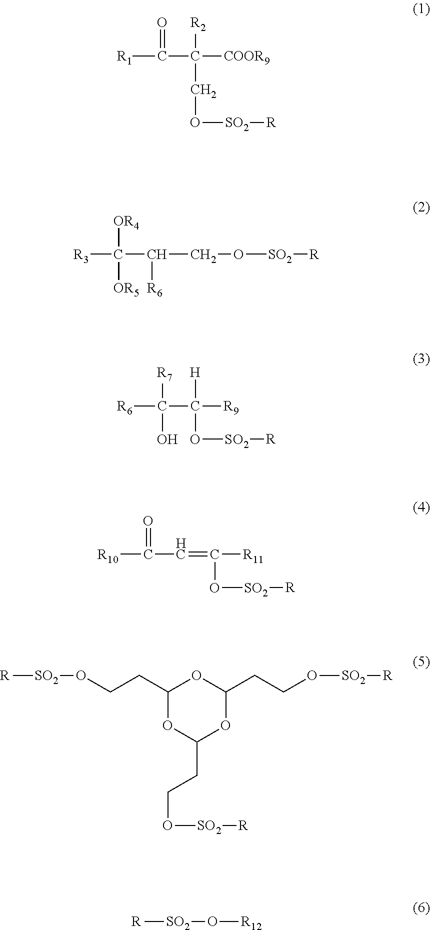

In general formulae (1) to (6),

R represents an alkyl group, a cycloalkyl group, an aryl group or an aralkyl group.

R₀ represents a group that is cleaved under the action of an acid.

R₁ represents an alkyl group, a cycloalkyl group, an aryl group, an aralkyl group, an alkoxy group or an aryloxy group.

R₂ represents an alkyl group or an aralkyl group.

R₃ represents an alkyl group, a cycloalkyl group, an aryl group or an aralkyl group.

Each of R₄ and R₅ independently represents an alkyl group, provided that R₄ and R₅ may be bonded to each other to thereby form a ring.

R₆ represents a hydrogen atom or an alkyl group.

R₇ represents a hydrogen atom, an alkyl group, a cycloalkyl group, an aryl group or an aralkyl group.

R₈ represents an alkyl group, a cycloalkyl group, an aryl group or an aralkyl group.

R₉ represents a hydrogen atom, an alkyl group, a cycloalkyl group, an aryl group or an aralkyl group.

R₉ and R₇ may be bonded to each other to thereby form a ring.

R₁₀ represents an alkyl group, a cycloalkyl group, an alkoxy group, an aryl group, an aralkyl group, an aryloxy group or an alkenyloxy group.

R₁₁ represents an alkyl group, a cycloalkyl group, an alkoxy group, an aryl group, an aralkyl group, an aryloxy group or an alkenyl group.

R₁₀ and R₁₁ may be bonded to each other to thereby form a ring.

R₁₂ represents an alkyl group, a cycloalkyl group, an aryl group, an alkenyl group, an alkynyl group or a cycloimido group.

In general formulae (1) to (6), the alkyl group can be one having 1 to 8 carbon atoms; the monovalent aliphatic hydrocarbon ring group can be a monocyclic or polycyclic one having 4 to 10 carbon atoms; the aryl group can be one having 6 to 14 carbon atoms; the aralkyl group can be one having 7 to 20 carbon atoms; the alkoxy group can be one having 1 to 8 carbon atoms; the alkenyl group can be one having 2 to 6 carbon atoms; the aryloxy group can be one having 6 to 14 carbon atoms; and the alkenyloxy group can be one having 2 to 8 carbon atoms.

Further substituents may be introduced in these substituents. As examples of such further substituents, there can be mentioned a halogen atom such as Cl, Br or F, a —CN group, an —OH group, an alkyl group having 1 to 4 carbon atoms, a cycloalkyl group having 3 to 8 carbon atoms, an alkoxy group having 1 to 4 carbon atoms, an acylamino group such as an acetylamino group, an aralkyl group such as a benzyl group or a phenethyl group, an aryloxyalkyl group such as a phenoxyethyl group, an alkoxycarbonyl group having 2 to 5 carbon atoms, an acyloxy group having 2 to 5 carbon atoms and the like.

As the ring formed by the mutual bonding of R₄ and R₅, there can be mentioned a 1,3-dioxorane ring, a 1,3-dioxane ring and the like.

As the ring formed by the mutual bonding of R₇ and R₉, there can be mentioned a cyclopentyl ring, a cyclohexyl ring and the like.

As the ring formed by the mutual bonding of R₁₀ and R₁₁, there can be mentioned a 3-oxocyclohexenyl ring, a 3-oxoindenyl ring and the like, in which an oxygen atom may be contained in the ring.

As the group cleaved under the action of an acid, contained in R₀, there can be mentioned, for example, a tertiary alkyl group, such as a t-butyl group or a t-amyl group; an isobornyl group; a 1-alkoxyethyl group, such as a 1-ethoxyethyl group, a 1-butoxyethyl group, a 1-isobutoxyethyl group or a 1-cyclohexyloxyethyl group; an alkoxymethyl group, such as a 1-methoxymethyl group or a 1-ethoxymethyl group; a tetrahydropyranyl group; a tetrahydrofuranyl group; a trialkylsilyl group; a 3-oxocyclohexyl group; and the like.

Preferred examples of the groups represented by R, R₀ and R₁ to R₁₁ are as follows.

R: a methyl group, an ethyl group, a propyl group, a butyl group, an octyl group, a trifluoromethyl group, a nonafluorobutyl group, a heptadecafluorooctyl group, a 2,2,2-trifluoroethyl group, a phenyl group, a pentafluorophenyl group, a methoxyphenyl group, a toluoyl group, a mesityl group, a fluorophenyl group, a naphthyl group, a cyclohexyl group or a camphor group.

R₀: a t-butyl group, a methoxymethyl group, an ethoxymethyl group, a 1-ethoxyethyl group or a tetrahydropyranyl group.

R₁: a methyl group, an ethyl group, a propyl group, a cyclopropyl group, a cyclopentyl group, a cyclohexyl group, a phenyl group, a naphthyl group, a benzyl group, a phenethyl group, a methoxy group, an ethoxy group, a propoxy group, a phenoxy group or a naphthoxy group.

R₂: a methyl group, an ethyl group, a propyl group, a butyl group or a benzyl group.

R₃: a methyl group, an ethyl group, a propyl group, a cyclopropyl group, a cyclopentyl group, a cyclohexyl group, a phenyl group, a naphthyl group, a benzyl group, a phenethyl group or a naphthylmethyl group.

R₄, R₅: a methyl group, an ethyl group, a propyl group, or, formed by mutual bonding thereof, an ethylene group or propylene group.

R₆: a hydrogen atom, a methyl group or an ethyl group.

R₇, R₉: a hydrogen atom, a methyl group, an ethyl group, a propyl group, a butyl group, a pentyl group, a cyclopropyl group, a cyclopentyl group, a cyclohexyl group, a phenyl group, a naphthyl group, a benzyl group, a phenethyl group, or, formed by the mutual bonding thereof, a cyclopentyl ring or cyclohexyl ring.

R₈: a methyl group, an ethyl group, an isopropyl group, a t-butyl group, a neopentyl group, a cyclohexyl group, a phenyl group or a benzyl group.

R₁₀: a methyl group, an ethyl group, a propyl group, an isopropyl group, a butyl group, an isobutyl group, a cyclopropyl group, a cyclopentyl group, a cyclohexyl group, a methoxy group, an ethoxy group, a phenyl group, a naphthyl group, a benzyl group, a phenoxy group, a naphthoxy group, a vinyloxy group, a methylvinyloxy group, or, formed by the mutual bonding thereof, a 3-oxocyclohexenyl ring or 3-oxoindenyl ring in which an oxygen atom may be contained.

R₁₁: a methyl group, an ethyl group, a propyl group, an isopropyl group, a butyl group, an isobutyl group, a cyclopropyl group, a cyclopentyl group, a cyclohexyl group, a methoxy group, an ethoxy group, a phenyl group, a naphthyl group, a benzyl group, a phenoxy group, a naphthoxy group, a vinyl group, an allyl group, or, formed by the mutual bonding thereof, a 3-oxocyclohexenyl ring or 3-oxoindenyl ring in which an oxygen atom may be contained.

In general formula (6), when R₁₂ is an alkyl group, the alkyl group is preferably a linear one having 1 to 12 carbon atoms or a branched one having 3 to 12 carbon atoms.

When R₁₂ is a monovalent aliphatic hydrocarbon ring group, the monovalent aliphatic hydrocarbon ring group is preferably a monocyclic or polycyclic one having 5 to 10 carbon atoms.

When R₁₂ is a substituted alkyl group or a substituted aliphatic hydrocarbon ring group, a monovalent nonmetallic atomic group excluding hydrogen is used as the substituent. As preferred examples of such substituents, there can be mentioned a halogen atom (—F, —Br, —Cl or —I), an alkoxy group, an aryloxy group, an alkylthio group, an arylthio group, an N-alkylamino group, an N,N-dialkylamino group, an acyloxy group, an N-alkylcarbamoyloxy group, an N-arylcarbamoyloxy group, an acylamino group, a formyl group, an acyl group, a carboxyl group, an alkoxycarbonyl group, an aryloxycarbonyl group, a carbamoyl group, an N-alkylcarbamoyl group, an N,N-dialkylcarbamoyl group, an N-arylcarbamoyl group, an N-alkyl-N-arylcarbamoyl group, a sulfo group, a sulfonato group, a sulfamoyl group, an N-alkylsulfamoyl group, an N,N-dialkylsulfamoyl group, an N-arylsulfamoyl group, an N-alkyl-N-arylsulfamoyl group, a phosphono group, a phosphonato group, a dialkylphosphono group, a diarylphosphono group, a monoalkylphosphono group, an alkylphosphonato group, a monoarylphosphono group, an arylphosphonato group, a phosphonoxy group, a phosphonatoxy group, an aryl group, an alkenyl group and the like.

When R₁₂ is an aryl group, as the aryl group, there can be mentioned a condensed ring formed by 1 to 3 benzene rings or a condensed ring formed by a benzene ring and a 5-membered unsaturated ring. Specific examples thereof include a phenyl group, a naphthyl group, an anthryl group, a phenanthryl group, an indenyl group, an acenaphthenyl group, a fluorenyl group and the like. Among these, a phenyl group and a naphthyl group are preferred. The aryl groups include not only the above carbon-ring aryl groups but also heterocyclic aryl groups. As the heterocyclic aryl groups, there can be mentioned those each containing 3 to 20 carbon atoms and 1 to 5 heteroatoms, such as a pyridyl group and a furyl group as well as, resulting from condensation with a benzene ring, a quinolyl group, benzofuryl group, thioxanthone group and carbazole group.

When R₁₂ is a substituted aryl group, as the substituted aryl group, use is made of one resulting from the introduction of, as a substituent, a monovalent nonmetallic atomic group excluding hydrogen in a ring-constructing carbon atom of the above aryl group. Examples of preferred substituents are the same as set forth above with respect to the alkyl group and cycloalkyl group.

When R₁₂ is an alkenyl group, a substituted alkenyl group [—C(R₁₄)═C(R₁₅)(R₁₆)], an alkynyl group or a substituted alkynyl group [—C≡C(R₁₇)], R₁₄ to R₁₇ can be monovalent nonmetallic atomic groups. As preferred examples of the substituents represented by R₁₄ to R₁₇, there can be mentioned a hydrogen atom, a halogen atom, an alkyl group, a substituted alkyl group, an aryl group and a substituted aryl group. As specific examples thereof, there can be mentioned those set forth above by way of example. As more preferred substituents represented by R₁₄ to R₁₇, there can be mentioned a hydrogen atom, a halogen atom and a linear, branched or cyclic alkyl group having 1 to 10 carbon atoms.

When R₁₂ is a cycloimido group, as the cycloimido, there can be mentioned one having 4 to 20 carbon atoms, such as succinimido, phthalimido, cyclohexanedicarboxyimido or norbornenedicarboxyimido group.

As specific examples of the compounds of general formulae (1) to (6), there can be mentioned the compounds (1-1) to (1-11), (2-1) to (2-6), (3-1) to (3-6), (4-1) to (4-7), (5-1) to (5-4) and (6-1) to (6-20) set forth as examples in section [0215] et seq. of JP-A-2008-209889.

<Other Component>

The composition of the present invention can be appropriately loaded with, in addition to the above components, an onium salt of carboxylic acid, any of the dissolution inhibiting compounds of 3000 or less molecular weight described in, for example, Proceeding of SPIE, 2724,355 (1996), a dye, a plasticizer, a photosensitizer, a light absorber, etc.

[Method of Forming Pattern]

In the use of the composition of the present invention, the above components are typically dissolved in a solvent, filtered and applied onto a support.

The filter medium preferably consists of a polytetrafluoroethylene, polyethylene or nylon having a pore size of 0.1 μm or less, more preferably 0.05 μm or less and further more preferably 0.03 μm or less.

The thickness of formed film is not particularly limited. However, the thickness is preferably in the range of 0.01 to 0.2 μm, more preferably 0.02 to 0.1 μm.

The method of application onto a substrate is preferably a spin coating method, in which the rotating speed is preferably in the range of 1000 to 3000 rpm.

The composition is applied onto a substrate, such as one for use in the production of integrated circuit elements, photomasks, imprint molds, etc. (e.g., silicon/silicon dioxide coating), by appropriate application means, such as a spinner. Thereafter, the applied composition is dried to thereby obtain a photosensitive film.

This film is exposed through a given mask to actinic rays or radiation, preferably baked (heated), developed and rinsed. Thus, a favorable pattern can be obtained. When the film is exposed to an electron beam, lithography without a mask (direct lithography) is generally carried out.

With respect to the particulars of the fabrication of an imprint mold structure using the composition of the present invention, reference can be made to, for example, “Fundamentals of nanoimprint and its technology development/application deployment—technology of nanoimprint substrate and its latest technology deployment” edited by Yoshihiko Hirai, published by Frontier Publishing (issued in June, 2006), Japanese Patent No. 4109085 and JP-A-2008-162101.

The actinic rays or radiation is not particularly limited, and, for example, a KrF excimer laser, an ArF excimer laser, EUV light, an electron beam and the like can be preferably used. EUV light and an electron beam are most preferred.

In the development step, an alkali developer is generally used. Generally, a quaternary ammonium salt, typically tetramethylammonium hydroxide, is used in the alkali developer for the development step. The alkali developer is not limited to this, and use can be made of an aqueous solution of an alkali selected from among an inorganic alkali (for example, sodium hydroxide, potassium hydroxide, sodium carbonate, sodium silicate, sodium metasilicate and the like), a primary to tertiary amine (for example, ethylamine, n-propylamine, diethylamine, di-n-butylamine, triethylamine, methyldiethylamine and the like), an alcoholamine (for example, dimethylethanolamine, triethanolamine and the like), a cycloamine (for example, pyrrole, piperidine and the like) and the like.

Before the use of the above alkali developer, appropriate amounts of an alcohol and a surfactant may be added thereto.

The alkali concentration of the alkali developer is generally in the range of 0.1 to 20 mass %.

The pH value of the alkali developer is generally in the range of 10.0 to 15.0.

Pure water can be used as the rinse liquid. Before the use, an appropriate amount of surfactant may be added thereto.

Prior to the formation of a film, the substrate may be coated with an antireflection film. As the antireflection film, use can be made of not only an inorganic film of titanium, titanium oxide, titanium nitride, chromium oxide, carbon, amorphous silicon and the like but also an organic film composed of a light absorber and a polymer material. Also, as the organic antireflection film, use can be made of commercially available organic antireflection films, such as the DUV30 Series and DUV40 Series produced by Brewer Science Inc. and AR-2, AR-3 and AR-5 produced by Shipley Co., Ltd.

### EXAMPLES

<Polymerizable Compounds Corresponding to the Repeating Unit (a)>

### Synthetic Example 1

### M-I-3

First, 100.00 parts by mass of p-acetoxystyrene was dissolved in 400 parts by mass of ethyl acetate, and cooled to 0° C. Subsequently, 47.60 parts by mass of sodium methoxide (28% methanol solution) was dropped into the cooled solution over a period of 30 minutes, and agitated at room temperature for five hours. Ethyl acetate was added, and the resultant organic phase was washed with distilled water thrice. The washed organic phase was dried over anhydrous sodium sulfate, and the solvent was distilled off. Thus, 131.70 parts by mass of p-hydroxystyrene (54% ethyl acetate solution) was obtained.

From the obtained p-hydroxystyrene (54% ethyl acetate solution), 18.52 parts by mass was taken and was dissolved in 56.00 parts by mass of ethyl acetate. Subsequently, 31.58 parts by mass of 1,1,2,2,3,3-hexafluoropropane-1,3-disulfonyl difluoride was added to the solution and cooled to 0° C. A solution obtained by dissolving 12.63 parts by mass of triethylamine in 25.00 parts by mass of ethyl acetate was dropped into the mixture over a period of 30 minutes, and agitated while cooling at 0° C. for four hours. Ethyl acetate was added, and the resultant organic phase was washed with saturated saline thrice for three times. Then the solvent was removed. 35.00 g of the obtained compound was dissolved in 315 parts by mass of methanol and cooled to 0° C. 245 parts by mass of sodium hydroxide aqueous solution was added and agitated for two hours at room temperature. The solvent was removed, followed by addition of ethyl acetate. The resultant organic phase was washed ith saturated saline thrice for three times and the solvent was distilled off. Thus, 34.46 parts by mass of compound A was obtained.

To 25.80 parts by mass of 4-phenylpyridine N-oxide was added 42.86 parts by mass of 2-ethyl hexane p-toluence sulfonate and agitated at 100° C. for two hours. This was allowed to stand still and to be cooled to room temperature. The precipitated solids was filtrated and washed with 100 parts by mass of ethyl acetate. The resultant white solids were dissolved in 30.00 parts by mass of methanol. The resultant solution was allowed to pass through an ion exchange resin (Amberlite(R); IRA410) to obtain 35.55 parts by mass of compound B.

30.00 parts by mass of compound A was dissolved in 100.00 parts by mass of methanol. To this was added 21.95 parts by mass of compound B. The resultant solution was agitated at room temperature for 3 hours.

The solvent was removed, a distilled water was added, and extracted using chloroform for three times. The resultant organic phase was washed with distilled water for three times. The solvent was removed to obtain 45.86 parts by mass of the desired compound (M-I-3).

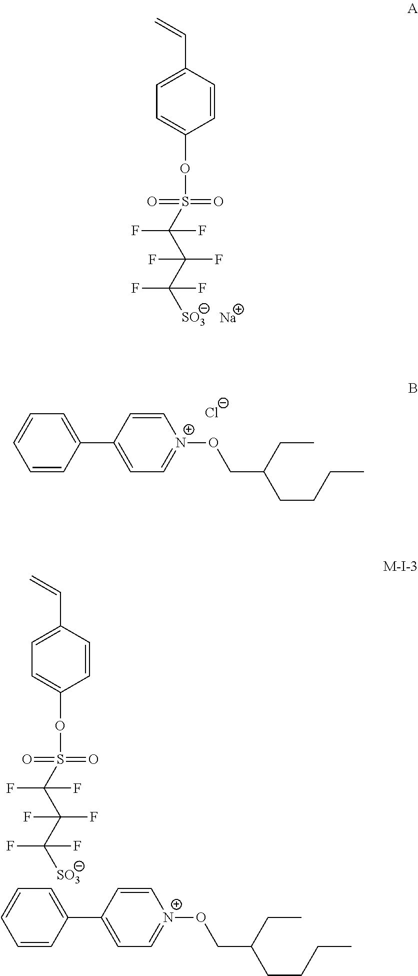

¹H NMR (400 MHz, CDCl₃) δ(ppm): 9.04 (d, 2H), 8.34 (d, 2H), 7.81 (d, 2H), 7.55 (m, 3H), 7.42 (d, 2H), 7.22 (d, 2H), 6.68 (dd, 1H), 5.74 (d, 1H), 5.32 (d, 1H), 4.57 (d, 2H), 1.58 (m, 15H).

Other polymerizable compounds corresponding to the repeating unit (A) (M-I-4, M-I-31, M-I-32, M-I-80, M-I-81, M-I-96, M-I-97, M-I-109, M-I-111, M-II-44, M-II-45, M-II-81, M-II-82, M-III-5, M-III-7, M-III-49, M-III-85, M-III-86, M-III-106, and M-III-108) were synthesized in the same way as described above.

<Synthesis of Resin (P)>

### Synthetic Example 2

### P-1

In a nitrogen stream, 9.33 parts by mass of methyl ethyl ketone was heated at 80° C. While agitating the liquid, a mixed solution consisting of 6.54 parts by mass of monomer M-I-3 obtained by synthetic example 1, 6.70 parts by mass of monomer below, 6.76 parts by mass of 4-hydroxystyrene, 37.33 parts by mass of methyl ethyl ketone and 1.51 parts by mass of dimethyl 2,2′-azobisisobutyrate (V601 produced by Wako Pure Chemical Industries, Ltd.) was dropped thereinto over a period of two hours. After the completion of the dropping, the mixture was further agitated at 80° C. for four hours. The thus obtained reaction liquid was allowed to stand still to cool, and the cooled reaction liquid was recrystallized from a large volume of hexane/ethyl acetate and dried in vacuum, thereby obtaining 9.5 parts by mass of resin P-1 according to the present invention.

The weight average molecular weight (Mw: polystyrene equivalent) of the obtained resin as determined by GPC (carrier: N-methyl-2-pyrrolidone (NMP)) was 9500, and the dispersity (Mw/Mn) thereof was 1.72.

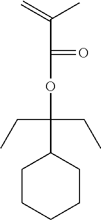

Resins P-2 to P-26 were synthesized in the same manner as described above. The following Table 3 shows the molar ratio of individual repeating units (mol %; corresponding to individual repeating units in order from the left), weight average molecular weight, and degree of dispersal with respect to each of the resins.

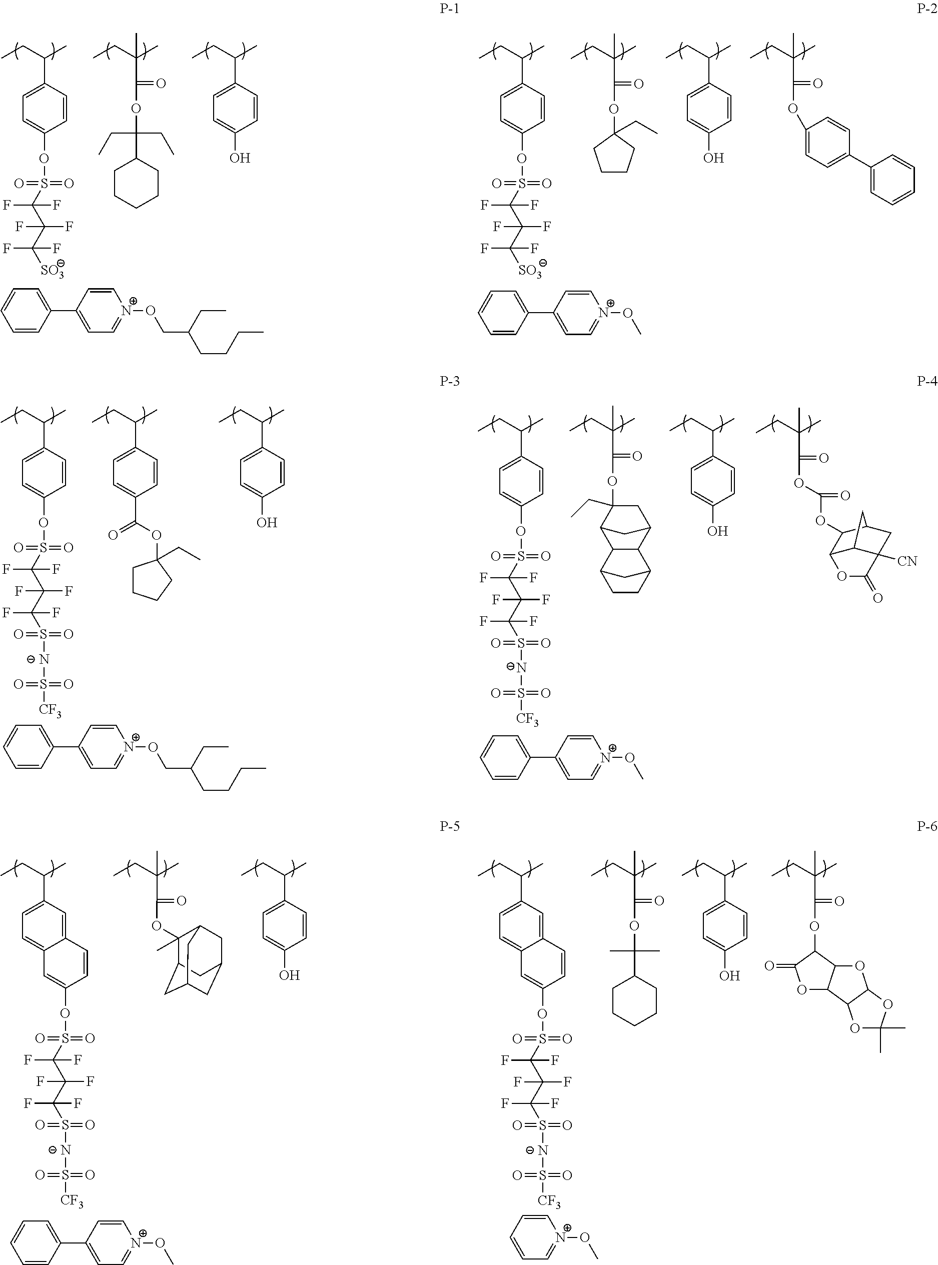

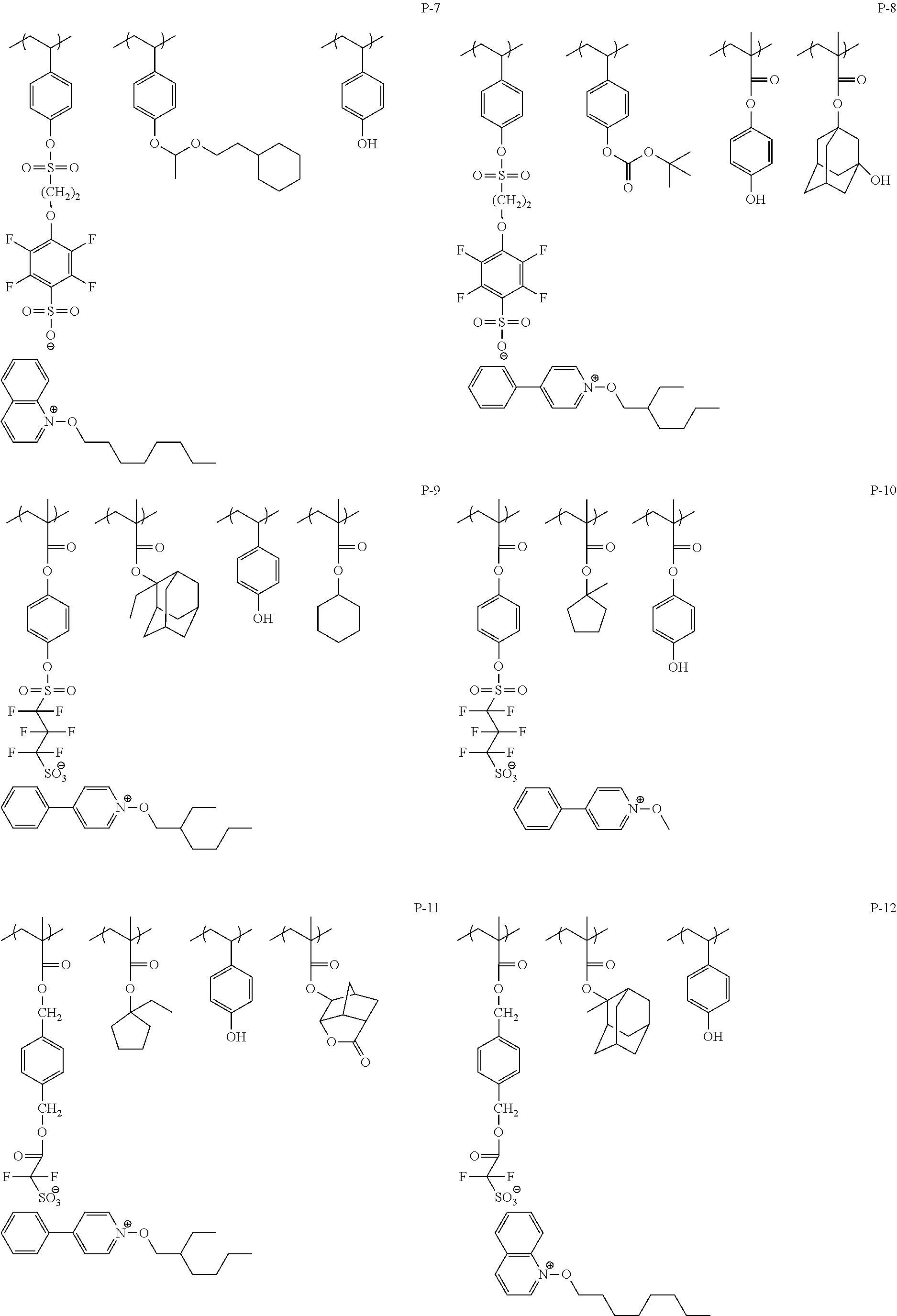

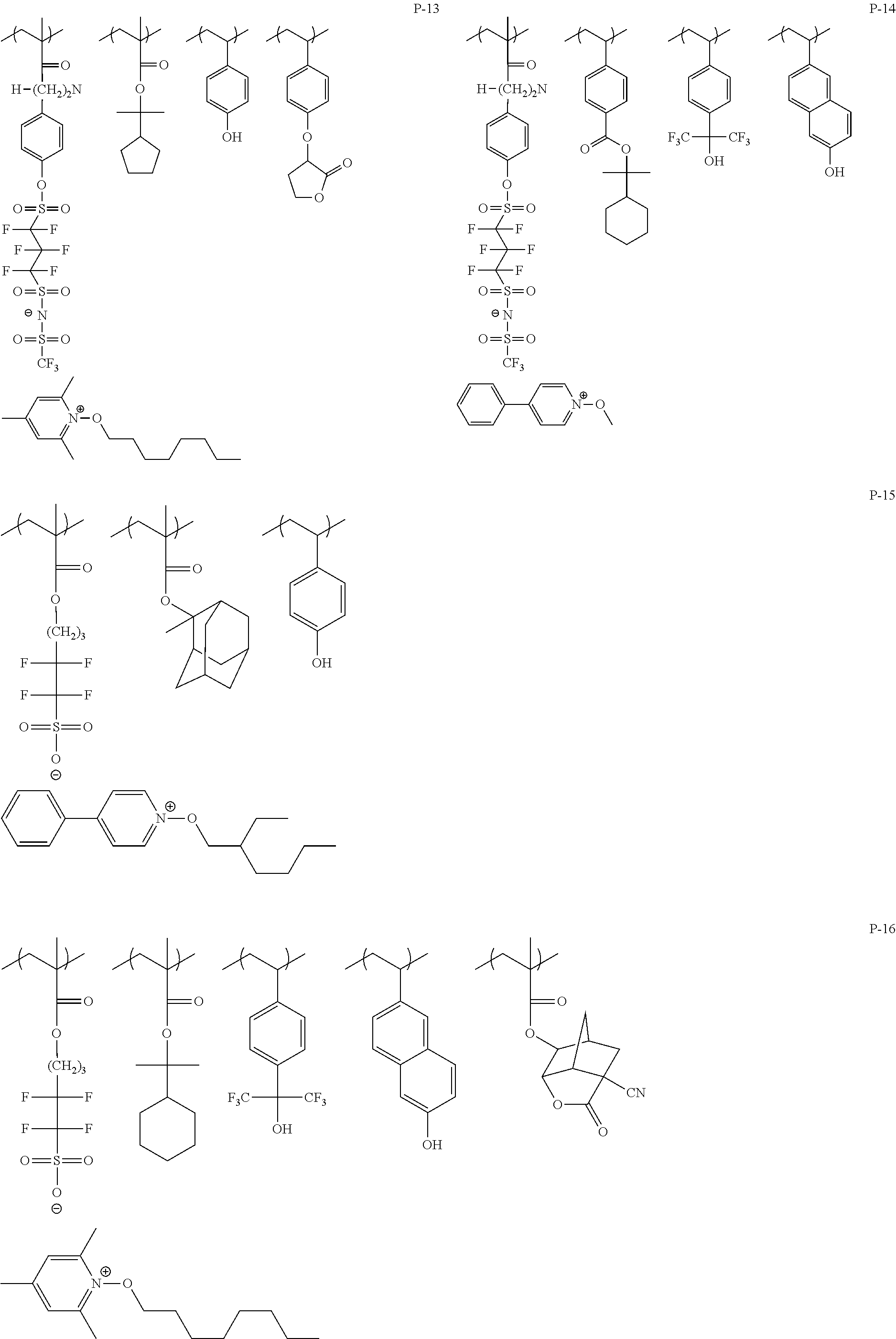

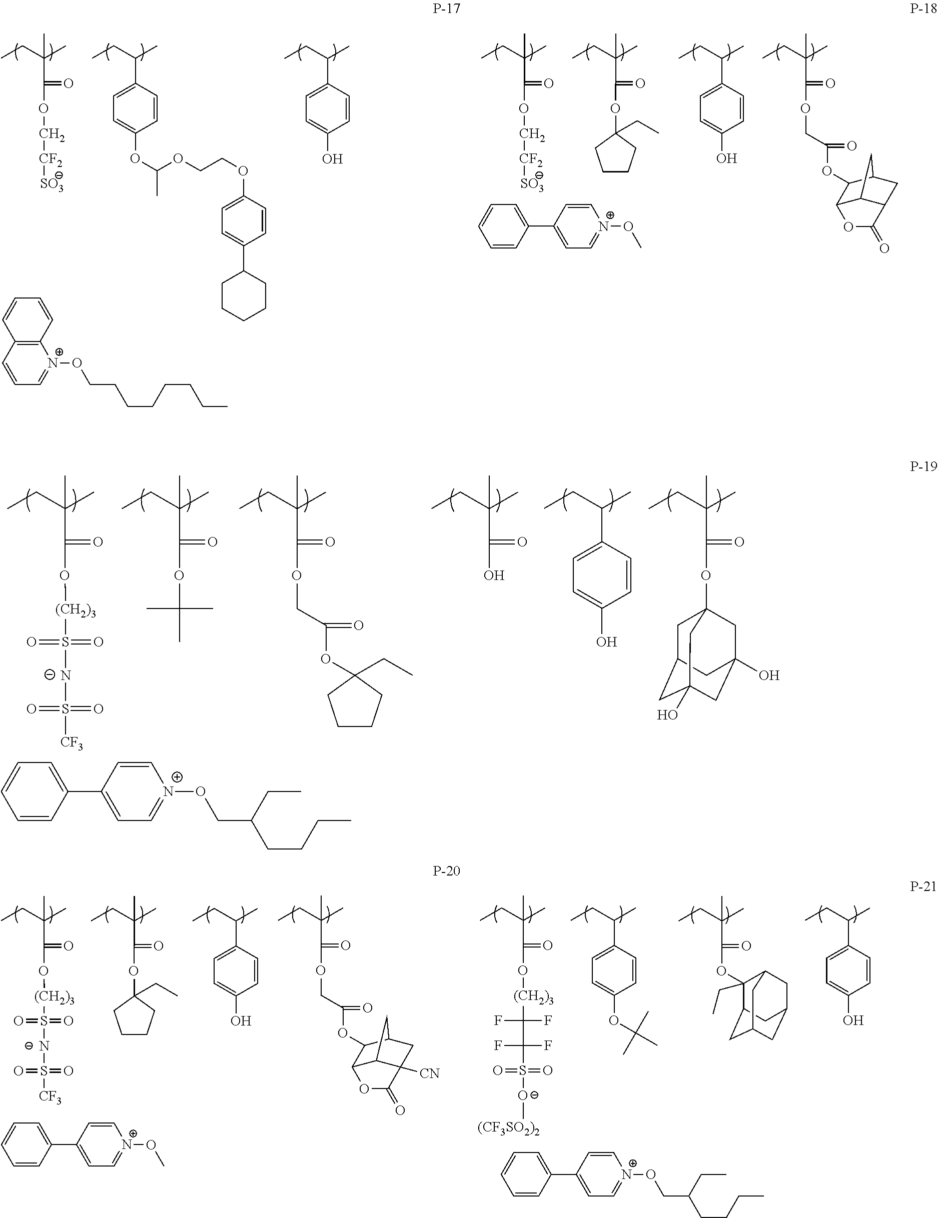

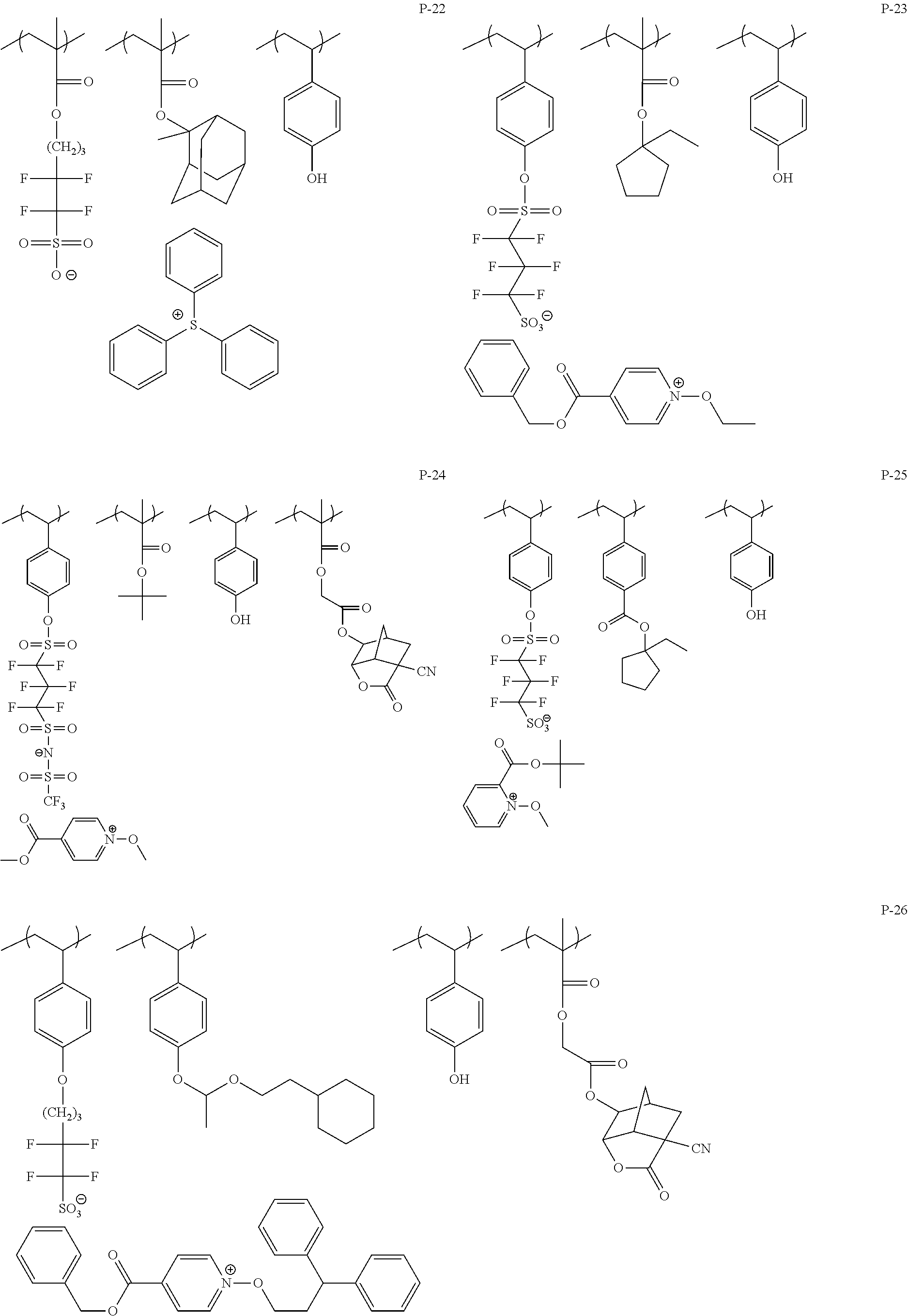

TABLE 3

| No. | Component Ratio (mol %) | | | | | | Mw | Mw/Mn |
|---|---|---|---|---|---|---|---|---|
| P-1 | 10 | 30 | 60 | — | — | — | 9500 | 1.72 |
| P-2 | 10 | 30 | 57 | 3 | — | — | 8800 | 1.70 |
| P-3 | 10 | 25 | 65 | — | — | — | 9700 | 1.69 |
| P-4 | 10 | 30 | 40 | 20 | — | — | 10000 | 1.71 |
| P-5 | 12 | 30 | 58 | — | — | — | 9200 | 1.72 |
| P-6 | 12 | 30 | 38 | 20 | — | — | 9400 | 1.73 |
| P-7 | 10 | 25 | 65 | — | — | — | 9600 | 1.71 |
| P-8 | 15 | 30 | 45 | 10 | — | — | 9000 | 1.69 |
| P-9 | 10 | 25 | 62 | 3 | — | — | 9900 | 1.70 |
| P-10 | 10 | 30 | 60 | — | — | — | 9800 | 1.72 |
| P-11 | 10 | 30 | 45 | 15 | — | — | 9300 | 1.73 |
| P-12 | 10 | 30 | 60 | — | — | — | 10300 | 1.71 |
| P-13 | 12 | 25 | 48 | 15 | — | — | 8900 | 1.70 |
| P-14 | 15 | 30 | 50 | 5 | — | — | 9100 | 1.72 |
| P-15 | 6 | 34 | 60 | — | — | — | 9500 | 1.69 |
| P-16 | 13 | 30 | 30 | 7 | 20 | — | 9600 | 1.71 |
| P-17 | 10 | 30 | 60 | — | — | — | 9200 | 1.72 |
| P-18 | 10 | 30 | 35 | 25 | — | — | 8900 | 1.70 |
| P-19 | 15 | 30 | 35 | 5 | 5 | 10 | 9100 | 1.71 |
| P-20 | 7 | 30 | 43 | 20 | — | — | 9300 | 1.73 |
| P-21 | 12 | 18 | 15 | 55 | — | — | 9600 | 1.72 |
| P-22 | 6 | 34 | 60 | — | — | — | 9400 | 1.70 |
| P-23 | 10 | 40 | 50 | | — | — | 9200 | 1.71 |
| P-24 | 13 | 40 | 35 | 12 | — | — | 9800 | 1.74 |
| P-25 | 13 | 35 | 52 | | — | — | 9100 | 1.68 |
| P-26 | 12 | 35 | 40 | 13 | — | — | 9600 | 1.72 |

<Evaluation of Resist>

Referring to Table 4 below, with respect to each of the resists, the individual components were dissolved in the solvent, thereby obtaining a solution of 4 mass % solid content. The solution was passed through a polytetrafluoroethylene filter of 0.10 μm pore size. Thus, the intended actinic-ray- or radiation-sensitive resin compositions were obtained. The actinic-ray- or radiation-sensitive resin compositions were evaluated by the following methods. The evaluation results are also given in the Table 4 below.

With respect to each of the components of the Table, the ratio indicated when a plurality of species are used are mass ratio.

(Exposure Condition 1: EB exposure; Examples 1 to 32 and Comparative Examples 1 and 2)

Each of the prepared radiation-sensitive resin compositions was uniformly applied onto a silicon substrate having undergone hexamethyldisilazane treatment by means of a spin coater, and dried by heating on a hot plate at 120° C. for 90 seconds. Thus, radiation-sensitive films each having a thickness of 100 nm were formed. Each of the formed radiation-sensitive films was irradiated with an electron beam by means of an electron beam irradiation apparatus (model HL750 manufactured by Hitachi, Ltd., acceleration voltage 50 keV). The irradiated film was immediately baked on a hot plate at 130° C. for 90 seconds. The baked film was developed with a 2.38 mass % aqueous tetramethylammonium hydroxide solution at 23° C. for 60 seconds, rinsed with pure water for 30 seconds and spin dried. Thus, resist patterns were formed.

(Exposure Condition 2: EUV exposure; Examples 33 to 40 and comparative example 3)

Each of the prepared radiation-sensitive resin compositions was uniformly applied onto a silicon substrate having undergone hexamethyldisilazane treatment by means of a spin coater, and dried by heating on a hot plate at 120° C. for 90 seconds. Thus, radiation-sensitive films each having a thickness of 100 nm were formed. Each of the formed radiation-sensitive films was irradiated with EUV by means of an EUV exposure apparatus. The irradiated film was immediately baked on a hot plate at 130° C. for 90 seconds. The baked film was developed with a 2.38 mass % aqueous tetramethylammonium hydroxide solution at 23° C. for 60 seconds, rinsed with pure water for 30 seconds and spin dried. Thus, resist patterns were obtained.

(Evaluation of Sensitivity)

The configuration of a cross section of each of the obtained patterns was observed by means of a scanning electron microscope (model S-9220, manufactured by Hitachi, Ltd.). The sensitivity was defined as the minimum exposure energy at which a 100-nm line (line:space=1:1) could be resolved.

(Evaluation of Resolving Power)

The resolving power was defined as a limiting resolving power (minimum width at which line and space separated and resolved from each other) under the amount of exposure exhibiting the above sensitivity.

(Evaluation of Pattern Configuration)

The configuration of a cross section of each 100-nm line pattern formed under the amount of exposure exhibiting the above sensitivity was observed by means of a scanning electron microscope (model S-4300, manufactured by Hitachi, Ltd.) The pattern configuration was evaluated into being rectangular, T-top and tapering on a 3-point scale.

(Evaluation of LER)

A 100-nm line pattern formed under the amount of exposure exhibiting the above sensitivity was observed by means of a scanning electron microscope (model S-9220, manufactured by Hitachi, Ltd.). The distance between actual edge and a reference line on which edges were to be present was measured on arbitrary 30 points within 50 μm in the longitudinal direction of the pattern. The standard deviation of measured distances was determined, and 3σ was computed therefrom.

TABLE 4

| | | | | | Basic | | | | | | total | | Resolu- | | |
|---|---|---|---|---|---|---|---|---|---|---|---|---|---|---|---|
| | Resin | | Acid | | com- | | Organic | mass | Surfac- | | solids | Sensitivity | tion | Pattern | LER |
| Ex. | (P) | conc. | generator | conc. | pound | conc. | solvent | ratio | tant | conc. | (mass %) | (μc/cm²) | (nm) | configuration | (nm) |
| 1 | P-1 | 98.44 | None | | TPI | 1.51 | S1/S2 | 40/60 | W-1 | 0.05 | 4.0 | 28.8 | 50 | Rectangular | 2.8 |
| 2 | P-1 | 98.44 | None | | TBAH | 1.51 | S1/S2 | 30/70 | W-4 | 0.05 | 4.0 | 29 | 50 | Rectangular | 2.7 |
| 3 | P-1/ | 98.27 | None | | TOA | 1.68 | S1/S2/ | 30/60/ | W-1 | 0.05 | 4.0 | 30.1 | 55 | Rectangular | 3.3 |
| | P-15 | | | | | | S3 | 10 | | | | | | | |
| 4 | P-2 | 98.25 | None | | TPI | 1.70 | S1/S2 | 40/60 | W-2 | 0.05 | 4.0 | 29.1 | 50 | Rectangular | 2.8 |
| 5 | P-2 | 98.25 | None | | TOA | 1.70 | S1/S2 | 20/80 | W-1 | 0.05 | 4.0 | 28.9 | 50 | Rectangular | 2.7 |
| 6 | P-3 | 98.50 | None | | TPI | 1.45 | S1/S2 | 40/60 | W-3 | 0.05 | 4.0 | 32.1 | 50 | Rectangular | 3.1 |
| 7 | P-3 | 97.00 | PAG1 | 1.5 | TPI | 1.45 | S1/S2 | 30/70 | W-1 | 0.05 | 4.0 | 29.9 | 50 | Rectangular | 3.0 |
| 8 | P-4 | 98.51 | None | | TPI | 1.44 | S1/S2 | 40/60 | W-1 | 0.05 | 4.0 | 31.9 | 50 | Rectangular | 3.1 |
| 9 | P-4 | 98.51 | None | | TBAH | 1.44 | S1/S2 | 30/70 | W-2 | 0.05 | 4.0 | 31.6 | 50 | Rectangular | 3.0 |
| 10 | P-5 | 98.29 | None | | TPI | 1.66 | S1/S2 | 40/60 | W-2 | 0.05 | 4.0 | 30.2 | 55 | Rectangular | 3.2 |
| 11 | P-6 | 98.40 | None | | TPI | 1.55 | S1/S2/ | 30/60/ | W-3 | 0.05 | 4.0 | 30.4 | 60 | Rectangular | 3.5 |
| | | | | | | | S3 | 10 | | | | | | | |
| 12 | P-7 | 98.47 | None | | TPI | 1.48 | S1/S2 | 20/80 | W-1 | 0.05 | 4.0 | 30.3 | 55 | Rectangular | 3.2 |
| 13 | P-8 | 98.23 | None | | TBAH | 1.72 | S1/S2 | 20/80 | W-3 | 0.05 | 4.0 | 28.5 | 55 | Rectangular | 3.3 |
| 14 | P-9 | 98.47 | None | | TPI | 1.48 | S1/S2 | 40/60 | W-2 | 0.05 | 4.0 | 30.7 | 50 | Rectangular | 3.1 |
| 15 | P-9 | 96.97 | PAG2 | 1.5 | TBAH | 1.48 | S1/S2 | 40/60 | W-4 | 0.05 | 4.0 | 29.8 | 50 | Rectangular | 3.0 |
| 16 | P-10 | 98.45 | None | | TPI | 1.50 | S1/S2 | 40/60 | W-3 | 0.05 | 4.0 | 30.5 | 55 | Rectangular | 3.2 |
| 17 | P-11 | 98.39 | None | | TPI | 1.56 | S1/S2 | 40/60 | W-2 | 0.05 | 4.0 | 30.4 | 55 | Rectangular | 3.2 |
| 18 | P-12 | 98.37 | None | | TOA | 1.58 | S1/S2 | 30/70 | W-1 | 0.05 | 4.0 | 30.1 | 55 | Rectangular | 3.3 |
| 19 | P-13 | 98.44 | None | | TPI | 1.51 | S1/S2 | 40/60 | W-3 | 0.05 | 4.0 | 30.3 | 55 | Rectangular | 3.2 |
| 20 | P-14 | 98.56 | None | | TPI | 1.39 | S1/S2 | 40/60 | W-2 | 0.05 | 4.0 | 33.3 | 60 | Rectangular | 3.6 |
| 21 | P-15 | 98.35 | None | | TPI | 1.60 | S1/S2 | 40/60 | W-1 | 0.05 | 4.0 | 30.1 | 55 | Rectangular | 3.2 |
| 22 | P-16 | 98.44 | None | | TPI | 1.51 | S1/S2/ | 30/60/ | W-2 | 0.05 | 4.0 | 30.4 | 60 | Rectangular | 3.5 |
| | | | | | | | S3 | 10 | | | | | | | |
| 23 | P-17 | 98.39 | None | | TOA | 1.56 | S1/S2 | 30/70 | W-3 | 0.05 | 4.0 | 30 | 55 | Rectangular | 3.3 |
| 24 | P-18 | 98.40 | None | | TPI | 1.55 | S1/S2 | 40/60 | W-1 | 0.05 | 4.0 | 30.4 | 55 | Rectangular | 3.3 |
| 25 | P-19 | 98.29 | None | | TPI | 1.66 | S1/S2 | 40/60 | W-2 | 0.05 | 4.0 | 35.1 | 60 | Rectangular | 3.9 |
| 26 | P-20 | 98.31 | None | | TPI | 1.64 | S1/S2 | 40/60 | W-2 | 0.05 | 4.0 | 30.2 | 55 | Rectangular | 3.2 |
| 27 | P-20 | 98.31 | None | | TBAH | 1.64 | S1/S2 | 20/80 | W-3 | 0.05 | 4.0 | 30.3 | 55 | Rectangular | 3.1 |
| 28 | P-21 | 98.32 | None | | TPI | 1.63 | S1/S2 | 40/60 | W-1 | 0.05 | 4.0 | 29.8 | 60 | Rectangular | 3.5 |
| 29 | P-23 | 98.40 | None | | TPI | 1.55 | S1/S2 | 40/60 | W-1 | 0.05 | 4.0 | 29.7 | 50 | Rectangular | 2.7 |
| 30 | P-24 | 98.30 | None | | TPI | 1.65 | S1/S2 | 40/60 | W-1 | 0.05 | 4.0 | 30.2 | 50 | Rectangular | 2.7 |
| 31 | P-25 | 98.34 | None | | TPI | 1.61 | S1/S2 | 40/60 | W-1 | 0.05 | 4.0 | 29.9 | 55 | Rectangular | 3.1 |
| 32 | P-26 | 99.47 | None | | TPI | 0.48 | S1/S2 | 40/60 | W-1 | 0.05 | 4.0 | 30.2 | 55 | Rectangular | 3.2 |
| Compar. 1 | P-22 | 98.91 | None | | TPI | 1.04 | S1/S2 | 40/60 | W-1 | 0.05 | 4.0 | 42.1 | 65 | T-top | 4.8 |
| Compar. 2 | P-22 | 99.23 | None | | PI | 0.72 | S1/S2 | 40/60 | W-1 | 0.05 | 4.0 | 31.1 | 75 | T-top | 6.2 |

TABLE 5

| | Resin | | Acid | | Basic | | Organic | mass | | | total solids | Sensitivity | Pattern |
|---|---|---|---|---|---|---|---|---|---|---|---|---|---|
| Ex. | (p) | conc. | generator | conc. | compound | conc. | solvent | ratio | Surfactant | conc. | (mass %) | (mJ/cm²) | configuration |
| 33 | P-1 | 98.44 | None | | TPI | 1.51 | S1/S2 | 40/60 | W-1 | 0.05 | 4.0 | 11.5 | Rectangular |
| 34 | P-2 | 98.25 | None | | TPI | 1.70 | S1/S2 | 40/60 | W-2 | 0.05 | 4.0 | 11.7 | Rectangular |
| 35 | P-4 | 98.51 | None | | TPI | 1.44 | S1/S2 | 40/60 | W-1 | 0.05 | 4.0 | 12.8 | Rectangular |
| 36 | P-9 | 98.47 | None | | TPI | 1.48 | S1/S2 | 40/60 | W-2 | 0.05 | 4.0 | 12.3 | Rectangular |
| 37 | P-15 | 98.35 | None | | TPI | 1.60 | S1/S2 | 40/60 | W-1 | 0.05 | 4.0 | 12.0 | Rectangular |
| 38 | P-20 | 98.31 | None | | TBAH | 1.64 | S1/S2 | 60/40 | W-3 | 0.05 | 4.0 | 12.2 | Rectangular |
| 39 | P-23 | 98.40 | None | | TPI | 1.55 | S1/S2 | 40/60 | W-1 | 0.05 | 4.0 | 11.4 | Rectangular |
| 40 | P-26 | 98.47 | None | | TPI | 1.48 | S1/S2 | 40/60 | W-1 | 0.05 | 4.0 | 11.9 | Rectangular |
| Compar. 3 | P-22 | 98.91 | None | | TPI | 1.04 | S1/S2 | 40/60 | W-1 | 0.05 | 4.0 | 16.8 | Rectangular |

The meanings of the abbreviations appearing in Tables above are as follows.

[Photoacid Generator]

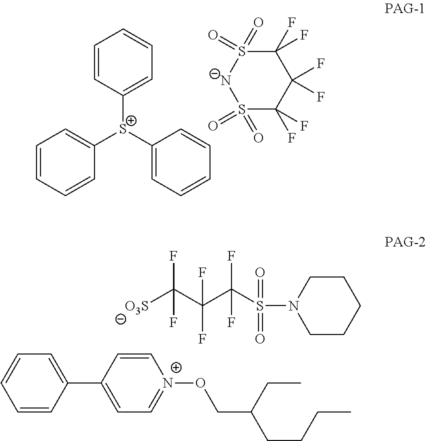

[Basic Compound]

TBAH: tetrabutylammonium hydroxide,

TOA: tri(n-octyl)amine, and

TPI: triphenylimidazole.

[Surfactant]

W-1: Megafac F176 (produced by Dainippon Ink & Chemicals, Inc., fluorinated),

W-2: Megafac R08 (produced by Dainippon Ink & Chemicals, Inc., fluorinated and siliconized),

W-3: polysiloxane polymer (produced by Shin-Etsu Chemical Co., Ltd., siliconized), and

W-4: PF6320 (produced by Omnova Solutiond, INC., fluorinated).

[Solvent]

S1: propylene glycol monomethyl ether acetate (PGMEA; 1-methoxy-2-acetoxypropane),

S2: propylene glycol monomethyl ether (PGME; 1-methoxy-2-propanol),

S3: ethyl lactate.

It is apparent from the results of foregoing tables that the actinic-ray- or radiation-sensitive resin compositions of the present invention are satisfactory in all the high sensitivity, high resolution, good pattern configuration, and good line edge roughness.

It is also apparent that the actinic-ray- or radiation-sensitive resin compositions of the present invention simultaneously satisfy the requirements for high sensitivity and good pattern configuration under EUV exposure.

What is claimed is:

1. An actinic-ray- or radiation-sensitive resin composition comprising a resin (P) containing a repeating unit (A) that is configured to decompose when exposed to actinic rays or radiation to thereby generate an acid, the repeating unit (A) containing a cation structure with a monocyclic or polycyclic heterocycle containing a nitrogen atom.

2. The composition according to claim 1, wherein the cation structure contains an azinium cation.

3. The composition according to claim 1, wherein the cation structure is represented by any of general formula (AZ) below. 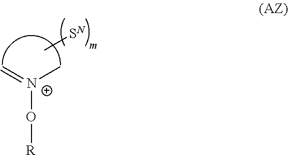
wherein
R represents a monovalent substituent,
the moiety: 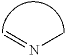
represents a monocyclic or polycyclic heterocycle containing a nitrogen atom,
S^{N} represents a substituent, and
m is an integer of 0 or greater.

4. The composition according to claim 1, wherein the resin (P) further contains a repeating unit (B) that is configured to decompose when acted on by an acid to thereby generate an alkali-soluble group.

5. The composition according to claim 1, wherein the resin (P) further contains a repeating unit represented by any of general formula (IV) below 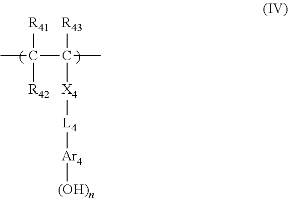
In the formula,
each of R₄₁, R₄₂ and R₄₃ independently represents a hydrogen atom, an alkyl group, a cycloalkyl group, a halogen atom, a cyano group or an alkoxycarbonyl group, provided that R₄₂ may be bonded to Ar₄ to thereby form a ring (preferably a 5- or 6-membered ring), which R₄₂ in this instance is an alkylene group.
X₄ represents a single bond, —COO—, or —CONR₆₄— in which R₆₄ represents a hydrogen atom or an alkyl group.
L₄ represents a single bond or an alkylene group.
Ar₄ represents a bivalent aromatic ring group; and
n is an integer of 1 to 4.

6. The composition according to claim 1, wherein the repeating unit (A) is configured to decompose when exposed to actinic rays or radiation to thereby generate an acid group in a side chain of the resin (P).

7. The composition according to claim 1, which is to be used as a positive resist composition.

8. The composition according to claim 1, which is to be exposed to electron beams, X-rays or soft X-rays.

9. A resist film formed from the composition according to claim 1.

10. A method of forming a pattern, comprising:
forming the composition according to claim 1 into a film,
exposing the film to light, and
developing the exposed film.

11. The method according to claim 10, wherein the exposure is performed using electron beams, X-rays or soft X-rays.
